(19) United States
(12) Patent Application Publication
(10) Pub. No.: US 2025/0127055 A1
(43) Pub. Date: Apr. 17, 2025

(54) LIGHT-EMITTING ELEMENT, DISPLAY DEVICE, AND FUSED POLYCYCLIC COMPOUND FOR THE LIGHT-EMITTING ELEMENT

(71) Applicant: Samsung Display Co., Ltd., Yongin-si (KR)

(72) Inventors: TAEIL KIM, Yongin-si (KR); SUN YOUNG PAK, Yongin-si (KR); JUNHA PARK, Yongin-si (KR); MinJae SUNG, Yongin-si (KR); MUN-KI SIM, Yongin-si (KR); CHANSEOK OH, Yongin-si (KR); MINJUNG JUNG, Yongin-si (KR); Giwoong HAN, Yongin-si (KR); Seonhyoung HUR, Yongin-si (KR)

(21) Appl. No.: 18/736,353

(22) Filed: Jun. 6, 2024

(30) Foreign Application Priority Data
Jul. 21, 2023 (KR) 10-2023-0095394

(51) Int. Cl. H10K 85/60; C07F 5/02; C09K 11/06; H10K 50/12

(52) U.S. Cl. CPC H10K 85/658; C07F 5/027; C09K 11/06; C07B 2200/05; C09K 2211/1018; H10K 50/12

(57) ABSTRACT

A light-emitting element including a first electrode, a second electrode provided on the first electrode, and an emission layer provided between the first electrode and the second electrode, a display device and a fused polycyclic compound are provided. The emission layer includes a fused polycyclic compound that may be a dopant material (e.g., thermally activated delayed fluorescence dopant). The emission layer may further include second to fourth compounds.

The fused polycyclic compound has a pentacyclic core that includes three aromatic rings fused by one boron and two nitrogen atoms. At least one substituent on the pentacyclic core is an electron-donating, tricyclic fused ring and is connected at a para-position with respect to boron. Due to steric demand the molecular shape of the fused polycyclic compound becomes twisted, which results in modulation of the difference between singlet and triplet energy states and the rate of reverse inter-system crossing of the fused polycyclic compound.

### CROSS-REFERENCE TO RELATED APPLICATION

The present application claims priority to and the benefit of Korean Patent Application No. 10-2023-0095394, filed on Jul. 21, 2023, in the Korean Intellectual Property Office, the entire content of which is incorporated herein by reference.

### BACKGROUND

### 1. Field

The present disclosure herein relates to a light-emitting element, a display device, and a fused polycyclic compound utilized in the light-emitting element.

### 2. Description of the Related Art

Recently, organic electroluminescence display devices and/or the like have been actively developed and/or pursued as image display devices. Organic electroluminescence display devices are different from liquid crystal display devices and are so-called “self-luminous” type or kind display devices. For example, in a light emitting material within an emission layer (e.g., light-emitting layer), holes and electrons, respectively, injected from a first electrode and a second electrode, are recombined. Subsequently, the light-emitting material of the emission layer emits light to accomplish (e.g., implement display (e.g., of an image).

Implementation of organic electroluminescence elements to display devices requires, (or there is a desire or demand for), organic electroluminescence elements having a low driving voltage, a high luminous efficiency, and a long lifespan, and/or the like. Therefore, the need or desire exists for development of materials, for organic electroluminescence elements capable of stably attaining such characteristics or desires.

For example, in recent years, to provide or achieve an organic electroluminescence element having a high efficiency and a long-lifespan, development of phosphorescence emission, utilizing triplet state energy, and/or fluorescence emission, utilizing triplet-triplet annihilation (TTA) (e.g., in which singlet excitons are generated through collision of triplet excitons) has been conducted and/or pursued. Another technology under development is thermally activated delayed fluorescence (TADF) materials (e.g., utilizing a delayed fluorescence phenomenon).

### SUMMARY

One or more aspects of embodiments of the present disclosure is directed toward a light-emitting element having improved luminous efficiency and/or element lifespan.

One or more aspects of embodiments of the present disclosure is directed toward a display device having improved luminous efficiency and/or element lifespan.

One or more aspects of embodiments of the present disclosure is directed toward a fused polycyclic compound capable of improving luminous efficiency and/or element lifespan. Additional aspects will be set forth in part in the description which follows and, in part, will be apparent from the description, or may be learned by practice of the presented embodiments of the disclosure.

One or more embodiments of the present disclosure provides a light-emitting element including a first electrode, a second electrode facing the first electrode, and an emission layer provided between the first electrode and the second electrode, wherein the emission layer comprises (e.g., contains) a first compound represented by Formula 1.

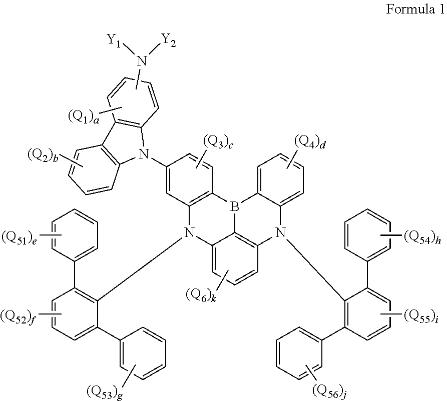

In Formula 1, b and d may each independently be an integer of 0 to 4, a, c, f, i, and k may each independently be an integer of 0 to 3, e, g, h, and j may each independently be an integer of 0 to 5, Q₁ to Q₃, and Q₅₁ to Q₅₆ may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be boned to an adjacent group to form a ring, Q₄ may be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted silyl group, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring, Q₆ may be a hydrogen atom, a deuterium atom, a substituted or unsubstituted alkyl group having 1 to 20 carbon atoms, a substituted or unsubstituted cycloalkyl group having 5 to 30 ring-forming carbon atoms, a substituted or unsubstituted aryl group having 6 to 30 ring-forming carbon atoms, a substituted or unsubstituted heteroaryl group having 2 to 30 ring-forming carbon atoms, a substituted or unsubstituted germyl group, or a substituted or unsubstituted silyl group, Y₁ and Y₂ may each independently be a hydrogen atom, a deuterium atom, a substituted or unsubstituted alkyl group having 1 to 20 carbon atoms, a substituted or unsubstituted cycloalkyl group having 5 to 30 ring-forming carbon atoms, a substituted or unsubstituted alkoxy group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In one or more embodiments, the first compound represented by Formula 1 may be represented by Formula 1-1.

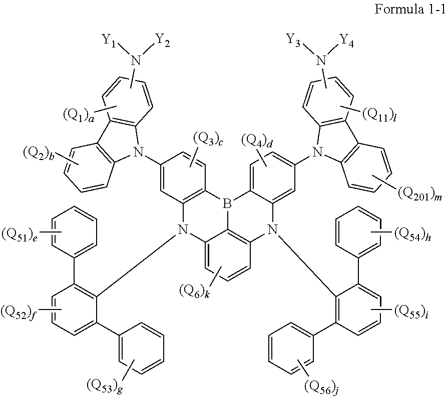

In Formula 1-1, I and d₁ may each independently be an integer of 0 to 3, m may be an integer of 0 to 4, Q₁₁ and Q₂₀₁ may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or a substituted or unsubstituted amine group, and/or may be bonded to an adjacent group to form a ring, Y₃ and Y₄ may each independently be a hydrogen atom, a deuterium atom, a substituted or unsubstituted alkyl group having 1 to 20 carbon atoms, a substituted or unsubstituted cycloalkyl group having 5 to 30 ring-forming carbon atoms, a substituted or unsubstituted alkoxy group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or is bonded to an adjacent group to form a ring, and Y₁, Y₂, Q₁ to Q₄, Q₅₁ to Q₅₆, Q₆, a to c, and e to k may each independently be as defined in Formula 1.

In one or more embodiments, the first compound represented by Formula 1 may be represented by at least one selected from among Formula 2-1 to Formula 2-10.

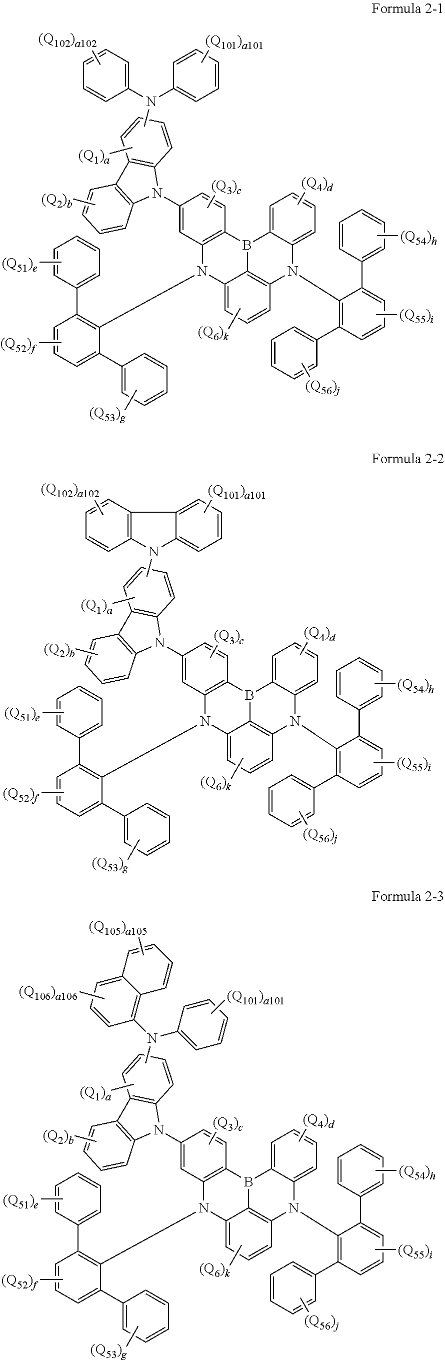

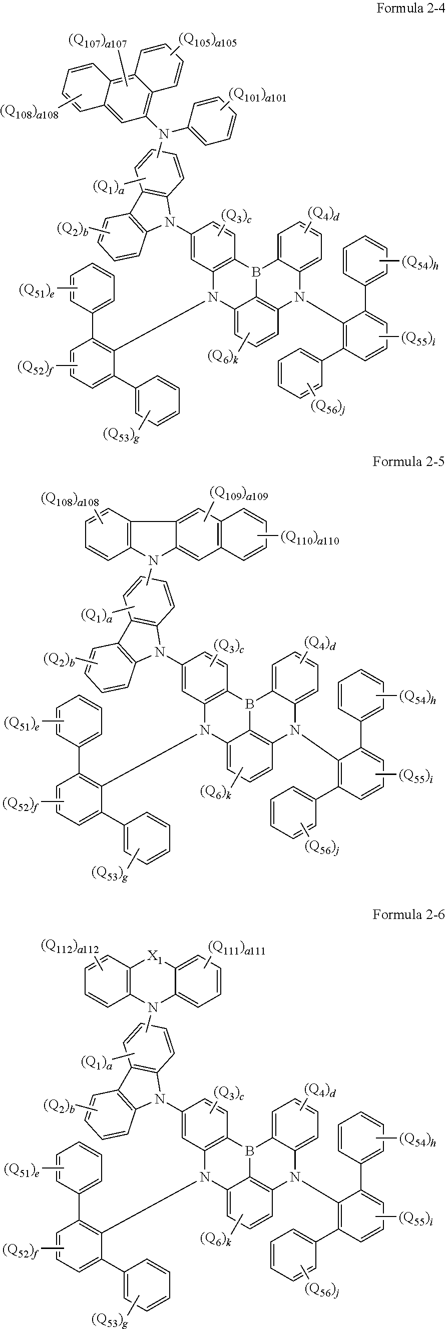

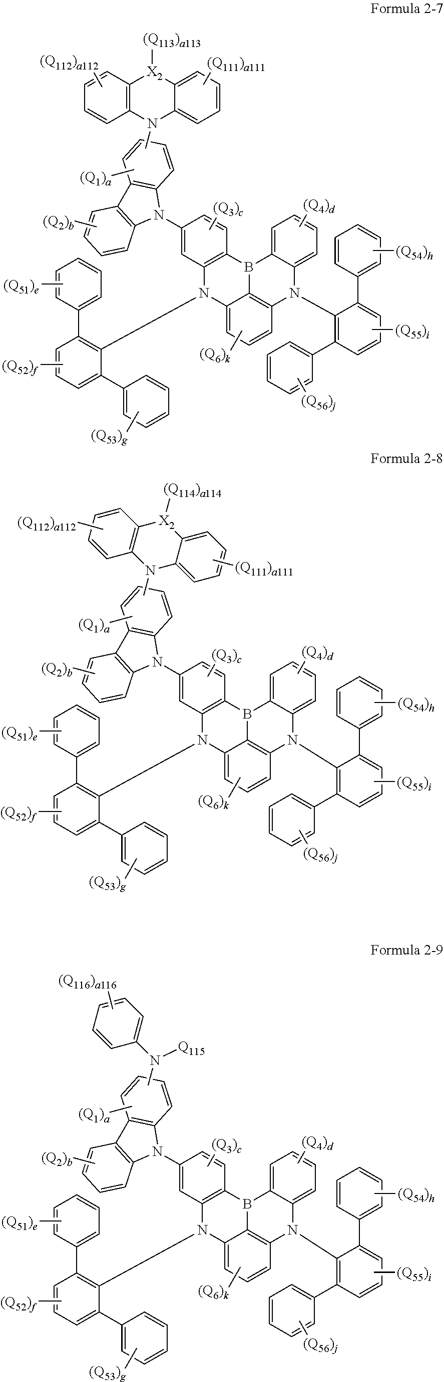

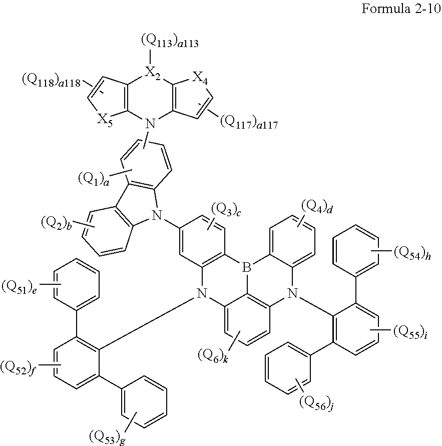

In Formula 2-1 to Formula 2-10, a₁₀₁, a₁₀₂, and a₁₁₆ may each independently be an integer of 0 to 5, a₁₀₃, a₁₀₄, a₁₀₅, a₁₀₈, a₁₁₀, a₁₁₁, and a₁₁₂ may each independently be an integer of 0 to 4, a₁₀₆ may be an integer of 0 to 3, a₁₀₉, a₁₁₄, a₁₁₇, a₁₁₈, and a₁₁₉ may each independently be an integer 0 to 2, a₁₀₇ and a₁₁₃ may each independently be 0 or 1, Q₁₀₁ to Q₁₁₂, and Q₁₁₆ to Q₁₁₉ may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or a substituted or unsubstituted amine group, and/or may be bonded to an adjacent group to form a ring, Q₁₁₃ to Q₁₁₅ may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring, X₁, X₄, and X₅ may each independently be an oxygen atom, a sulfur atom, a selenium atom, or a tellurium atom, X₂ may be a nitrogen atom, X₃ may be a carbon atom, a silicon atom, or germanium atom, and Q₁ to Q₄, Q₅₁ to Q₅₆, Q₆, and a to k may each independently be as defined in Formula 1.

In one or more embodiments, the first compound represented by Formula 1 may be represented by Formula 3.

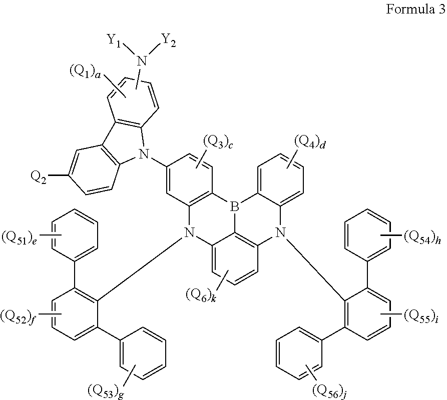

In Formula 3, Y₁, Y₂, Q₁ to Q₄, Q₅₁ to Q₅₆, Q₆, a, and c to k may each independently be as defined in Formula 1.

Q₂ may be represented by any one selected from among Formula 3-1 to Formula 3-5.

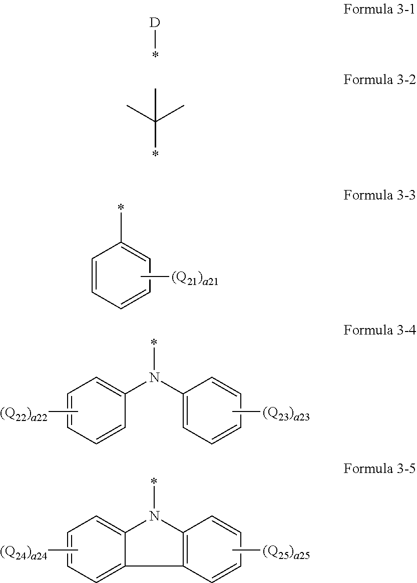

In Formula 3-1, D is a deuterium atom, in Formula 3-3 to Formula 3-5, Q₂₁ to Q₂₅ may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or a substituted or unsubstituted amine group, and/or may be bonded to an adjacent group to form a ring, a₂₁ to a₂₃ may each independently be an integer of 0 to 5, and a₂₄ and a₂₃ may each independently be an integer of 0 to 4, and in Formula 3-1 to Formula 3-5, -* is a position connected to Formula 3.

In one or more embodiments, the first compound represented by Formula 1 may be represented by Formula 4 or Formula 5.

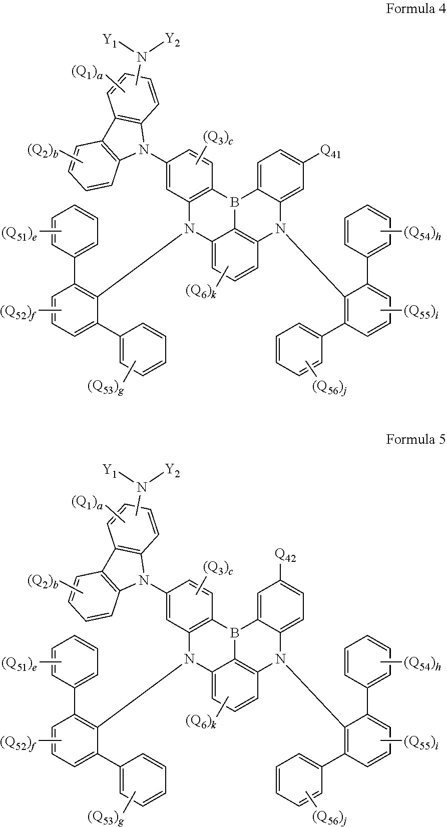

In Formulas 4 and 5, Q₄₁ and Q₄₂ may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or a substituted or unsubstituted amine group, and Y₁, Y₂, Q₁ to Q₃, Q₅₁ to Q₅₆, Q₆, a to c, and e to k may each independently be as defined in Formula 1.

Q₄₁ may be represented by Formula 4-1 or Formula 4-2.

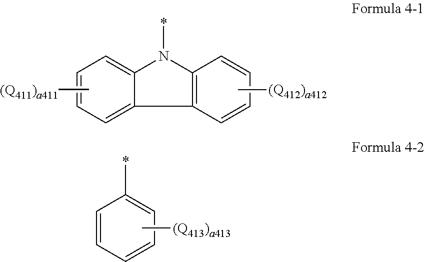

In Formulas 4-1 and 4-2, a₄₁₁ and a₄₁₂ may each independently be an integer of 0 to 4, a₄₁₃ may be an integer of 0 to 5, Q₄₁₁, Q₄₁₂, and Q₄₁₃ may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or a substituted or unsubstituted amine group, and/or may be bonded to an adjacent group to form a ring, and -* is a position connected to Formula 4.

Q₄₂ may be represented by Formula 4-3 or Formula 4-4.

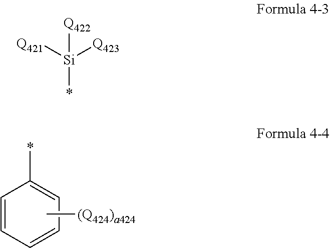

In Formula 4-3 and Formulas 4-4, a₄₂₄ may be an integer of 0 to 5, Q₄₂₁ to Q₄₂₃ may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring, Q₄₂₄ is a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or a substituted or unsubstituted amine group, and/or may be bonded to an adjacent group to form a ring, and -* is a position connected to Formula 5.

In one or more embodiments, the first compound represented by Formula 1 may be represented by Formula 6.

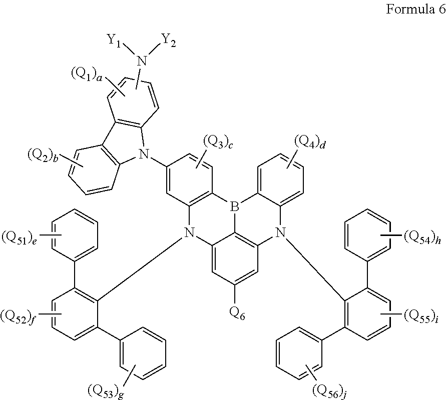

In Formula 6, Y₁, Y₂, Q₁ to Q₄, Q₅₁ to Q₅₆, Q₆, and a to j may each independently be as defined in Formula 1.

Q₆ may be represented by any one selected from among Formula 6-1 to Formula 6-6.

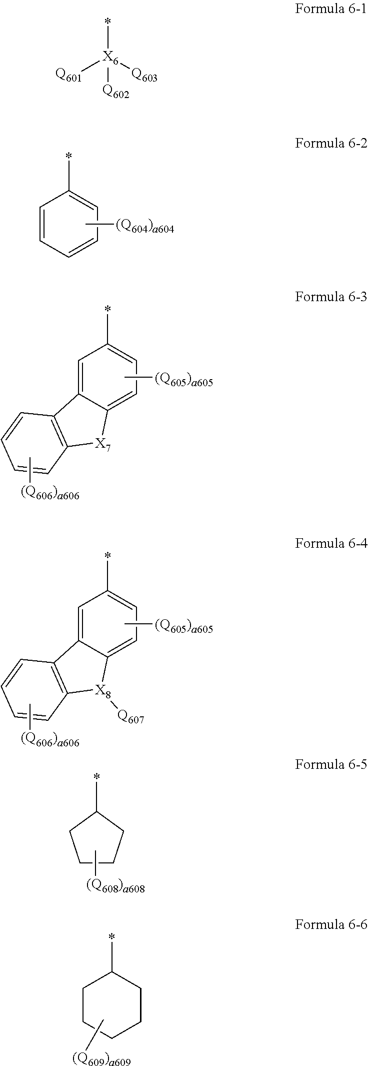

In Formula 6-1 to Formula 6-6, X₆ may be a carbon atom, a silicon atom, or a germanium atom, X₇ may be an oxygen atom, a sulfur atom, a selenium atom, or a tellurium atom, X₈ may be a nitrogen atom, a₆₀₄ may be an integer of 0 to 5, a₆₀₅ may be an integer of 0 to 3, a₆₀₆ may be an integer of 0 to 4, a 608 may be an integer of 0 to 9, a₆₀₉ may be an integer of 0 to 11, Q₆₀₁ to Q₆₀₆, Q₆₀₈ and Q₆₀₉ may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or a substituted or unsubstituted amine group, and/or may be bonded to an adjacent group to form a ring, Q₆₀₇ is a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring, and is a position connected to Formula 6.

In one or more embodiments, the compound represented by Formula 1 may be represented by at least one selected from among compounds in Compound Group 1.

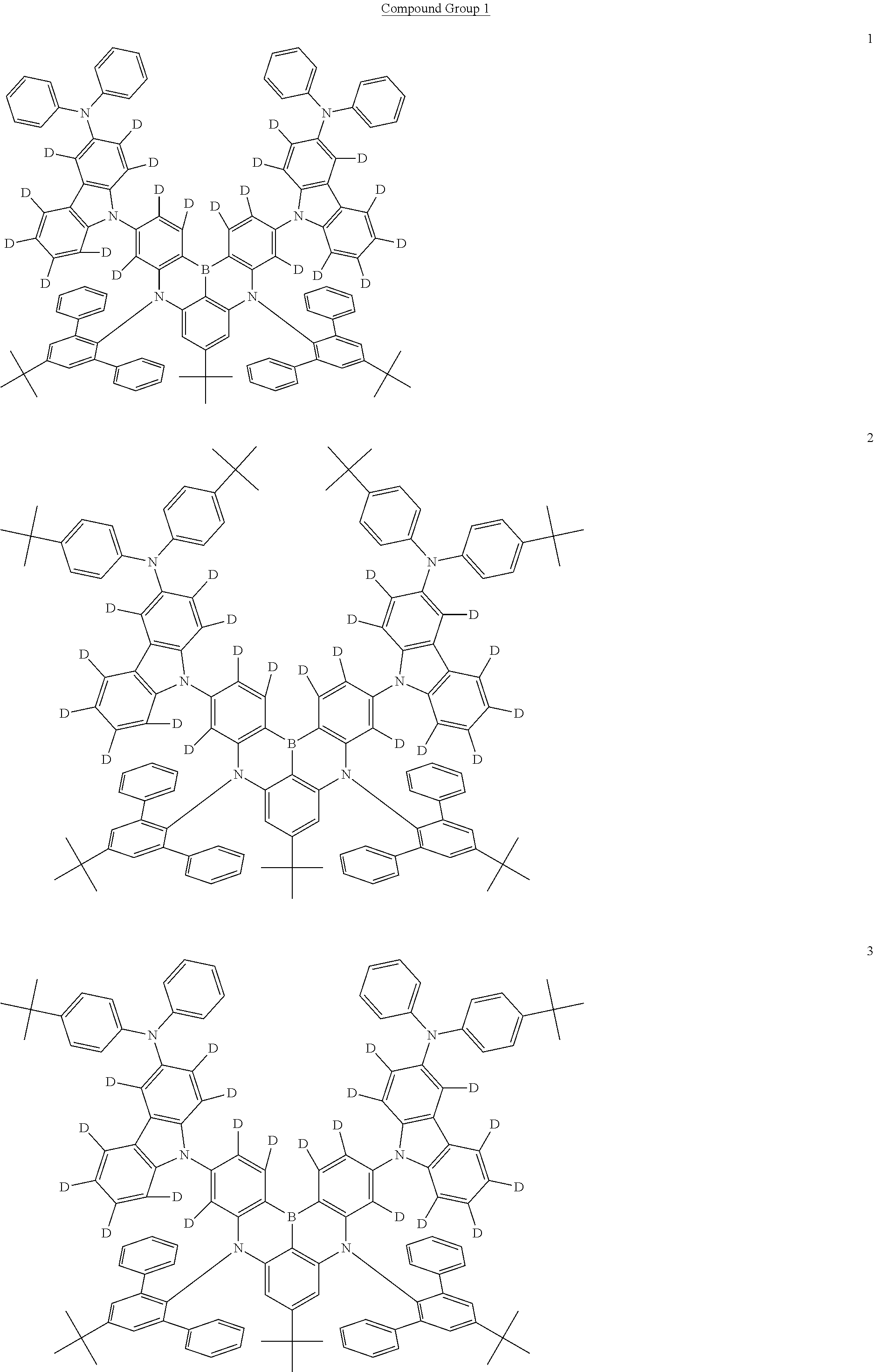

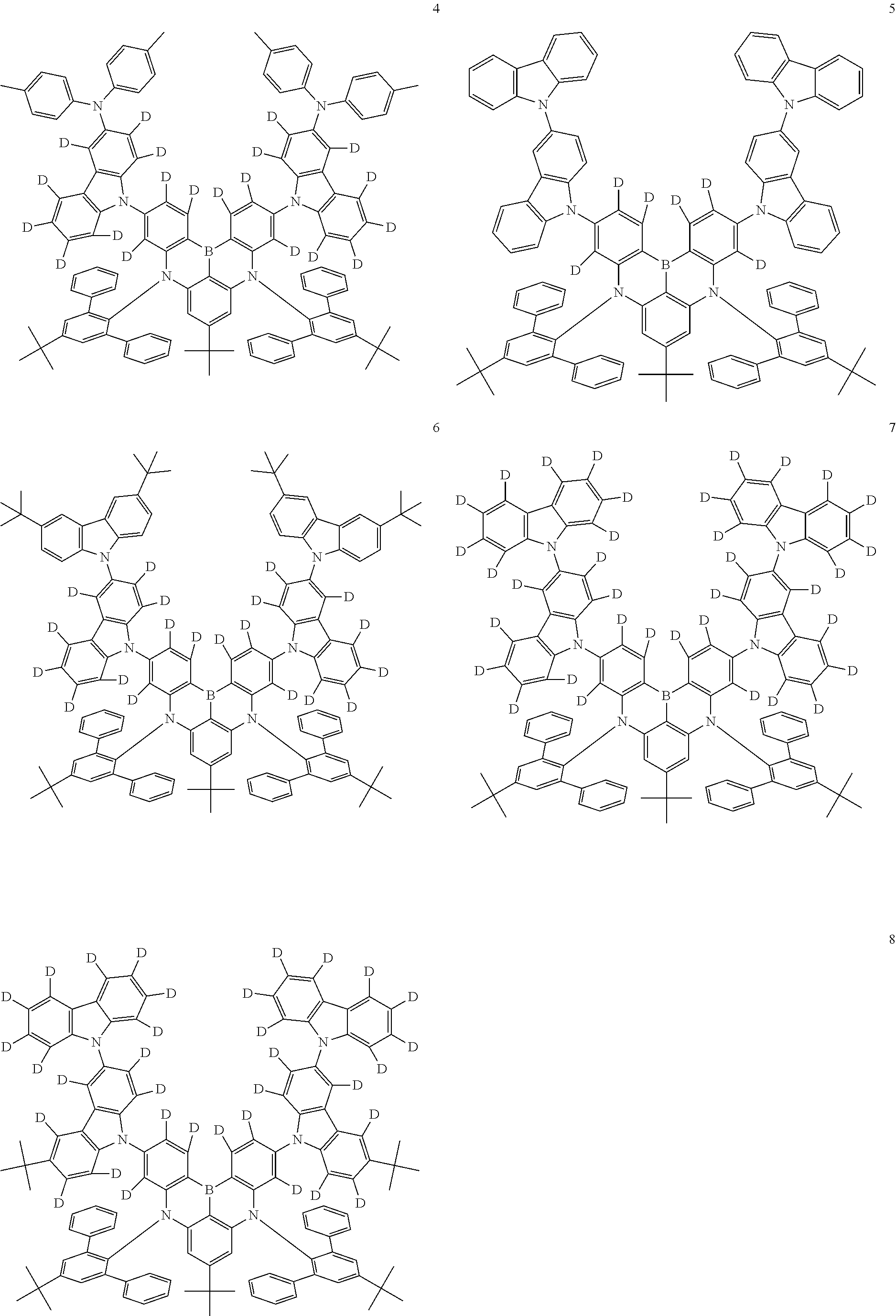

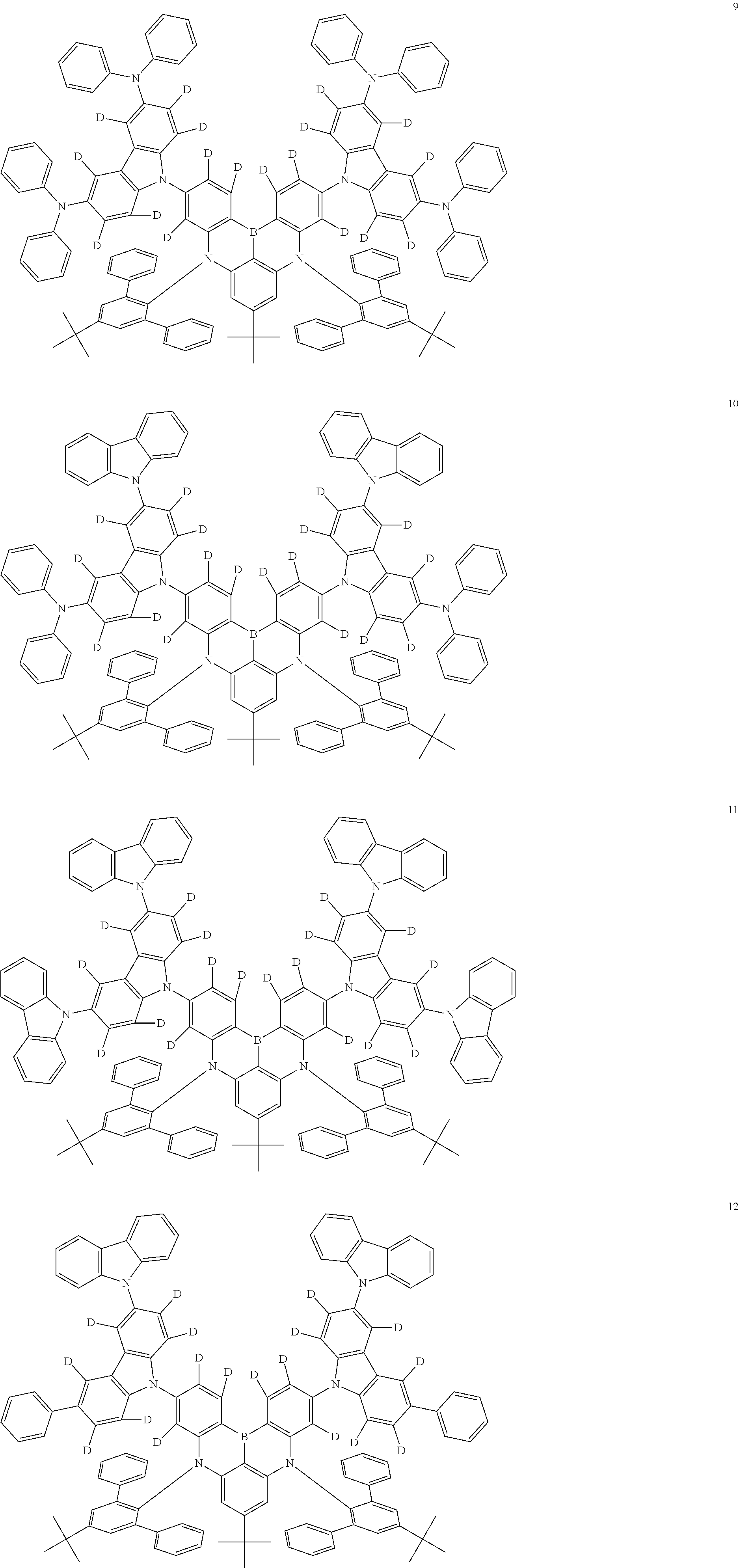

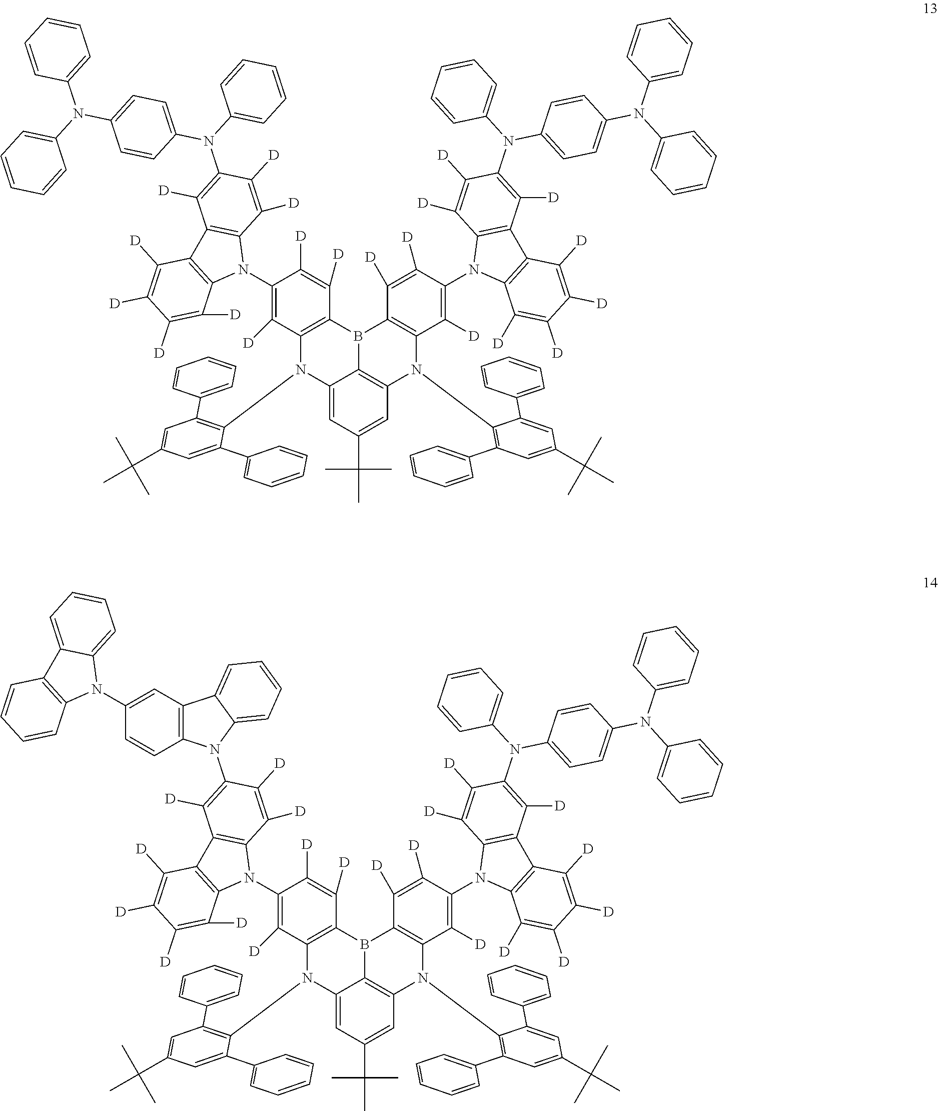

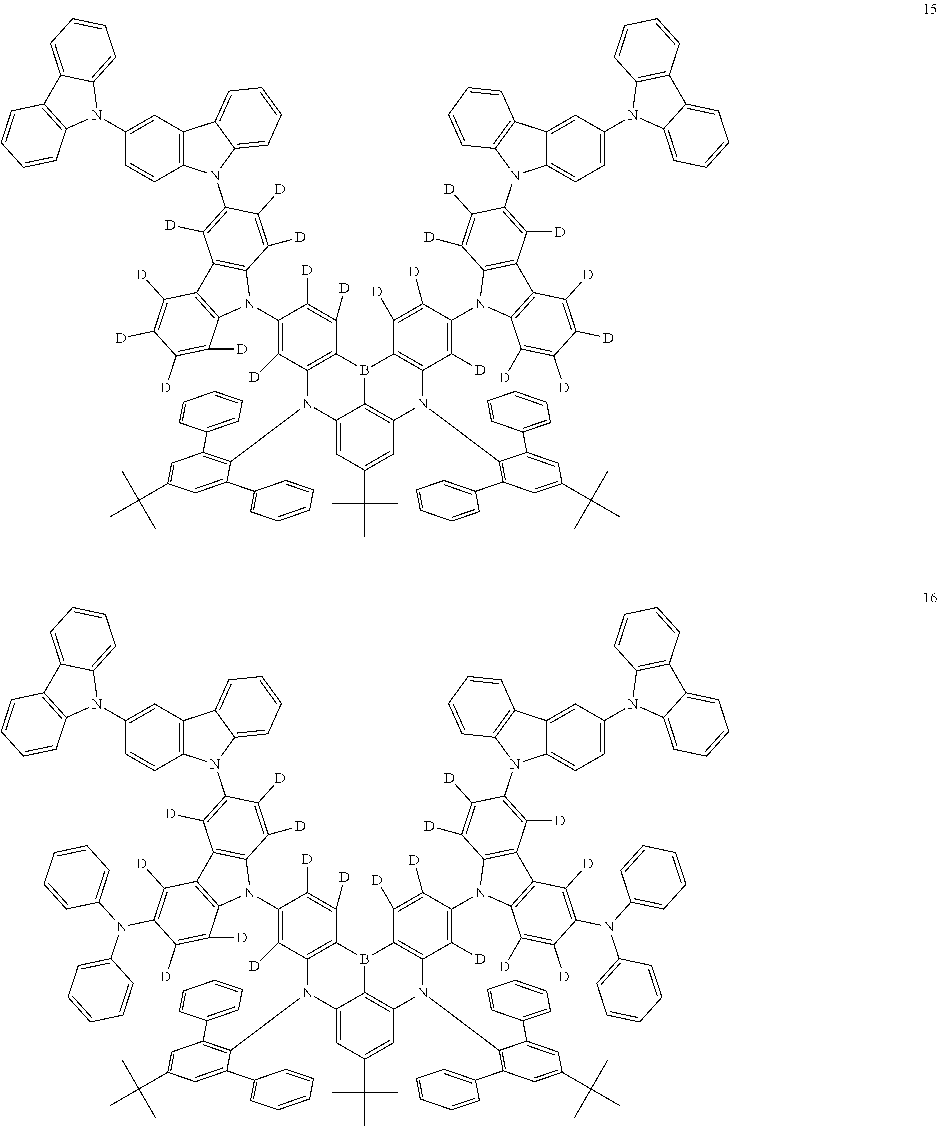

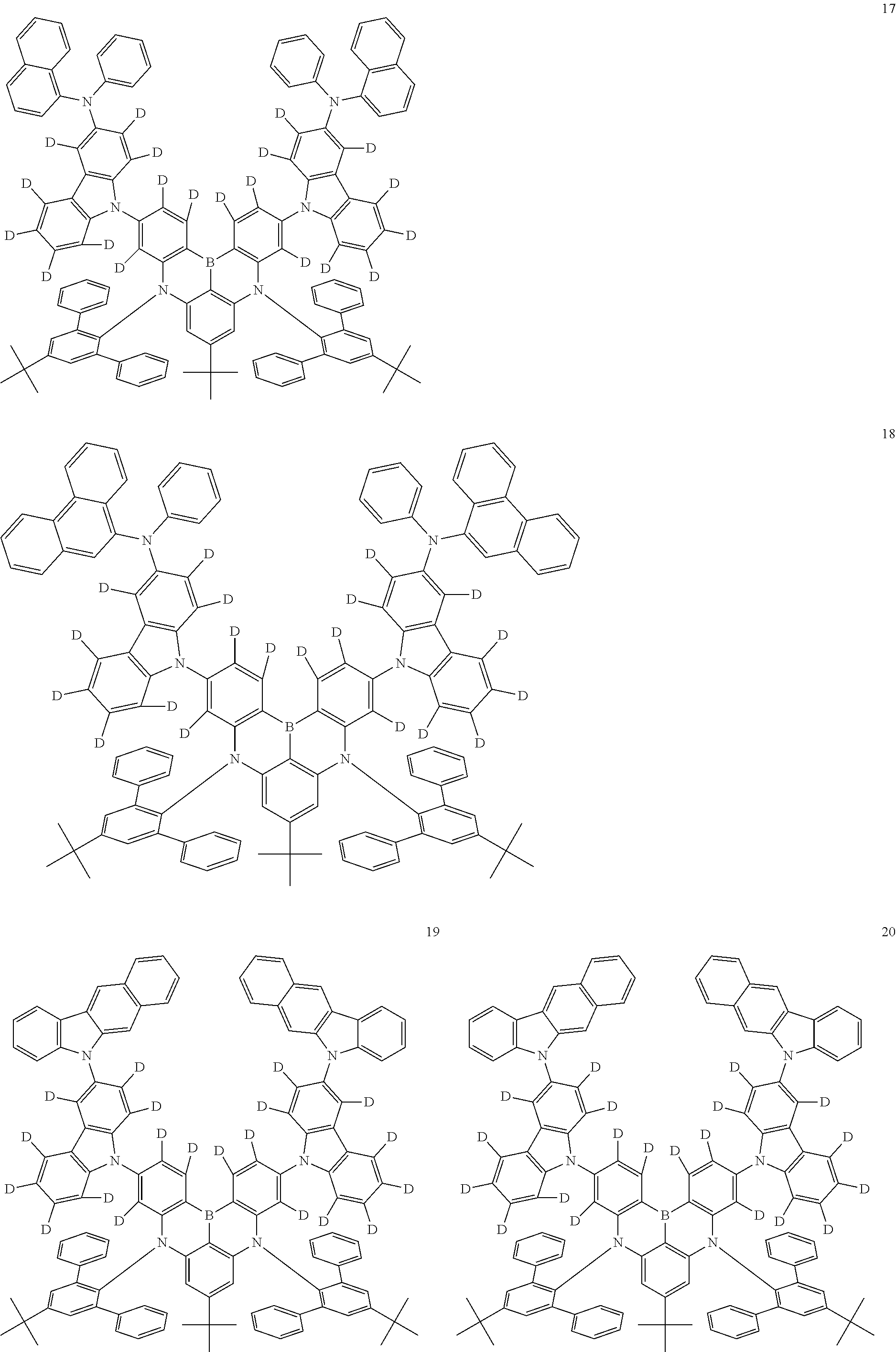

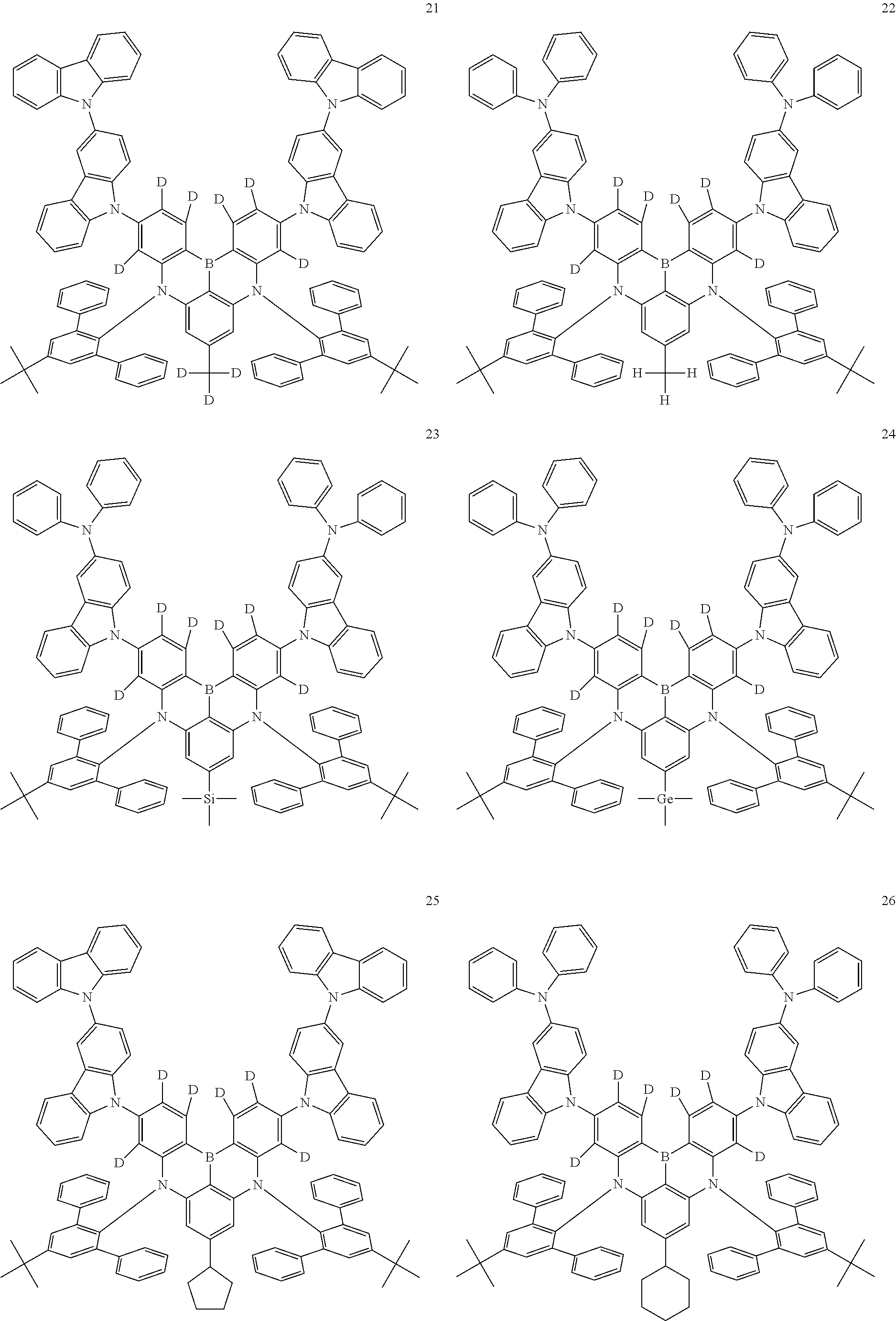

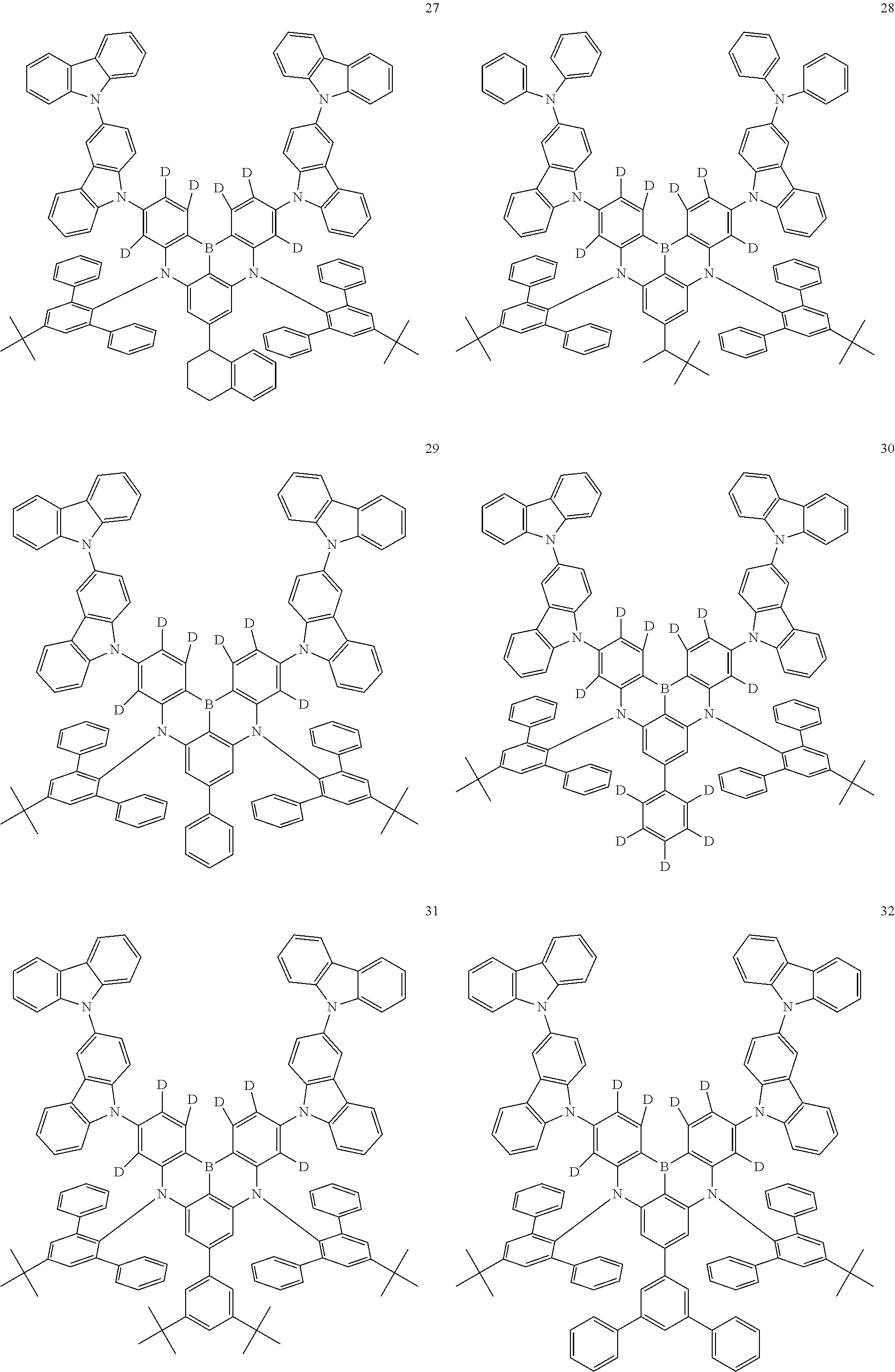

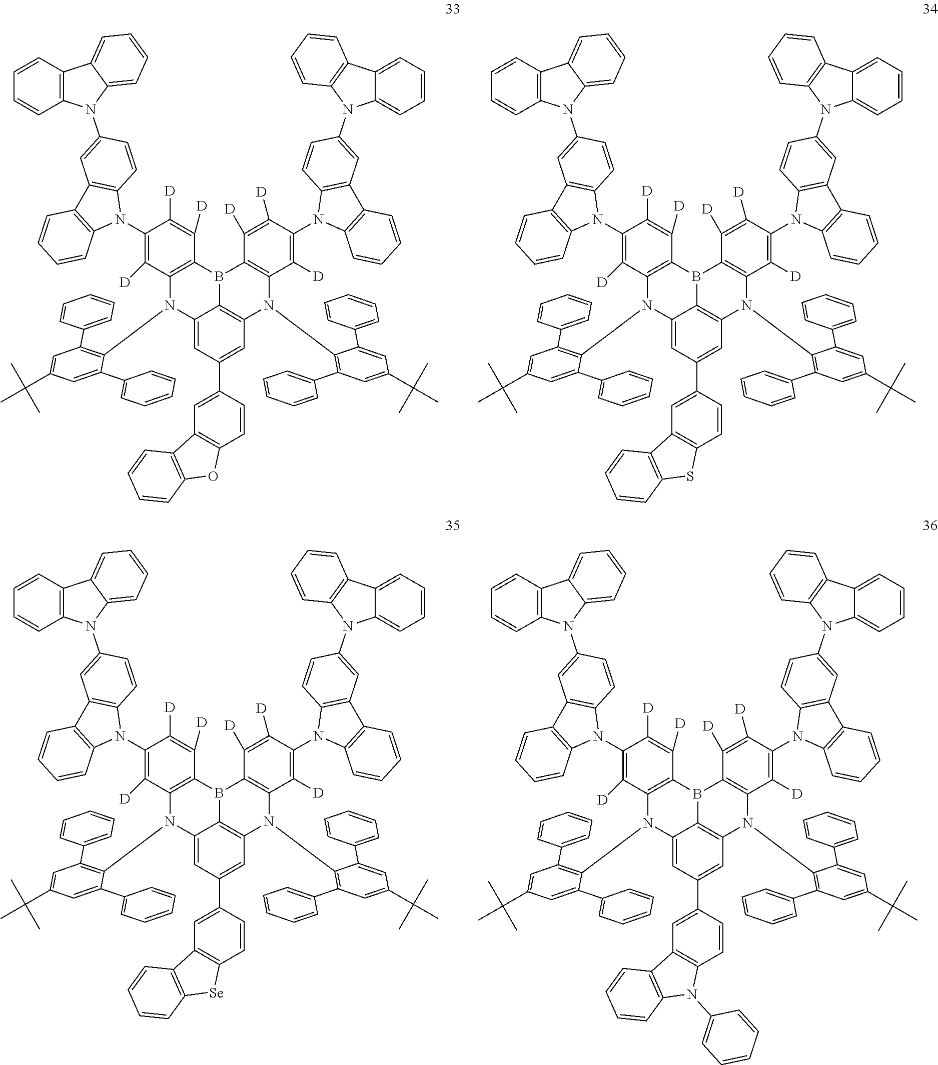

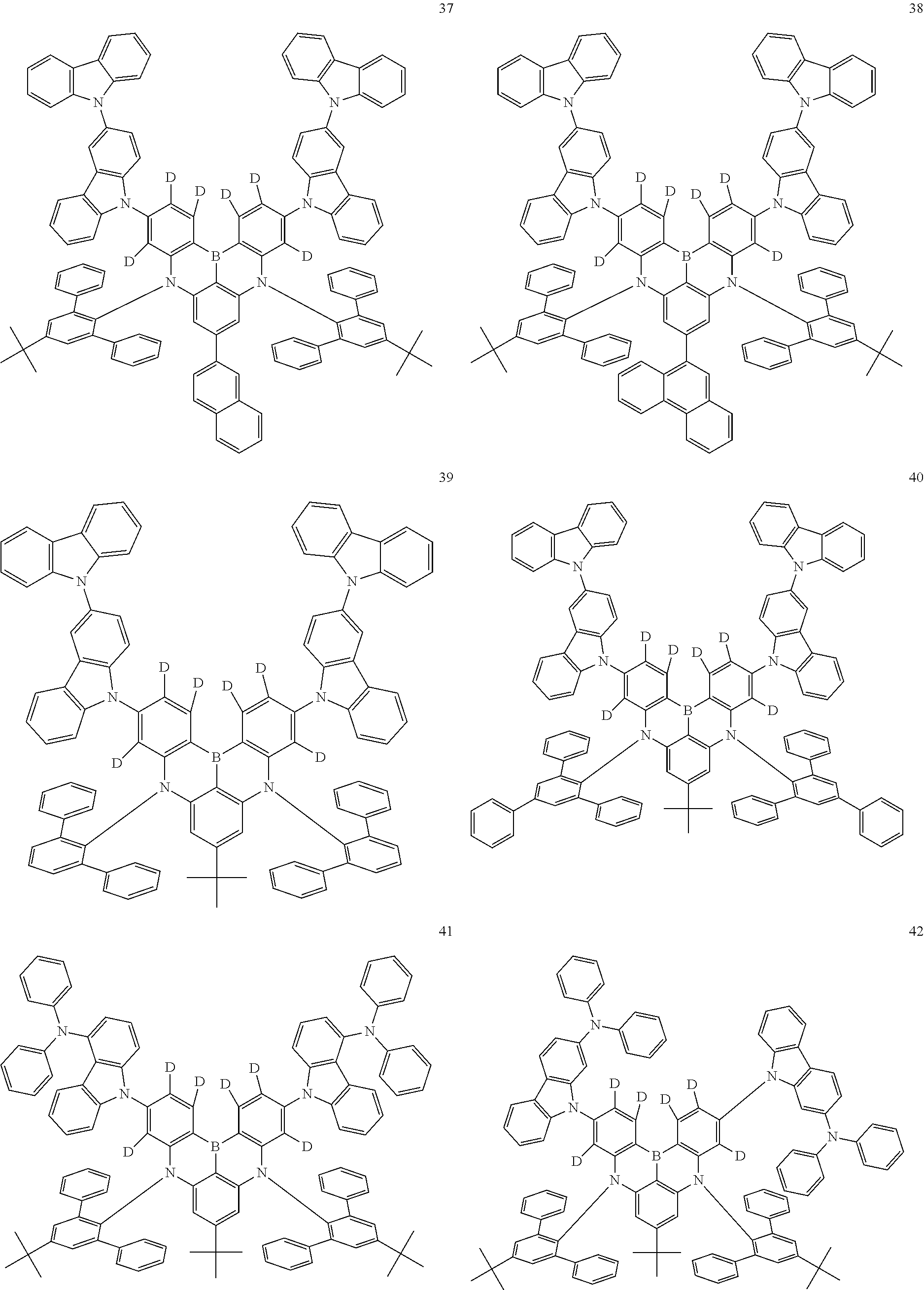

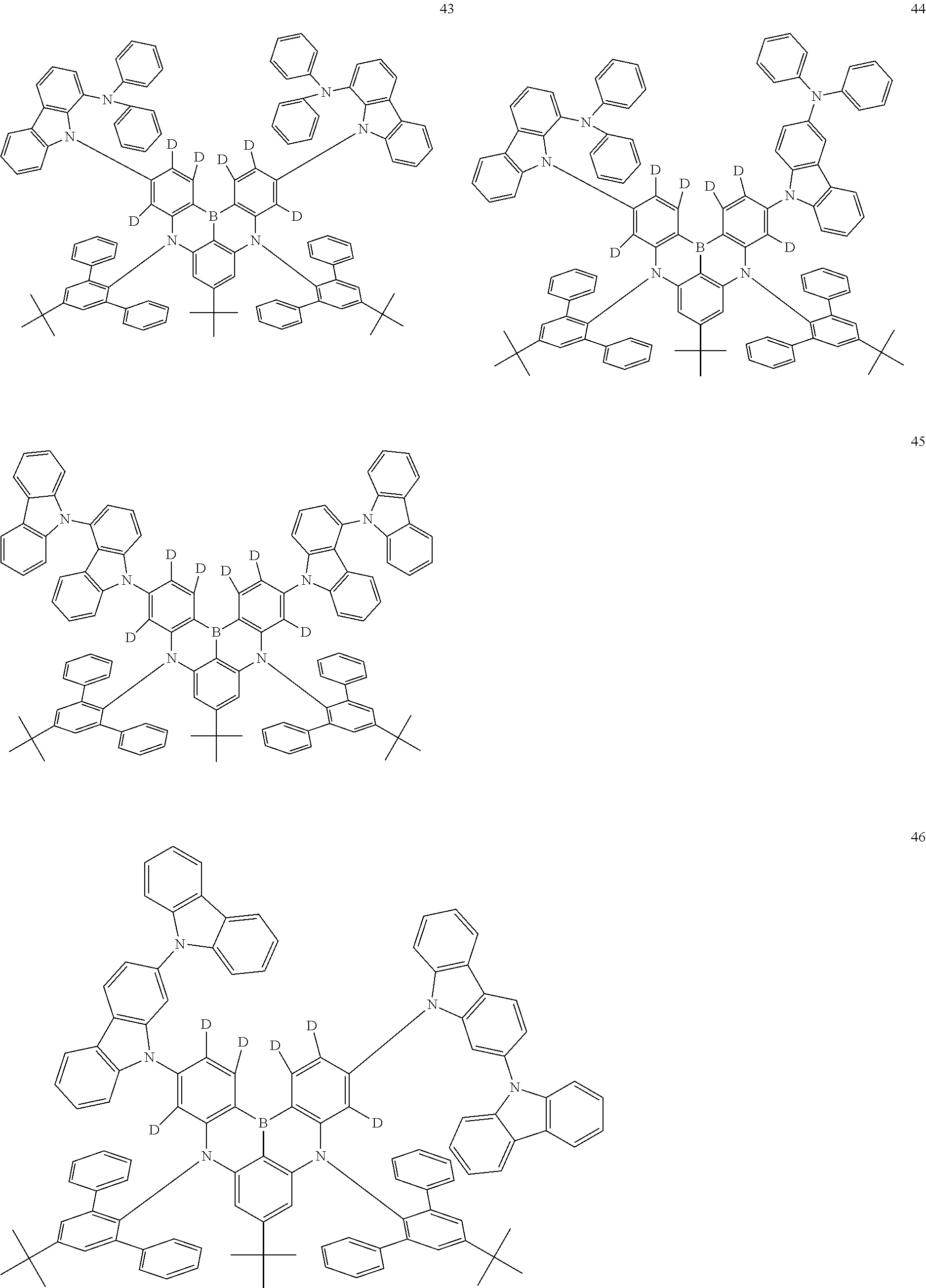

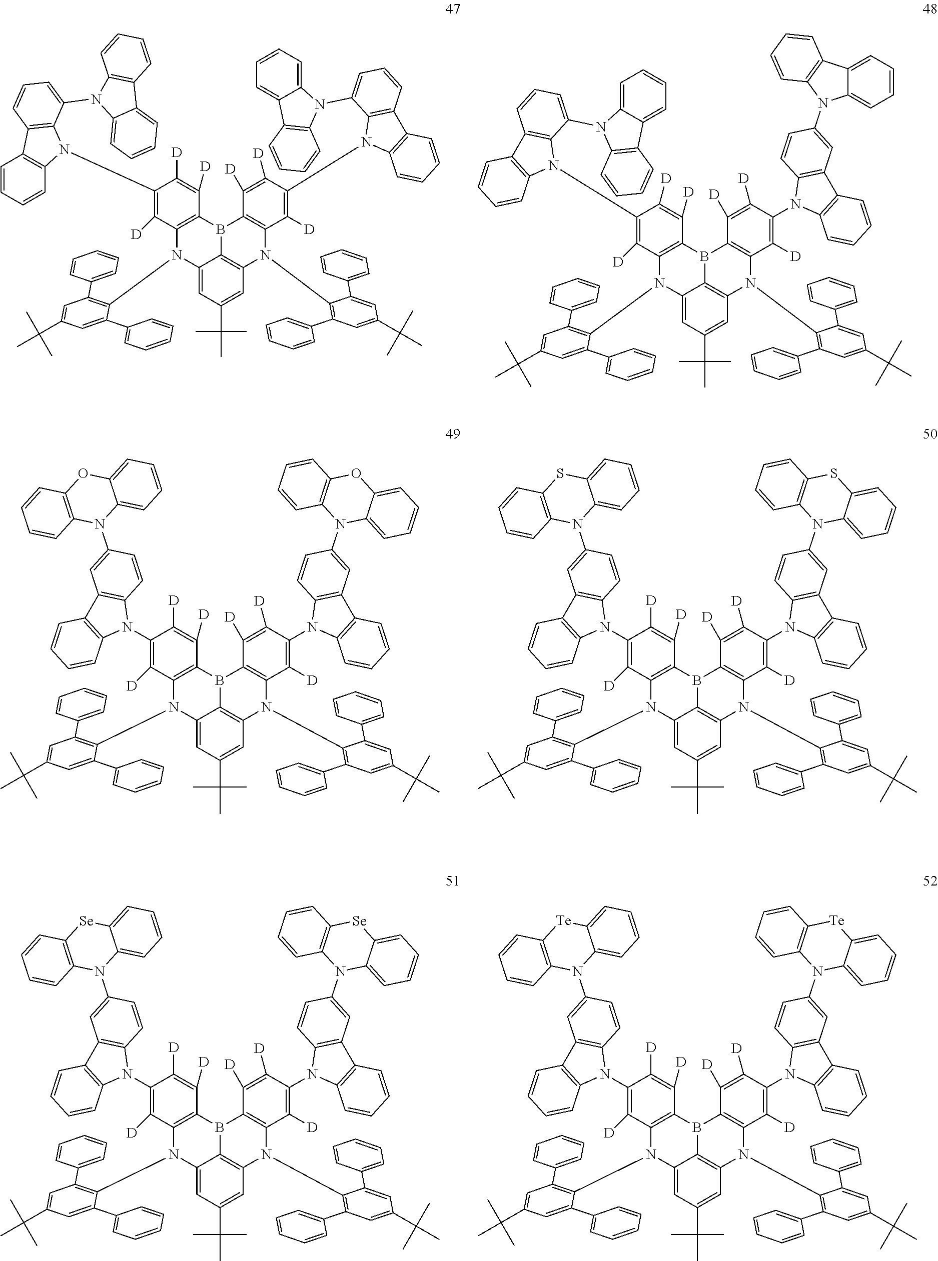

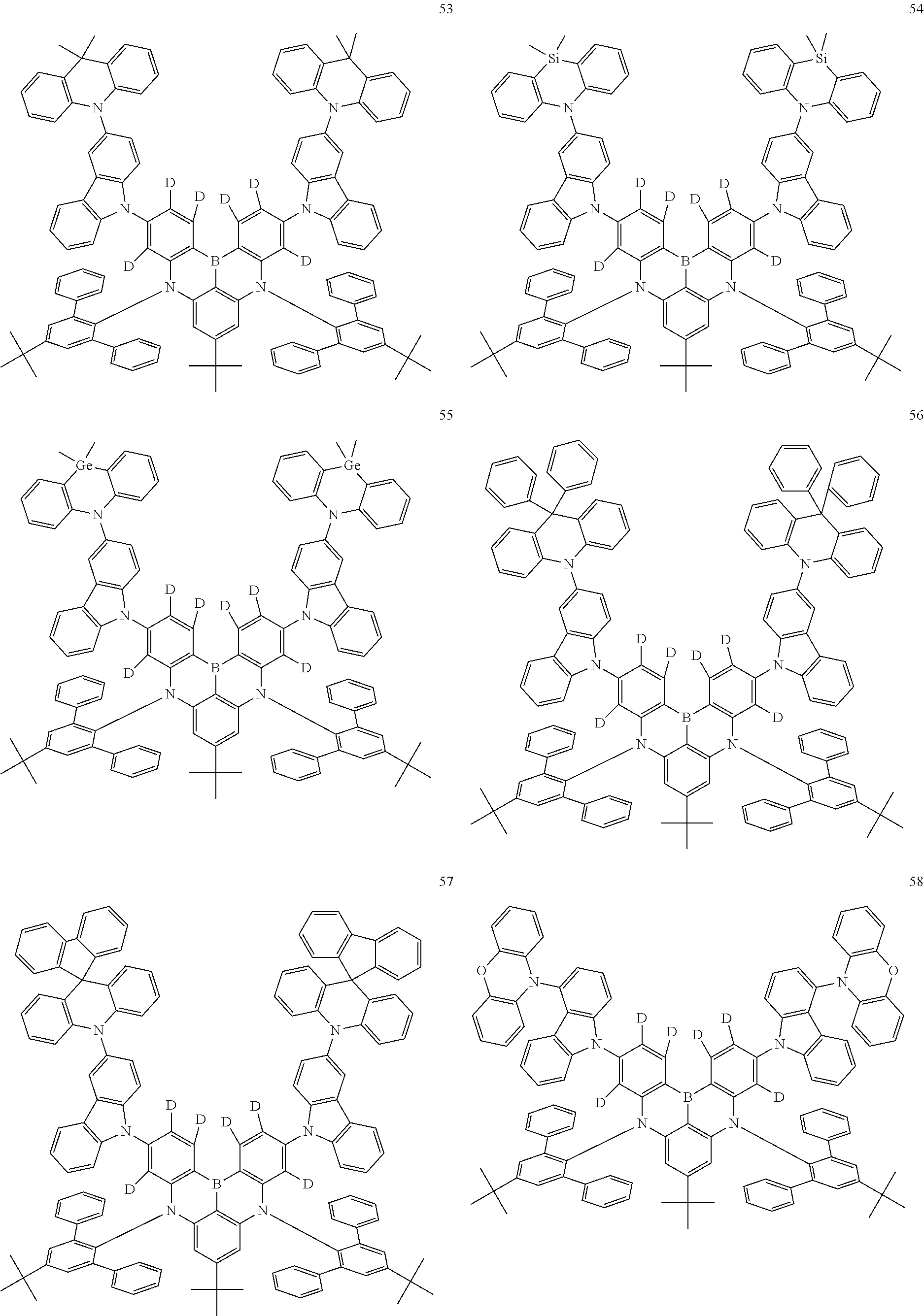

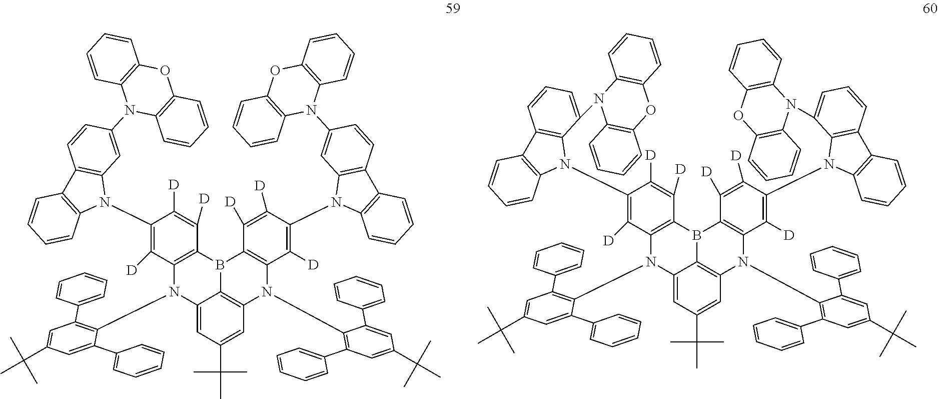 [SMILES: [2H]c1c([2H])c(-n2c3ccccc3c3ccc(N4c5ccccc5Oc5ccccc54)cc32)c([2H])c2c1B1c3c(cc(C(C)(C)C)cc3N(c3c(-c4ccccc4)cc(C(C)(C)C)cc3-c3ccccc3)c3c([2H])c(-n4c5ccccc5c5ccc(N6c7ccccc7Oc7ccccc76)cc54)c([2H])c([2H])c31)N2c1c(-c2ccccc2)cc(C(C)(C)C)cc1-c1ccccc1 ; [2H]c1c([2H])c(-n2c3ccccc3c3cccc(N4c5ccccc5Oc5ccccc54)c32)c([2H])c2c1B1c3c(cc(C(C)(C)C)cc3N(c3c(-c4ccccc4)cc(C(C)(C)C)cc3-c3ccccc3)c3c([2H])c(-n4c5ccccc5c5cccc(N6c7ccccc7Oc7ccccc76)c54)c([2H])c([2H])c31)N2c1c(-c2ccccc2)cc(C(C)(C)C)cc1-c1ccccc1]

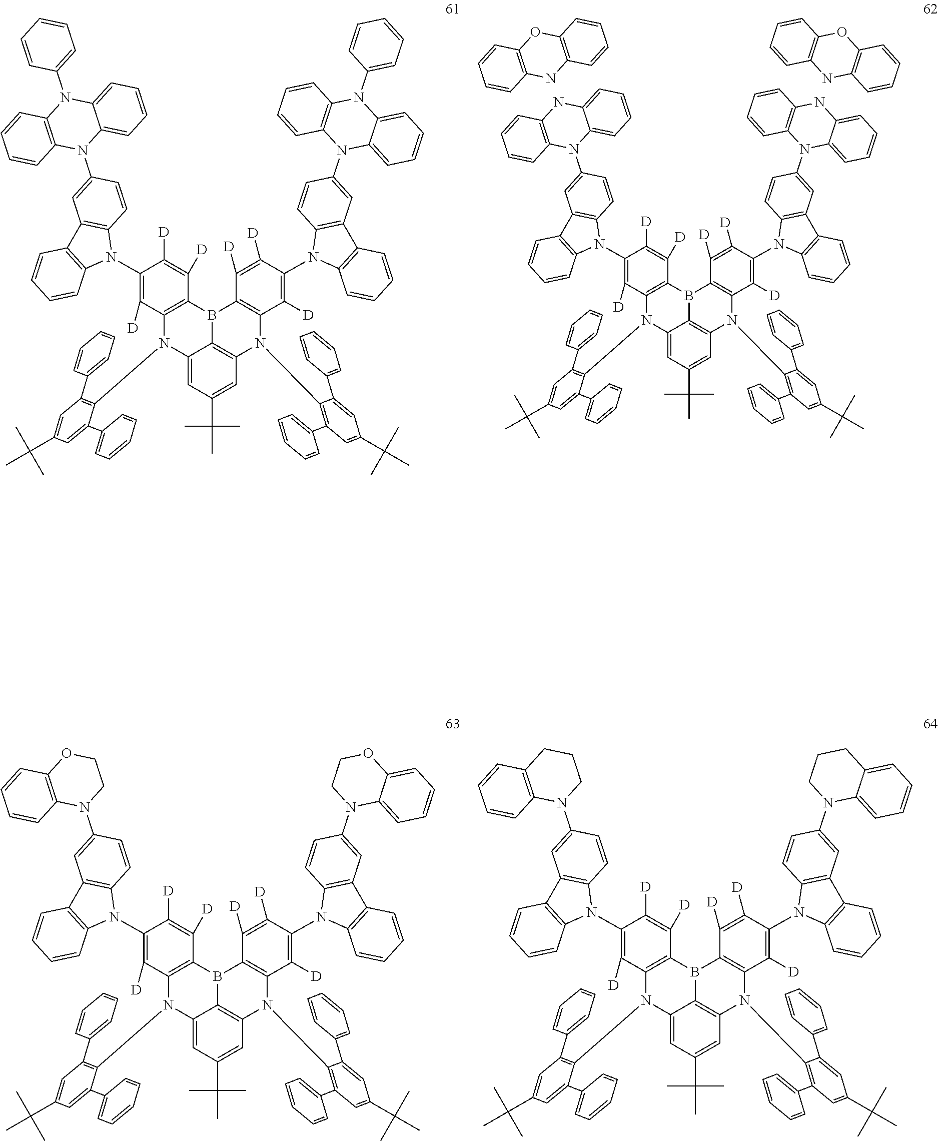

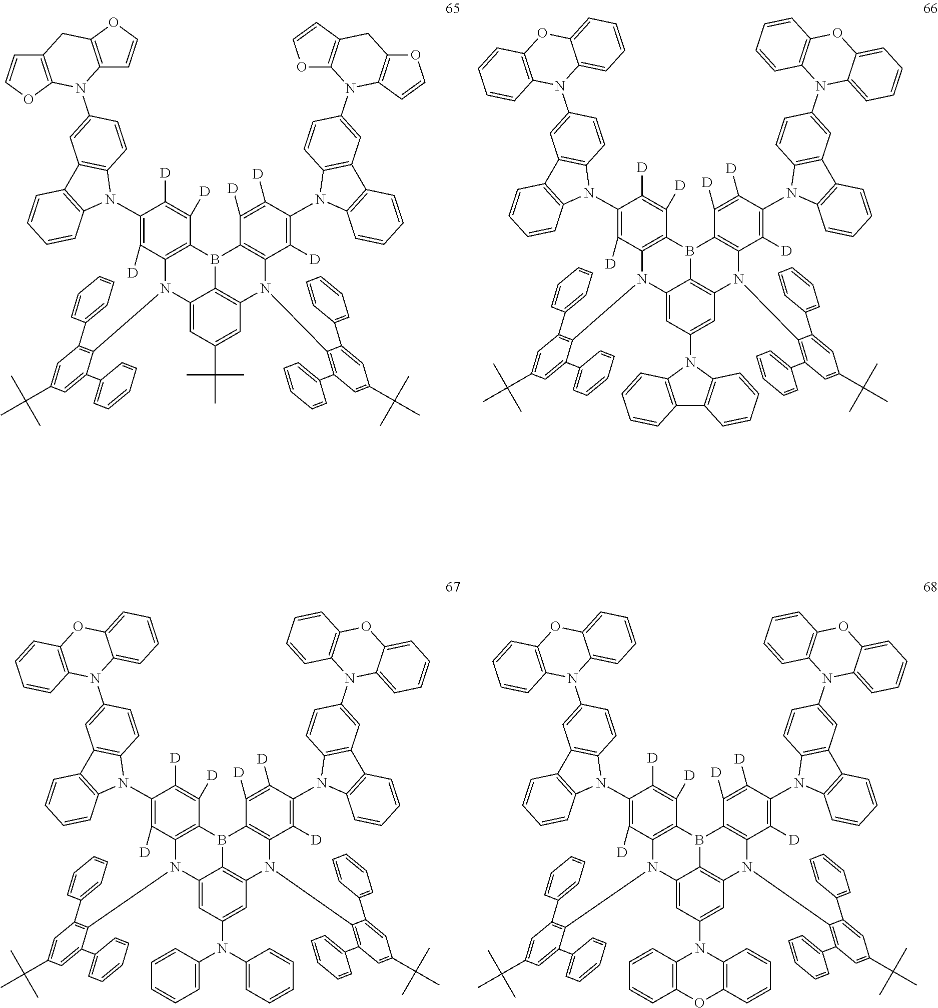

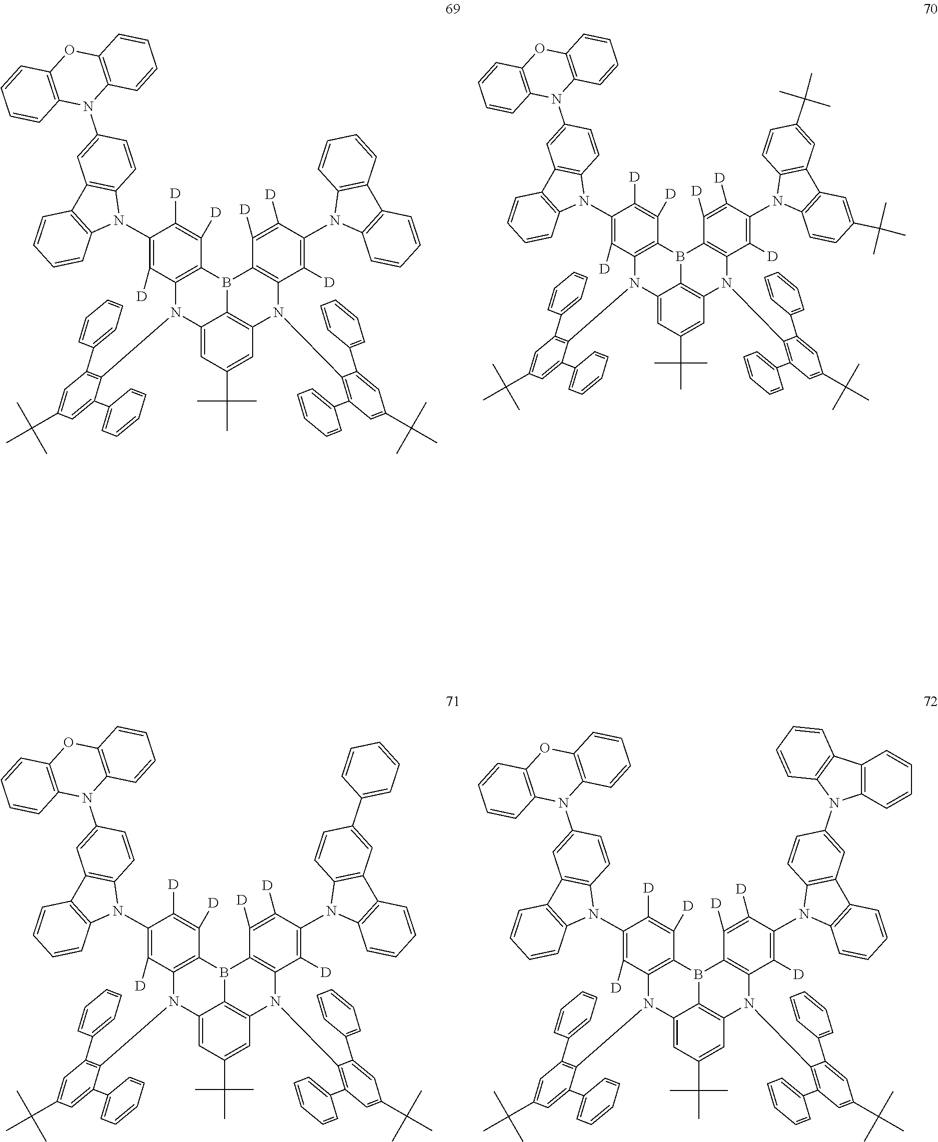

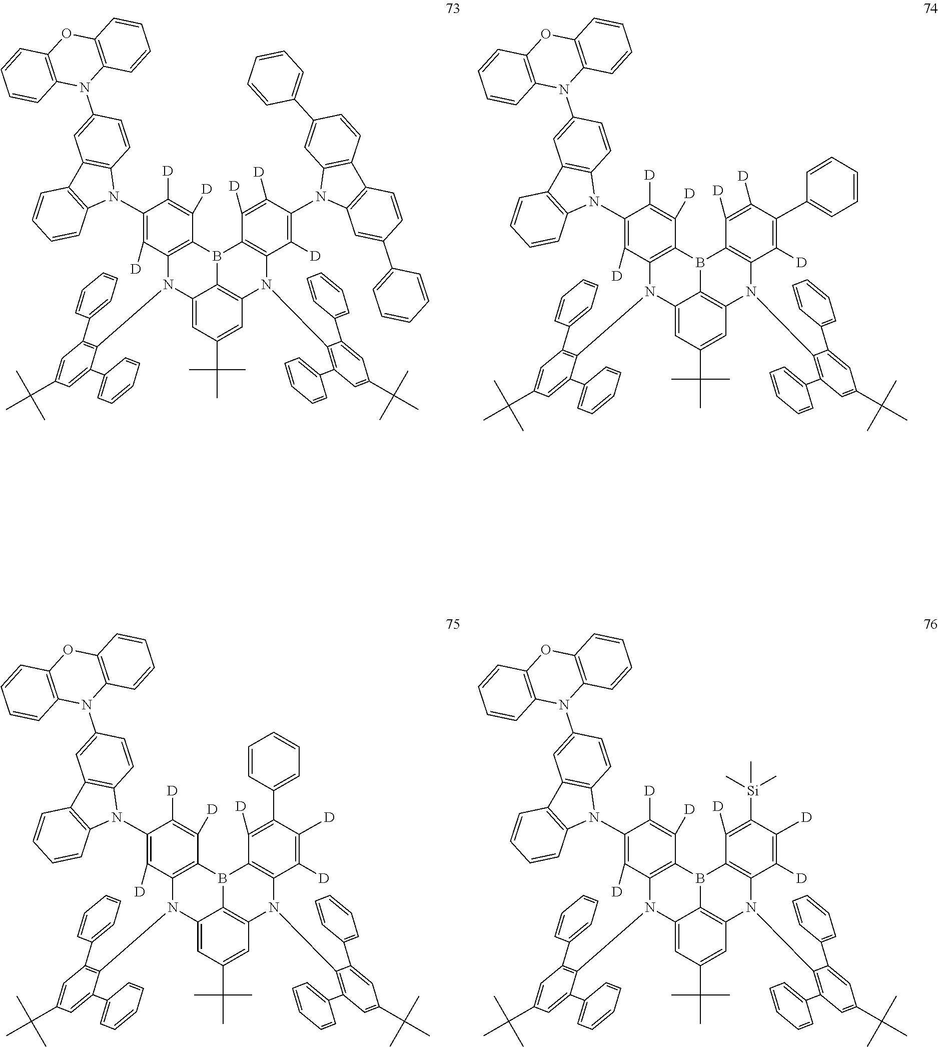

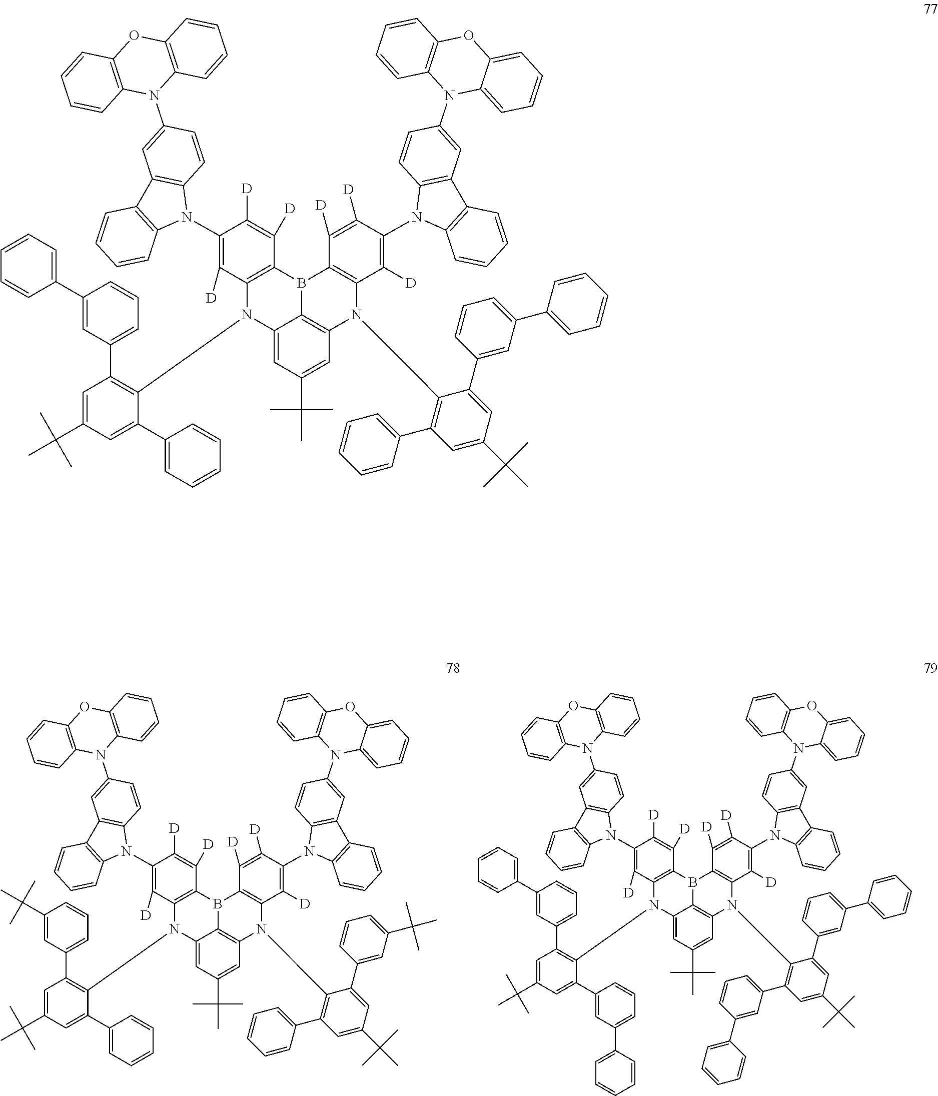

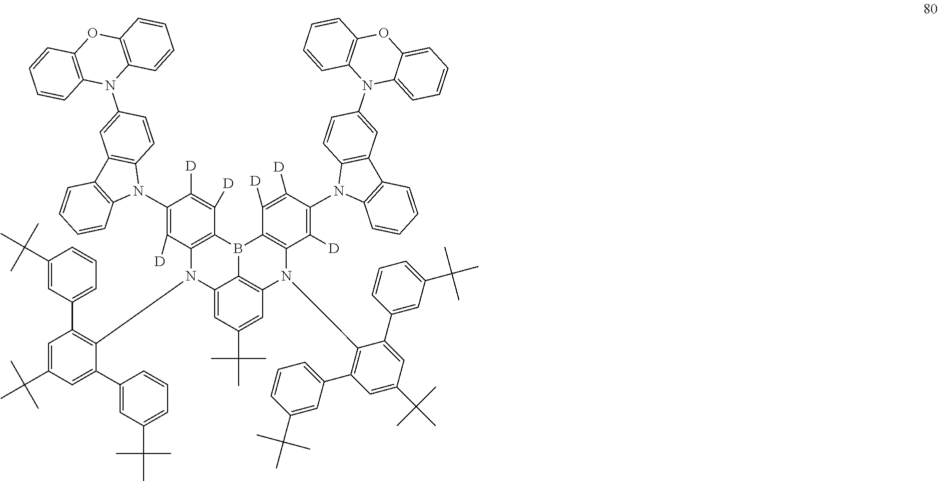 [SMILES: [2H]c1c([2H])c(-n2c3ccccc3c3cc(N4c5ccccc5Oc5ccccc54)ccc32)c([2H])c2c1B1c3c(cc(C(C)(C)C)cc3N(c3c(-c4cccc(C(C)(C)C)c4)cc(C(C)(C)C)cc3-c3cccc(C(C)(C)C)c3)c3c([2H])c(-n4c5ccccc5c5cc(N6c7ccccc7Oc7ccccc76)ccc54)c([2H])c([2H])c31)N2c1c(-c2cccc(C(C)(C)C)c2)cc(C(C)(C)C)cc1-c1cccc(C(C)(C)C)c1]

In one or more embodiments, a light-emitting element may further include a hole transport region provided between the first electrode and the emission layer, and an electron transport region provided between the emission layer and the second electrode.

In one or more embodiments, the emission layer may be to emit delayed fluorescence.

In one or more embodiments, the emission layer may be to emit light having an emission center wavelength of about 430 nanometer (nm) to about 490 nm.

In one or more embodiments, the emission layer may further include at least one selected from among a second compound represented by Formula HT-1 and a third compound represented by Formula ET-1.

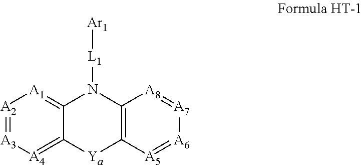

In Formula HT-1, A₁ to A₈ may each independently be N or CR₅₁, L₁ may be a direct linkage, a substituted or unsubstituted arylene group having 6 to 30 ring-forming carbon atoms, or a substituted or unsubstituted heteroarylene group having 2 to 30 ring-forming carbon atoms, Yₐ may be a direct linkage, CR₅₂R₅₃, or SR₅₄R₅₅, Ar₁ may be a substituted or unsubstituted aryl group having 6 to 30 ring-forming carbon atoms, or a substituted or unsubstituted heteroaryl group having 2 to 30 ring-forming carbon atoms, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 (e.g., 6 to 30) ring-forming carbon atoms, or a substituted or unsubstituted heteroaryl group having 2 to 60 (e.g., 2 to 30) ring-forming carbon atoms, and/or may be bonded to an adjacent group to form a ring.

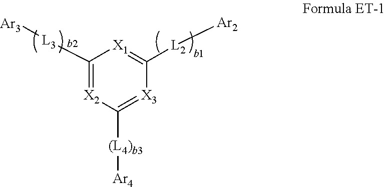

In Formula ET-1, at least one selected from among X₁ to X₃ may be N, and the rest (e.g., any remaining X₁ to X₃) may be CR₅₆,

R₅₆ may be a hydrogen atom, a deuterium atom, a substituted or unsubstituted alkyl group having 1 to 20 carbon atoms, a substituted or unsubstituted aryl group having 6 to 60 (e.g., 6 to 30) ring-forming carbon atoms, or a substituted or unsubstituted heteroaryl group having 2 to 60 ring-forming carbon atoms, b1 to b3 may each independently be an integer of 0 to 10, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms, when b1 to b3 are each an integer of 2 or more, L₂ to L₄ may each independently be a substituted or unsubstituted arylene group having 6 to 30 ring-forming carbon atoms, or a substituted or unsubstituted heteroarylene group having 2 to 30 ring-forming carbon atoms, and Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In one or more embodiments, the light-emitting element may further include a fourth compound represented by Formula D-1.

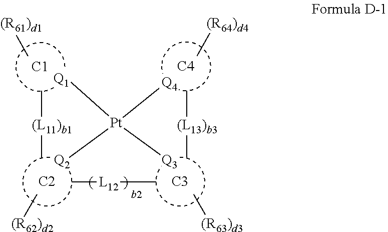

In Formula D-1, Q₁ to Q₄ may each independently be C or N, C1 to C4 may each independently be a substituted or unsubstituted hydrocarbon ring having 5 to 30 ring-forming carbon atoms, or a substituted or unsubstituted heterocycle having 2 to 30 ring-forming carbon atoms, L₁₁ to L₁₃ may each independently be a direct linkage,

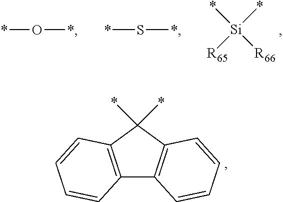

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, b1 to b3 may each independently be 0 or 1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and/or may be bonded to an adjacent group to form a ring, and d1 to d4 may each independently be an integer of 0 to 4.

In one or more embodiments of the present disclosure, a display device includes a base layer, a circuit layer provided on the base layer, and a display element layer provided on the circuit layer and including a light-emitting element. The light-emitting element includes a first electrode, a second electrode provided on the first electrode, and an emission layer that may be provided between the first electrode and the second electrode, and may include a first compound represented by Formula 1, and may further include at least one selected from among a second compound represented by Formula HT-1, a third compound represented by Formula ET-1, and a fourth compound represented by Formula D-1.

In one or more embodiments, the light-emitting element may further include a light control layer disposed on the display element layer, wherein the light control layer may include quantum dots.

In one or more embodiments of the present disclosure, a fused polycyclic compound is represented by Formula 1, as described elsewhere herein.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a plan view of a display device according to one or more embodiments of the present disclosure;

FIG. 2 is a cross-sectional view of a display device according to one or more embodiments of the present disclosure;

FIG. 3 is a cross-sectional view schematically illustrating a light-emitting element according to one or more embodiments of the present disclosure;

FIG. 4 is a cross-sectional view schematically illustrating a light-emitting element according to one or more embodiments of the present disclosure;

FIG. 5 is a cross-sectional view schematically illustrating a light-emitting element according to one or more embodiments of the present disclosure;

FIG. 6 is a cross-sectional view schematically illustrating a light-emitting element according to one or more embodiments of the present disclosure;

FIGS. 7 and 8 are each a cross-sectional view of a display device according to one or more embodiments of the present disclosure;

FIG. 9 is a cross-sectional view illustrating a display device according to one or more embodiments of the present disclosure;

FIG. 10 is a cross-sectional view illustrating a display device according to one or more embodiments of the present disclosure;

FIG. 11 is a view illustrating a vehicle in which a display device according to one or more embodiments is provided;

FIG. 12A is an orbital distribution of a highest occupied molecular orbital (HOMO) of Comparative Example Compound A;

FIG. 12B is an orbital distribution of a lowest unoccupied molecular orbital (LUMO) of Comparative Example Compound A;

FIG. 13A is an orbital distribution of HOMO of a fused polycyclic compound according to one or more embodiments of the present disclosure; and

FIG. 13B is an orbital distribution of LUMO of a fused polycyclic compound according to one or more embodiments of the present disclosure.

### DETAILED DESCRIPTION

The present disclosure may be modified in one or more suitable manners and have many forms, and thus specific embodiments will be exemplified in the drawings and described in more detail in the detailed description of the present disclosure. It should be understood, however, that it is not intended to limit the present disclosure to the particular forms disclosed, but rather, is intended to cover all modifications, equivalents, and alternatives falling within the spirit and scope of the present disclosure.

When explaining each of drawings, like reference numbers are utilized for referring to like elements. In the accompanying drawings, the dimensions of each structure are exaggeratingly illustrated for clarity of the present disclosure.

It will be understood that, although the terms “first,” “second,” and/or the like, may be utilized herein to describe one or more suitable components, these components should not be limited by these terms. These terms are only utilized to distinguish one component from another. For example, a first component could be termed a second component, and, similarly, a second component could be termed a first component, without departing from the scope of example embodiments of the present disclosure. As utilized herein, the singular forms, “a,” “an,” and “the” are intended to include the plural forms as well, unless the context clearly indicates otherwise. As utilized herein, the term “and/or” includes any and all combinations that the associated configurations can define.

In the present application, it will be understood that the terms “include,” “includes,” “including,” “comprise,” “comprises”, “comprising,” “has,” “having,” “have,” and/or the like specify the presence of features, numbers, steps, operations, component, parts, or combinations thereof disclosed in the specification, but do not exclude the possibility of presence or addition of one or more other features, numbers, steps, operations, component, parts, or combinations thereof.

As utilized herein, the terms “use,” “using,” and “used” may be considered synonymous with the terms “utilize,” “utilizing,” and “utilized,” respectively.

As utilized herein, expressions such as “at least one of,” “one of,” “selected from,” and “selected from among,” when preceding a list of elements, modify the entire list of elements and do not modify the individual elements of the list. For example, the expressions “at least one of a to c,” and “at least one of a, b and c” may indicate only a, only b, only c, both (e.g., simultaneously) a and b, both (e.g., simultaneously) a and c, both (e.g., simultaneously) b and c, all of a, b, and c, or variations thereof.

In the present application, when a layer, a film, a region, or a plate is referred to as being “on” or “in an upper portion of” another layer, film, region, or plate, it may be not only “directly on” the another layer, film, region, or plate, but intervening layers, films, regions, or plates may also be present. On the contrary to this, when a layer, a film, a region, or a plate is referred to as being “below”, “in a lower portion of” another layer, film, region, or plate, it can be not only directly under the another layer, film, region, or plate, but intervening layers, films, regions, or plates may also be present. In some embodiments, it will be understood that when a part is referred to as being “on” another part, it can be provided above the other part, or provided under the other part as well. The terms, such as “lower”, “above”, “upper” and/or the like, are utilized herein for ease of description to describe one element's relation to another element(s) as illustrated in the drawings. The terms are relative concepts and are described based on the directions indicated in the drawings. It will be understood that the terms have a relative concept and are described on the basis of the orientation depicted in the drawings. It will be understood that the spatially relative terms are intended to encompass different orientations of the device in use or operation in addition to the orientation depicted in the drawings. For example, if the device in the drawings is turned over, elements described as “beneath” other elements or features would then be oriented “above” or “over” the other elements or features. Thus, the term “beneath” may encompass both an orientation of above and below. The device may be otherwise oriented (rotated 90 degrees or at other orientations), and the spatially relative descriptors used herein should be interpreted accordingly.

As utilized herein, the term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

Unless otherwise defined, all terms (including chemical, technical and scientific terms) utilized herein have the same meaning as commonly understood by one of ordinary skill in the art to which this present disclosure belongs. It will be further understood that terms, such as those defined in commonly utilized dictionaries, should be interpreted as having a meaning that is consistent with their meaning in the context of the relevant art and will not be interpreted in an idealized or overly formal sense unless expressly so defined herein.

As utilized herein, the phrase “consisting essentially of” means that any additional components will not materially affect the chemical, physical, optical, or electrical properties of the semiconductor film.

As utilized herein, the phrase “on a plane,” or “plan view,” refers to viewing a target portion from the top, and the phrase “on a cross-section” means viewing a cross-section formed by vertically cutting a target portion from the side.

In present disclosure, “not include a or any ‘component’” “exclude a or any ‘component’”, “‘component’-free”, and/or the like refers to that the “component” not being added, selected or utilized as a component in the composition or structure, but the “component” of less than a suitable amount may still be included due to other impurities and/or external factor.

### Definitions

In the specification, the term “unsubstituted or substituted” may refer to substituted or unsubstituted with at least one substituent selected from the group consisting of a deuterium atom, a halogen atom, a cyano group, a nitro group, an amino (amine) group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the substituents exemplified above may be substituted or unsubstituted. For example, a biphenyl group may be interpreted as an aryl group or a phenyl group substituted with a phenyl group.

In the specification, the phrase “bonded to an adjacent group to form a ring” may refer to that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In some embodiments, the rings formed by being bonded to each other may be connected to another ring to form a spiro structure.

In the specification, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In some embodiments, two methyl groups in 4,5-dimethylphenanthrene may be interpreted as “adjacent groups” to each other.

In the specification, examples of the halogen atom may include a fluorine atom, a chlorine atom, a bromine atom, or an iodine atom.

In the specification, the alkyl group may be linear or branched. The number of carbons in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but the embodiment of the present disclosure is not limited thereto.

In the specification, a cycloalkyl group may refer to a cyclic alkyl group. The number of carbons in the cycloalkyl group is 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and/or the like, but the embodiment of the present disclosure is not limited thereto.

In the specification, an alkenyl group refers to a hydrocarbon group including at least one carbon double bond in the middle or terminal of an alkyl group having 2 or more carbon atoms. The alkenyl group may be linear or branched. The number of carbon atoms in the alkenyl group is not specifically limited, but is 2 to 30, 2 to 20, or 2 to 10. Examples of the alkenyl group include a vinyl group, a 1-butenyl group, a 1-pentenyl group, a 1,3-butadienyl group, a styrenyl group, a styryl vinyl group, and/or the like, but the embodiment of the present disclosure is not limited thereto.

In the specification, an alkynyl group refers to a hydrocarbon group including at least one carbon triple bond in the middle or terminal of an alkyl group having 2 or more carbon atoms. The alkynyl group may be linear or branched. Although the number of carbon atoms is not specifically limited, it is 2 to 30, 2 to 20, or 2 to 10. Specific examples of the alkynyl group may include an ethynyl group, a propynyl group, and/or the like, but are not limited thereto.

In the specification, the hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the specification, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and/or the like, but the embodiment of the present disclosure is not limited thereto.

In the specification, the fluorenyl group may be substituted, and two substituents may be bonded to each other to form a spiro structure. Examples of the substituted fluorenyl group are as follows. However, the embodiment of the present disclosure is not limited thereto.

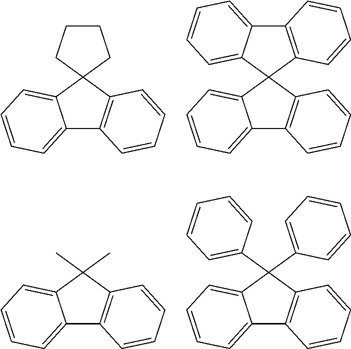

The heterocyclic group herein refers to any functional group or substituent derived from a ring containing at least one of B, O, N, P, Si, S, and Se as a heteroatom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the heterocyclic group may contain at least one of B, O, N, P, Si, Se and S as a heteroatom. When the heterocyclic group contains two or more heteroatoms, the two or more heteroatoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 30, 2 to 20, or 2 to 10.

In the specification, the aliphatic heterocyclic group may include at least one of B, O, N, P, Si, Se, and S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but the embodiment of the present disclosure is not limited thereto.

In the specification, the heteroaryl group may contain at least one of B, O, N, P, Si, Se, and S as a heteroatom. When the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, but the embodiment of the present disclosure is not limited thereto.

In the specification, the description of the aryl group may be applied to an arylene group except that the arylene group is a divalent group. The description of the heteroaryl group may be applied to a heteroarylene group except that the heteroarylene group is a divalent group.

In the specification, the silyl group includes an alkylsilyl group and an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but the embodiment of the present disclosure is not limited thereto.

As utilized herein, a germyl group includes an alkyl germyl group and an aryl germyl group. Examples of a germyl group include a trimethylgermyl group, a triethylgermyl group, a t-butyldimethylgermyl group, a vinyldimethylgermyl group, a propyldimethylgermyl group, a triphenylgermyl group, a diphenylgermyl group, a phenylgermyl group, and/or the like. However, one or more embodiments of the present disclosure is not limited thereto.

In the specification, the number of ring-forming carbon atoms in the carbonyl group is not specifically limited, but may be 1 to 40, 1 to 30, or 1 to 20. For example, the carbonyl group may have the following structures, but the embodiment of the present disclosure is not limited thereto.

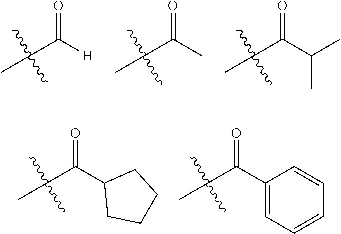

In the specification, the number of carbon atoms in the sulfinyl group and the sulfonyl group is not particularly limited, but may be 1 to 30. The sulfinyl group may include an alkyl sulfinyl group and an aryl sulfinyl group. The sulfonyl group may include an alkyl sulfonyl group and an aryl sulfonyl group.

In the specification, the thio group may include an alkylthio group and an arylthio group. The thio group may refer to that a sulfur atom is bonded to the alkyl group or the aryl group as defined herein. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but the embodiment of the present disclosure is not limited thereto.

In the specification, an oxy group may refer to that an oxygen atom is bonded to the alkyl group or the aryl group as defined herein. The oxy group may include an alkoxy group and an aryl oxy group. The alkoxy group may be a linear chain, a branched chain or a ring. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like, but the embodiment of the present disclosure is not limited thereto.

The boron group herein may refer to that a boron atom is bonded to the alkyl group or the aryl group as defined herein. The boron group includes an alkyl boron group and an aryl boron group. Examples of the boron group may include a dimethylboron group, a diethylboron group, a t-butylmethylboron group, a diphenylboron group, a phenylboron group, and/or the like, but the embodiment of the present disclosure is not limited thereto.

In the specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, and/or the like, but the embodiment of the present disclosure is not limited thereto.

In the specification, the alkyl group selected from among an alkyoxy group, an alkylthio group, an alkylsulfinyl group, an alkylsulfonyl group, an alkylaryl group, an alkylamino group, an alkyl boron group, an alkyl silyl group, and an alkyl amine group is the same as the examples of the alkyl group described herein.

In the specification, the aryl group selected from among an aryloxy group, an arylthio group, an arylsulfinyl group, an arylsulfonyl group, an arylamino group, an arylboron group, an arylsilyl group, and an arylamine group is the same as the examples of the aryl group described herein.

In the specification, a direct linkage may refer to a single bond.

In some embodiments, in the specification,

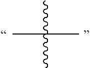

and “-*” refer to a position to be connected.

Hereinafter, embodiments of the present disclosure will be described with reference to the accompanying drawings.

### Display Device

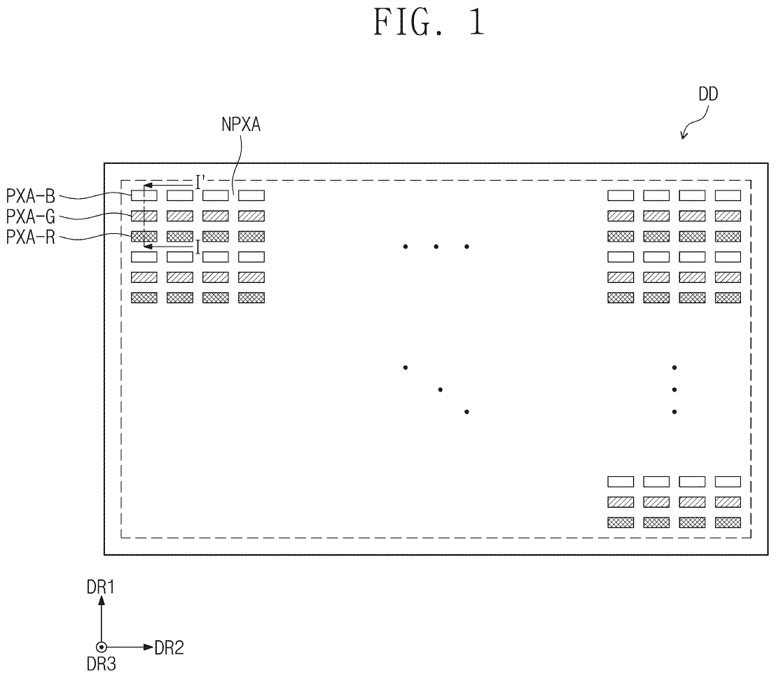

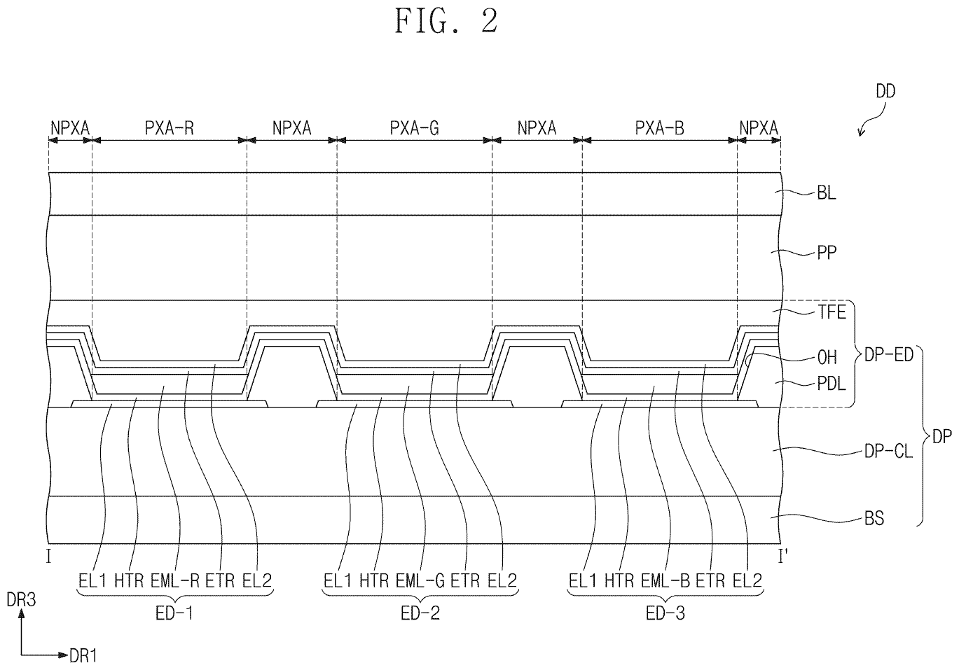

FIG. 1 is a plan view illustrating one or more embodiments of a display device DD. FIG. 2 is a cross-sectional view of the display device DD of the embodiment. FIG. 2 is a cross-sectional view illustrating a part taken along line I-I′ of FIG. 1.

The display device DD may include a display panel DP and an optical layer PP provided on the display panel DP in a third direction axis DR3. The display panel DP includes light-emitting elements ED-1, ED-2, and ED-3. The display device DD may include a plurality of light-emitting elements ED-1, ED-2, and ED-3. The optical layer PP may be provided on the display panel DP to control reflected light in the display panel DP due to external light. The optical layer PP may include, for example, a polarization layer or a color filter layer. In some embodiments, unlike the configuration illustrated in the drawing, the optical layer PP may not be provided from the display device DD of one or more embodiments.

A base substrate BL may be provided on the optical layer PP. The base substrate BL may be a member which provides a base surface on which the optical layer PP may be provided. The base substrate BL may be a glass substrate, a metal substrate, a plastic substrate, and/or the like. However, the embodiment of the present disclosure is not limited thereto, and the base substrate BL may be an inorganic layer, an organic layer, or a composite material layer. In some embodiments, unlike the configuration illustrated, in one or more embodiments, the base substrate BL may not be provided.

The display device DD according to one or more embodiments may further include a filling layer. The filling layer may be provided between a display device layer DP-ED and the base substrate BL. The filling layer may be an organic material layer. The filling layer may include at least one of an acrylic-based resin, a silicone-based resin, and an epoxy-based resin (e.g., at least one selected from among an acrylic-based resin, a silicone-based resin, and an epoxy-based resin).

The display panel DP may include a base layer BS, and a circuit layer DP-CL and the display device layer DP-ED provided on the base layer BS. The display device layer DP-ED may include a pixel defining film PDL, the light-emitting elements ED-1, ED-2, and ED-3 provided between portions of the pixel defining film PDL, and an encapsulation layer TFE provided on the light-emitting elements ED-1, ED-2, and ED-3.

The base layer BS may be a member which provides a base surface on which the display device layer DP-ED is provided. The base layer BS may be a glass substrate, a metal substrate, a plastic substrate, and/or the like. However, the embodiment is not limited thereto, and the base layer BS may be an inorganic layer, an organic layer, or a composite material layer.

In one or more embodiments, the circuit layer DP-CL is provided on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light-emitting elements ED-1, ED-2, and ED-3 of the display device layer DP-ED.

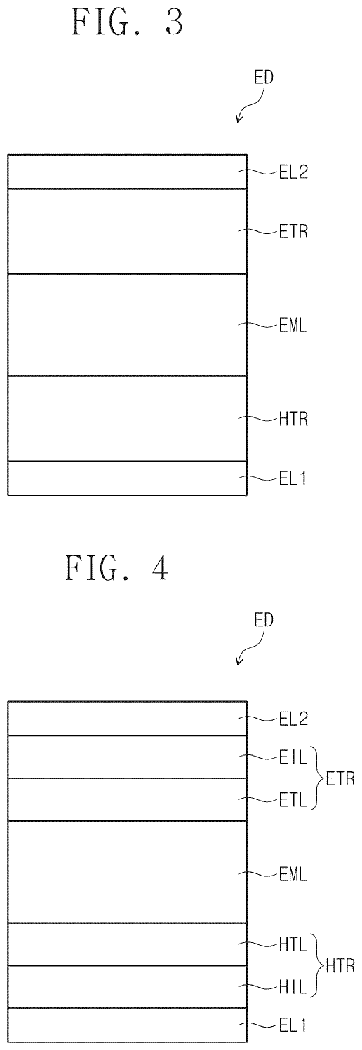

Each of the light-emitting elements ED-1, ED-2, and ED-3 may have a structure of each light-emitting element ED of embodiments according to FIGS. 3 to 6, as described in more detail herein. Each of the light-emitting elements ED-1, ED-2, and ED-3 may include a first electrode EL1, a hole transport region HTR, a layer selected from emission layers EML-R, EML-G, and EML-B, an electron transport region ETR, and a second electrode EL2.

FIG. 2 illustrates one or more embodiments in which the emission layers EML-R, EML-G, and EML-B of the light-emitting elements ED-1, ED-2, and ED-3 are provided in openings OH defined in the pixel defining film PDL, and the hole transport region HTR, the electron transport region ETR, and the second electrode EL2 are provided as a common layer in the entire light-emitting elements ED-1, ED-2, and ED-3. However, the embodiment of the present disclosure is not limited thereto, and unlike the configuration illustrated in FIG. 2, the hole transport region HTR and the electron transport region ETR in one or more embodiments may be provided by being patterned inside the openings OH defined in the pixel defining film PDL. For example, the hole transport region HTR, the emission layers EML-R, EML-G, and EML-B, and the electron transport region ETR of the light-emitting elements ED-1, ED-2, and ED-3 in one or more embodiments may be provided by being patterned in an inkjet printing method.

The encapsulation layer TFE may cover the light-emitting elements ED-1, ED-2 and ED-3. The encapsulation layer TFE may seal the light-emitting elements ED-1, ED-2, and ED-3. The encapsulation layer TFE may be a thin film encapsulation layer. The encapsulation layer TFE may be formed by laminating one layer or a plurality of layers. The encapsulation layer TFE includes at least one insulation layer. The encapsulation layer TFE according to one or more embodiments may include at least one inorganic film (hereinafter, an encapsulation-inorganic film). The encapsulation layer TFE according to one or more embodiments may also include at least one organic film (hereinafter, an encapsulation-organic film) and at least one encapsulation-inorganic film.

The encapsulation-inorganic film protects the light-emitting elements ED-1, ED-2, and ED-3 from moisture and/or oxygen, and the encapsulation-organic film protects the light-emitting elements ED-1, ED-2, and ED-3 from foreign substances such as dust particles. The encapsulation-inorganic film may include silicon nitride, silicon oxynitride, silicon oxide, titanium oxide, aluminum oxide, and/or the like, but the embodiment of the present disclosure is not particularly limited thereto. The encapsulation-organic film may include an acrylic-based compound, an epoxy-based compound, and/or the like. The encapsulation-organic film may include a photopolymerizable organic material, but the embodiment of the present disclosure is not particularly limited thereto.

The encapsulation layer TFE may be provided on the second electrode EL2 and may be provided filling the opening OH.

Referring to FIGS. 1 and 2, the display device DD may include one or more non-light emitting region(s) NPXA and also include light emitting regions PXA-R, PXA-G, and PXA-B. The light emitting regions PXA-R, PXA-G, and PXA-B may be regions in which light generated by the respective light-emitting elements ED-1, ED-2, and ED-3 is emitted. The light emitting regions PXA-R, PXA-G, and PXA-B may be spaced and/or apart from each other on a plane (e.g., in a plan view).

Each of the light emitting regions PXA-R, PXA-G, and PXA-B may be a region divided (i.e., defined) by the pixel defining film PDL. The non-light emitting areas NPXA may be areas between the adjacent light emitting areas PXA-R, PXA-G, and PXA-B, which correspond to the pixel defining film PDL. In some embodiments, in the specification, the light emitting regions PXA-R, PXA-G, and PXA-B may respectively correspond to pixels. The pixel defining film PDL may divide the light-emitting elements ED-1, ED-2, and ED-3. The emission layers EML-R, EML-G, and EML-B of the light-emitting elements ED-1, ED-2, and ED-3 may be provided in openings OH defined in the pixel defining film PDL and separated from each other.

The light emitting regions PXA-R, PXA-G, and PXA-B may be divided into a plurality of groups according to the color of light generated from the light-emitting elements ED-1, ED-2, and ED-3. In the display device DD of one or more embodiments illustrated in FIGS. 1 and 2, three light emitting regions PXA-R, PXA-G, and PXA-B, which emit red light, green light, and blue light, respectively, are exemplarily illustrated. For example, the display device DD of one or more embodiments may include the red light emitting region PXA-R, the green light emitting region PXA-G, and the blue light emitting region PXA-B that are separated from each other.

In the display device DD according to one or more embodiments, the plurality of light-emitting elements ED-1, ED-2 and ED-3 may be to emit light beams having wavelengths different from each other. For example, in one or more embodiments, the display device DD may include a first light-emitting element ED-1 that emits red light, a second light-emitting element ED-2 that emits green light, and a third light-emitting element ED-3 that emits blue light. For example, the red light emitting region PXA-R, the green light emitting region PXA-G, and the blue light emitting region PXA-B of the display device DD may correspond to the first light-emitting element ED-1, the second light-emitting element ED-2, and the third light-emitting element ED-3, respectively.

However, the embodiment of the present disclosure is not limited thereto, and the first to third light-emitting elements ED-1, ED-2, and ED-3 may be to emit light beams in substantially the same wavelength range or at least one light-emitting element may be to emit a light beam in a wavelength range different from the others. For example, the first to third light-emitting elements ED-1, ED-2, and ED-3 may all emit blue light.

The light emitting regions PXA-R, PXA-G, and PXA-B in the display device DD according to one or more embodiments may be arranged in a stripe form. Referring to FIG. 1, the plurality of red light emitting regions PXA-R may be arranged with each other along a second directional axis DR2, the plurality of green light emitting regions PXA-G may be arranged with each other along the second directional axis DR2, and the plurality of blue light emitting regions PXA-B may be arranged with each other along the second directional axis DR2. In some embodiments, the red light emitting region PXA-R, the green light emitting region PXA-G, and the blue light emitting region PXA-B may be alternately arranged with each other in this order along a first directional axis DR1.

FIGS. 1 and 2 illustrate that all the light emitting regions PXA-R, PXA-G, and PXA-B have similar area, but the embodiment of the present disclosure is not limited thereto. Thus, the light emitting regions PXA-R, PXA-G, and PXA-B may have different areas from each other according to the wavelength range of the emitted light. In this case, the areas of the light emitting regions PXA-R, PXA-G, and PXA-B may refer to areas when viewed on a plane defined by the first directional axis DR1 and the second directional axis DR2 (e.g., in a plan view).

In some embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality required in the display device DD. For example, the arrangement form of the light emitting regions PXA-R, PXA-G, and PXA-B may be a pentile (PENTILE®) arrangement form or a diamond (Diamond Pixel®) arrangement form, (PENTILE® and Diamond Pixel® are registered trademarks owned by Samsung Display Co., Ltd.).

In some embodiments, the areas of the light emitting regions PXA-R, PXA-G, and PXA-B may be different from each other. For example, in one or more embodiments, the area of the green light emitting region PXA-G may be smaller than that of the blue light emitting region PXA-B, but the embodiment of the present disclosure is not limited thereto.

Hereinafter, FIG. 3 to FIG. 6 are cross-sectional views schematically showing light-emitting elements ED according to embodiments. The light-emitting element ED of one or more embodiments may include a first electrode EL1, a hole transport region HTR, an emission layer EML, an electron transport region ETR, and a second electrode EL2 stacked in order (e.g., stacked sequentially).

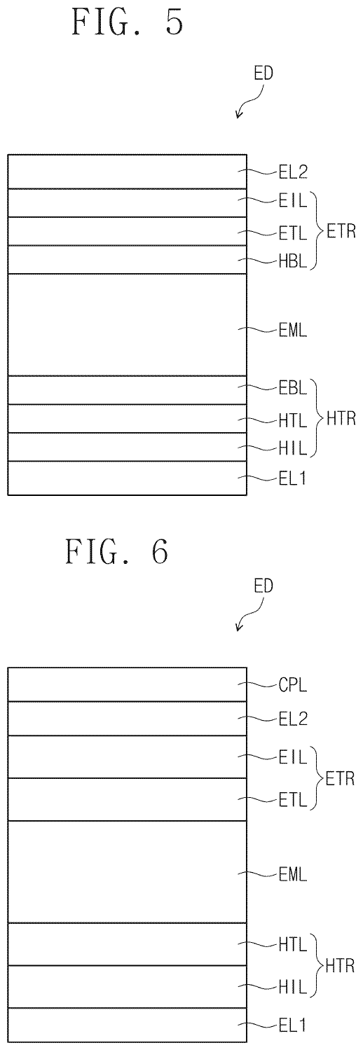

Compared with FIG. 3, FIG. 4 illustrates a cross-sectional view of a light-emitting element ED of one or more embodiments, in which a hole transport region HTR includes a hole injection layer HIL and a hole transport layer HTL, and an electron transport region ETR includes an electron injection layer EIL and an electron transport layer ETL. In some embodiments, compared with FIG. 3, FIG. 5 illustrates a cross-sectional view of a light-emitting element ED of one or more embodiments, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared with FIG. 4, FIG. 6 illustrates a cross-sectional view of a light-emitting element ED of one or more embodiments including a capping layer CPL provided on a second electrode EL2.

The first electrode EL1 has conductivity (e.g., is a conductor). The first electrode EL1 may be formed of a metal material, a metal alloy, or a conductive compound. The first electrode EL1 may be an anode or a cathode. However, the embodiment of the present disclosure is not limited thereto. In some embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these, a mixture of two or more selected from among these, and/or an oxide thereof.

When the first electrode EL1 is the transmissive electrode, the first electrode EL1 may include a transparent metal oxide such as indium tin oxide (ITO), indium zinc oxide (IZO), zinc oxide (ZnO), or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/, Mo, Ti, W, a compound or mixture thereof (e.g., a mixture of Ag and Mg), or materials with multilayer structures such as LiF/Ca (a stacked structure of LiF and Ca), LiF/Al (a stacked structure of LiF and Al). In some embodiments, the first electrode EL1 may have a multilayer structure including a reflective film or a transflective film formed of the herein-described materials, and a transparent conductive film formed of ITO, IZO, ZnO, ITZO, and/or the like. For example, the first electrode EL1 may have a three-layer structure of ITO/Ag/ITO, but the embodiment of the present disclosure is not limited thereto. In some embodiments, the embodiment of the present disclosure is not limited thereto, and the first electrode EL1 may include the herein-described metal materials, combinations of at least two metal materials of the herein-described metal materials, oxides of the herein-described metal materials, and/or the like. The thickness of the first electrode EL1 may be from about 700 angstrom (Å) to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a buffer layer or an emission-auxiliary layer, and an electron blocking layer EBL. The thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, the hole transport region HTR may have a single layer structure of the hole injection layer HIL or the hole transport layer HTL, or may have a single layer structure formed of a hole injection material and a hole transport material. In some embodiments, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order from the first electrode EL1, but the embodiment of the present disclosure is not limited thereto.

The hole transport region HTR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1:

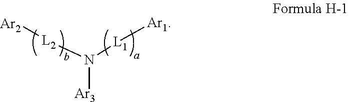

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In some embodiments, when a or b is an integer of 2 or greater, a plurality of L₁'s and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

The compound represented by Formula H-1 may be a monoamine compound. In some embodiments, the compound represented by Formula H-1 may be a diamine compound in which at least one selected from among Ar₁ to Ar₃ includes the amine group as a substituent. In some embodiments, the compound represented by Formula H-1 may be a carbazole-based compound including a substituted or unsubstituted carbazole group in at least one of Ar₁ and Ar₂, or a fluorene-based compound including a substituted or unsubstituted fluorene group in at least one of Ar₁ and Ar₂.

The compound represented by Formula H-1 may be represented by any one selected from among the compounds in Compound Group H. However, the compounds listed in Compound Group H are examples, and the compounds represented by Formula H-1 are not limited to those represented by Compound Group H:

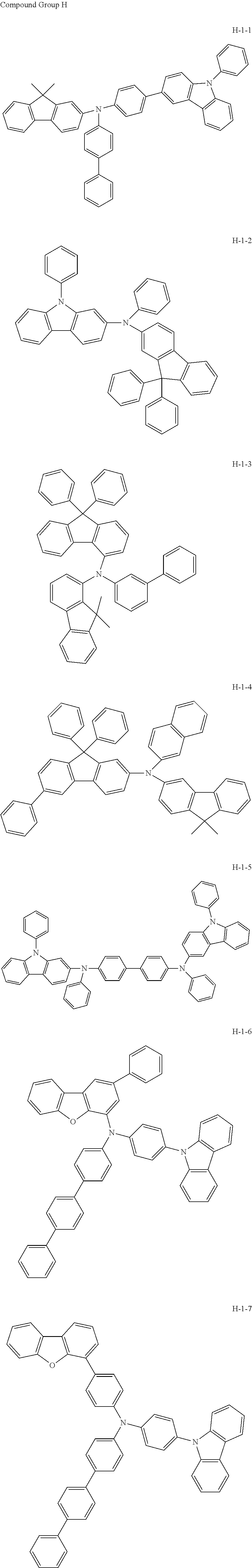

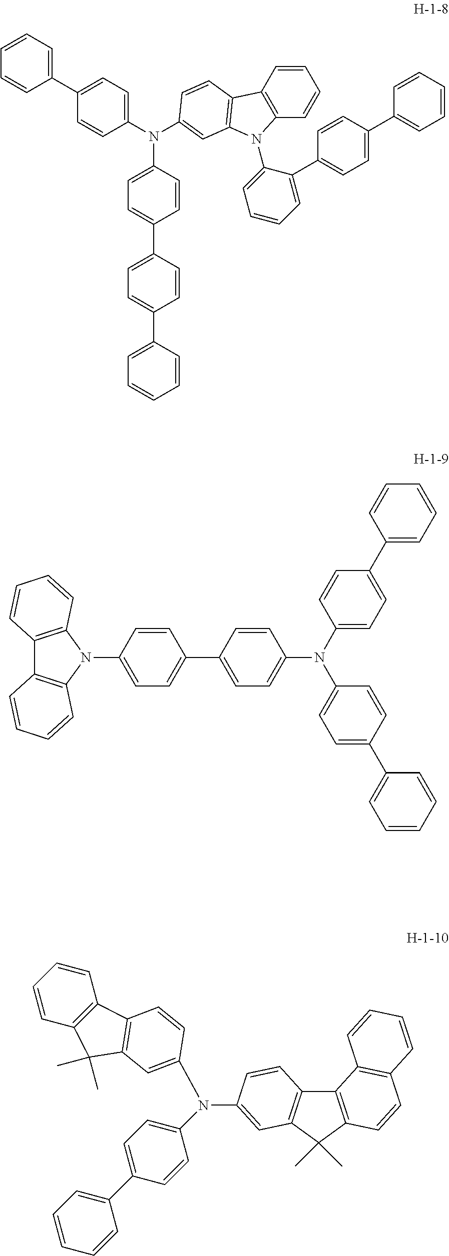 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

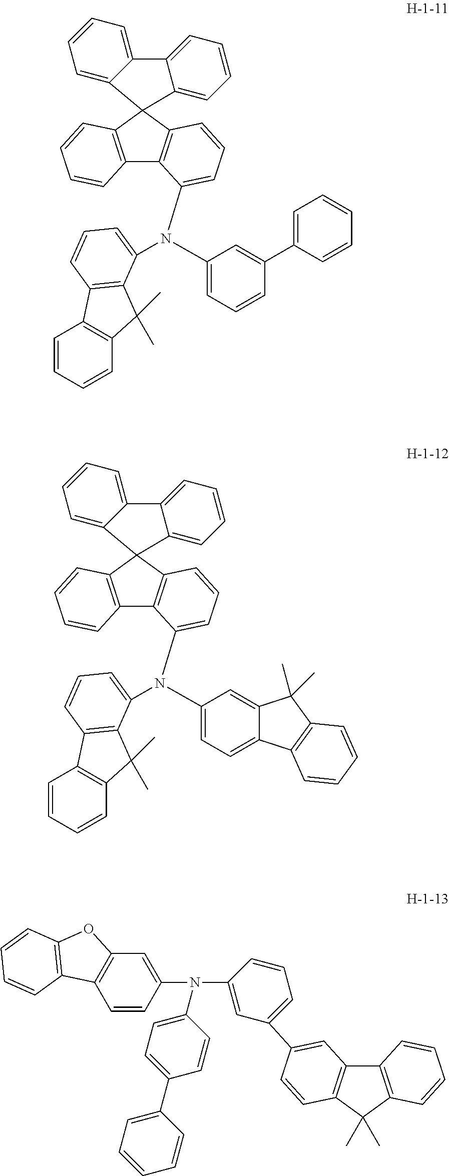 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

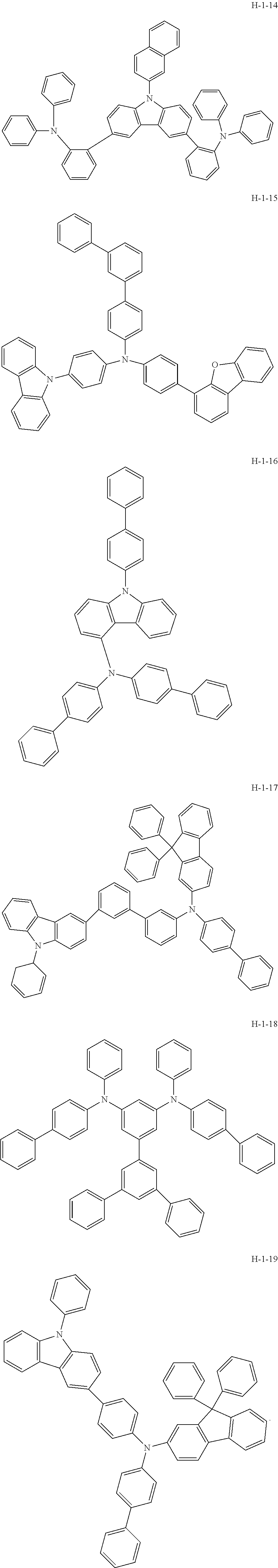

The hole transport region HTR may include at least one selected from among a phthalocyanine compound such as copper phthalocyanine, N¹,N¹-([1,1′-biphenyl]-4,4′-diyl)bis(N¹-phenyl-N⁴,N⁴-d₁-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N-(2-naphthyl)-N-phenylamino]triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HAT-CN), and the like.

The hole transport region HTR may include at least one selected from among a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1′-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene-bis[N,N-bis(4-methylphenyl]benzenamine) (TAPC), 4,4′-bis[N,N′-(3-tolyl)amino]-3,3′-dimethylbiphenyl (HMTPD), 1,3-bis(N-carbazolyl)benzene (mCP), and the like.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

The hole transport region HTR may include the herein-described compounds of the hole transport region HTR in at least one of a hole injection layer HIL, a hole transport layer HTL, and an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, when the hole transport region HTR includes the electron blocking layer EBL, the electron blocking layer EBL may have a thickness of about 10 Å to about 1,000 Å. When the thicknesses of the hole transport region HTR, the hole injection layer HIL, the hole transport layer HTL and the electron blocking layer EBL satisfy the herein-described ranges, satisfactory hole transport properties may be achieved without a substantial increase in driving voltage.

The hole transport region HTR may further include a charge generating material to increase conductivity in addition to the herein-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, and a cyano group-containing compound, but the embodiment of the present disclosure is not limited thereto. For example, the p-dopant may include a halogenated metal compound such as Cul or Rbl, a quinone derivative such as tetracyanoquinodimethane (TCNQ) or 2,3,5,6-tetrafluoro-7,7,8,8-tetracyanoquinodimethane (F₄-TCNQ), a metal oxide such as tungsten oxide or molybdenum oxide, a cyano group-containing compound such as dipyrazino[2,3-f: 2′,3′-h] quinoxaline-2,3,6,7,10,11-hexacarbonitrile (HAT-CN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but the embodiment of the present disclosure is not limited thereto.

As described herein, the hole transport region HTR may further include at least one of the buffer layers and the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be included in the hole transport region HTR may be utilized as a material to be included in the buffer layer. The electron blocking layer EBL is a layer that serves to prevent or reduce the electron injection from the electron transport region ETR to the hole transport region HTR.

The emission layer EML is provided on the hole transport region HTR. The emission layer EML may have a thickness of, for example, about 100 Å to about 1,000 Å or about 100 Å to about 300 Å. The emission layer EML may have a single layer formed of a single material, a single layer formed of a plurality of different materials, or a multilayer structure having a plurality of layers formed of a plurality of different materials.

A light-emitting element ED according to one or more embodiments may contain a fused polycyclic compound according to one or more embodiments in at least one of the functional layers provided between a first electrode EL1 and a second electrode EL2. In the light-emitting element ED according to one or more embodiments, an emission layer EML may contain a fused polycyclic compound according to one or more embodiments. In one or more embodiments, the emission layer EML may contain the fused polycyclic compound according to one or more embodiments as a dopant material. The fused polycyclic compound according to one or more embodiments may be a dopant material of the emission layer EML. In some embodiments, as utilized herein, the fused polycyclic compound according to one or more embodiments, which will be described later, may be referred to as a first compound.

### Fused Polycyclic Compound

The fused polycyclic compound according to one or more embodiments includes, as a core structure (hereinafter, referred to as an NBN core), a pentacyclic fused ring containing two nitrogen (N) atoms and one boron (B) atom as a ring-forming atom. The NBN core according to one or more embodiments includes three substituted or unsubstituted benzene rings. In the NBN core of the fused polycyclic compound according to one or more embodiments, a substituent of a tricyclic fused ring is bonded to a carbon atom at a para position with respect to a boron atom that forms a ring. For example, in one or more embodiments, the tricyclic fused ring substituent is bonded at a specific position to the core structure, and thus the twist of a molecule in the fused polycyclic compound increases. Accordingly, an energy difference between a singlet and a triplet is improved, leading to an increase in a rate of reverse inter-system crossing (RISC), and thus, material stability may be improved.

In the fused polycyclic compound according to one or more embodiments, the tricyclic substituent capable of being substituted for the carbon atom at the para position with respect to the boron atom of the NBN core may be an electron donating group. In the fused polycyclic compound according to one or more embodiments, the tricyclic substituent capable of being substituted for the carbon atom at the para position with respect to the boron atom of the NBN core is a carbazole group.

The fused polycyclic compound according to one or more embodiments includes at least one carbazole group connected to the NBN core. The carbazole group connected to the NBN core is linked to a nitrogen-containing substituent.

In the fused polycyclic compound according to one or more embodiments, two nitrogen atoms of the NBN core are each substituted with an aryl group. The aryl groups, linked to two nitrogen atoms of the NBN core, may be substituted phenyl groups. For example, the aryl groups, linked to the two nitrogen atoms of the NBN core, may be terphenyl groups. The phenyl groups, linked to the two nitrogen atoms of the NBN core may be each substituted at an ortho position with respect to the carbon atom connected to the nitrogen atom of the NBN core.

The fused polycyclic compound according to one or more embodiments is represented by Formula 1.

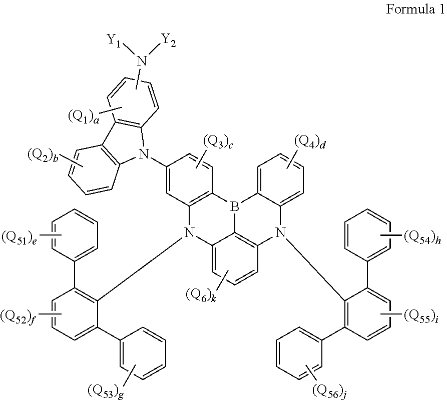

In Formula 1, Y₁ and Y₂ may each independently be a hydrogen atom, a deuterium atom, a substituted or unsubstituted alkyl group having 1 to 20 carbon atoms, a substituted or unsubstituted cycloalkyl group having 5 to 30 ring-forming carbon atoms, a substituted or unsubstituted alkoxy group having 2 to 20 carbon atoms, a substituted or unsubstituted aryl group having 6 to 30 ring-forming carbon atoms or a substituted or unsubstituted heteroaryl group having 2 to 30 ring-forming carbon atoms, and/or may be bonded to an adjacent group to form a ring. For example, Y₁ and Y₂ may each independently be a substituted or unsubstituted phenyl group, a substituted or unsubstituted naphthyl group, a substituted or unsubstituted phenanthrene group, a substituted or unsubstituted phenoxy group, a substituted or unsubstituted phenylthio group, a substituted or unsubstituted phenylselenyl group, a substituted or unsubstituted phenyltellanyl group, a substituted or unsubstituted phenylsilyl group, a substituted or unsubstituted phenylgermyl group, a substituted or unsubstituted phenylamino group, a substituted or unsubstituted hydroxyethyl group, a substituted or unsubstituted propenyl group, or a substituted or unsubstituted furan group. In some embodiments, Y₁ may be a substituted or unsubstituted phenyl group, Y₂ may be a phenyl group substituted with an oxy group and Y₁ and Y₂ may be bonded to each other to form an additional ring.

In Formula 1, Q₁ to Q₃, and Q₅₁ to Q₅₆ may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms or a substituted or unsubstituted heteroaryl group having 2 to 30 ring-forming carbon atoms, and/or may be bonded to an adjacent group to form a ring. For example, Q₁ and Q₃ may each independently be a hydrogen atom, or a deuterium atom. For example, Q₂ may be any one selected from among a hydrogen atom, a deuterium atom, a substituted or unsubstituted tert-butyl (t-butyl) group, a substituted or unsubstituted diphenylamine group, and a substituted or unsubstituted carbazole group. For example, Q₅₁ to Q₅₆ may each independently be a hydrogen atom, a deuterium atom, a substituted or unsubstituted t-butyl group, or a substituted or unsubstituted phenyl group.

In Formula 1, Q₄ may be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted silyl group, a substituted or unsubstituted aryl group having 6 to 30 ring-forming carbon atoms or a substituted or unsubstituted heteroaryl group having 2 to 30 ring-forming carbon atoms, and/or may be bonded to an adjacent group to form a ring. For example, Q₄ may be a hydrogen atom, a deuterium atom, a substituted or unsubstituted carbazole group, a substituted or unsubstituted phenyl group, or a substituted or unsubstituted silyl group.

In Formula 1, Q₆ may be a hydrogen atom, a deuterium atom, a substituted or unsubstituted alkyl group having 1 to 20 carbon atoms, a substituted or unsubstituted cycloalkyl group having 5 to 30 ring-forming carbon atoms, a substituted or unsubstituted aryl group having 6 to 30 ring-forming carbon atoms, a substituted or unsubstituted heteroaryl group having 2 to 30 ring-forming carbon atoms, a substituted or unsubstituted germyl group, or a substituted or unsubstituted silyl group. For example, Q₆ may be a hydrogen atom, a deuterium atom, a substituted or unsubstituted methyl group, a substituted or unsubstituted silyl group, a substituted or unsubstituted germyl group, a substituted or unsubstituted cyclopentenyl group, a substituted or unsubstituted cyclohexenyl group, a substituted or unsubstituted butyl group, a substituted or unsubstituted phenyl group, a substituted or unsubstituted terphenyl group, a substituted or unsubstituted dibenzofuran group, a substituted or unsubstituted dibenzothiophene group, a substituted or unsubstituted dibenzoselenophene group, a substituted or unsubstituted tellurophene group, a substituted or unsubstituted carbazole group, a substituted or unsubstituted naphthyl group, or a substituted or unsubstituted phenanthrene group.

In Formula 1, b and d may each independently be an integer of 0 to 4. In Formula 1, when b is 0, the fused polycyclic compound according to one or more embodiments may be unsubstituted with Q₂. A case where b is 4 and Q₂s are hydrogen atoms may be the same as the case where b is 0. When b is an integer of 2 or more, Q₂s provided in plurality may be the same, or at least one selected from among the plurality of Q₂s may be different. In Formula 1, when d is 0, the fused polycyclic compound according to one or more embodiments may be unsubstituted with Q₄. A case where d is 4 and Q₄s are hydrogen atoms may be the same as the case where d is 0. When d is an integer of 2 or more, Q₄s provided in plurality may be the same, or at least one selected from among the plurality of Q₄s may be different.

In Formula 1, a, c, f, i, and k may each independently be an integer of 0 to 3. In Formula 1, when a is 0, the fused polycyclic compound according to one or more embodiments may be unsubstituted with Q₁ and be substituted only with a nitrogen-containing substituent and a hydrogen atom. When a is an integer of 2 or more, Q₁s provided in plurality may be the same, or at least one selected from among the plurality of Qis may be different. In Formula 1, when c is 0, the fused polycyclic compound according to one or more embodiments may be unsubstituted with Q₃. A case where c is 3 and Q₃s are hydrogen atoms may be the same as the case where c is 0. When c is an integer of 2 or more, Q₃s provided in plurality may each independently be the same, or at least one selected from among the plurality of Q₃s may be different. In Formula 1, when f is 0, the fused polycyclic compound according to one or more embodiments may be unsubstituted with Q₅₂. A case where f is 3 and Q₅₂s are hydrogen atoms may be the same as the case where f is 0. When f is an integer of 2 or more, Q₅₂s provided in plurality may be the same, or at least one selected from among the plurality of Q₅₂s may be different. In Formula 1, when i is 0, the fused polycyclic compound according to one or more embodiments may be unsubstituted with Q₅₅. A case where i is 3 and Q₅₅s are hydrogen atoms may be the same as the case where i is 0. When i is an integer of 2 or more, Q₅₅s provided in plurality may be the same, or at least one selected from among the plurality of Q₅₅s may be different. In Formula 1, when k is 0, the fused polycyclic compound according to one or more embodiments may be unsubstituted with Q₆. A case where k is 3 and Q₆s are hydrogen atoms may be the same as the case where k is 0. When k is an integer of 2 or more, Q₆s provided in plurality may be the same, or at least one selected from among the plurality of Q₆s may be different.

The first compound represented by Formula 1 may be represented by Formula 1-1.

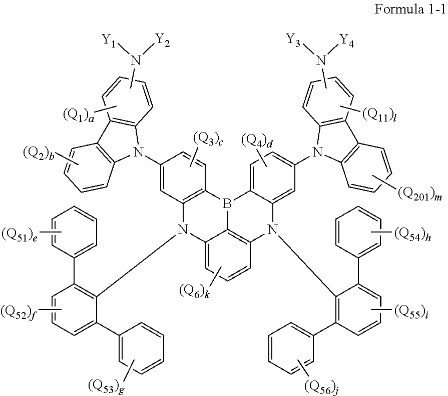

In Formula 1-1, Y₃ and Y₄ may each independently be a hydrogen atom, a deuterium atom, a substituted or unsubstituted alkyl group having 1 to 20 carbon atoms, a substituted or unsubstituted cycloalkyl group having 5 to 30 ring-forming carbon atoms, a substituted or unsubstituted alkoxy group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. For example, Y₃ and Y₄ may each independently be a substituted or unsubstituted phenyl group, a substituted or unsubstituted naphthyl group, a substituted or unsubstituted phenanthrene group, a substituted or unsubstituted phenoxy group, a substituted or unsubstituted phenylthio group, a substituted or unsubstituted phenylselenyl group, a substituted or unsubstituted phenyltellanyl group, a substituted or unsubstituted phenylsilyl group, a substituted or unsubstituted phenylgermyl group, a substituted or unsubstituted phenylamino group, a substituted or unsubstituted hydroxyethyl group, a substituted or unsubstituted prophenyl group, or a substituted or unsubstituted furan group.

In Formula 1-1, Q₁₁ and Q₂₀₁ may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or a substituted or unsubstituted amine group, and/or be bonded to an adjacent group to form a ring. For example, Q₁₁ and Q₂₀₁ may each independently be a hydrogen atom, or a deuterium atom.

In Formula 1-1, I and d₁ may each independently be an integer of 0 to 3. In Formula 1-1, when I is 0, the fused polycyclic compound according to one or more embodiments may be unsubstituted with Q₁₁. A case where I is 3 and Q₁₁s are hydrogen atoms may be the same as the case where I is 0. When I is an integer of 2 or more, Q₁₁s provided in plurality may be the same, or at least one selected from among the plurality of Q₁₁s may be different. In Formula 1-1, when d₁ is 0, the fused polycyclic compound according to one or more embodiments may be unsubstituted with Q₄. A case d₁ is 3 and Q₄s are hydrogen atoms may be the same as the case where d₁ is 0. When d₁ is an integer of 2 or more, Q₄s provided in plurality may be the same, or at least one among the plurality of Q₄s may be different.

In Formula 1-1, m may be an integer of 0 to 4. In Formula 1-1, when m is 0, the fused polycyclic compound according to one or more embodiments may be unsubstituted with Q₂₀₁. A case where m is 4 and Q₂₀₁s are hydrogen atoms may be the same as the case where m is 0. When m is an integer of 2 or more, Q₂₀₁s provided in plurality may be the same or at least one selected from among the plurality of Q₂₀₁s may be different.

In Formula 1-1, the same descriptions in Formula 1 may be applied to Y₁, Y₂, Q₁ to Q₄, Q₅₁ to Q₅₆, Q₆, a to c, and e to k.

The first compound represented by Formula 1 may be represented by any one selected from among Formula 2-1 to Formulas 2-10.

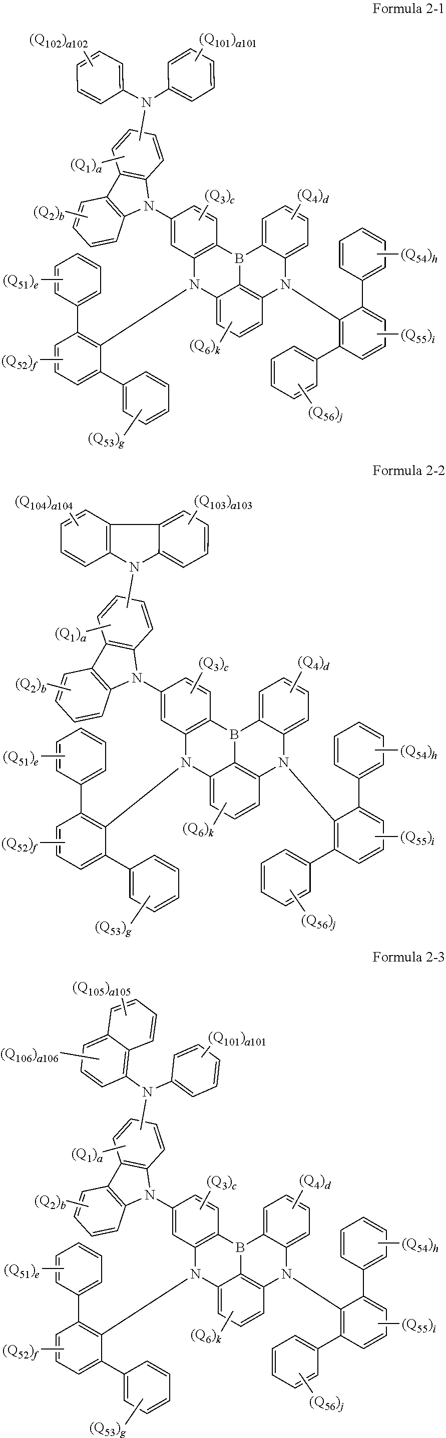

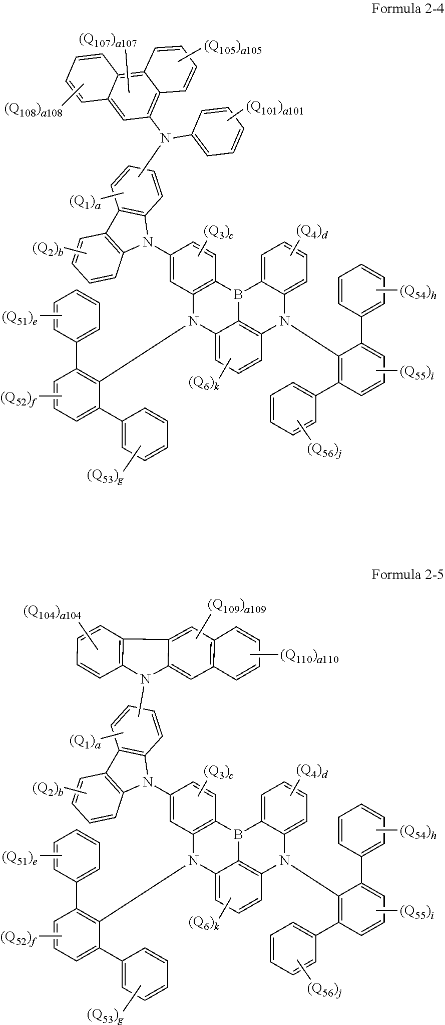

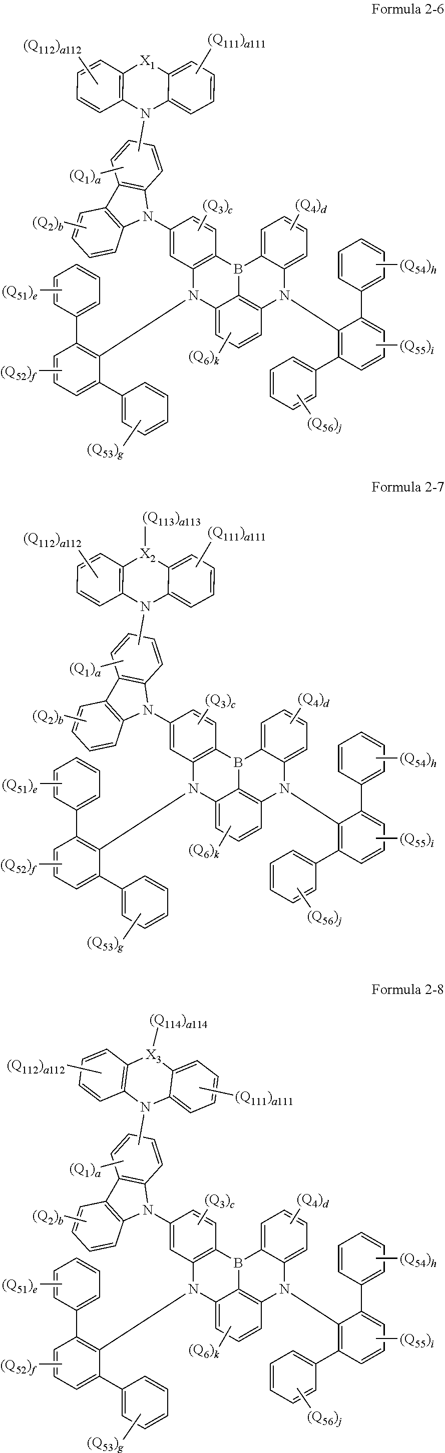

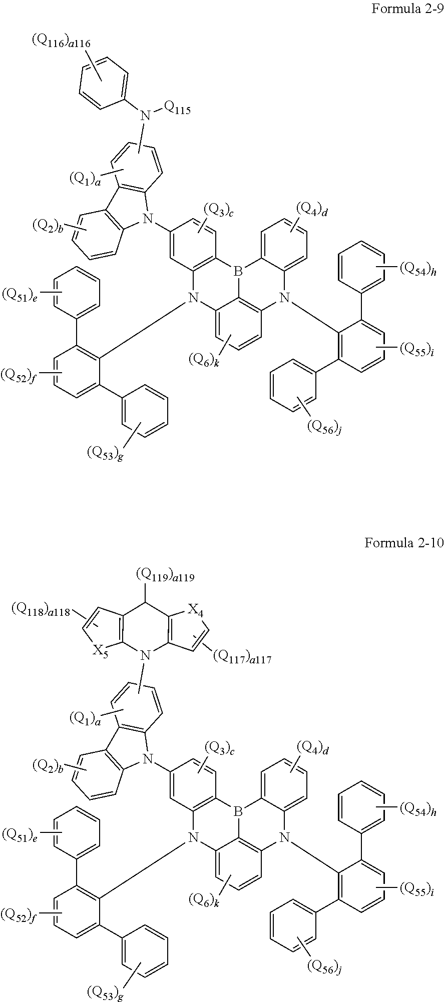

In the fused polycyclic compound represented by Formula 2-1 to Formula 2-10, Q₁₀₁ to Q₁₁₂, and Q₁₁₆ to Q₁₁₉ may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or a substituted or unsubstituted amine group, and/or be bonded to an adjacent group to form a ring. For example, Q₁₀₁ may be a hydrogen atom, a deuterium atom, a substituted or unsubstituted methyl group, or a substituted or unsubstituted t-butyl group. For example, Q₁₀₂ may be a hydrogen atom, a deuterium atom, a substituted or unsubstituted methyl group, a substituted or unsubstituted t-butyl group, a substituted or unsubstituted diphenylamine group, or a substituted or unsubstituted vinyl group. For example, Q₁₀₃ may be a hydrogen atom, a deuterium atom, a substituted or unsubstituted t-butyl group, or a substituted or unsubstituted carbazole group. For example, Q₁₀₅ to Q₁₁₂ may each independently be a hydrogen atom, or a deuterium atom. For example, Q₁₁₃ may be a hydrogen atom, a deuterium atom, or a substituted or unsubstituted phenyl group. For example, Q₁₁₄ may be a hydrogen atom, a deuterium atom, a substituted or unsubstituted methyl group, or a substituted or unsubstituted phenyl group. For example, Q₁₁₅ may be a hydrogen atom, a deuterium atom, a substituted or unsubstituted hydroxyethyl group, or a substituted or unsubstituted propane group. For example, Q₁₁₆ may be a hydrogen atom, a deuterium atom, or a hydroxy group. For example, Q₁₁₇ to Q₁₁₉ may each independently be a hydrogen atom or a deuterium atom.

In the fused polycyclic compound represented by Formula 2-1 to Formulas 2-10, Q₁₁₃ to Q₁₁₅ may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms or a substituted or unsubstituted heteroaryl group having 2 to 30 ring-forming carbon atoms, and/or may be bonded to an adjacent group to form a ring.

In the fused polycyclic compound represented by Formula 2-1 to Formula 2-10, X₁, X₄, and X₅ may each independently be an oxygen atom, a sulfur atom, a selenium atom, or a tellurium atom. X₂ may be a nitrogen atom. X₃ may be a carbon atom, a silicon atom, or a germanium atom.

In the fused polycyclic compound represented by Formula 2-1 to Formula 2-10, a₁₀₁, a₁₀₂, and a₁₁₆ may each independently be an integer of 0 to 5, a₁₀₃, a₁₀₄, a₁₀₅, a₁₀₈, a₁₁₀, a₁₁₁, and a₁₁₂ may each independently be an integer of 0 to 4, a₁₀₆ may be an integer of 0 to 3, a₁₀₉, a₁₁₄, a₁₁₇, a₁₁₈, and a₁₁₉ may each independently be an integer of 0 to 2, and a₁₀₇, and a₁₁₃ may each independently be 0 or 1.

For example, in Formula 2-1, when a₁₀₁ is 0, the fused polycyclic compound according to one or more embodiments may be unsubstituted with Q₁₀₁. A case where a₁₀₁ is 5 and Q₁₀₁s are hydrogen atoms may be the same as the case where a₁₀₁ is 0. When a₁₀₁ is an integer of 2 or more, Q₁₀₁s provided in plurality may be the same, or at least one selected from among the plurality of Q₁₀₁s may be different. In Formula 2-1, when a₁₀₂ is 0, the fused polycyclic compound according to one or more embodiments may be unsubstituted with Q₁₀₂. A case where a₁₀₂ is 5 and Q₁₀₂s are hydrogen atoms may be the same as the case where a₁₀₂ is 0. When a₁₀₂ is an integer of 2 or more, Q₁₀₂s provided in plurality may be the same, or at least one selected from among the plurality of Q₁₀₂s may be different. In Formula 2-2, when a₁₀₃ is 0, the fused polycyclic compound according to one or more embodiments may be unsubstituted with Q₁₀₃. A case where a₁₀₃ is 4 and Q₁₀₃ are hydrogen atoms may be the same as the case where a₁₀₃ is 0. When a₁₀₃ is an integer of 2 or more, Q₁₀₃s provided in plurality may be the same, or at least one selected from among the plurality of Q₁₀₃s may be different. In Formula 2-2, when a₁₀₄ is 0, the fused polycyclic compound according to one or more embodiments may be unsubstituted with Q₁₀₄. A case where a₁₀₄ is 4 and Q₁₀₄s are hydrogen atoms may be the same as the case where a₁₀₄ is 0. When a₁₀₄ is an integer of 2 or more, Q₁₀₄s provided in plurality may be the same, or at least one selected from among the plurality of Q₁₀₄s may be different. In Formula 2-3, when a₁₀₅ is 0, the fused polycyclic compound according to one or more embodiments may be unsubstituted with Q₁₀₅. A case where a₁₀₅ is 4 and Q₁₀₅s are hydrogen atoms may be the same as the case where a₁₀₅ is 0. When a₁₀₅ is an integer of 2 or more, Q₁₀₅s provided in plurality may be the same, or at least one selected from among the plurality of Q₁₀₅s may be different. In Formula 2-3, when a₁₀₆ is 0, the fused polycyclic compound according to one or more embodiments may be unsubstituted with Q₁₀₆. A case where a₁₀₆ is 3 and Q₁₀₆s are hydrogen atoms may be the same as the case where a₁₀₆ is 0. When a₁₀₆ is an integer of 2 or more, Q₁₀₆s provided in plurality may be the same, or at least one selected from among the plurality of Q₁₀₆s may be different. The same description in Formula 2-1 may be applied to a₁₀₁. In Formula 2-4, when a₁₀₇ is 0, the fused polycyclic compound according to one or more embodiments may be unsubstituted with Q₁₀₇. A case where a₁₀₇ is 1 and Q₁₀₇s are hydrogen atoms may be the same as the case where a₁₀₇ is 0. In Formula 2-4, when a₁₀₈ is 0, the fused polycyclic compound according to one or more embodiments may be unsubstituted with Q₁₀₈. A case where a₁₀₈ is 4 and Q₁₀₈s are hydrogen atoms may be the same as the case where a₁₀₈ is 0. When a₁₀₈ is an integer of 2 or more, Q₁₀₈s provided in plurality may each independently be the same, or at least one of the plurality of Q₁₀₈s may be different. The same description in Formula 2-1 may be applied to a₁₀₁. The same description in Formula 2-3 may be applied to a₁₀₅. In Formula 2-5, when a₁₀₉ is 0, the fused polycyclic compound according to one or more embodiments may be unsubstituted with Q₁₀₉. A case where a₁₀₉ is 2 and Q₁₀₉s are hydrogen atoms may be the same as the case where a₁₀₉ is 0. When a₁₀₉ is 2, Q₁₀₉s provided in plurality may be the same, or at least one selected from among the plurality of Q₁₀₉s may be different. In Formula 2-5, when a₁₁₀ is 0, the fused polycyclic compound according to one or more embodiments may be unsubstituted with Q₁₁₀. A case where a₁₁₀ is 4, and Q₁₁₀s are hydrogen atoms may be the same as the case where a₁₁₀ is 0. When a₁₁₀ is an integer of 2 or more, Q₁₁₀s provided in plurality may be the same, or at least one selected from among the plurality of Q₁₁₀s may be different. The same description as in Formula 2-2 may be applied to a₁₀₄. In Formula 2-6, when a₁₁₁ is 0, the fused polycyclic compound according to one or more embodiments may be unsubstituted with Q₁₁₁. A case a₁₁₁ is 4 and Q₁₁₁s are hydrogen atoms may be the same as the case a₁₁₁ is 0. When a₁₁₁ is an integer of 2 or more, Q₁₁₁s provided in plurality may be the same, or at least one selected from among the plurality of Q₁₁₁s may be different. In Formula 2-6, when a₁₁₂ is 0, the fused polycyclic compound according to one or more embodiments may be unsubstituted with Q₁₁₂. A case where a₁₁₂ is 4 and Q₁₁₂s are hydrogen atoms may be the same as the case a₁₁₂ is 0. When a₁₁₂ is an integer of 2 or more, Q₁₁₂s provided in plurality may be the same, or at least one selected from among the plurality of Q₁₁₂s may be different. In Formula 2-7, when a₁₁₃ is 0, the fused polycyclic compound according to one or more embodiments may be unsubstituted with Q₁₁₃. A case where a₁₁₃ is 1 and Q₁₁₁s are hydrogen atoms may be the same as the case a₁₁₃ is 0. The same descriptions as in Formula 2-6 may be applied to a₁₁₁ and a₁₁₂. In Formula 2-8, when a₁₁₄ is 0, the fused polycyclic compound according to one or more embodiments may be unsubstituted with Q₁₁₄. A case where a₁₁₄ is 2 and Q₁₁₄s are hydrogen atoms may be the same as the case where a₁₁₄ is 0. When a₁₁₄ is 2, Q₁₁₄s provided in plurality may be the same, or at least one selected from among the plurality of Q₁₁₄s may be different. The same descriptions as in Formula 2-6 may be applied to a₁₁₁ and a₁₁₂. In Formula 2-9, when a₁₁₆ is 0, the fused polycyclic compound according to one or more embodiments may be unsubstituted with Q₁₁₆. A case a₁₁₆ is 5 and Q₁₁₆s are hydrogen atoms may be the same as the case where a₁₁₆ is 0. When a₁₁₆ is an integer of 2 or more, Q₁₁₆s provided in plurality may be the same, or at least one selected from among the plurality of Q₁₁₆s may be different. In Formula 2-10, when a₁₁₇ is 0, the fused polycyclic compound according to one or more embodiments may be unsubstituted with Q₁₁₇. A case where a₁₁₇ is 2, and Q₁₁₇s are hydrogen atoms may be the same as the case where a₁₁₇ is 0. When a₁₁₇ is 2, Q₁₁₇s provided in plurality may be the same, or at least one selected from among the plurality of Q₁₁₇s may be different. When a₁₁₈ is 0, the fused polycyclic compound according to one or more embodiments may be unsubstituted with Q₁₁₈. A case where a₁₁₈ is 2, and Q₁₁₈s are hydrogen atoms may be the same as the case where a₁₁₈ is 0. When a₁₁₈ is 2, Q₁₁₈s provided in plurality may be the same, or at least one selected from among the plurality of Q₁₁₈s may be different. When a₁₁₉ is 0, the fused polycyclic compound according to one or more embodiments may be unsubstituted with Q₁₁₉. A case a₁₁₉ is 2 and Q₁₁₉s are hydrogen atoms may be the same as the case where a₁₁₉ is 0. When a₁₁₉ is 2, Q₁₁₉s provided in plurality may be the same, or at least one selected from among the plurality of Q₁₁₉s may be different.

In Formula 2-1 to Formula 2-10, the same descriptions as in Formula 1 may be applied to Q₁ to Q₄, Q₅₁ to Q₅₆, Q₆, and a to k.

The first compound represented by Formula 1 may be represented by Formula 3.

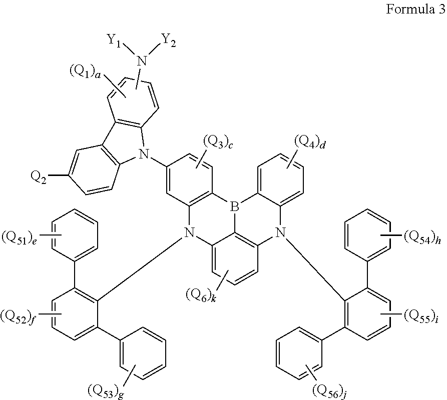

In Formula 3, the same descriptions as in Formula 1 may be applied to Y₁, Y₂, Q₁ to Q₄, Q₅₁ to Q₅₆, Q₆, a, and c to k.

In the fused polycyclic compound represented by Formula 3, Q₂ may be represented by any one selected from among Formula 3-1 to Formula 3-5.

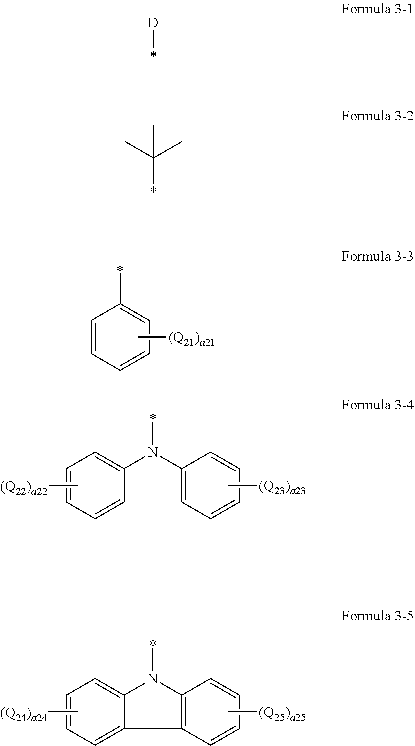

In Formula 3-1, D is a deuterium atom.

In Formula 3-3 to Formula 3-5, Q₂₁ to Q₂₅ may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or a substituted or unsubstituted amine group, and/or may be bonded to an adjacent group to form a ring. For example, Q₂₁ to Q₂₅ may be a hydrogen atom or a deuterium atom. a₂₁ to a₂₃ may be an integer of 0 to 5. a₂₄ and a₂₅ may each independently be an integer of 0 to 4.

In Formula 3-3, when a₂₁ is 0, the fused polycyclic compound according to one or more embodiments may be unsubstituted with Q₂₁. A case where a₂₁ is 5 and Q₂₁s are hydrogen atoms may be the same as the case where a₂₁ is 0. When a₂₁ is an integer of 2 or more, Q₂₁s provided in plurality may be the same, or at least one selected from among the plurality of Q₂₁s may be different. In Formula 3-4, when a₂₂ is 0, the fused polycyclic compound according to one or more embodiments may be unsubstituted with Q₂₂. A case where a₂₂ is 5 and Q₂₂s are hydrogen atoms may be the same as the case where a₂₂ is 0. When a₂₂ is an integer of 2 or more, Q₂₂s provided in plurality may be the same, or at least one selected from among the plurality of Q₂₂s may be different. When a₂₃ is 0, the fused polycyclic compound according to one or more embodiments may be unsubstituted with Q₂₃. A case where a₂₃ is 5 and Q₂₃s are hydrogen atoms may be the same as the case where a₂₃ is 0. When a₂₃ is an integer of 2 or more, Q₂₃s provided in plurality may be the same, or at least one selected from among the plurality of Q₂₃s may be different. In Formula 3-5, when a₂₄ is 0, the fused polycyclic compound according to one or more embodiments may be unsubstituted with Q₂₄. A case where a₂₄ is 4 and Q₂₄s are hydrogen atoms may be the same as the case where a₂₄ is 0. When a₂₄ is an integer of 2 or more, Q₂₄s provided in plurality may be the same, or at least one selected from among the plurality of Q₂₄s may be different. When a₂₅ is 0, the fused polycyclic compound according to one or more embodiments may be unsubstituted with Q₂₅. A case where a₂₅ is 4 and Q₂₅s are hydrogen atoms may be the same as the case where a₂₅ is 0. When a₂₅ is an integer of 2 or more, Q₂₅s provided in plurality may be the same, or at least one selected from among the plurality of Q₂₅s may be different.

In Formula 3-1 to Formula 3-5, -* is a position connected to Formula 3.

The first compound represented by Formula 1 may be represented by Formula 4 or Formula 5.

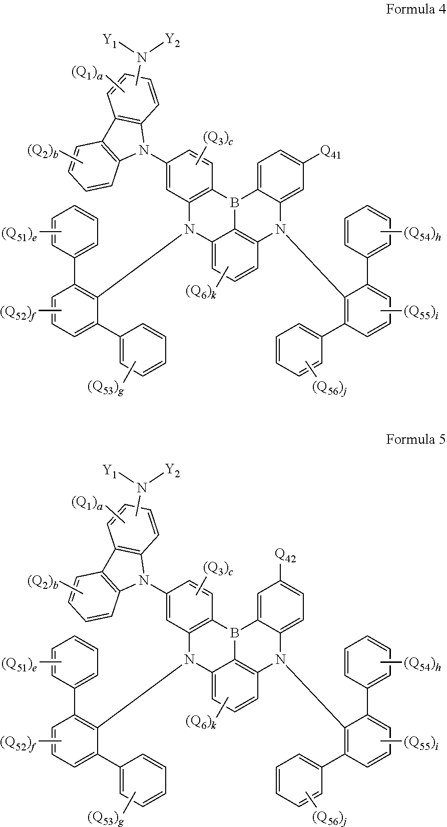

In Formula 4 and/or Formula 5, Q₄₁ and Q₄₂ may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or a substituted or unsubstituted amine group.

In Formulas 4 and 5, the same descriptions as in Formulas 1 may be applied to Y₁, Y₂, Q₁ to Q₃, Q₅₁ to Q₅₆, Q₆, a to c, and e to k.

In the fused polycyclic compound represented by Formula 4, Q₄₁ may be represented by Formula 4-1 or Formula 4-2.

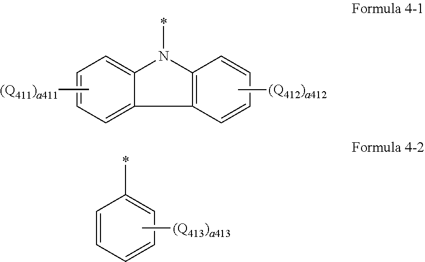

In Formula 4-1 and Formula 4-2, Q₄₁₁, Q₄₁₂, and Q₄₁₃ may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or a substituted or unsubstituted amine group, and/or may be bonded to an adjacent group to form a ring.

In Formula 4-1, a₄₁₁ and a₄₁₂ may each independently be an integer of 0 to 4, and in Formula 4-2, a₄₁₃ is an integer of 0 to 5.

In Formula 4-1, when a₄₁₁ is 0, the fused polycyclic compound according to one or more embodiments may be unsubstituted with Q₄₁₁. A case where a₄₁₁ is 4 and Q₄₁₁s are hydrogen atoms may be the same as the case where a₄₁₁ is 0. When a₄₁₁ is an integer of 2 or more, Q₄₁₁s provided in plurality may be the same, or at least one among the plurality of Q₄₁₁s may be different. In Formula 4-1, when a₄₁₂ is 0, the fused polycyclic compound according to one or more embodiments may be unsubstituted with Q₄₁₂. A case where a₄₁₂ is 4 and Q₄₁₂s are hydrogen atoms may be the same as the case where a₄₁₂ is 0. When a₄₁₂ is an integer of 2 or more, Q₄₁₂s provided in plurality may be the same, or at least one selected from among the plurality of Q₄₁₂s may be different. In Formula 4-2, when a₄₁₃ is 0, the fused polycyclic compound according to one or more embodiments may be unsubstituted with Q₄₁₃. A case where a₄₁₃ is 5 and Q₄₁₃s are hydrogen atoms may be the same as the case where a₄₁₃ is 0. When a₄₁₃ is an integer of 2 or more, Q₄₁₃s provided in plurality may be the same, or at least one selected from among the plurality of Q₄₁₃s may be different.

In Formula 4-1 and Formula 4-2, -* is a position connected to Formula 4.

In the fused polycyclic compound represented by Formula 5, Q₄₂ may be represented by Formula 4-3 or 4-4.

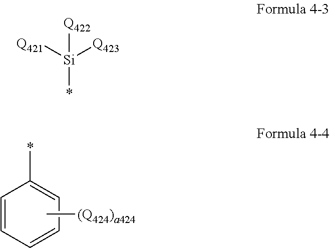

In Formula 4-3, Q₄₂₁ to Q₄₂₃ may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms or a substituted or unsubstituted heteroaryl group having 2 to 30 ring-forming carbon atoms, and/or may be bonded to an adjacent group to form a ring.

In Formula 4-4, Q₄₂₄ may be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or a substituted or unsubstituted amine group, and/or may be bonded to an adjacent group to form a ring.

In Formula 4-4, a₄₂₄ may be an integer of 0 to 5.

When a₄₂₄ is 0, the fused polycyclic compound according to one or more embodiments may be unsubstituted with Q₄₂₄. A case where a₄₂₄ is 5 and Q₄₂₄ are hydrogen atoms may be the same as the case where a₄₂₄ is 0. When a₄₂₄ is an integer of 2 or more, Q₄₂₄s provided in plurality may be the same or at least one selected from among the plurality of Q₄₂₄s may be different.

In Formula 4-3 and Formula 4-4, -* is a position connected to Formula 5.

The first compound represented by Formula 1 may be represented by Formula 6.

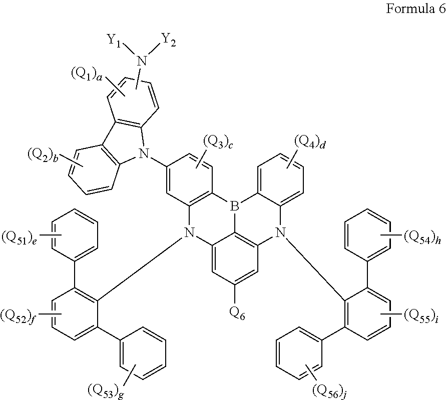

In Formula 6, the same descriptions as in Formula 1 may be applied to Y₁, Y₂, Q₁ to Q₄, Q₅₁ to Q₅₆, Q₆, and a to j.

In the fused polycyclic compound represented by Formula 6, Q₆ may be represented by any one selected from among Formula 6-1 to Formula 6-6.

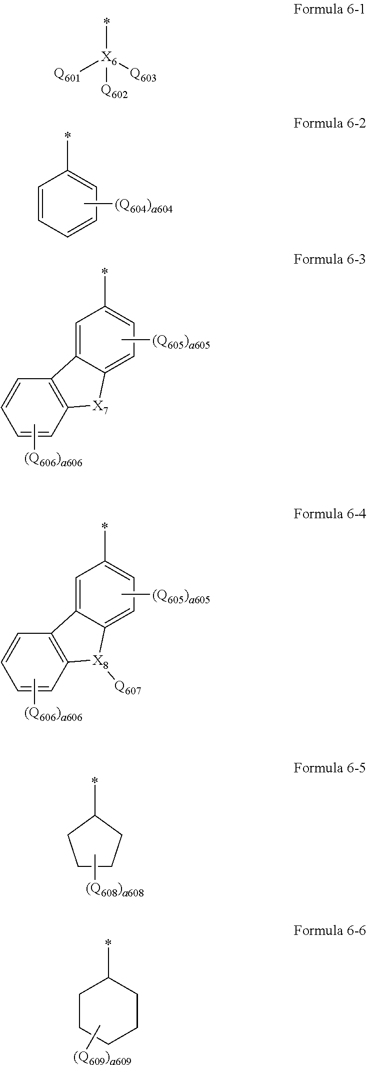

In Formulas 6-1 to 6-6, X₆ may be a carbon atom, a silicon atom, or a germanium atom, X₇ may be an oxygen atom, a sulfur atom, a selenium atom, or a tellurium atom, and X₈ may be a nitrogen atom.

In Formulas 6-1 to 6-6, Q₆₀₁ to Q₆₀₆, Q₆₀₈, and Q₆₀₉ may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or a substituted or unsubstituted amine group, and/or may be bonded to an adjacent group to form a ring. Q₆₀₇ may be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In Formula 6-2, a₆₀₄ is an integer of 0 to 5. In Formulas 6-3 and 6-4, a₆₀₅ is an integer of 0 to 3. In Formula 6-5, a₆₀₈ is an integer of 0 to 9. In Formula 6-6, a₆₀₉ is an integer of 0 to 11.

When a₆₀₄ is 0, the fused polycyclic compound according to one or more embodiments may be unsubstituted with Q₆₀₄. A case where a₆₀₄ is 5 and Q₆₀₄s are hydrogen atoms may be the same as the case where a₆₀₄ is 0. When a₆₀₄ is an integer of 2 or more, Q₆₀₄s provided in plurality may be the same, or at least one selected from among the plurality of Q₆₀₄s may be different. When a₆₀₅ is 0, the fused polycyclic compound according to one or more embodiments may be unsubstituted with Q₆₀₅. A case where a₆₀₅ is 3 and Q₆₀₅s are hydrogen atoms may be the same as the case where a₆₀₅ is 0. When a₆₀₅ is an integer of 2 or more, Q₆₀₅s provided in plurality may be the same or at least one selected from among the plurality of Q₆₀₅s may be different. a₆₀₆ is an integer of 0 to 4. When a₆₀₆ is 0, the fused polycyclic compound according to one or more embodiments may be unsubstituted with Q₆₀₆. A case where a₆₀₆ is 4 and Q₆₀₆ are hydrogen atoms may be the same as the case where a₆₀₆ is 0. When a₆₀₆ is an integer of 2 or more, Q₆₀₅s provided in plurality may be the same or at least one selected from among the plurality of Q₆₀₆s may be different. When a₆₀₈ is 0, the fused polycyclic compound according to one or more embodiments may be unsubstituted with Q₆₀₈. A case where a₆₀₈ is 9 and Q₆₀₈ are hydrogen atoms may be the same as the case where a₆₀₈ is 0. When a₆₀₈ is an integer of 2 or more, Q₆₀₈s provided in plurality may be the same or at least one selected from among the plurality of Q₆₀₈s may be different. When a₆₀₈ is an integer of 2 or more, one a₆₀₈ or two a₆₀₈s may be bonded to one carbon atom. When a₆₀₉ is 0, the fused polycyclic compound according to one or more embodiments may be unsubstituted with Q₆₀₉. A case where a₆₀₉ is 5 and Q₆₀₉s are hydrogen atoms may be the same as the case where a₆₀₉ is 0. When a₆₀₉ is an integer of 2 or more, Q₆₀₉s provided in plurality may be the same or at least one selected from among the plurality of Q₆₀₉s may be different. When a₆₀₉ is an integer of 2 or more, one a₆₀₉ or two a₆₀₉s may be bonded to one carbon atom.

In Formula 6-1 to Formula 6-6, -* is a position connected to Formula 6.

The fused polycyclic compound according to one or more embodiments may be any one selected from among compounds present (e.g., a compound) in Compound Group 1. A light-emitting element ED according to one or more embodiments may include at least one fused polycyclic compound selected from among compounds present (e.g., a compound) in Compound Group 1 as a first compound in the emission layer EML.

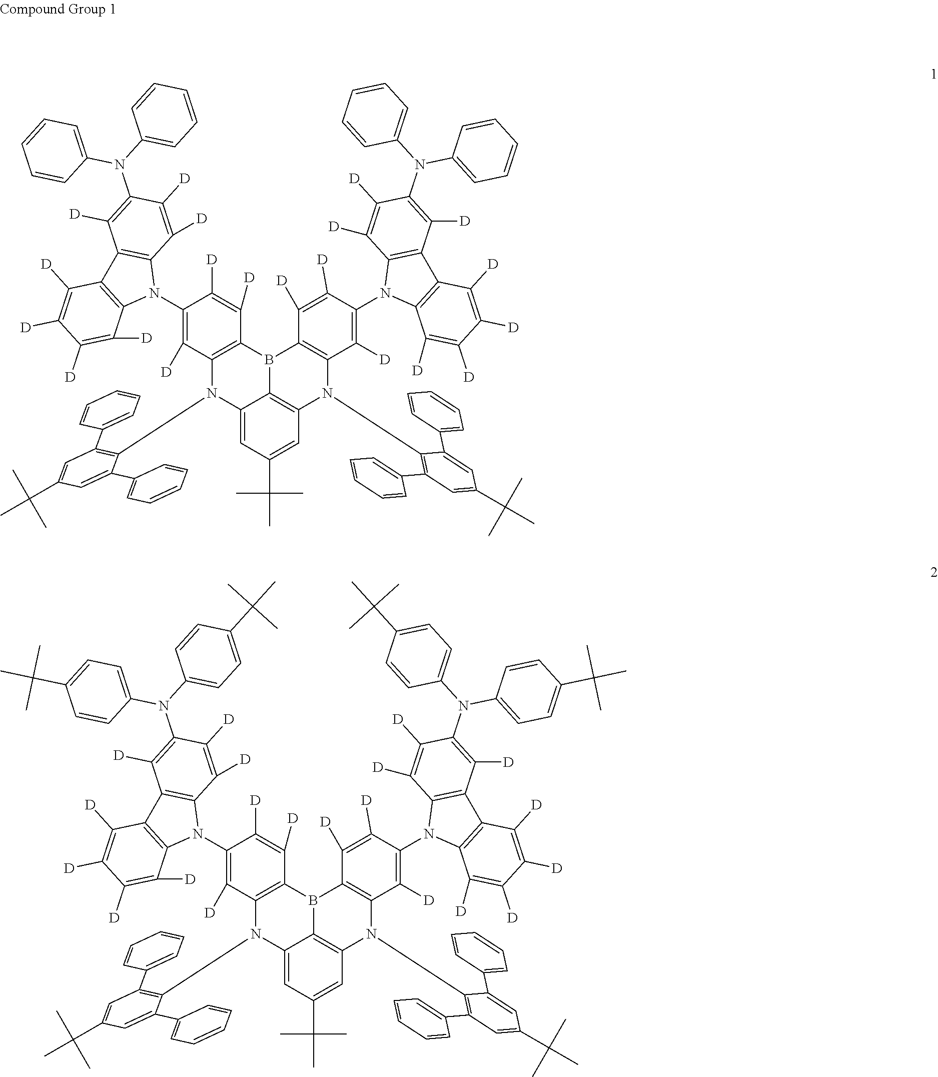

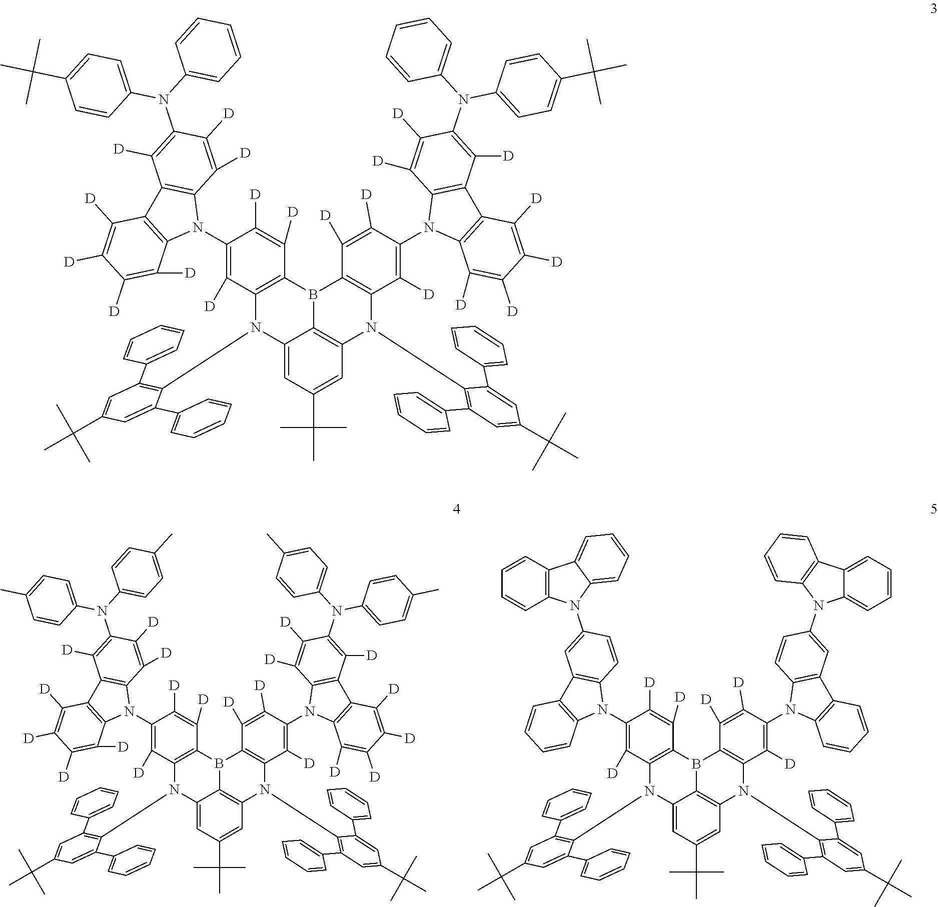

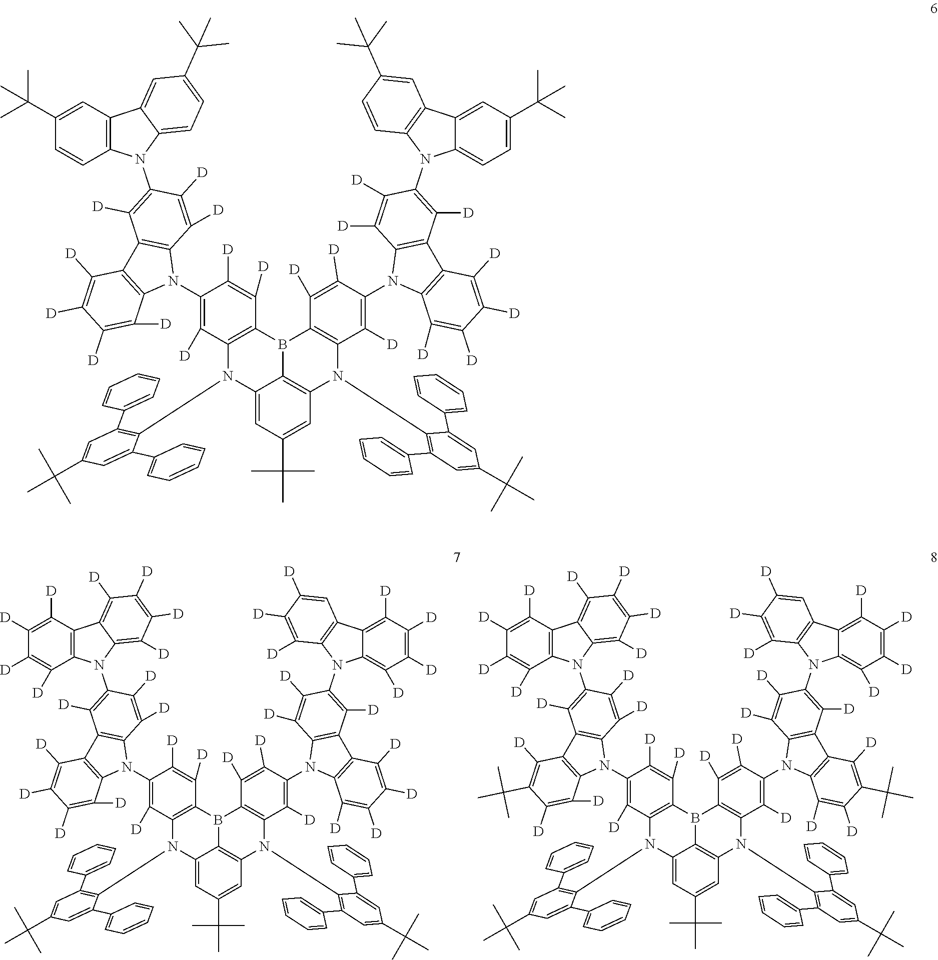

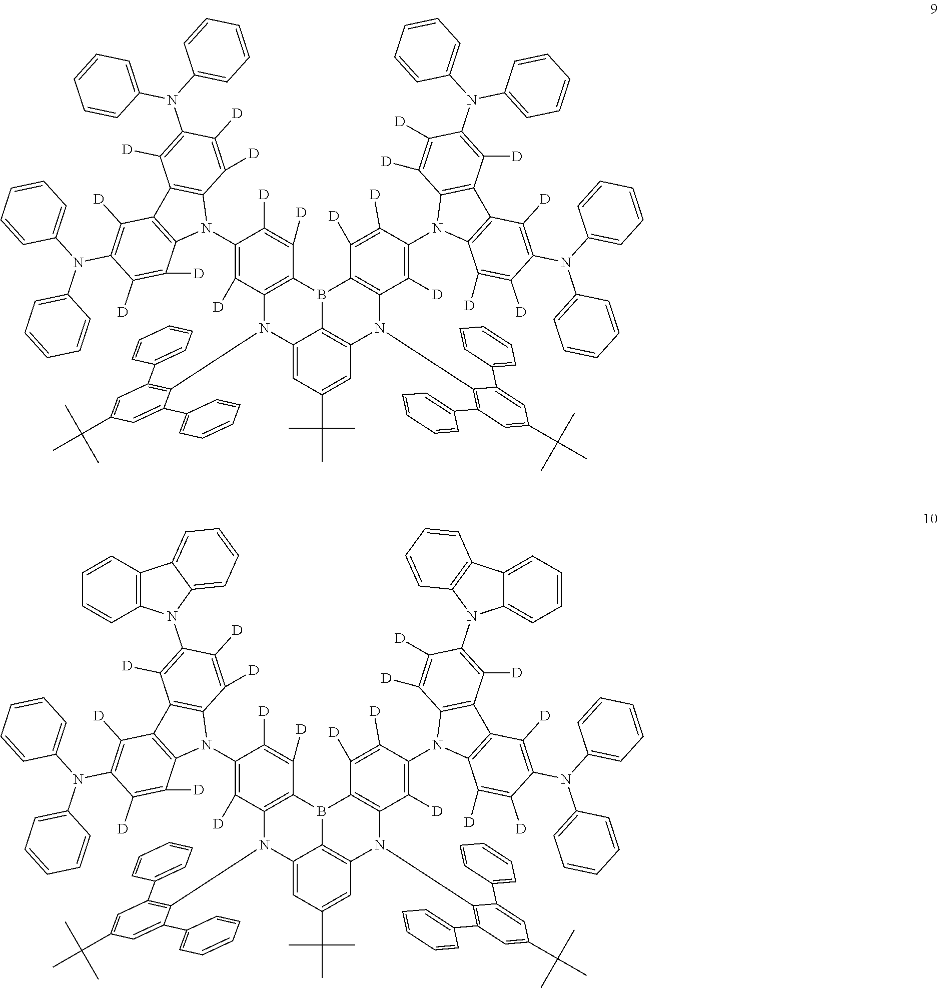

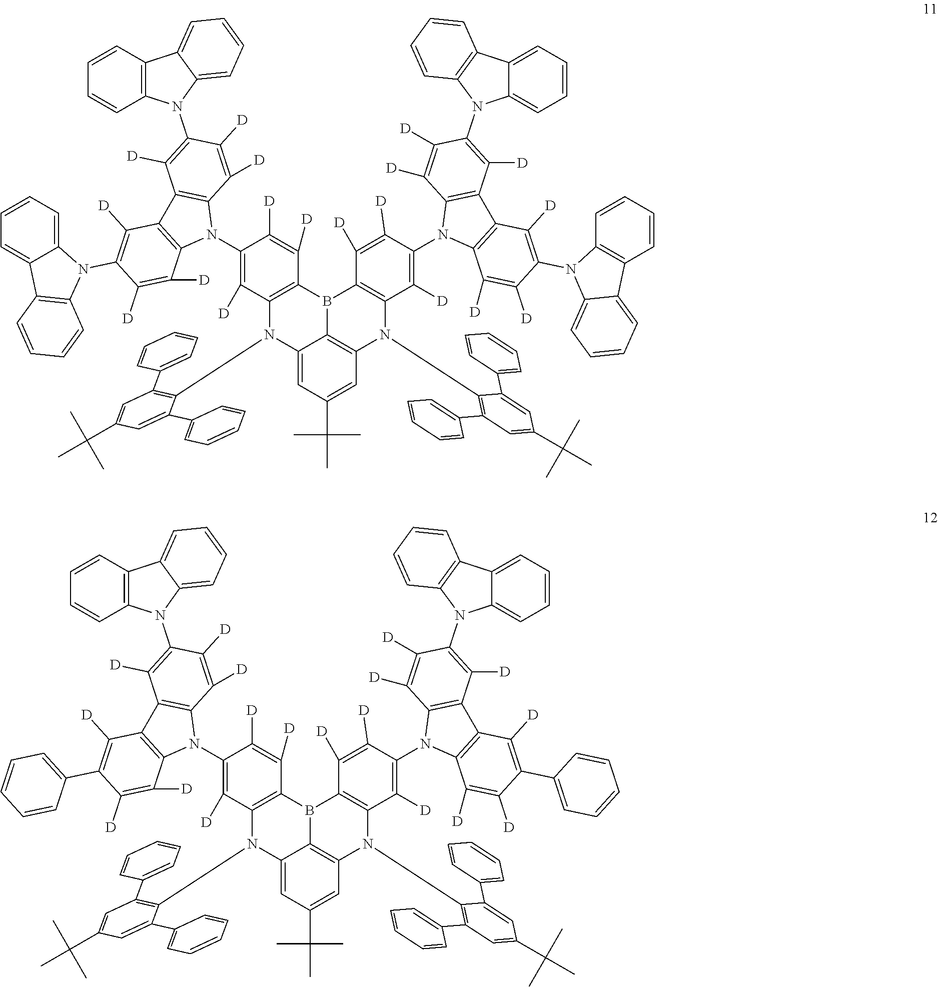

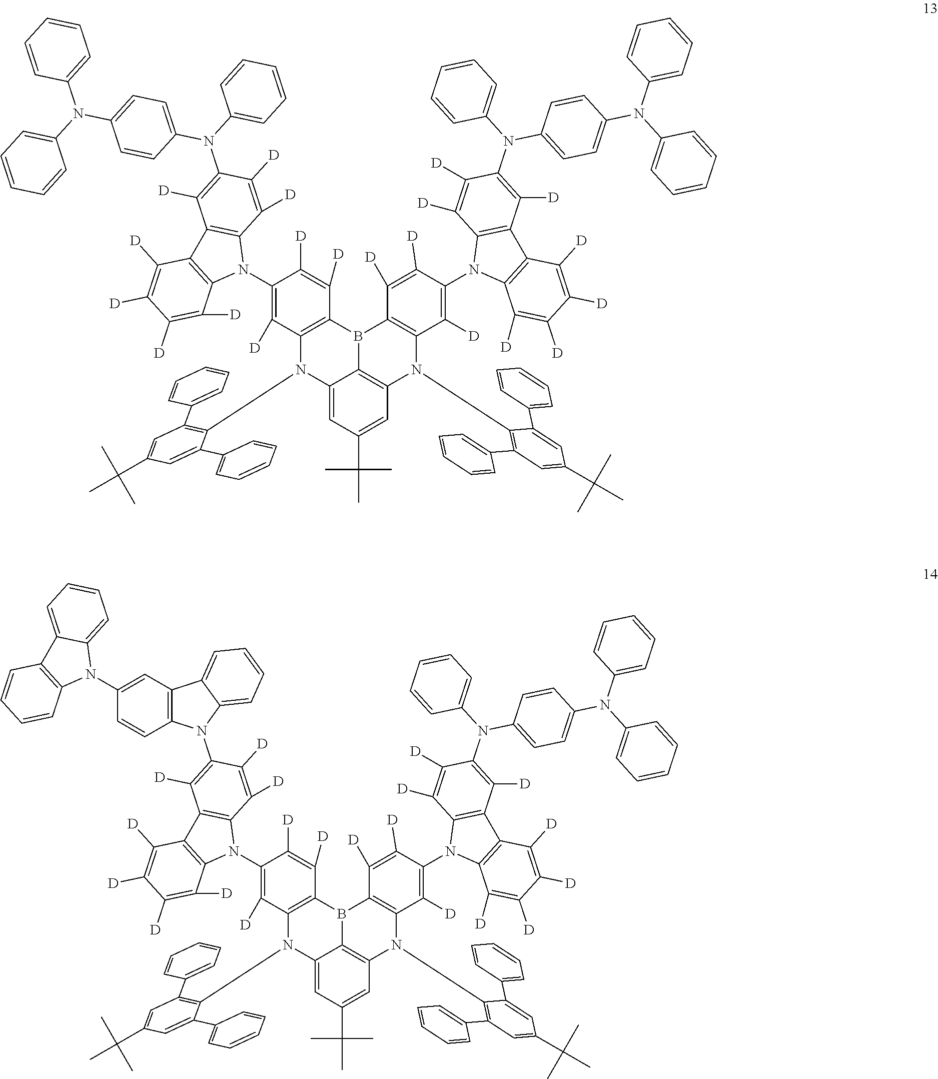

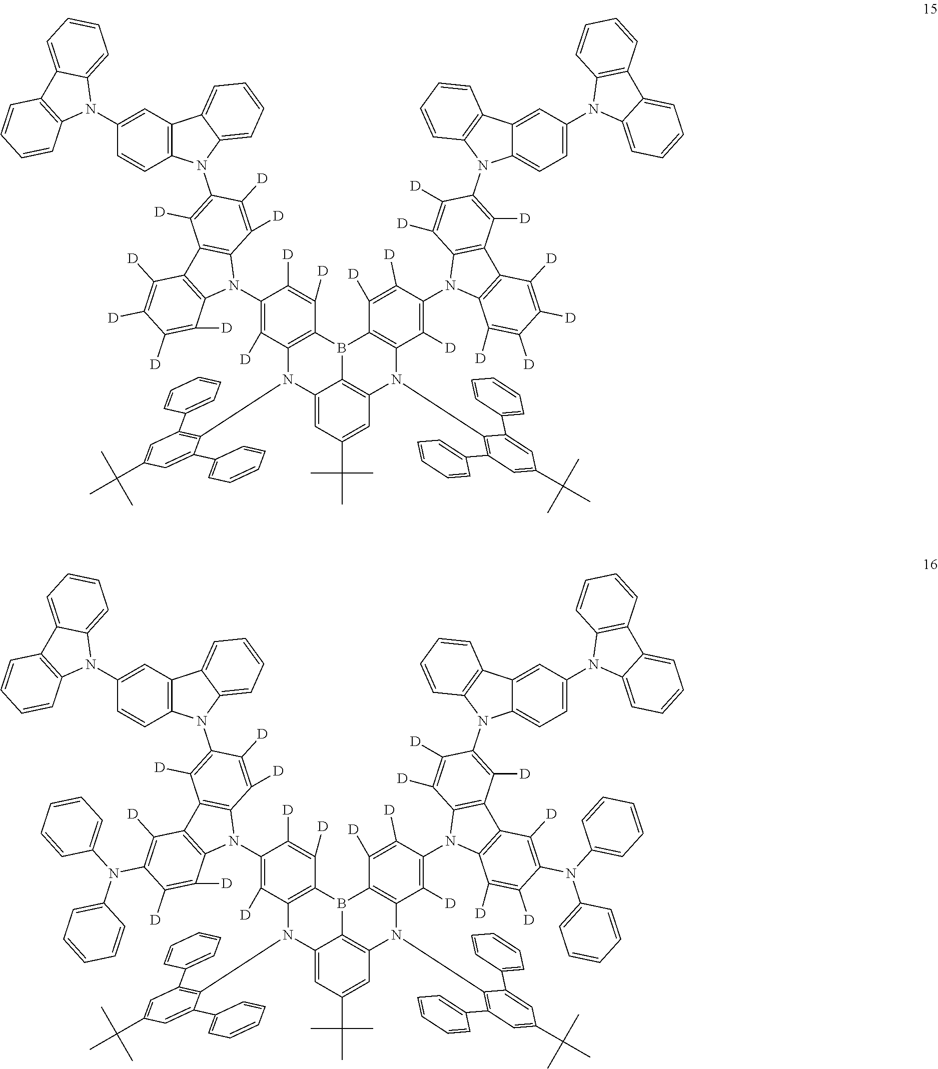

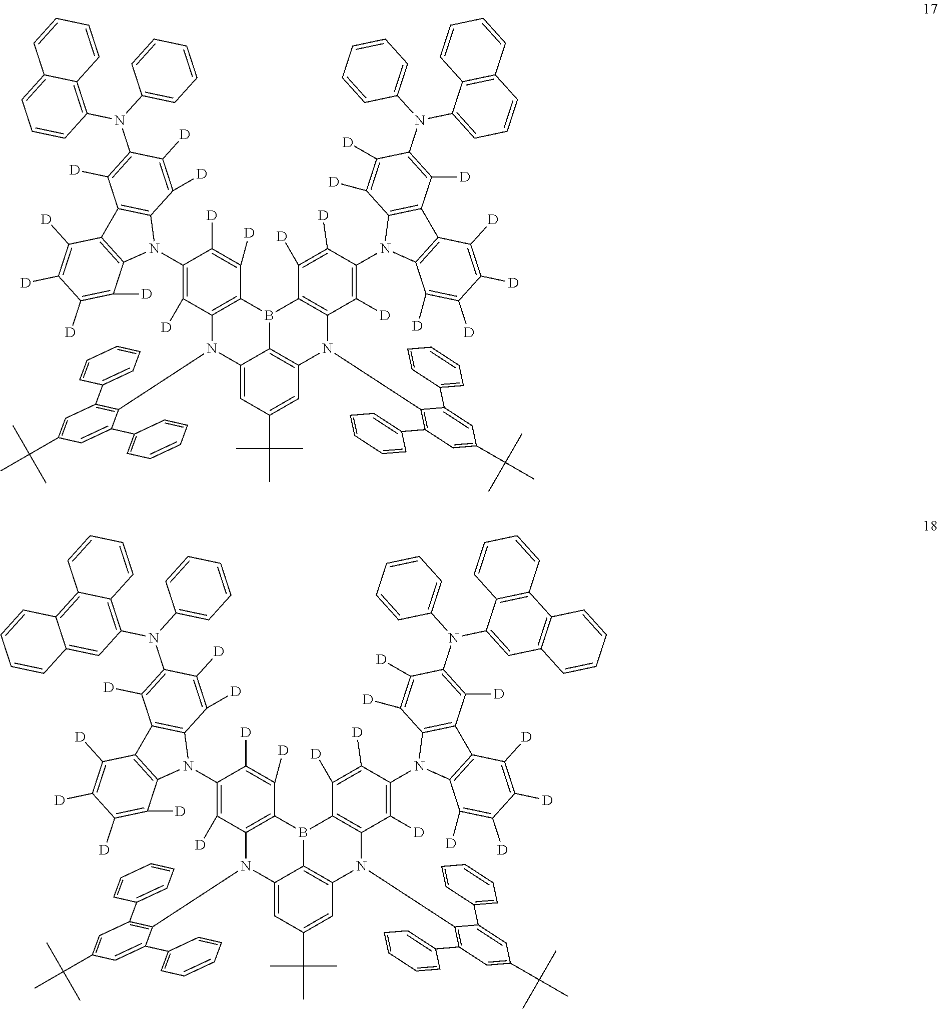

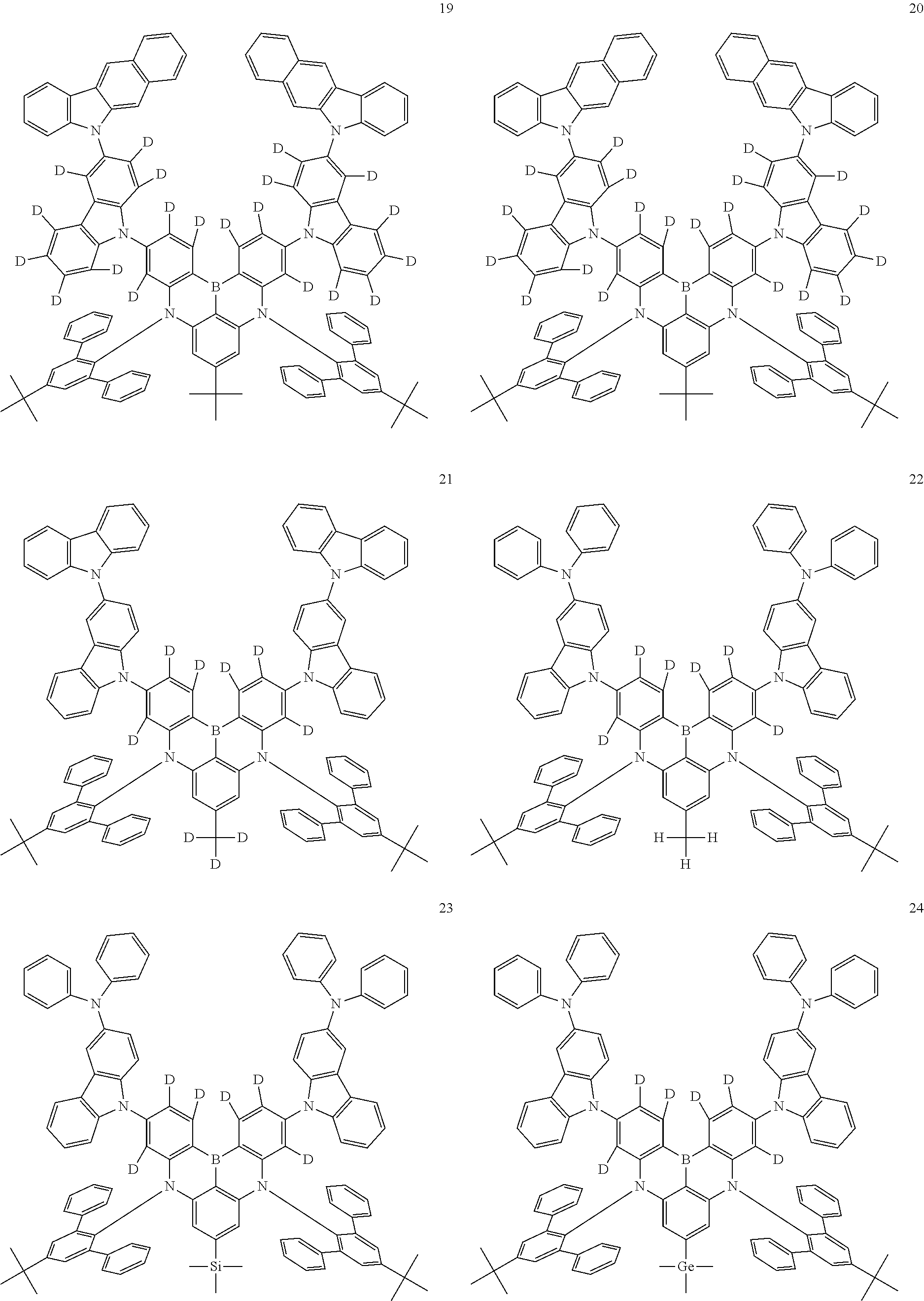

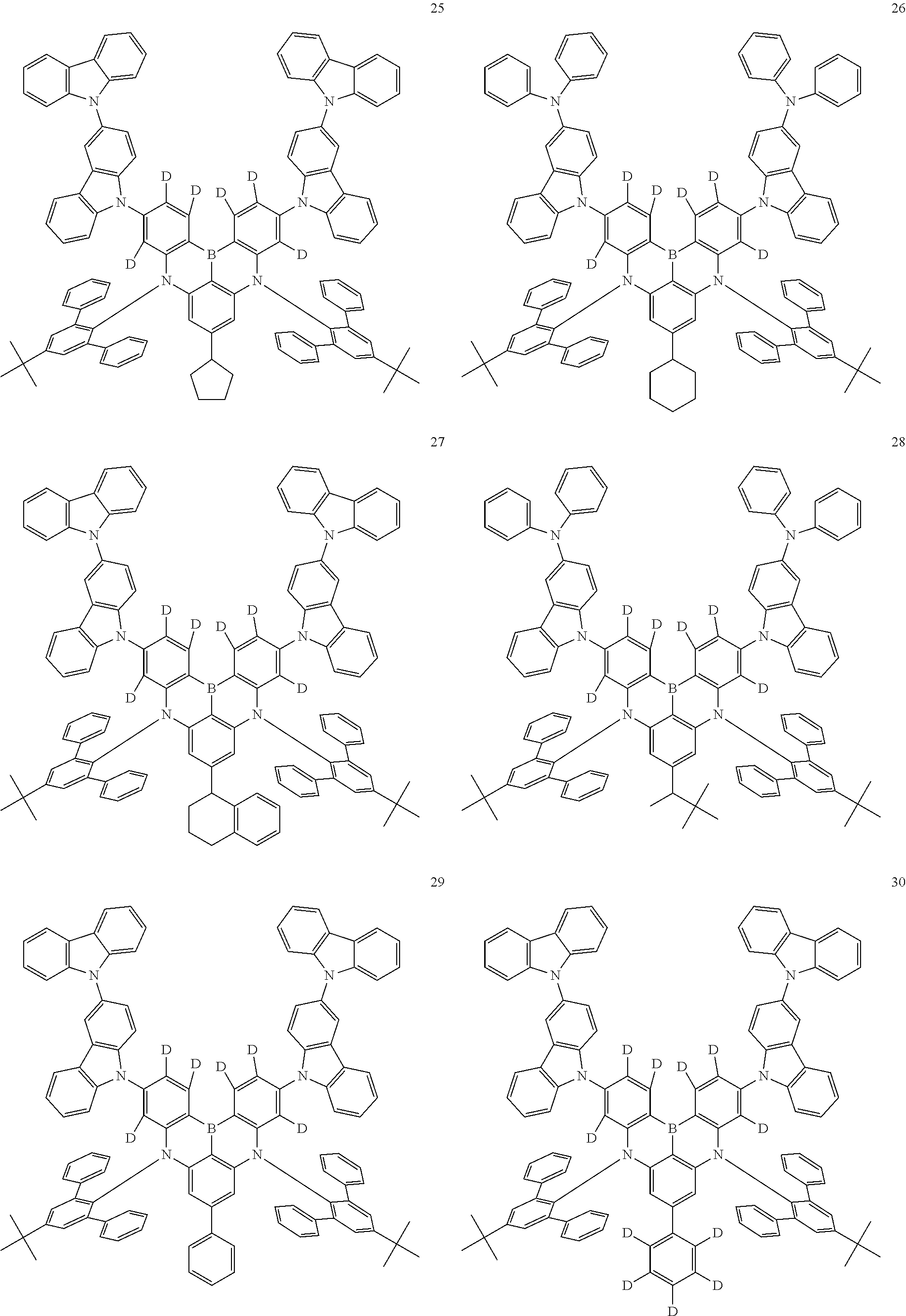

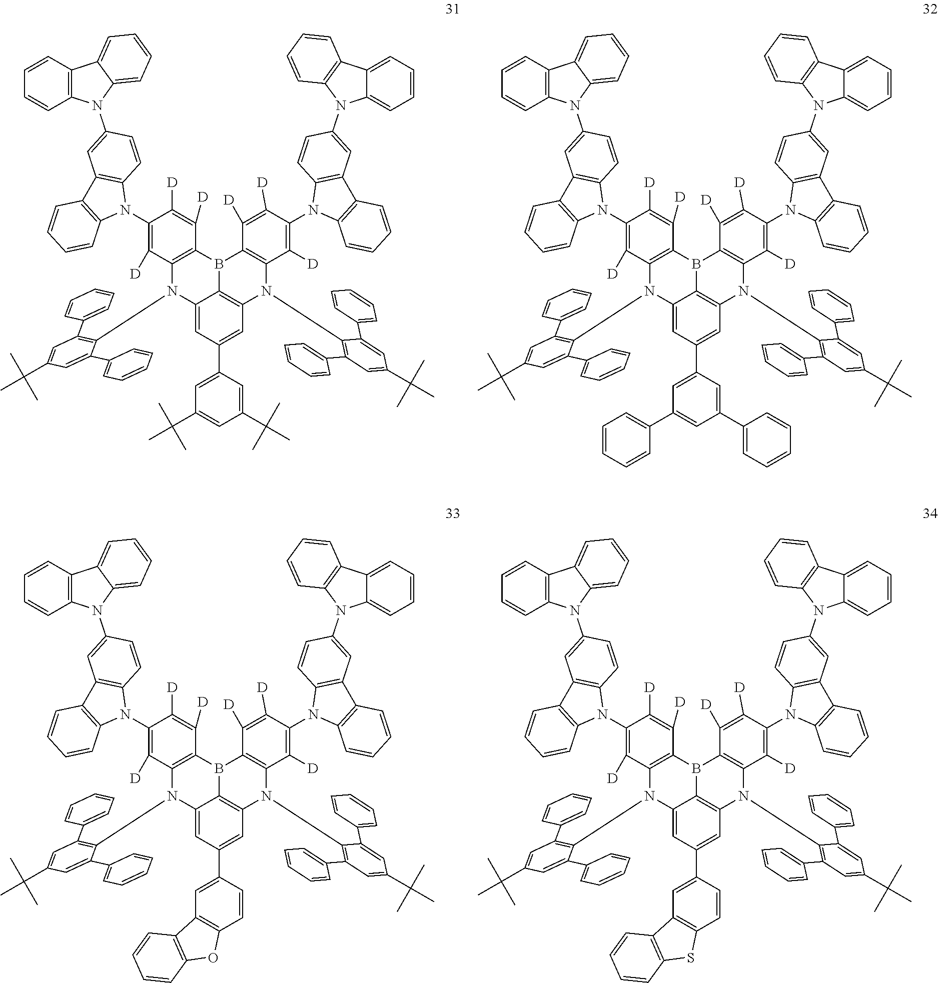

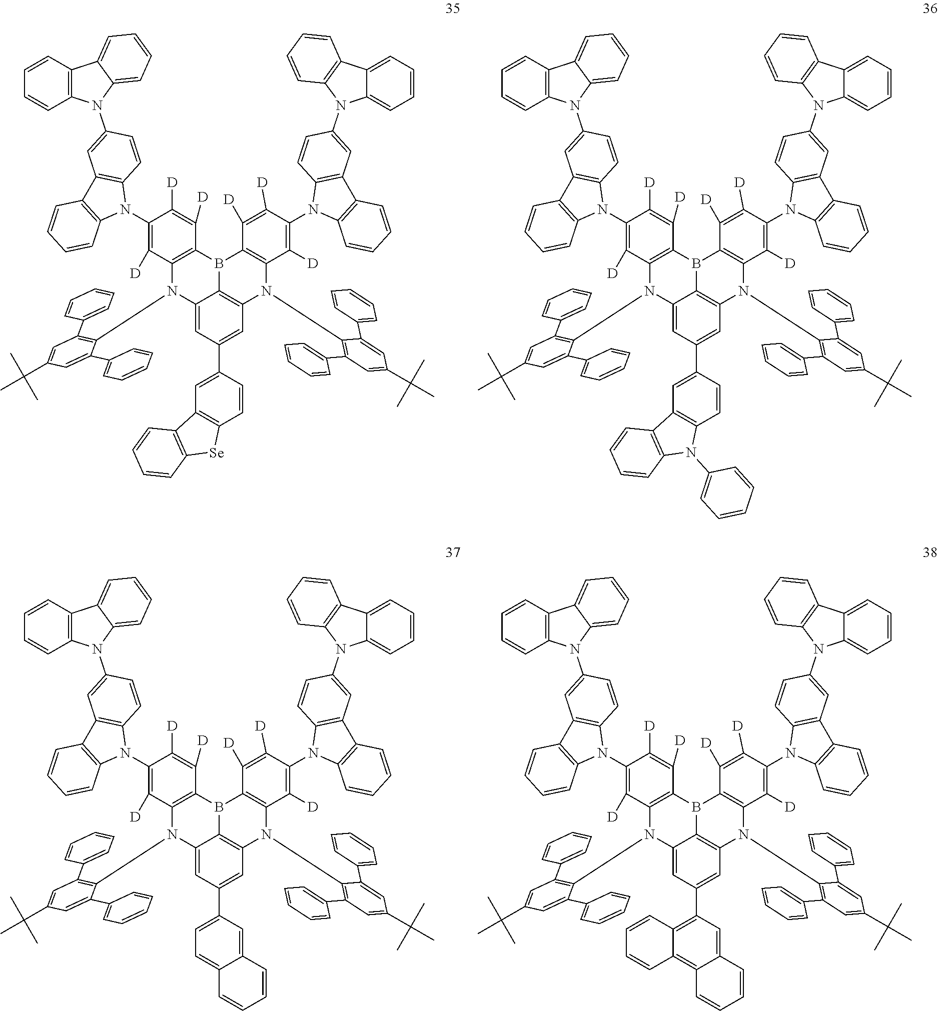

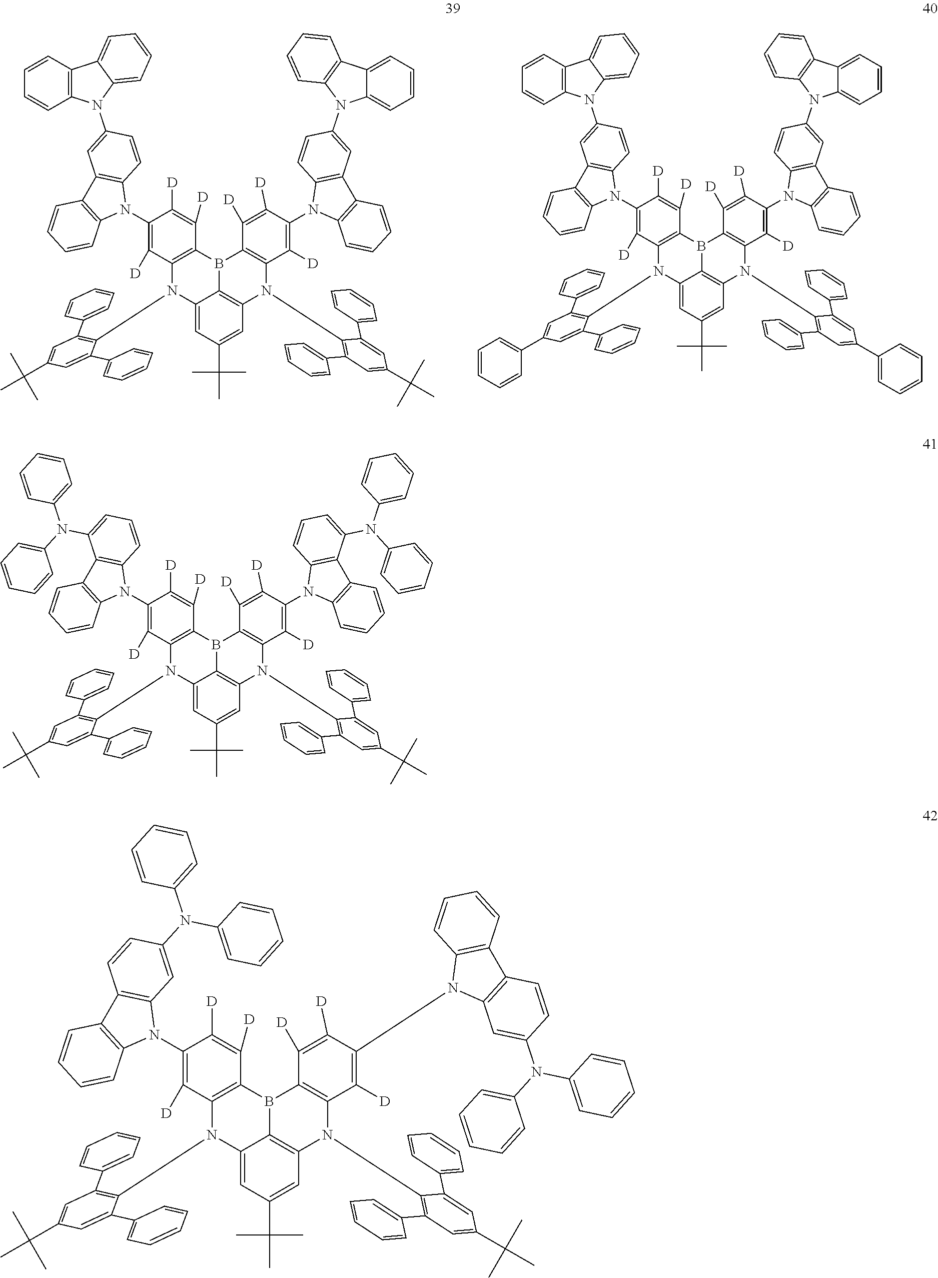

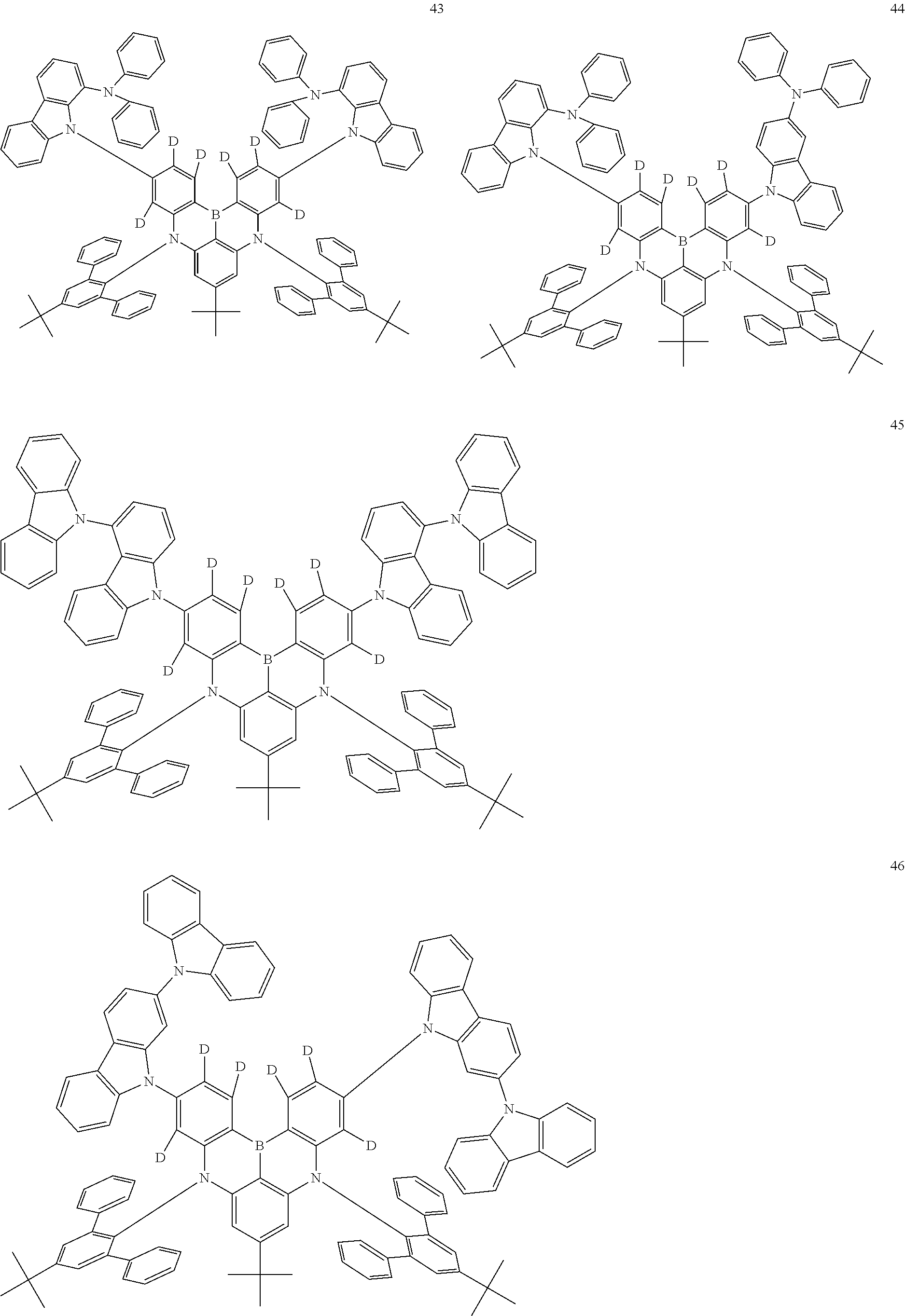

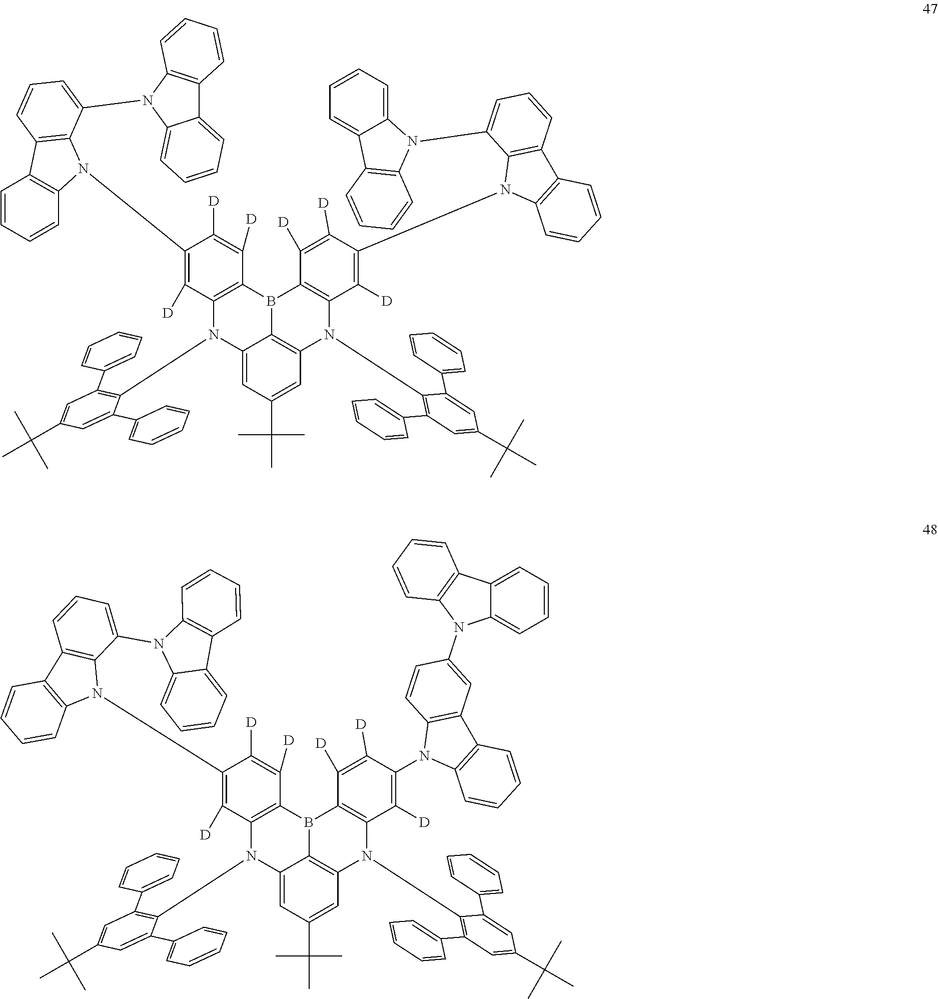 [SMILES: [2H]c1c([2H])c(-n2c3ccccc3c3cccc(-n4c5ccccc5c5ccccc54)c32)c([2H])c2c1B1c3c(cc(C(C)(C)C)cc3N(c3c(-c4ccccc4)cc(C(C)(C)C)cc3-c3ccccc3)c3c([2H])c(-n4c5ccccc5c5cccc(-n6c7ccccc7c7ccccc76)c54)c([2H])c([2H])c31)N2c1c(-c2ccccc2)cc(C(C)(C)C)cc1-c1ccccc1 ; [2H]c1c([2H])c(-n2c3ccccc3c3cc(-n4c5ccccc5c5ccccc54)ccc32)c([2H])c2c1B1c3c(cc(C(C)(C)C)cc3N(c3c(-c4ccccc4)cc(C(C)(C)C)cc3-c3ccccc3)c3c([2H])c(-n4c5ccccc5c5cccc(-n6c7ccccc7c7ccccc76)c54)c([2H])c([2H])c31)N2c1c(-c2ccccc2)cc(C(C)(C)C)cc1-c1ccccc1]

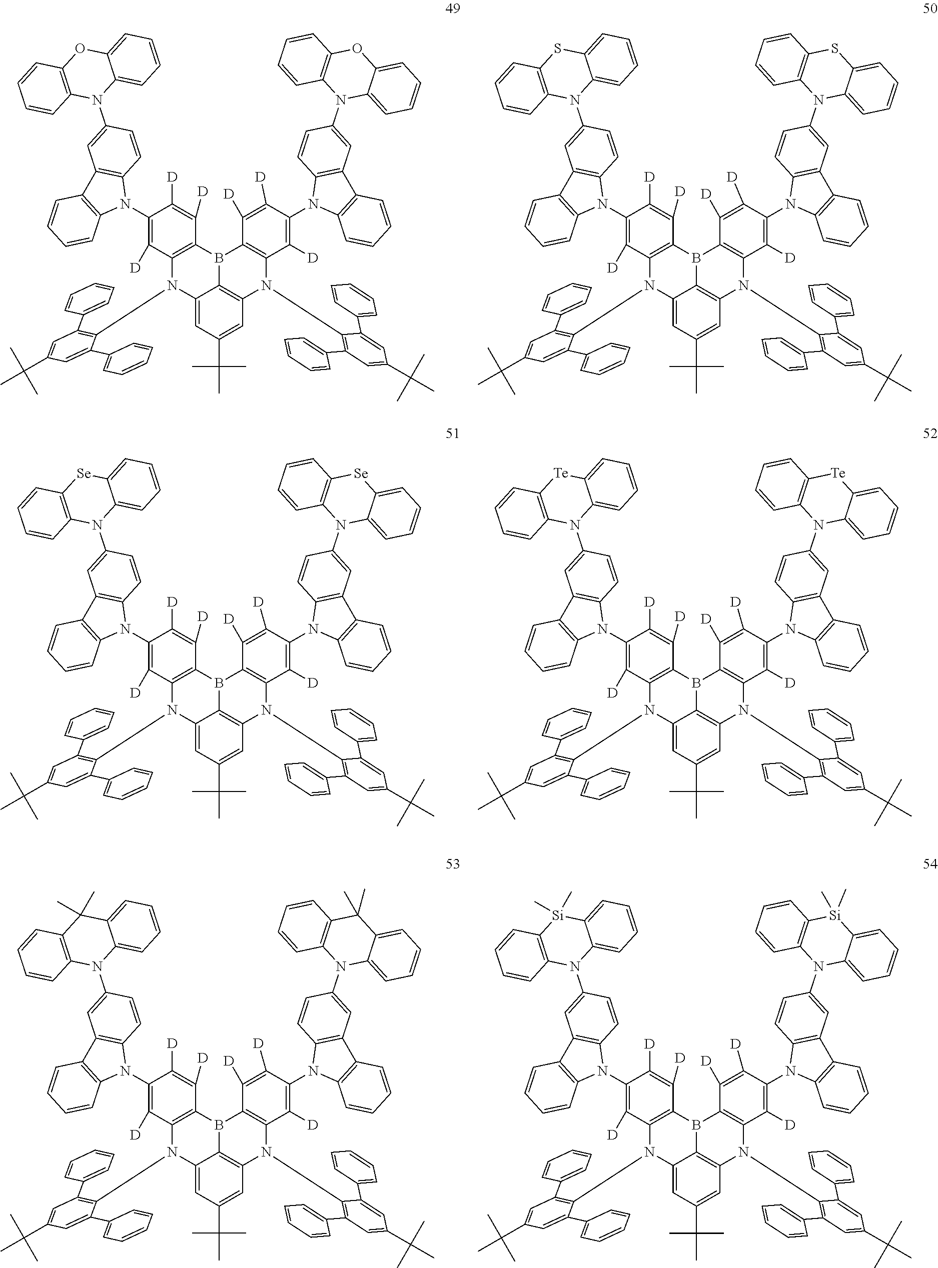

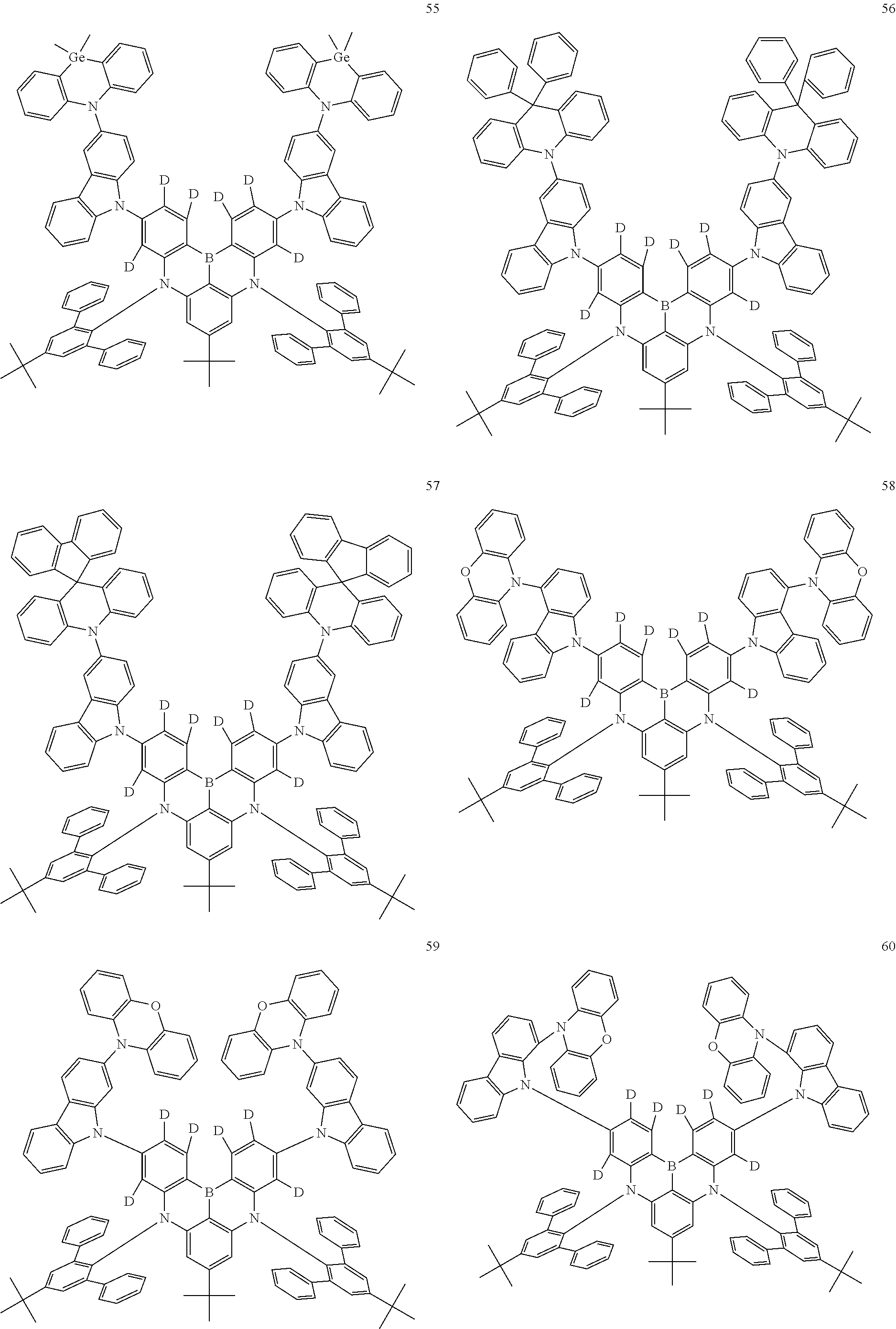

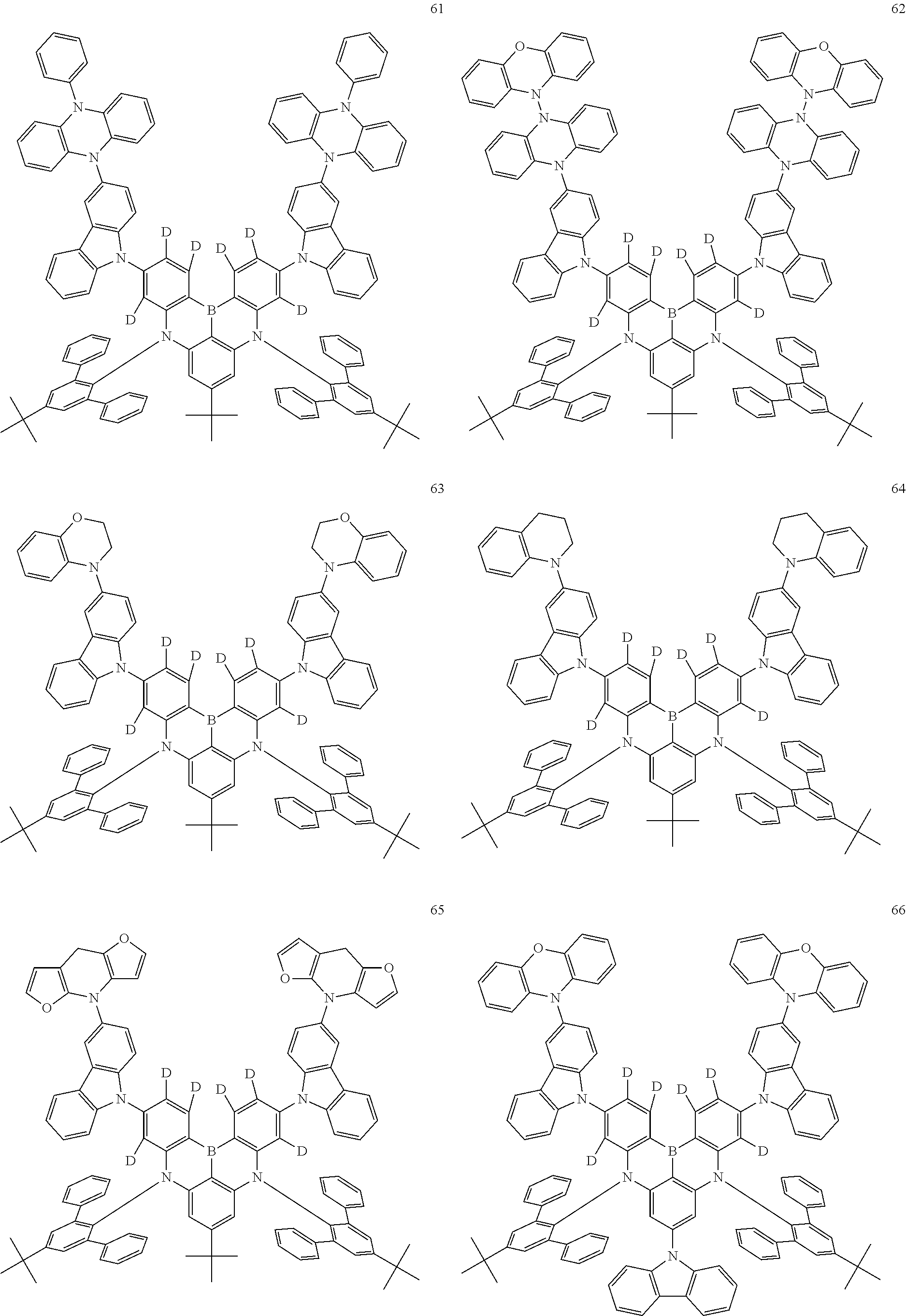

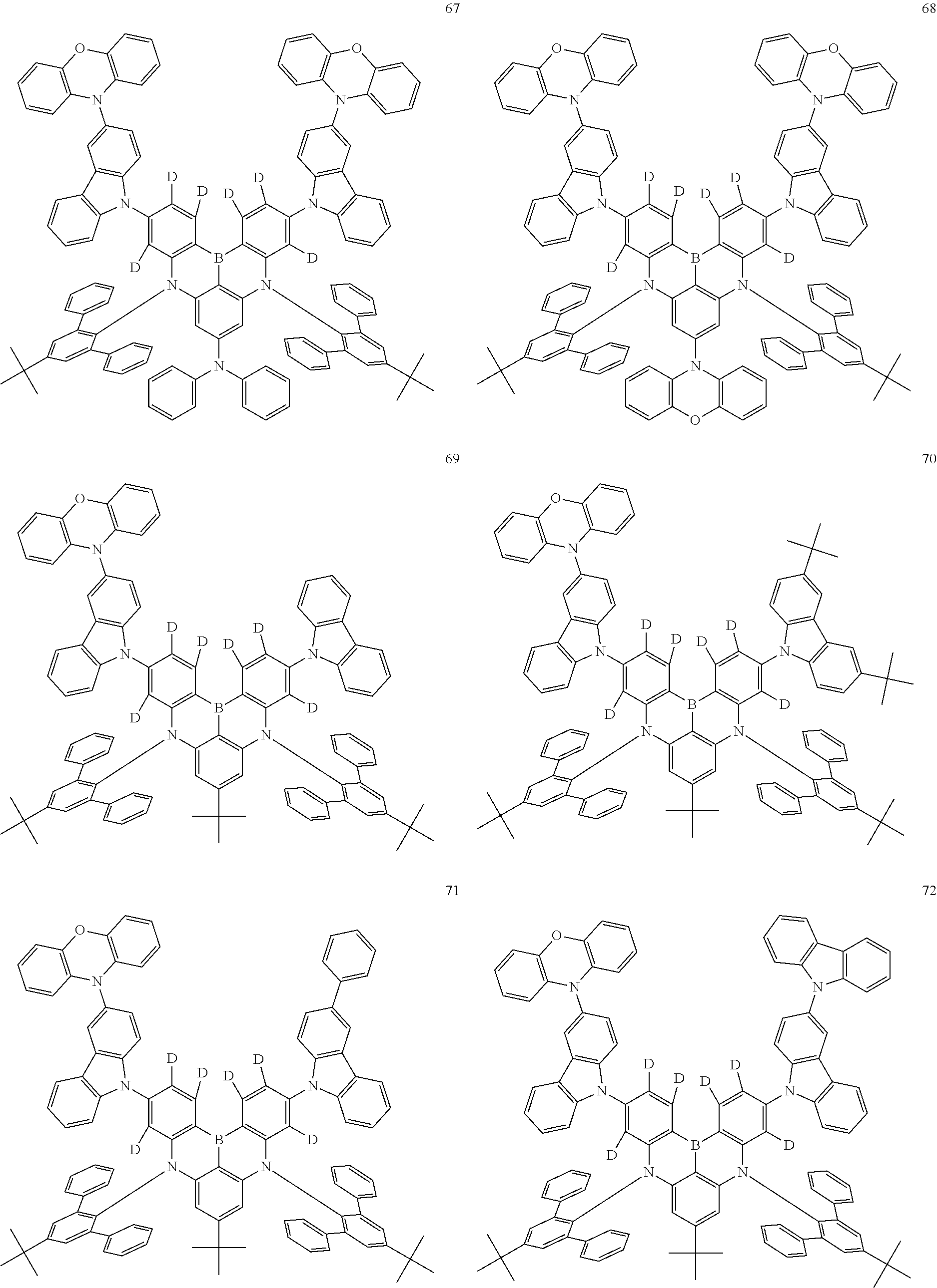

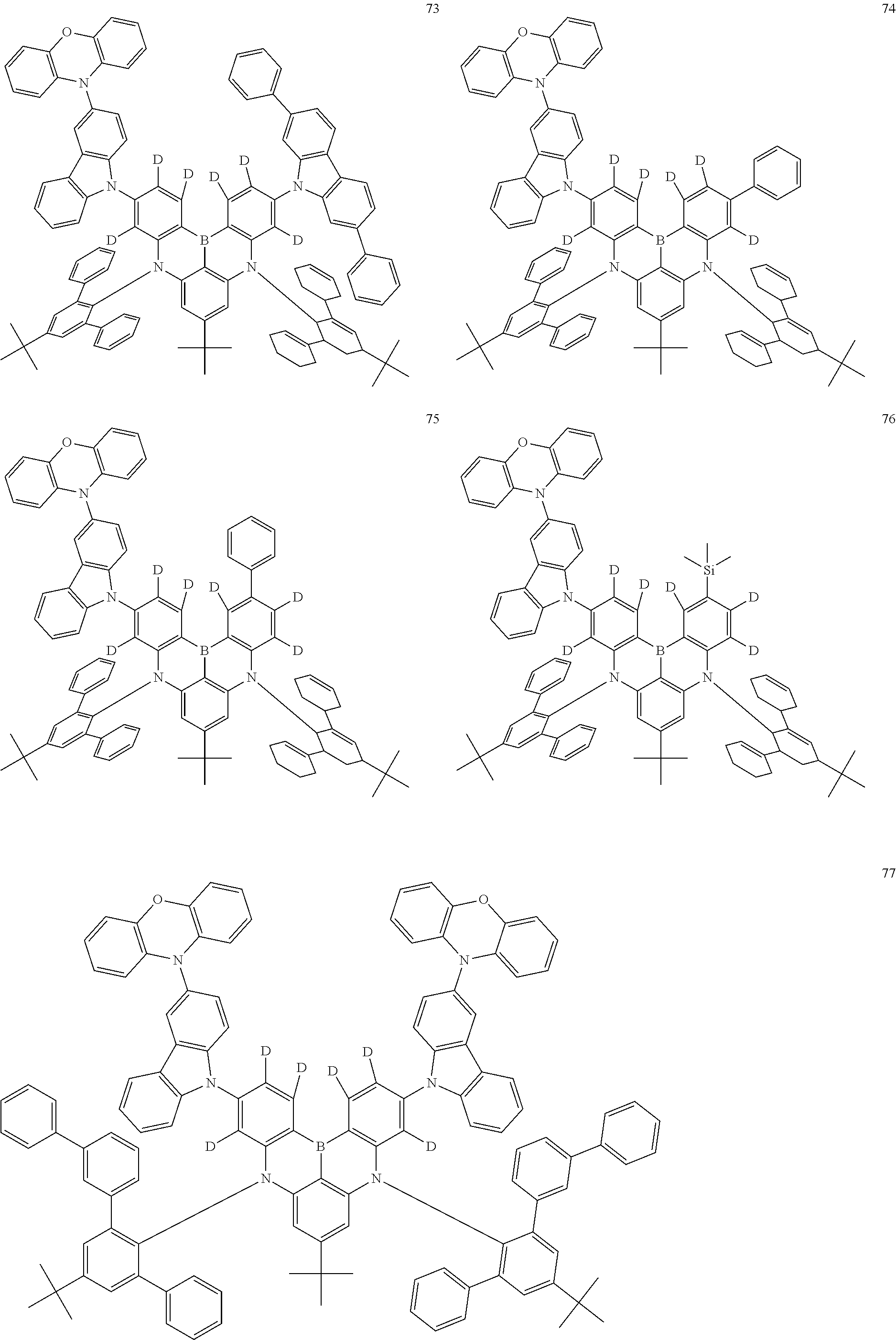

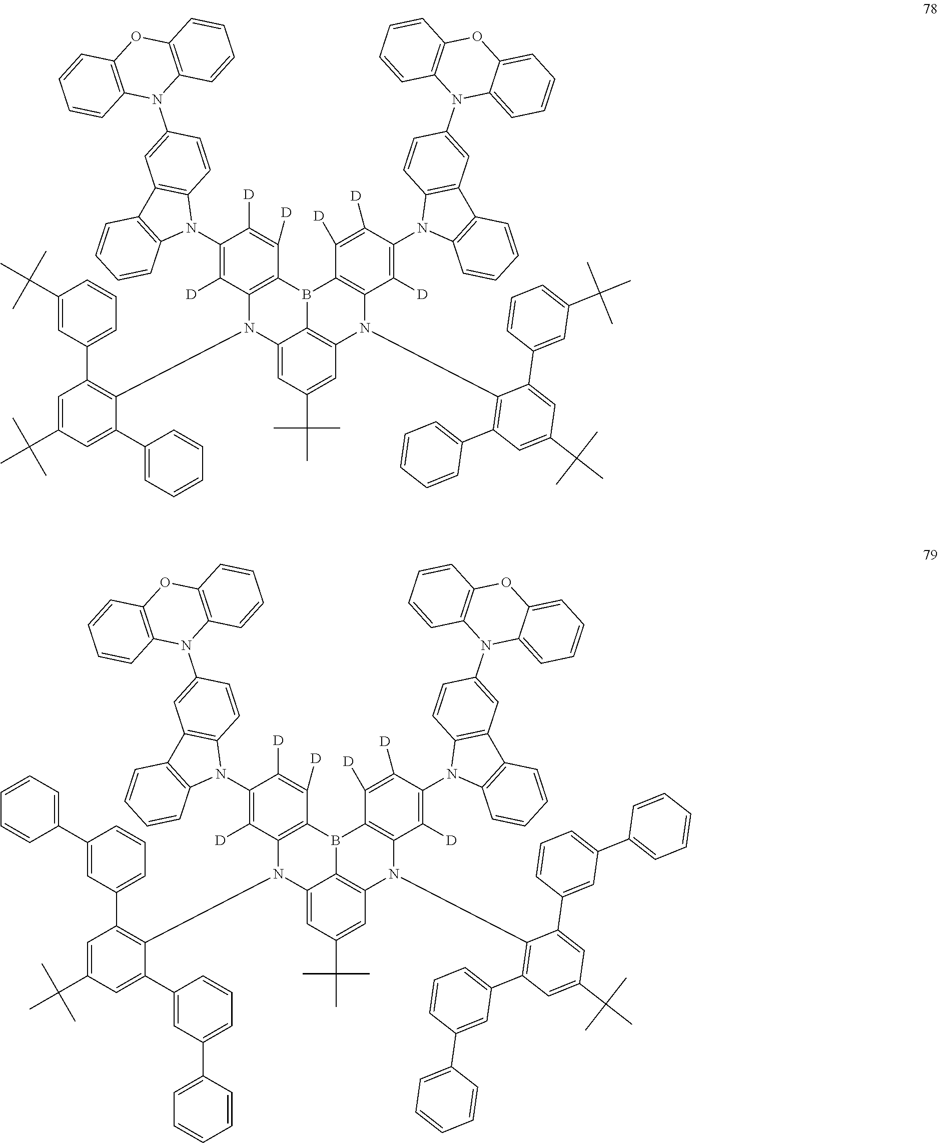

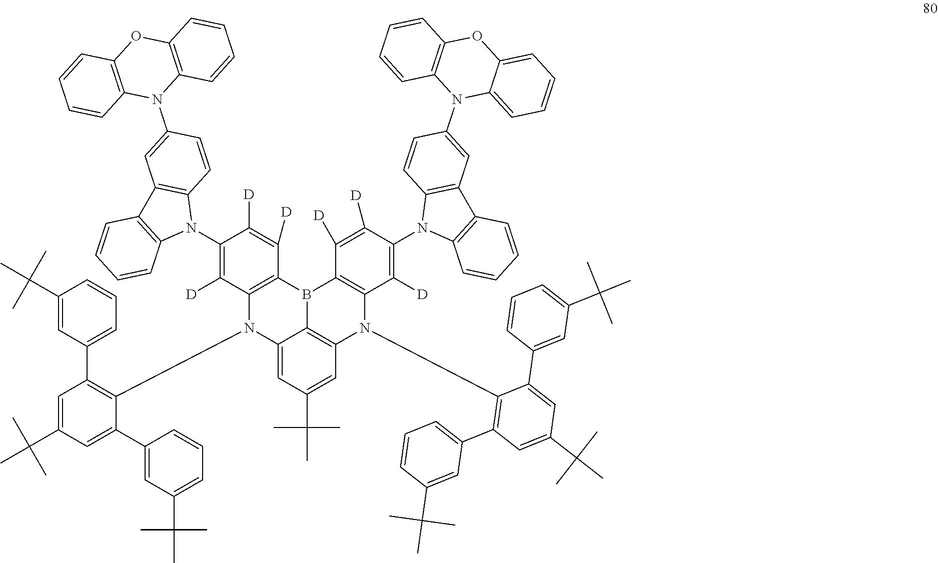 [SMILES: [2H]c1c([2H])c(-n2c3ccccc3c3cc(N4c5ccccc5Oc5ccccc54)ccc32)c([2H])c2c1B1c3c(cc(C(C)(C)C)cc3N(c3c(-c4cccc(C(C)(C)C)c4)cc(C(C)(C)C)cc3-c3cccc(C(C)(C)C)c3)c3c([2H])c(-n4c5ccccc5c5cc(N6c7ccccc7Oc7ccccc76)ccc54)c([2H])c([2H])c31)N2c1c(-c2cccc(C(C)(C)C)c2)cc(C(C)(C)C)cc1-c1cccc(C(C)(C)C)c1]

In specific example compounds suggested in Compound Group 1, “D” refers to a deuterium atom.

In the fused polycyclic compound represented by Formula 1, according to one or more embodiments, a carbazole group linked to a nitrogen-containing substituent is utilized in the NBN core structure, and thus improvements in high luminous efficiency and long-lifespan may be achieved.

The fused polycyclic compound represented by Formula 1 according to one or more embodiments may be a phosphorescent light-emitting dopant material, or a thermally activated delayed fluorescence (TADF) dopant material. In some embodiments, the fused polycyclic compound represented by Formula 1 may be a thermally activated delayed fluorescence dopant having a difference (AEST) of at most 0.2 eV between a lowest triplet excited state energy level (T1 level) and a lowest singlet excited state energy level (S1 level).

In the light-emitting element ED according to one or more embodiments, an emission layer EML may be to emit phosphorescence or delayed fluorescence. For example, the emission layer EML may be to emit phosphorescence or thermally activated delayed fluorescence.

The fused polycyclic compound according to one or more embodiments may be included in the emission layer EML. The fused polycyclic compound according to one or more embodiments may be included in the emission layer EML as a dopant material. The fused polycyclic compound according to one or more embodiments may be utilized as the phosphorescent dopant material, or the thermally activated delayed fluorescent dopant material. For example, in the light-emitting element ED according to one or more embodiments, the emission layer EML may include at least one selected from among the fused polycyclic compounds present (e.g., a compound) in Compound Group 1, previously described, as the phosphorescent dopant material or the thermally activated delayed fluorescent dopant material. However, applications of the fused polycyclic compound according to one or more embodiments of the present disclosure are not limited thereto.

A light-emitting element ED including the fused polycyclic compound, according to one or more embodiments, represented by Formula 1, may include an emission layer EML having an emission center wavelength in a wavelength region of about 430 nanometer (nm) to about 490 nm. For example, the fused polycyclic compound according to one or more embodiments, represented by Formula 1, may be a blue-thermally activated delayed fluorescence dopant, or a blue-phosphorescent dopant. However, one or more embodiments of the present disclosure is not limited thereto. When the fused polycyclic compound according to one or more embodiments is utilized as a light-emitting dopant material, the first compound may be utilized as dopant materials emitting light with one or more suitable wavelengths, such as a red-light emitting dopant material, and a green-light emitting dopant material.

In one or more embodiments, the emission layer EML may include the first compound represented by Formula 1, and may further include at least one of the second compound represented by Formula HT-1, the third compound represented by Formula ET-1, and the fourth compound represented by Formula D-1.

In one or more embodiments, the second compound may be utilized as a hole transporting host material of the emission layer EML.

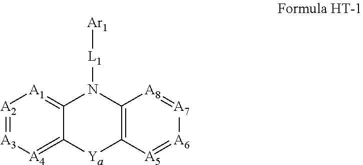

In Formula HT-1, A₁ to A₈ may each independently be N or CR₅₁. For example, each (e.g., all) of A₁ to A₈ may be CR₅₁. In some embodiments, any one selected from among A₁ to A₈ may be N, and the rest (e.g., each of the remaining A₁ to A₈) may be CR₅₁.

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, and/or the like, but the embodiment of the present disclosure is not limited thereto.

In Formula HT-1, Yₐ may be a direct linkage, CR₅₂R₅₃, or SiR₅₄R₅₅. For example, it may refer to that the two benzene rings linked to the nitrogen atom in Formula HT-1 are linked via a direct linkage,

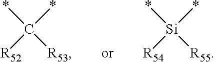

In Formula HT-1, when Yₐ is a direct linkage, the second compound represented by Formula HT-1 may include a carbazole moiety.

In Formula HT-1, Ar₁ may be a substituted or unsubstituted aryl group having 6 to 30 ring-forming carbon atoms, or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, and/or the like, but the embodiment of the present disclosure is not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In some embodiments, each of R₅₁ to R₅₅ may be bonded to an adjacent group to form a ring. For example, R₅₁ to R₅₅ may each independently be a hydrogen atom or a deuterium atom. R₅₁ to R₅₅ may each independently be an unsubstituted methyl group or an unsubstituted phenyl group.

In one or more embodiments, the second compound represented by Formula HT-1 may be represented by any one selected from among the compounds represented by Compound Group 2. The emission layer EML may include at least one selected from among the compounds represented by Compound Group 2 as a hole transporting host material.

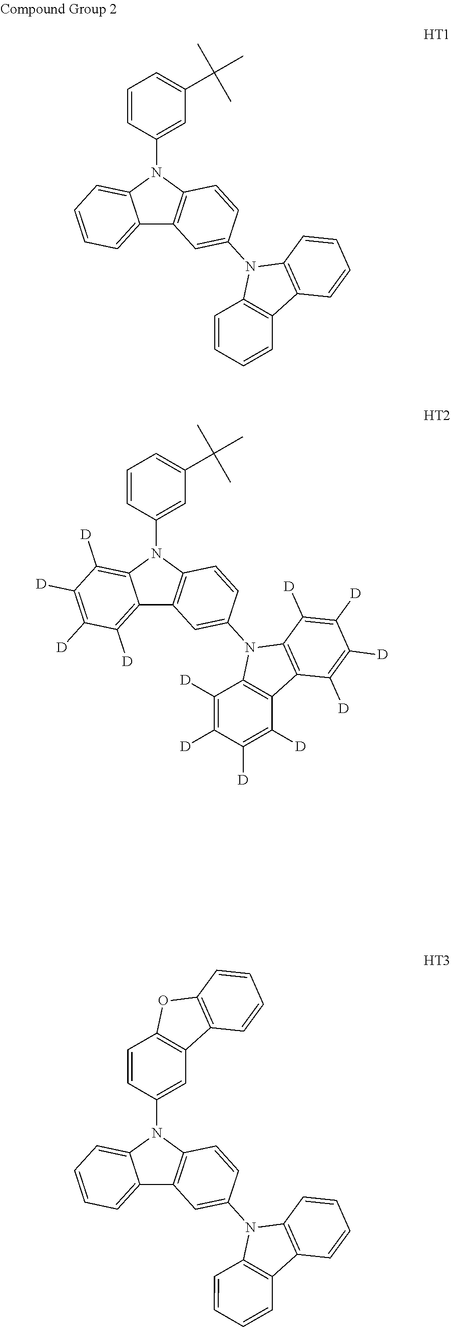

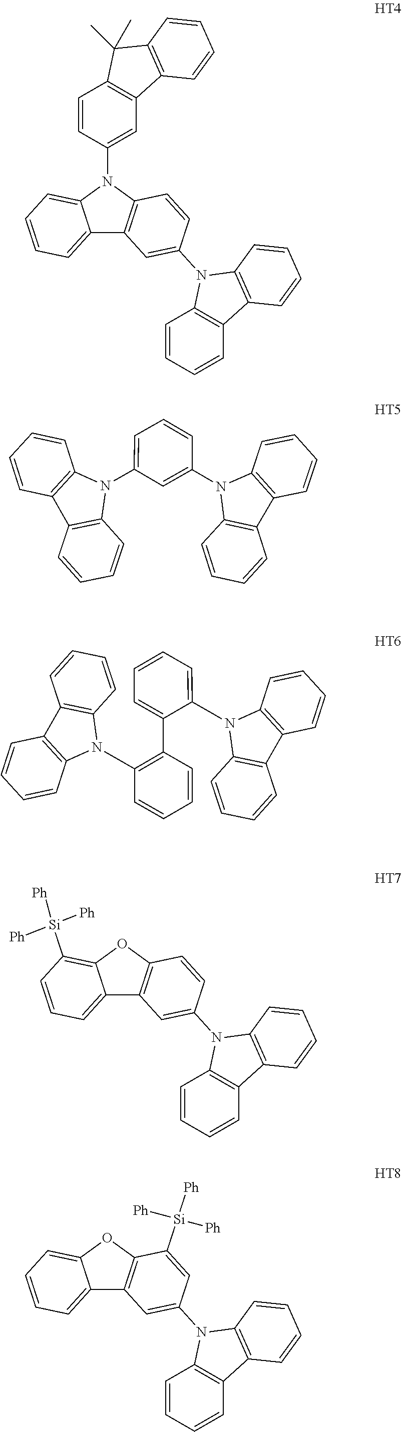 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

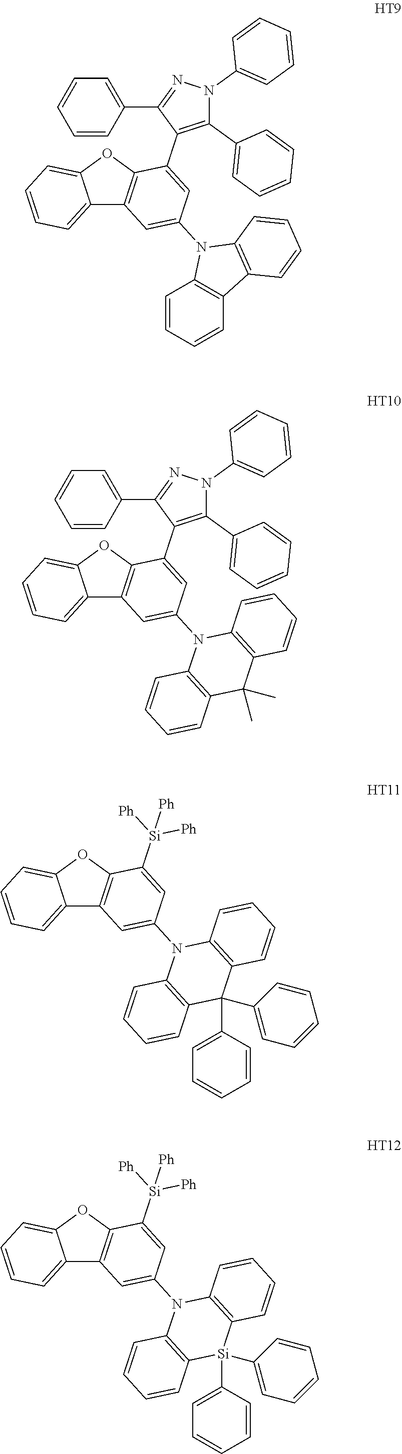 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

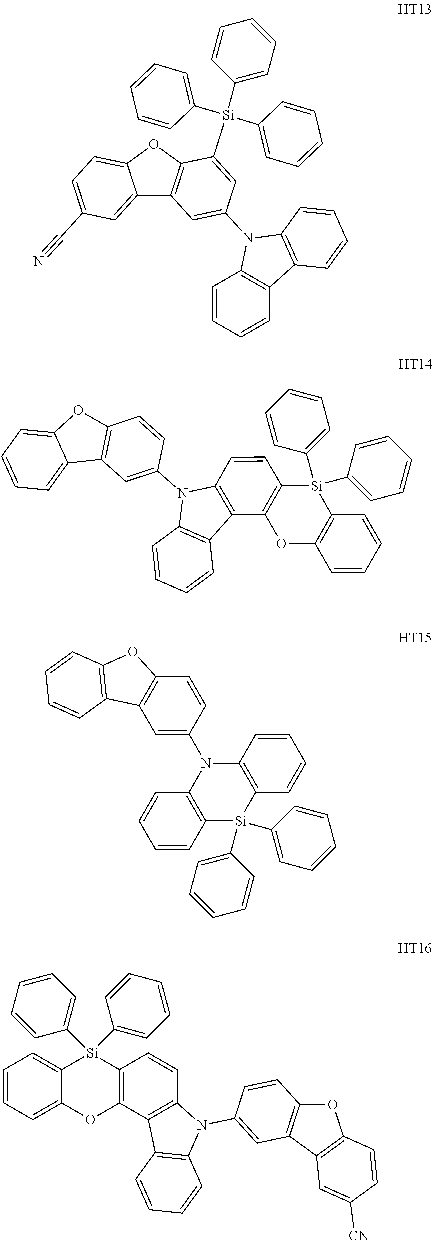 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

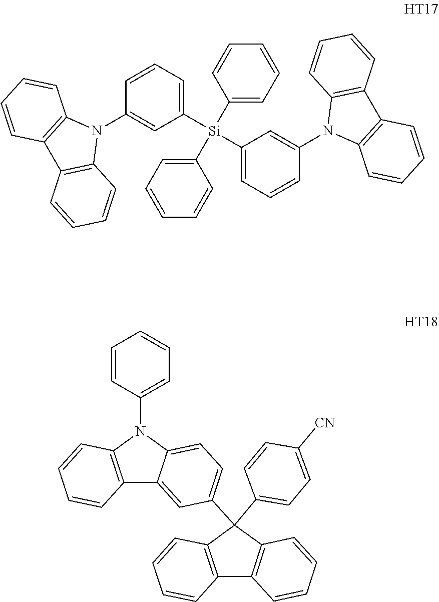 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1]

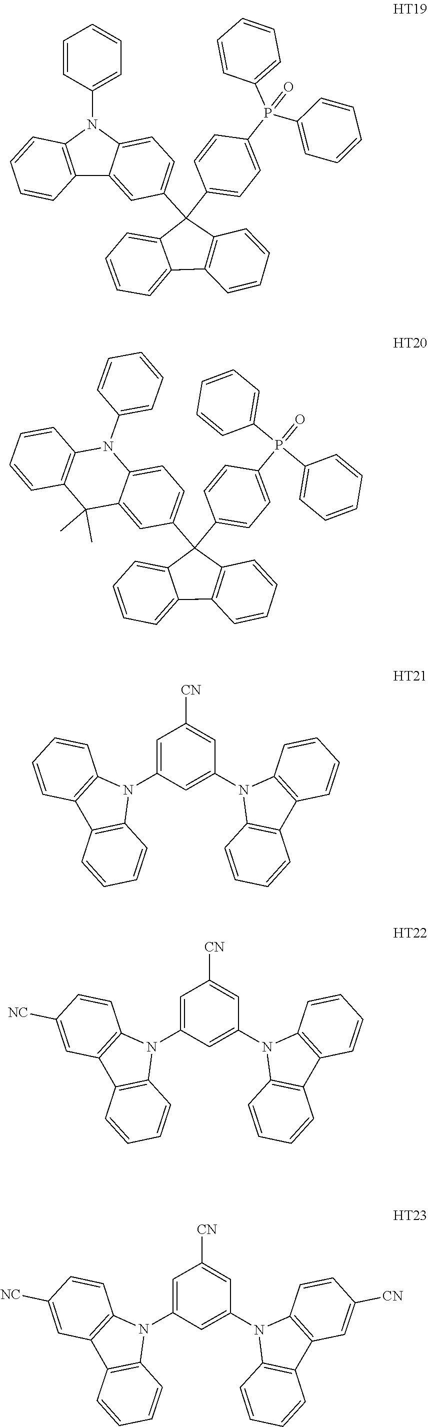 [SMILES: O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1]

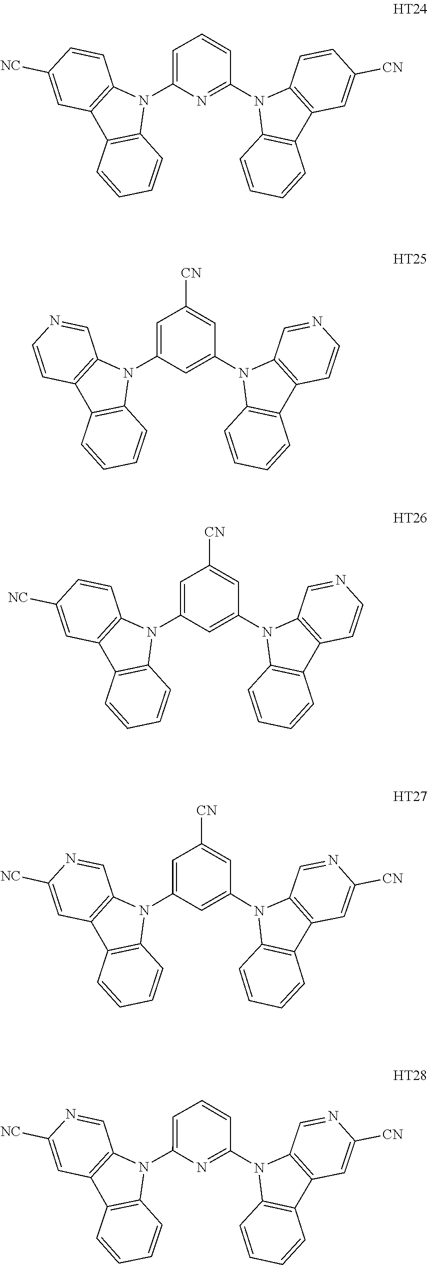 [SMILES: N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

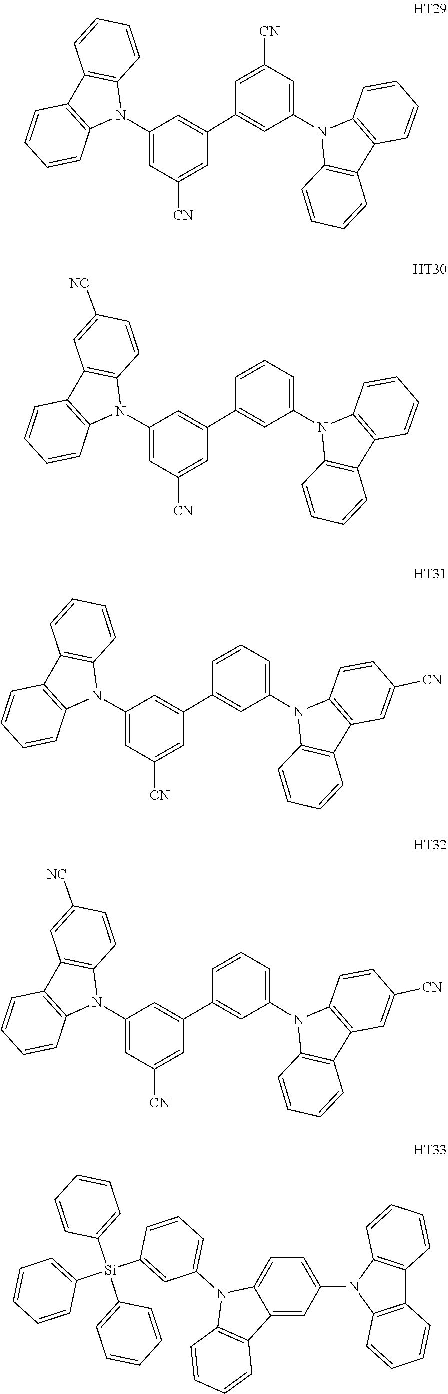 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

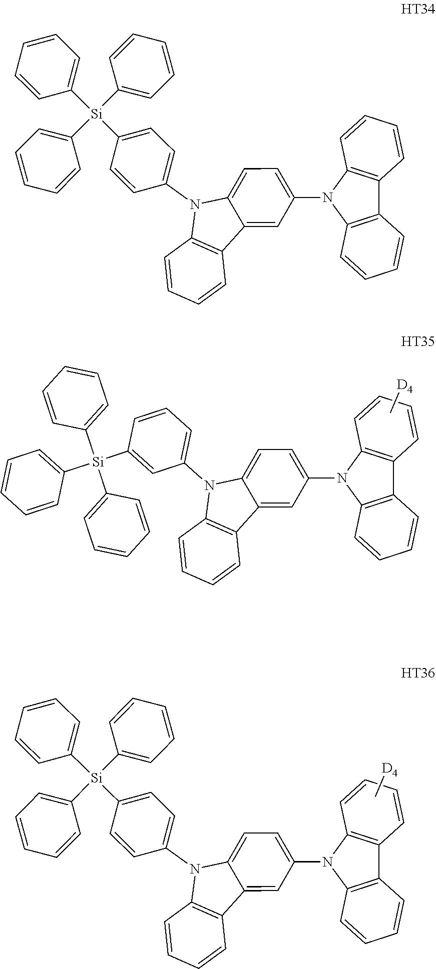

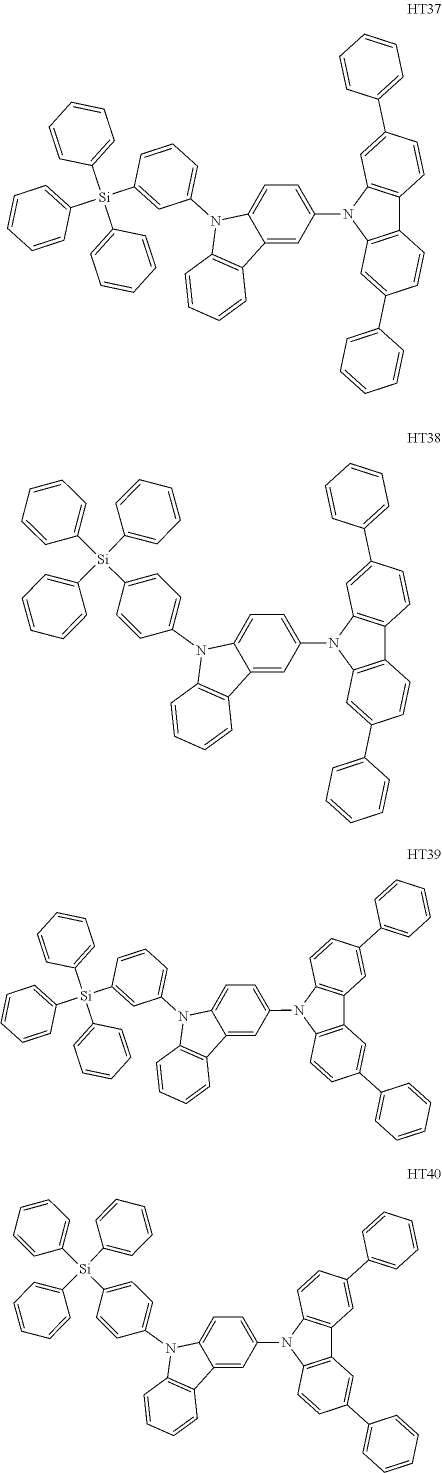 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

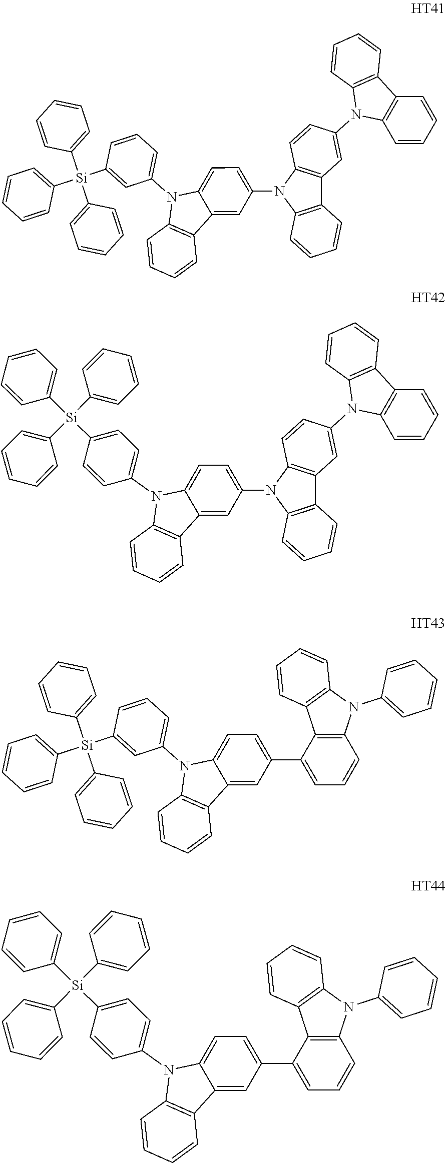 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1]

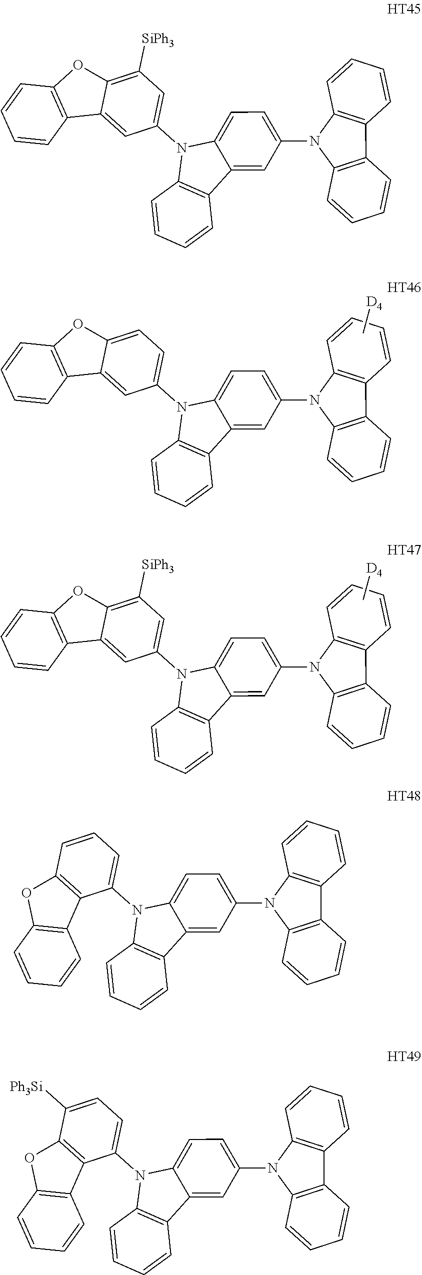

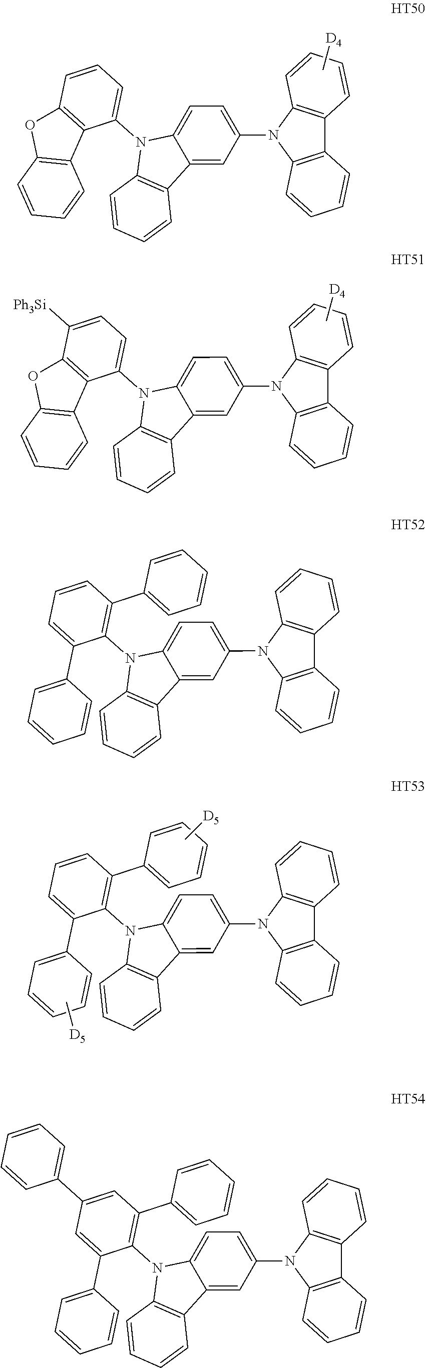

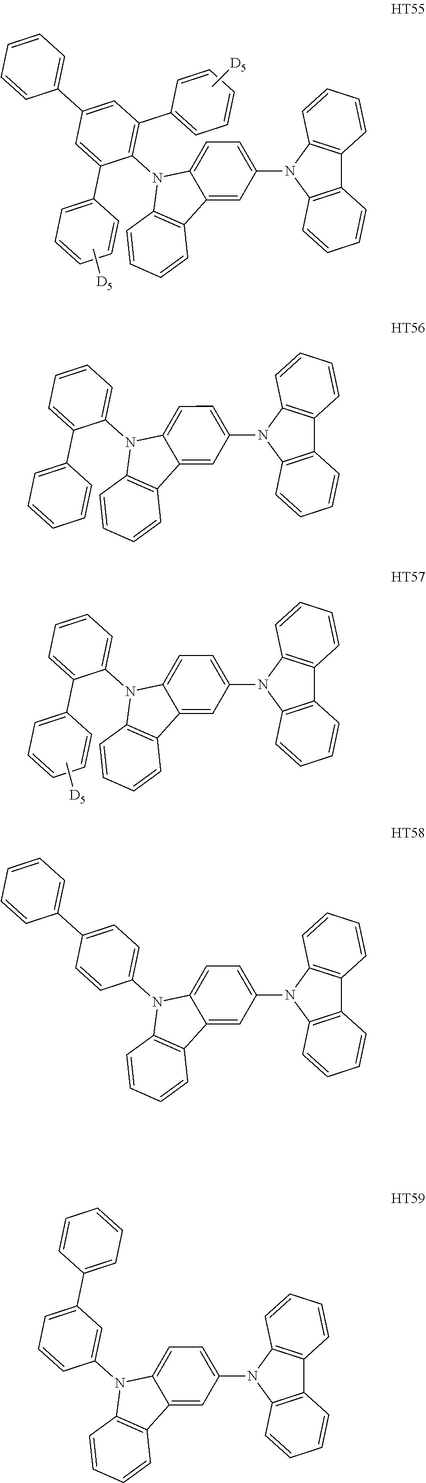

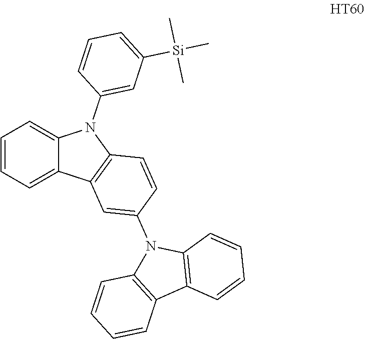 [SMILES: C[Si](C)(C)c1cccc(-n2c3ccccc3c3cc(-n4c5ccccc5c5ccccc54)ccc32)c1]

In embodiment compounds presented in Compound Group 2, “D” may refer to a deuterium atom, and “Ph” may refer to a substituted or unsubstituted phenyl group. For example, in embodiment compounds presented in Compound Group 2, “Ph” may refer to an unsubstituted phenyl group.

In one or more embodiments, the emission layer EML may include the third compound represented by Formula ET-1. For example, the third compound may be utilized as an electron transport host material for the emission layer EML.

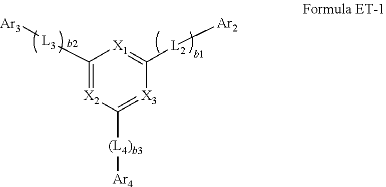

In Formula ET-1, at least one selected from among X₁ to X₃ is N, and the rest (e.g., each of the remaining X₁ to X₃) may be CR₅₆. For example, any one selected from among X₁ to X₃ may be N, and the rest (e.g., each of the remaining X₁ to X₃) may each independently be CR₅₆. In this case, the third compound represented by Formula ET-1 may include a pyridine moiety. In some embodiments, two selected from among X₁ to X₃ may be N, and the rest (one remaining X₁ to X₃) may be CR₅₆. In this case, the third compound represented by Formula ET-1 may include a pyrimidine moiety. In some embodiments, X₁ to X₃ may all be N. In this case, the third compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer of 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group, or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when b1 to b3 are integers of 2 or greater, L₂ to L₄ may each independently be a substituted or unsubstituted arylene group having 6 to 30 ring-forming carbon atoms, or a substituted or unsubstituted heteroarylene group having 2 to 30 ring-forming carbon atoms.

In one or more embodiments, the third compound may be represented by any one selected from among compounds in Compound Group 3. The light-emitting element ED of one or more embodiments may include any one selected from among the compounds (e.g., a compound) in Compound Group 3.

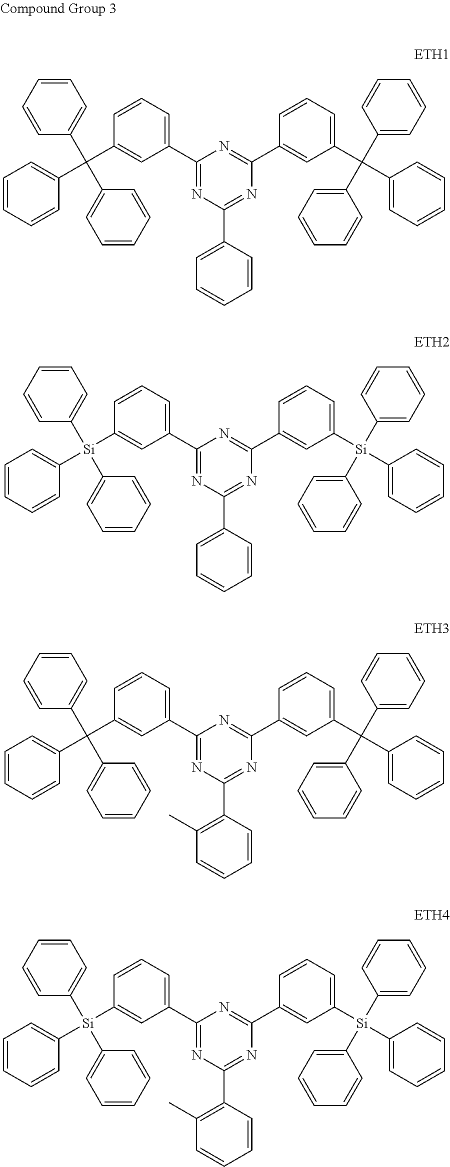 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

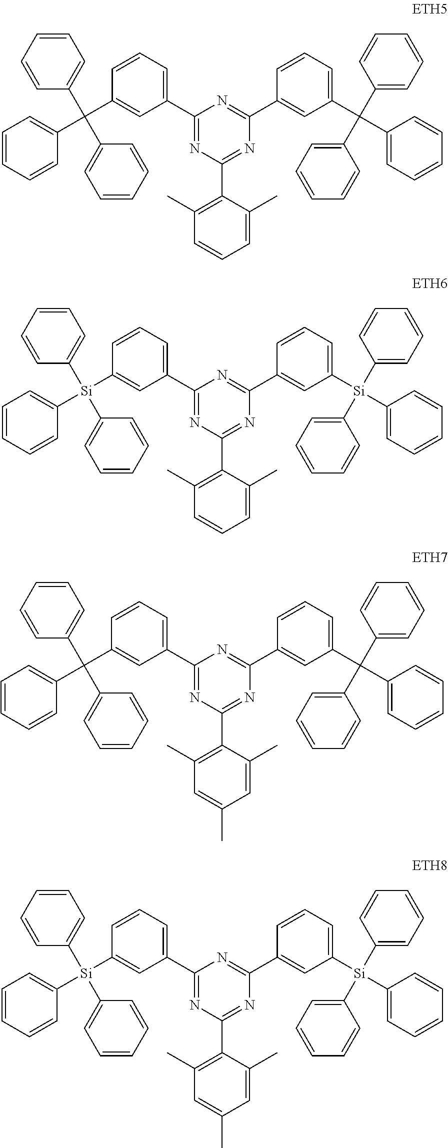 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

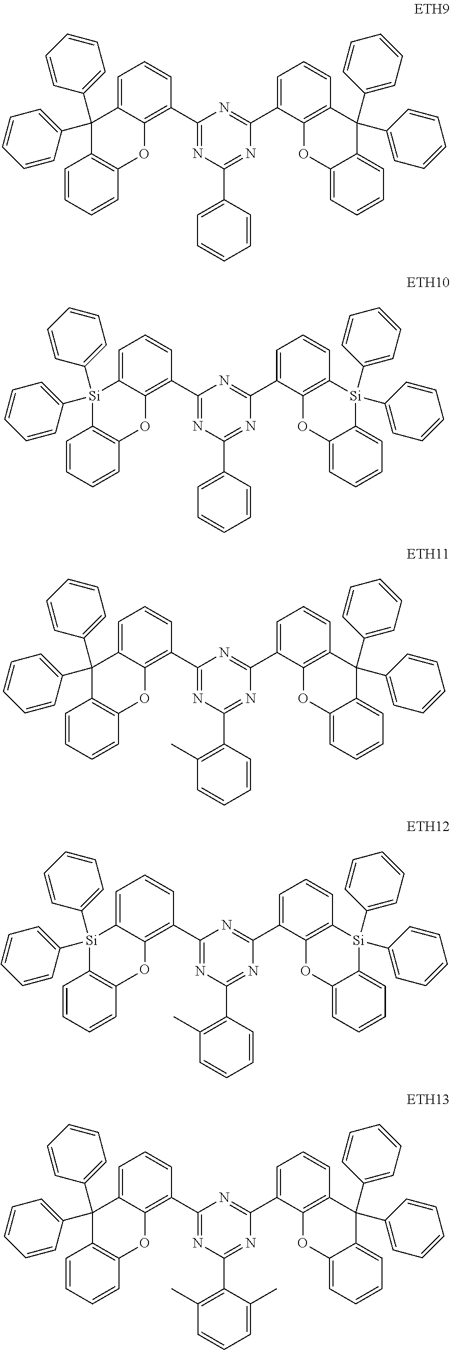

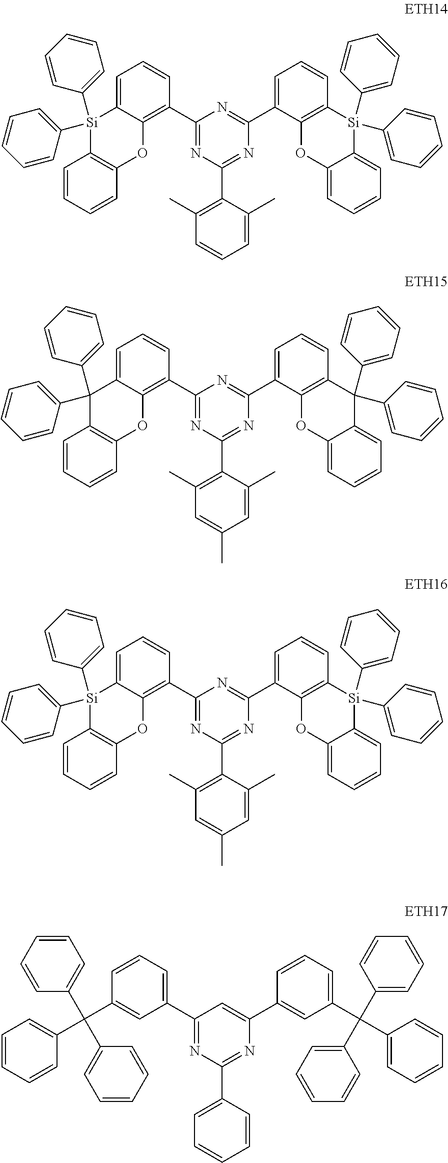 [SMILES: Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1 ; c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1]

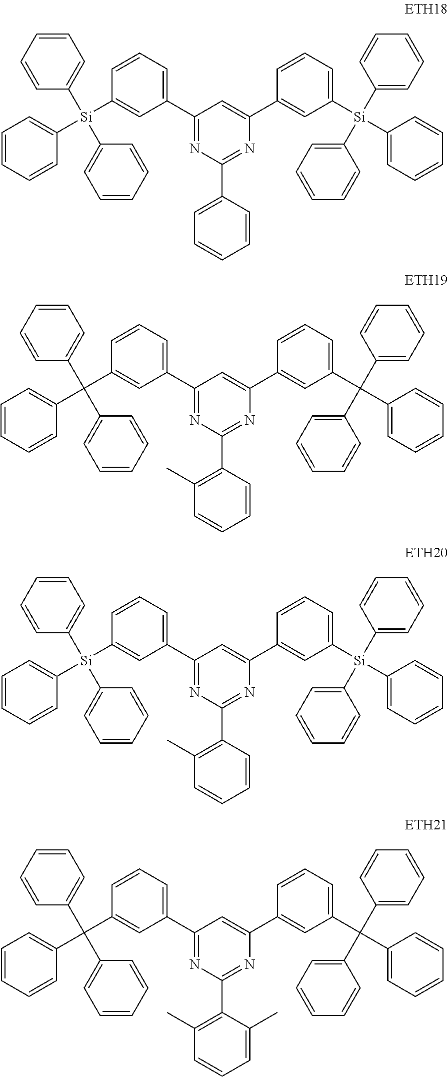 [SMILES: c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1]

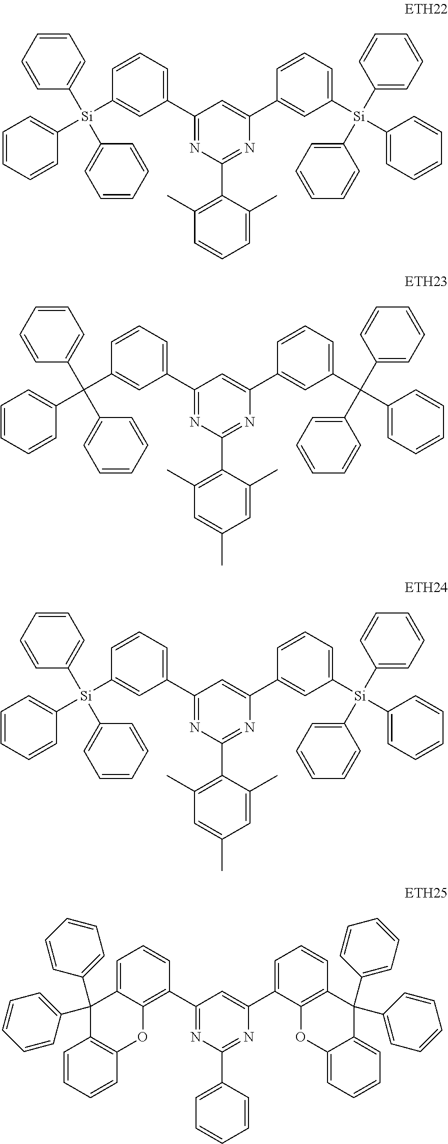 [SMILES: Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1 ; c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1]

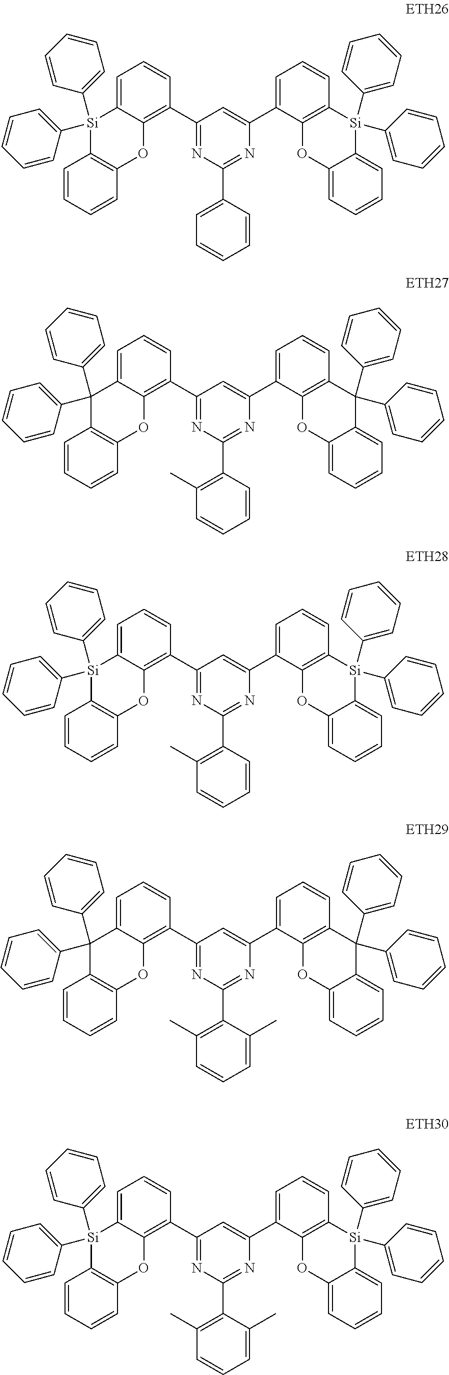

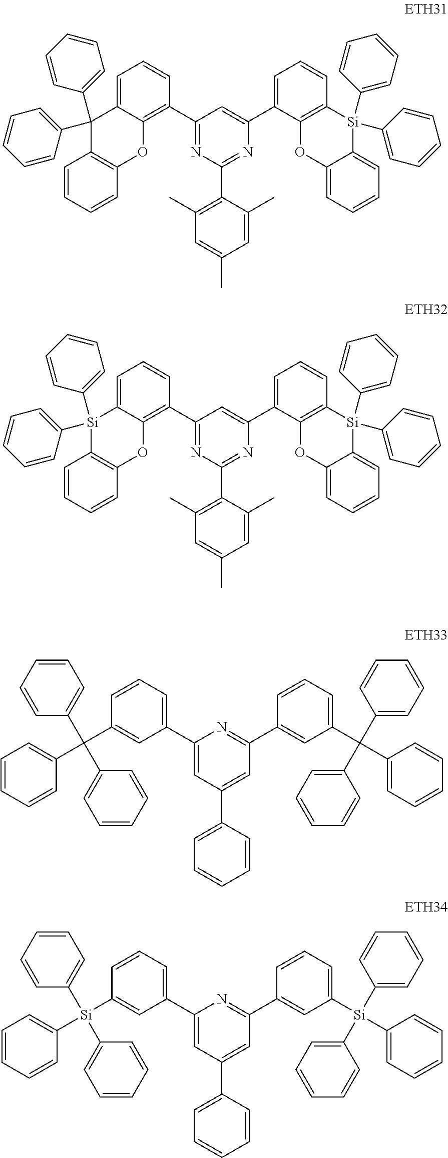 [SMILES: Cc1cc(C)c(-c2nc(-c3cccc4c3Oc3ccccc3C4(c3ccccc3)c3ccccc3)cc(-c3cccc4c3Oc3ccccc3[Si]4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1 ; c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1]

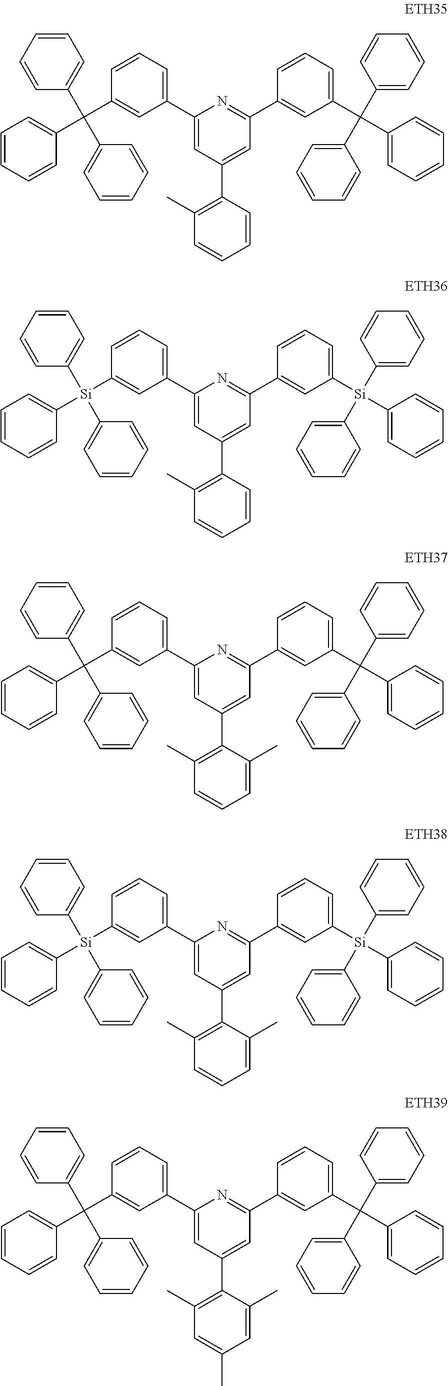

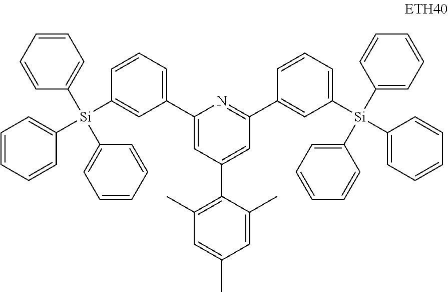 [SMILES: Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

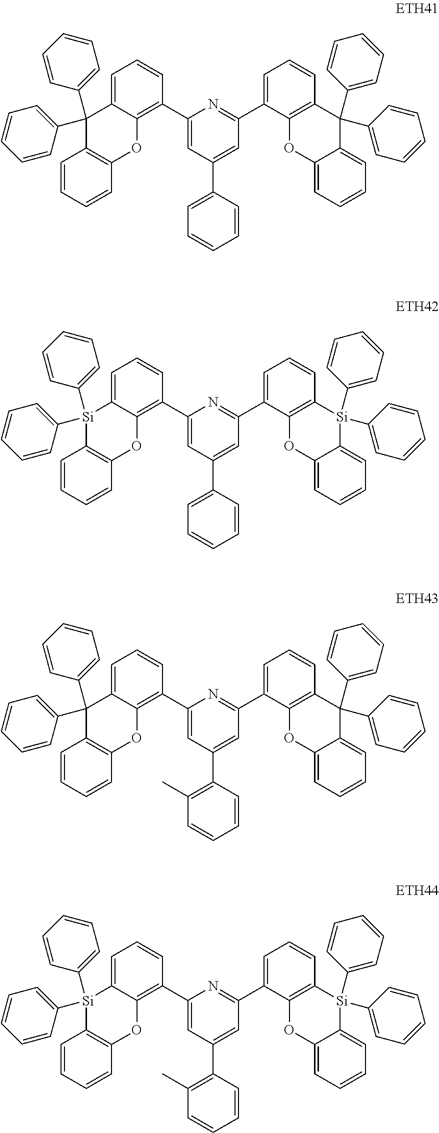 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

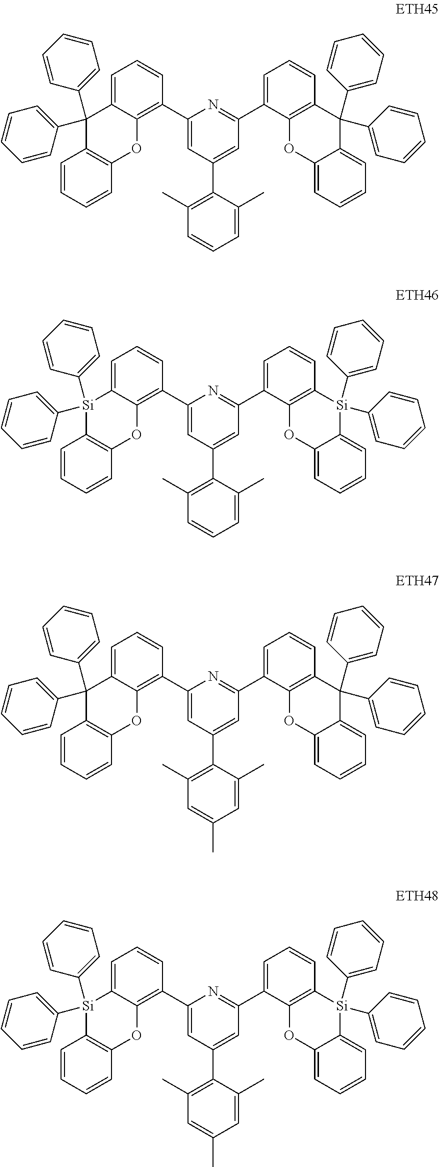 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

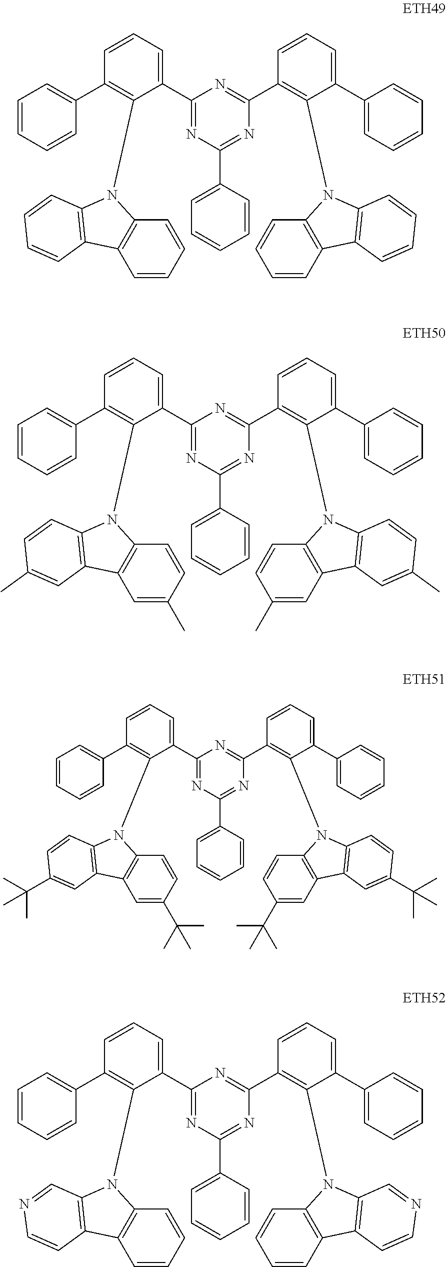

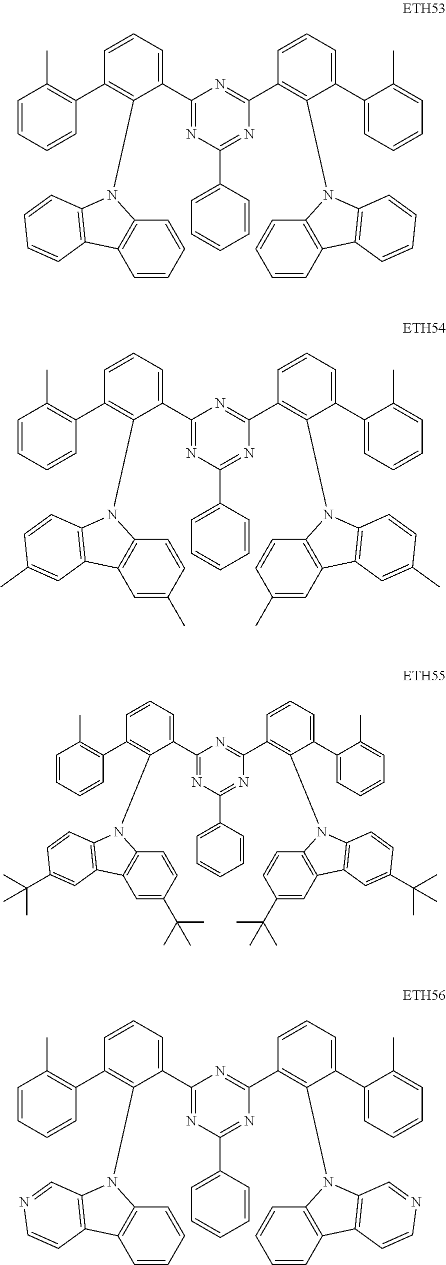

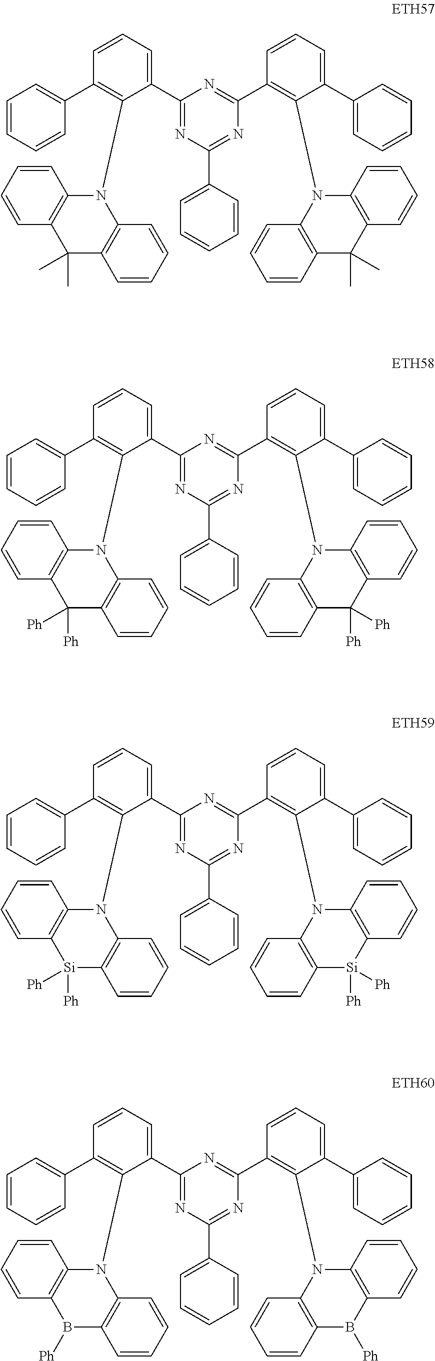

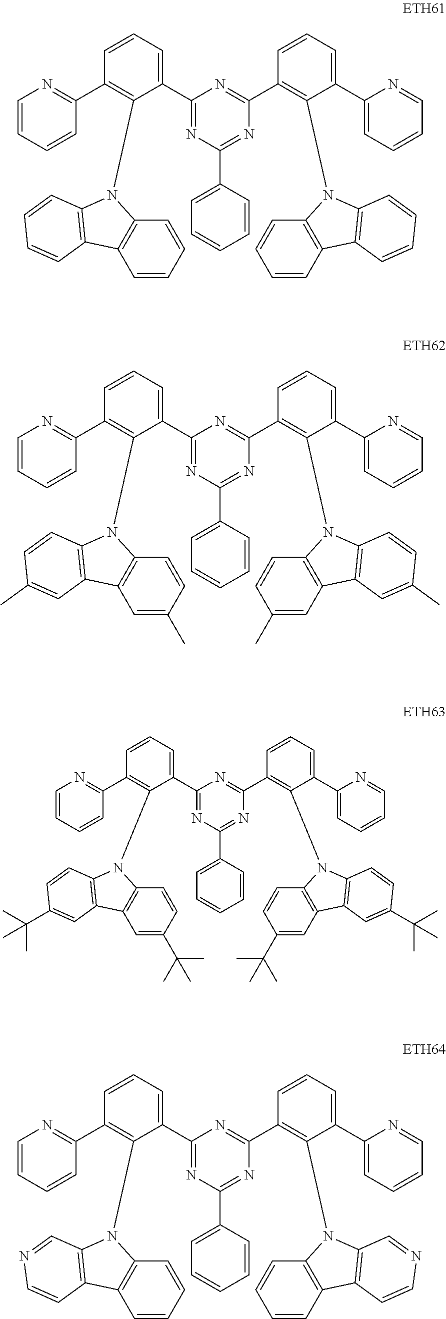

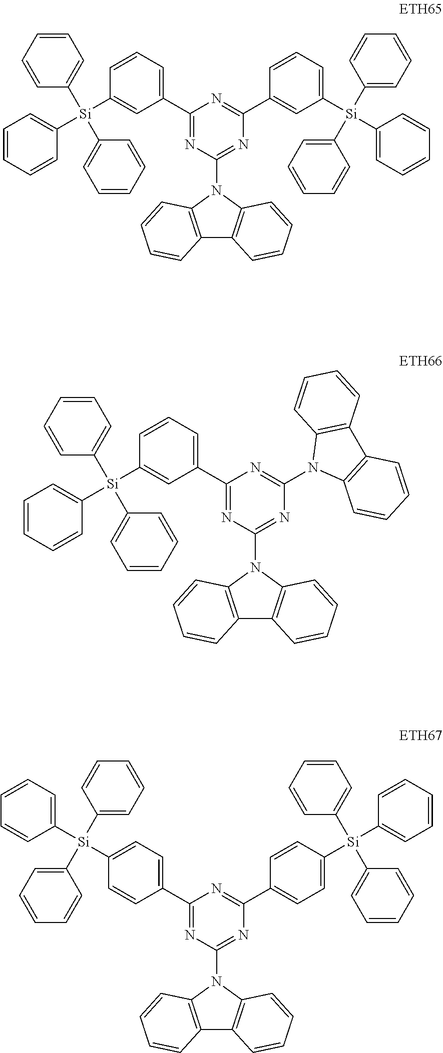 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1]

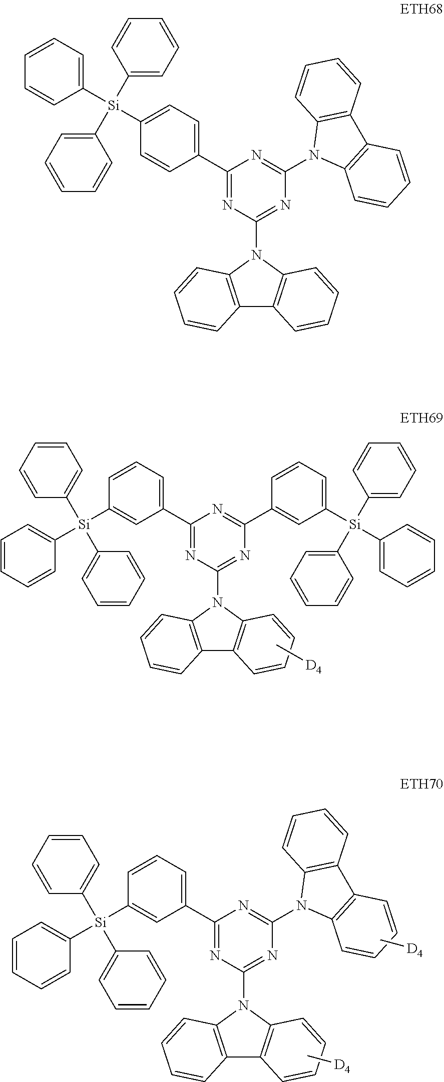

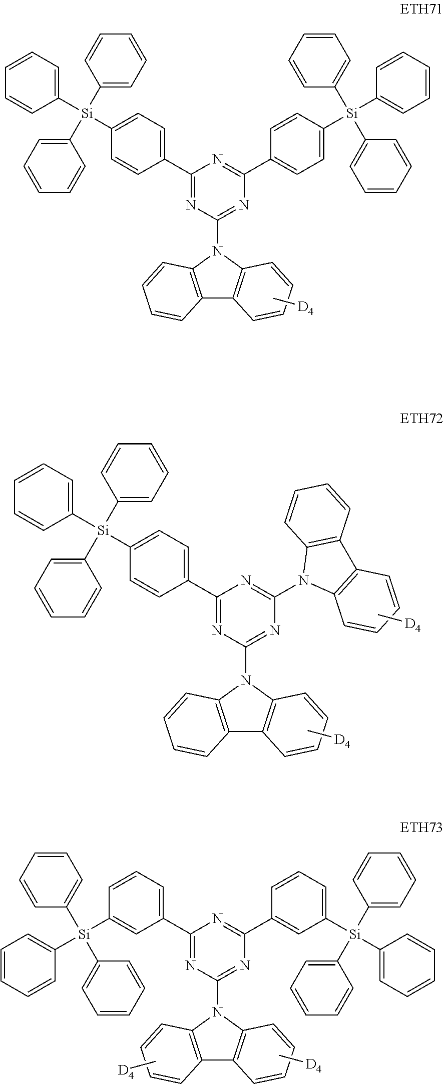

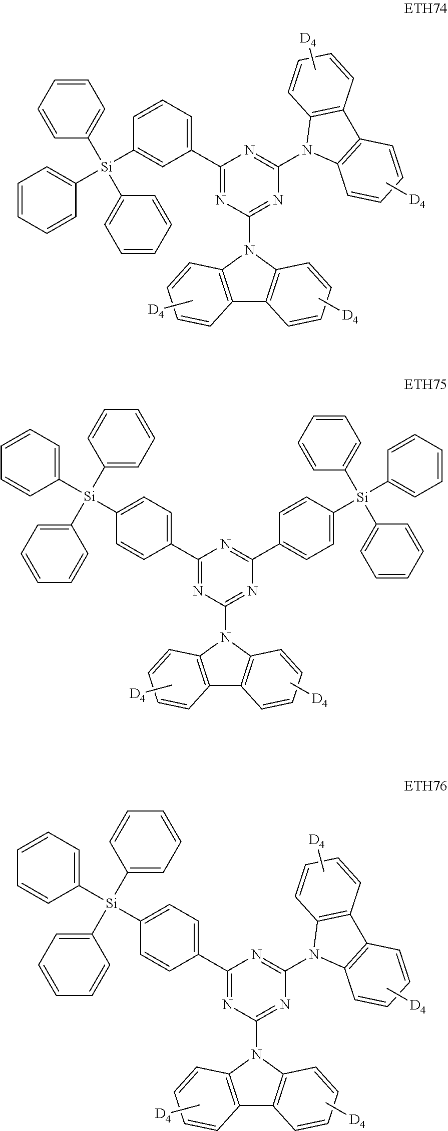

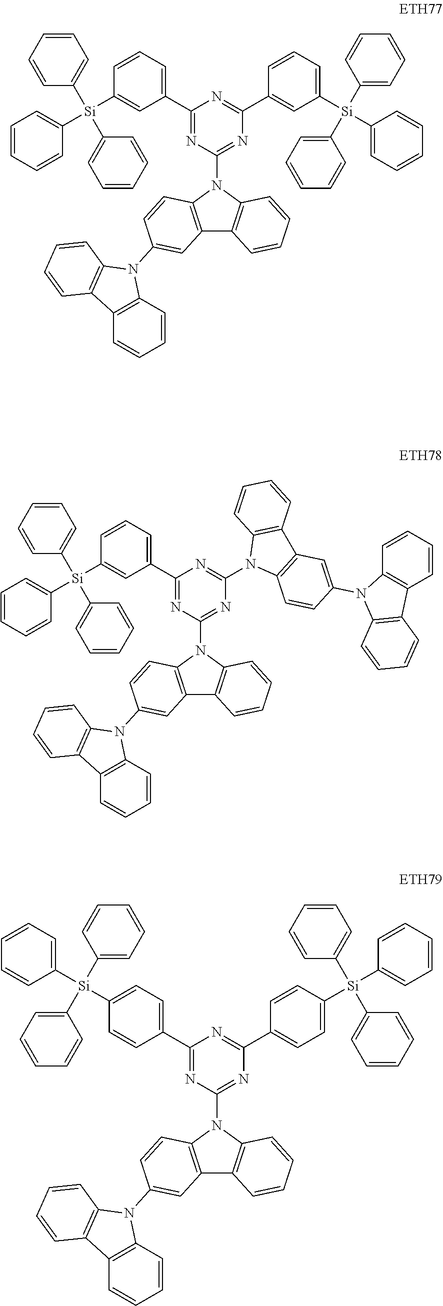 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

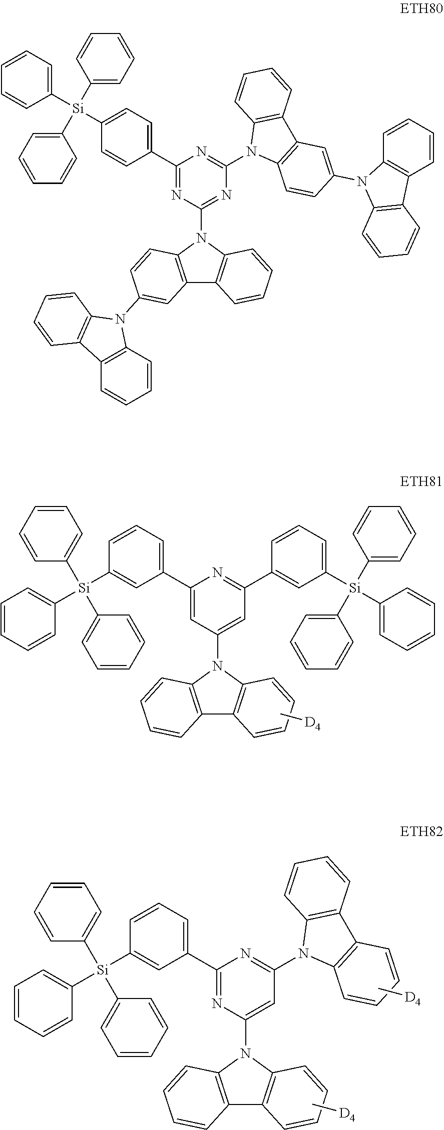

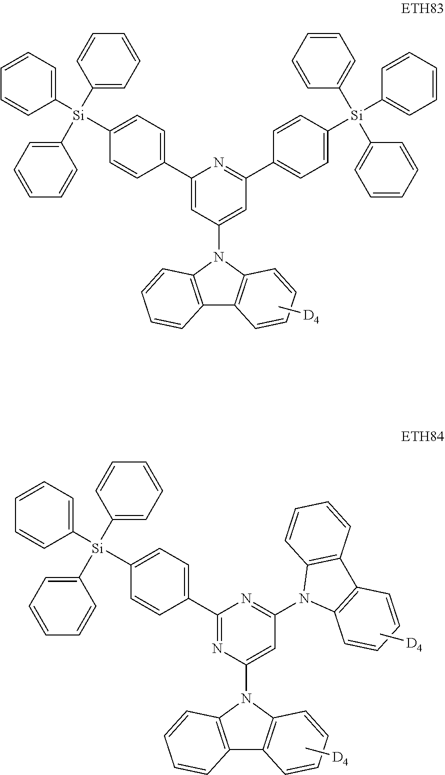

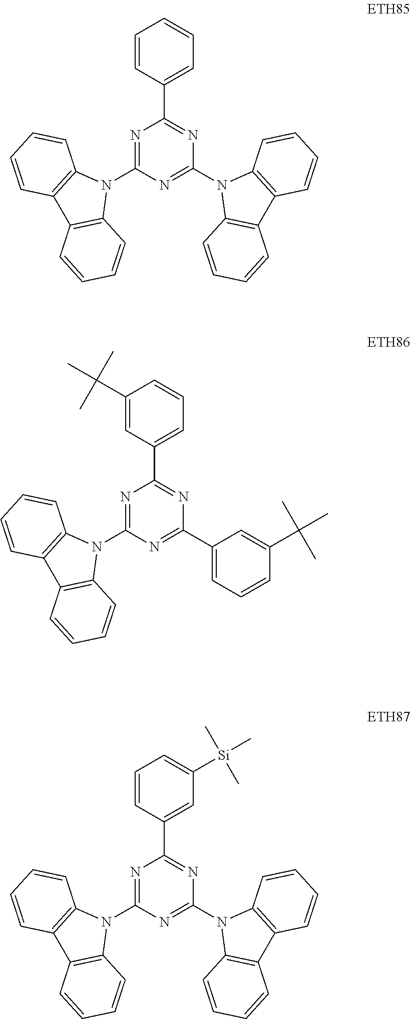 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1 ; C[Si](C)(C)c1cccc(-c2nc(-n3c4ccccc4c4ccccc43)nc(-n3c4ccccc4c4ccccc43)n2)c1]

In the embodiment compounds presented in Compound Group 3, “D” refers to a deuterium atom and “Ph” refers to an unsubstituted phenyl group.

The emission layer EML may include the second compound and the third compound, and the second compound and the third compound may form an exciplex. In the emission layer EML, an exciplex may be formed by the hole transport host and the electron transport host. In this case, a triplet energy of the exciplex formed by the hole transporting host and the electron transporting host may correspond to the difference between a lowest unoccupied molecular orbital (LUMO) energy level of the electron transporting host and a highest occupied molecular orbital (HOMO) energy level of the hole transporting host.

For example, the absolute value of the triplet energy (T1) of the exciplex formed by the hole transporting host and the electron transporting host may be about 2.4 eV to about 3.0 eV. In some embodiments, the triplet energy of the exciplex may be a value smaller than an energy gap of each host material. The exciplex may have a triplet energy of about 3.0 eV or less that is an energy gap of each of the hole transporting host and the electron transporting host.

In one or more embodiments, the emission layer EML may include a fourth compound in addition to the first compound to the third compound as described. The fourth compound may be utilized as a phosphorescent sensitizer of the emission layer EML. The energy may be transferred from the fourth compound to the first compound, thereby emitting light.

For example, the emission layer EML may include, as the fourth compound, an organometallic complex containing platinum (Pt) as a central metal atom and ligands linked to the central metal atom. The emission layer EML in the light-emitting element ED of one or more embodiments may include, as the fourth compound, a compound represented by Formula D-1:

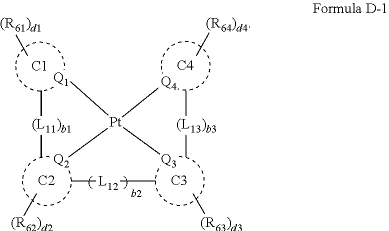

In Formula D-1, Q₁ to Q₄ may each independently be C or N.

In Formula D-1, C1 to C4 may each independently be a substituted or unsubstituted hydrocarbon ring having 5 to 30 ring-forming carbon atoms, or a substituted or unsubstituted heterocycle having 2 to 30 ring-forming carbon atoms.

In Formula D-1, L₁₁ to L₁₃ may each independently be a direct linkage,

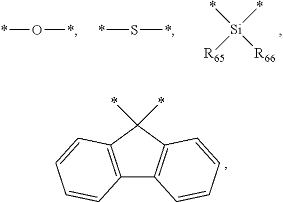

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, “-*” refers to a part linked to C1 to C4.

In Formula D-1, b1 to b3 may each independently be 0 or 1. When b1 is 0, C1 and C2 may not be linked to each other. When b2 is 0, C2 and C3 may not be linked to each other. When b3 is 0, C3 and C4 may not be linked to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In some embodiments, each of R₆₁ to R₆₆ may be bonded to an adjacent group to form a ring. R₆₁ to R₆₆ may each independently be a substituted or unsubstituted methyl group, or a substituted or unsubstituted t-butyl group.

In Formula D-1, d1 to d4 may each independently be an integer of 0 to 4. In Formula D-1, when each of d1 to d4 is 0, the fourth compound may not be substituted with each of R₆₁ to R₆₄. The case where each of d1 to d4 is 4 and R₆₁'s to R₆₄′ are each hydrogen atoms may be the same as the case where each of d1 to d4 is 0. When each of d1 to d4 is an integer of 2 or more, a plurality of R₆₁'s to R₆₄'s may each be the same or at least one selected from among the plurality of R₆₁'s to R₆₄'s may be different from the others.

In Formula D-1, C1 to C4 may each independently be a substituted or unsubstituted hydrocarbon ring or a substituted or unsubstituted heterocycle represented by any one selected from among C-1 to C-4:

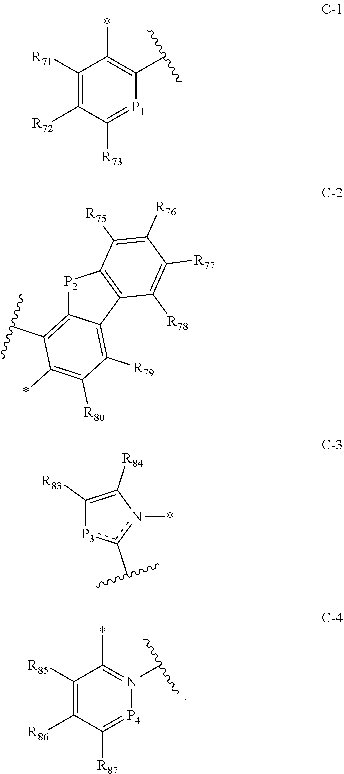

In C-1 to C-4, P₁ may be C—* or CR₇₄, P₂ may be N—* or NR₈₁, P₃ may be N—* or NR₈₂, and P₄ may be C—* or CR₈₈. R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

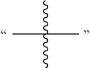

In some embodiments, in C-1 to C-4, corresponds to a part linked to Pt that is a central metal atom, and “-*” corresponds to a part linked to a neighboring cyclic group (C1 to C4) or a linker (L₁₁ to L₁₃).

The emission layer EML of one or more embodiments may include the first compound, which is a fused polycyclic compound, and at least one of the second to fourth compounds. For example, the emission layer EML may include the first compound, the second compound, and the third compound. In the emission layer EML, the second compound and the third compound may form an exciplex, and the energy may be transferred from the exciplex to the first compound, thereby emitting light.

In some embodiments, the emission layer EML may include the first compound, the second compound, the third compound, and the fourth compound. In the emission layer EML, the second compound and the third compound may form an exciplex, and the energy may be transferred from the exciplex to the fourth compound and the first compound, thereby emitting light. In one or more embodiments, the fourth compound may be a sensitizer. The fourth compound included in the emission layer EML in the light-emitting element ED of one or more embodiments may serve as a sensitizer to deliver energy from the host to the first compound that is a light emitting dopant. For example, the fourth compound serving as an auxiliary dopant accelerates energy delivery to the first compound that is a light emitting dopant, thereby increasing the emission ratio of the first compound. Therefore, the emission layer EML of one or more embodiments may improve luminous efficiency. In some embodiments, when the energy delivery to the first compound is increased, an exciton formed in the emission layer EML is not accumulated inside the emission layer EML and emits light rapidly, and thus deterioration of the light-emitting element ED may be reduced. Therefore, the service life (e.g., lifespan) of the light-emitting element ED of one or more embodiments may increase.

The light-emitting element ED of one or more embodiments may include all of the first compound, the second compound, the third compound, and the fourth compound, and the emission layer EML may include the combination of two host materials and two dopant materials. In the light-emitting element ED of one or more embodiments, the emission layer EML may concurrently (e.g., simultaneously) include the second compound and the third compound, which are two different hosts, the first compound that emits a delayed fluorescence, and the fourth compound including an organometallic complex, thereby exhibiting excellent or suitable luminous efficiency characteristics.

In one or more embodiments, the fourth compound represented by Formula D-1 may represented by at least one selected from among the compounds represented by Compound Group 4. The emission layer EML may include at least one selected from among the compounds represented by Compound Group 4 as a sensitizer material.

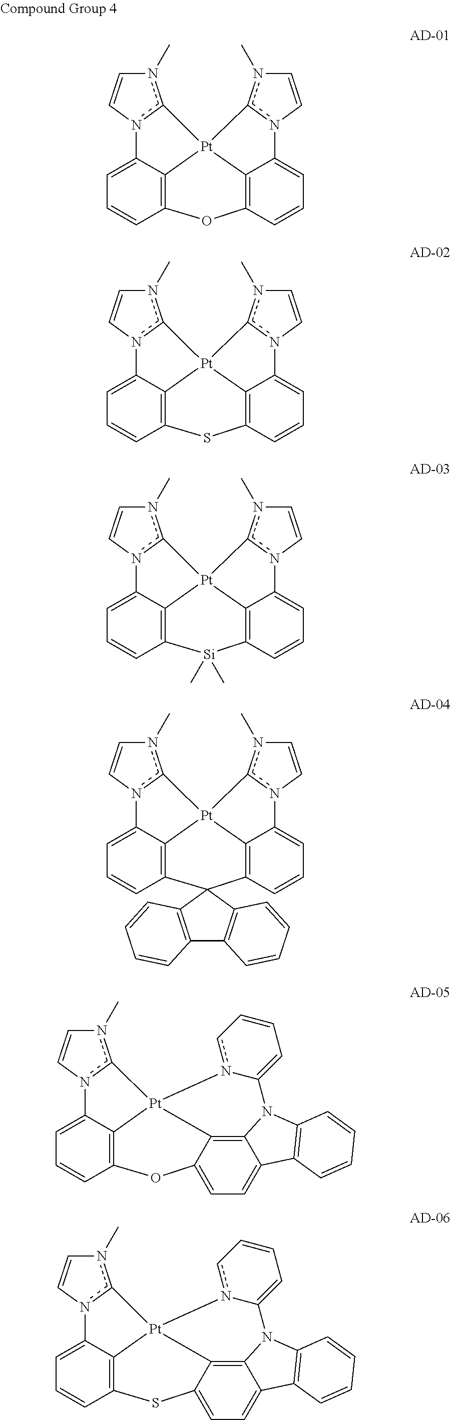

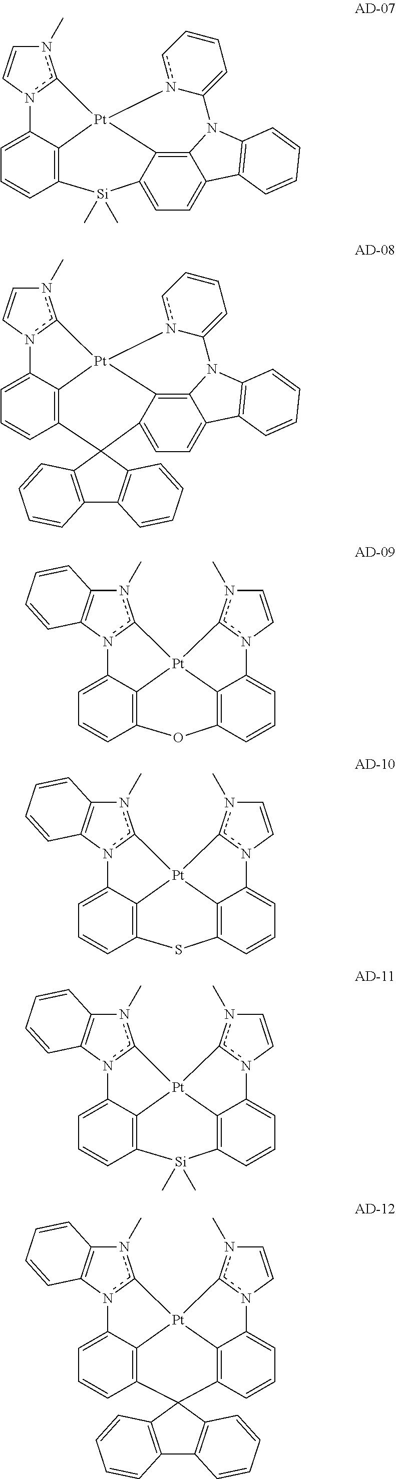

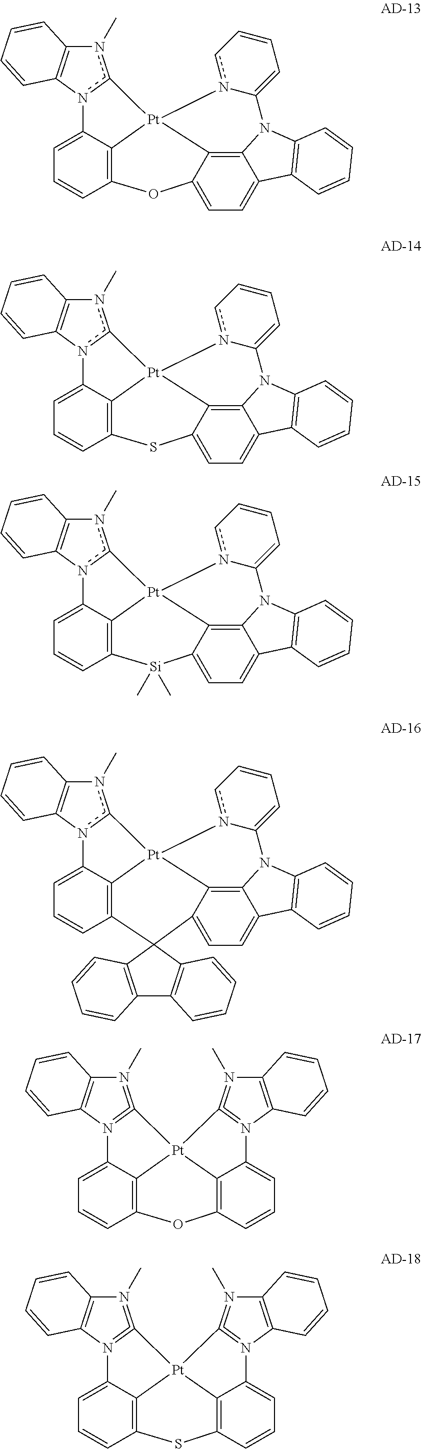

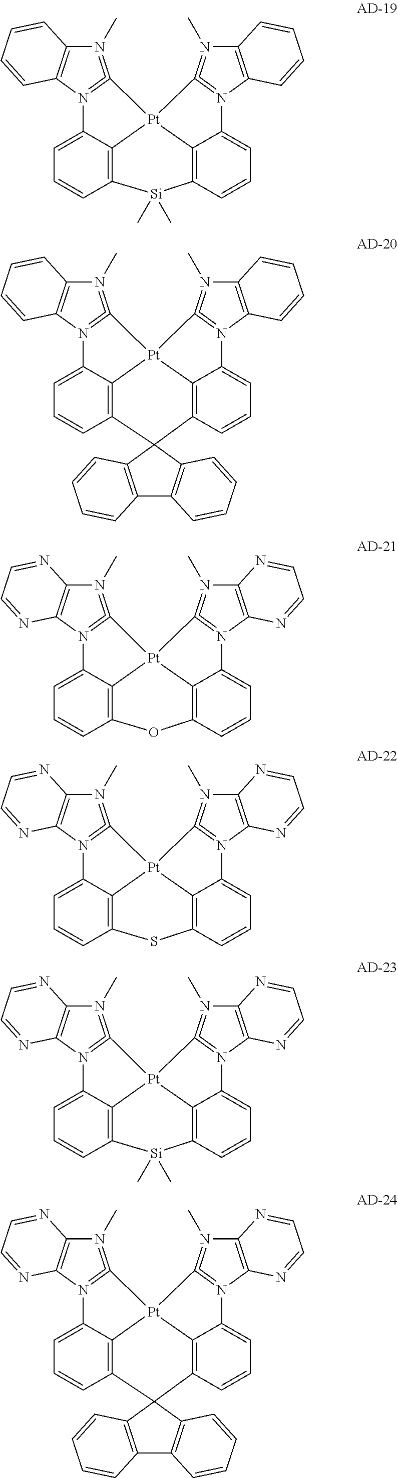

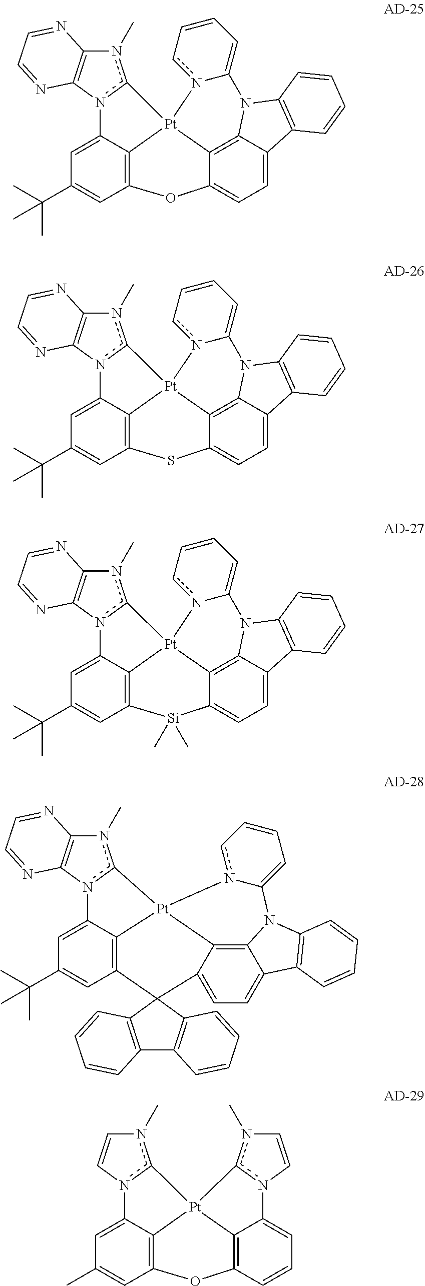

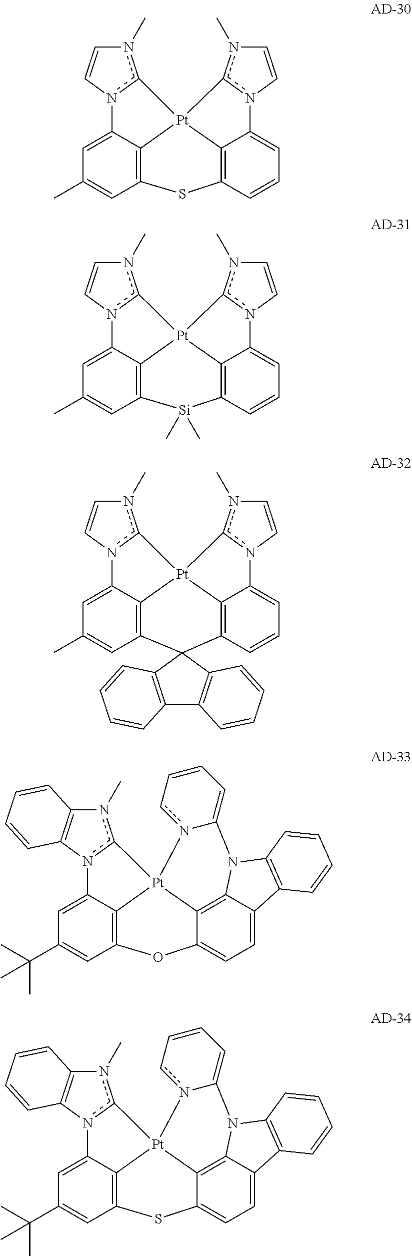

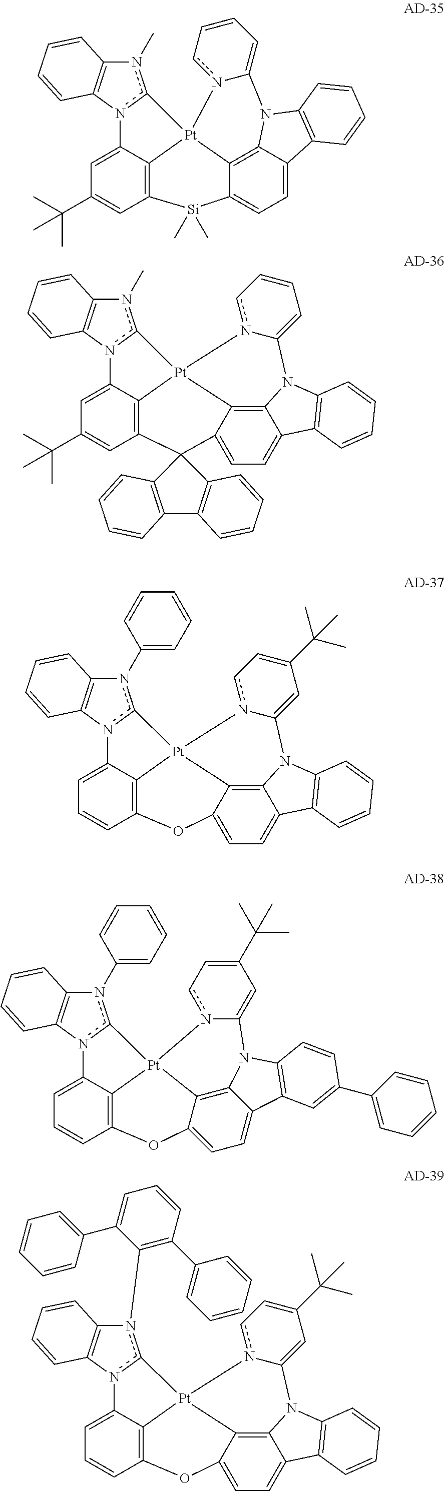

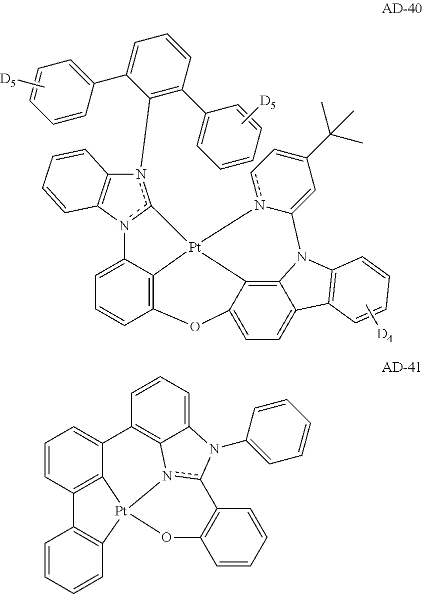

In the embodiment compounds presented in Compound Group 4, “D” refers to a deuterium atom.

When the emission layer EML in the light-emitting element ED of one or more embodiments includes all of the first compound, the second compound, and the third compound, with respect to the total weight of the first compound, the second compound, and the third compound, the content (e.g., amount) of the first compound may be about 0.1 wt % to about 5 wt %. However, the embodiment of the present disclosure is not limited thereto. When the content (e.g., amount) of the first compound satisfy the herein-described proportion, the energy transfer from the second compound and the third compound to the first compound may increase, and thus the luminous efficiency and device service life (e.g., lifespan) may increase.

The contents of the second compound and the third compound in the emission layer EML may be the rest excluding the weight of the first compound. For example, the contents of the second compound and the third compound in the emission layer EML may be about 65 wt % to about 95 wt % with respect to the total weight of the first compound, the second compound, and the third compound.

In the total weight of the second compound and the third compound, the weight ratio of the second compound and the third compound may be about 3:7 to about 7:3.

When the contents of the second compound and the third compound satisfy the herein-described ratio, a charge balance characteristic in the emission layer EML are improved, and thus the luminous efficiency and device service life (e.g., lifespan) may increase. When the contents of the second compound and the third compound deviate from the herein-described ratio range, a charge balance in the emission layer EML is broken, and thus the luminous efficiency may be reduced and the light-emitting element ED may be easily deteriorated.

When the emission layer EML includes the fourth compound, the content (e.g., amount) of the fourth compound in the emission layer EML may be about 10 wt % to about 30 wt % with respect to the total weight of the first compound, the second compound, the third compound, and the fourth compound. However, the embodiment of the present disclosure is not limited thereto. When the content (e.g., amount) of the fourth compound satisfies the herein-described content (e.g., amount), the energy delivery from the host to the first compound which is a light emitting dopant may be increased, thereby a luminous ratio may be improved, and thus the luminous efficiency of the emission layer EML may be improved. When the first compound, the second compound, the third compound, and the fourth compound included in the emission layer EML satisfy the herein-described content (e.g., amount) ratio range, excellent or suitable luminous efficiency and long service life (e.g., lifespan) may be achieved.

In some embodiments, the light-emitting element ED of one embodiment may include a plurality of emission layers. A plurality of emission layers may be provided by being sequentially stacked. For example, a light-emitting element ED including a plurality of emission layers may be to emit white light. A light-emitting element ED including a plurality of emission layers may be a light-emitting element with a tandem structure. When the light-emitting element ED includes a plurality of emission layers, at least one emission layer EML may include the first compound represented by Formula 1 in one embodiment. Additionally, when the light-emitting element ED includes a plurality of emission layers, at least one emission layer EML may include all of the first compound, second compound, third compound, and fourth compound as described herein.

In the light-emitting element ED of one or more embodiments, the emission layer EML may include an anthracene derivative, a pyrene derivative, a fluoranthene derivative, a chrysene derivative, a dehydrobenzanthracene derivative, or a triphenylene derivative. For example, the emission layer EML may include the anthracene derivative or the pyrene derivative.

In each light-emitting element ED of embodiments illustrated in FIGS. 3 to 6, the emission layer EML may further include a suitable host and dopant besides the herein-described host and dopant, and for example the emission layer EML may include a compound represented by Formula E-1. The compound represented by Formula E-1 may be utilized as a fluorescent host material.

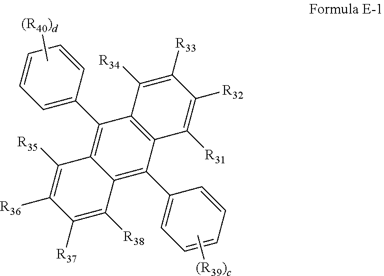

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In some embodiments, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer of 0 to 5.

Formula E-1 may be represented by any one selected from among Compound E1 to Compound E19:

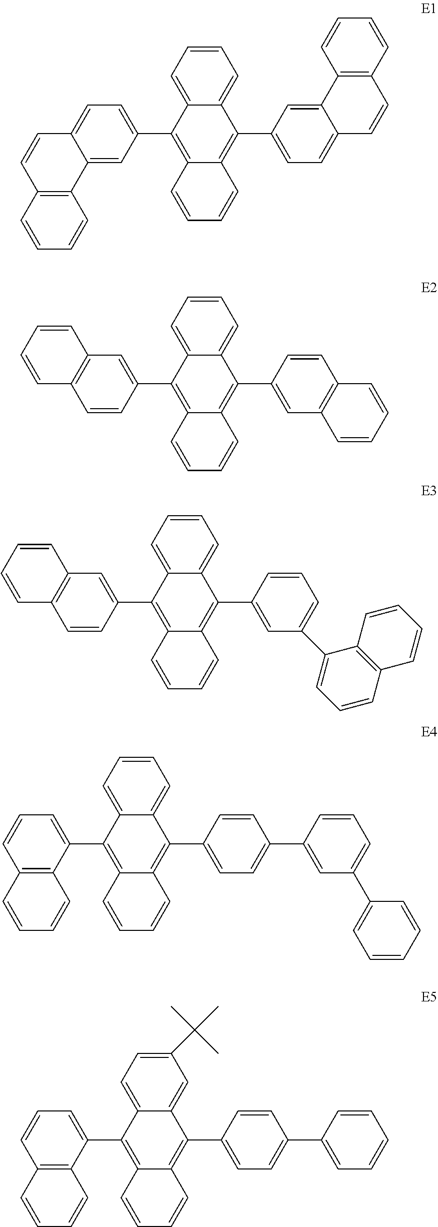

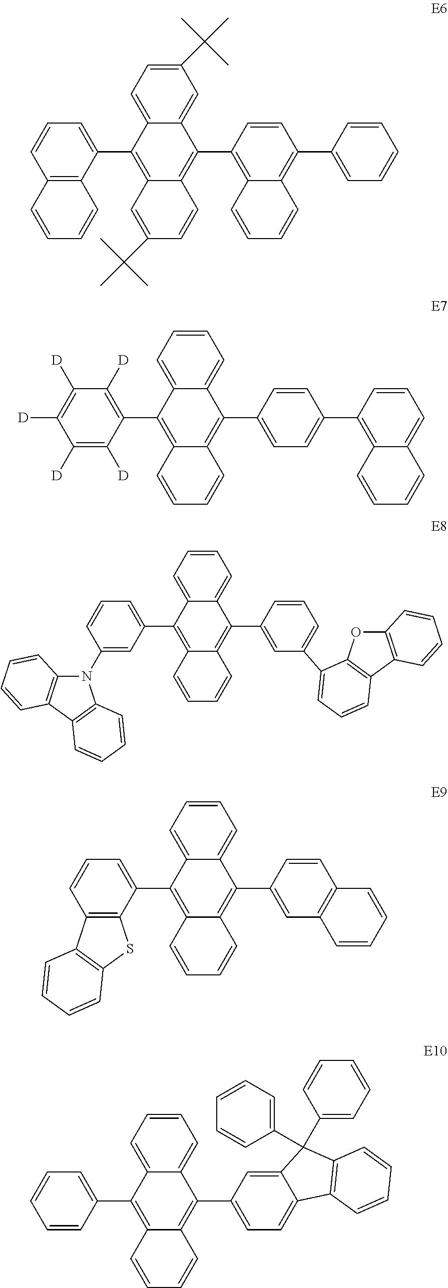

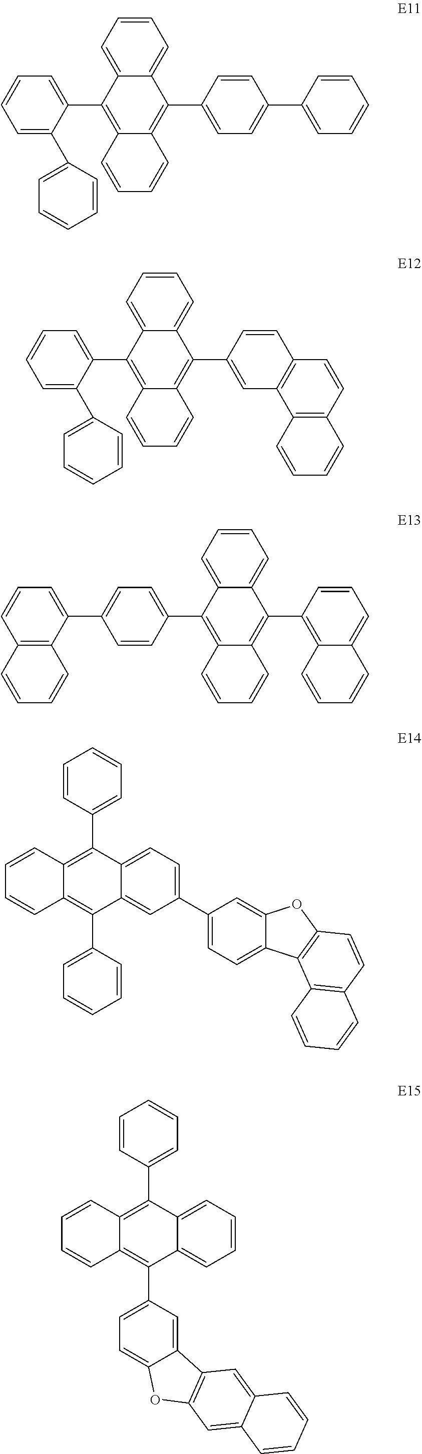

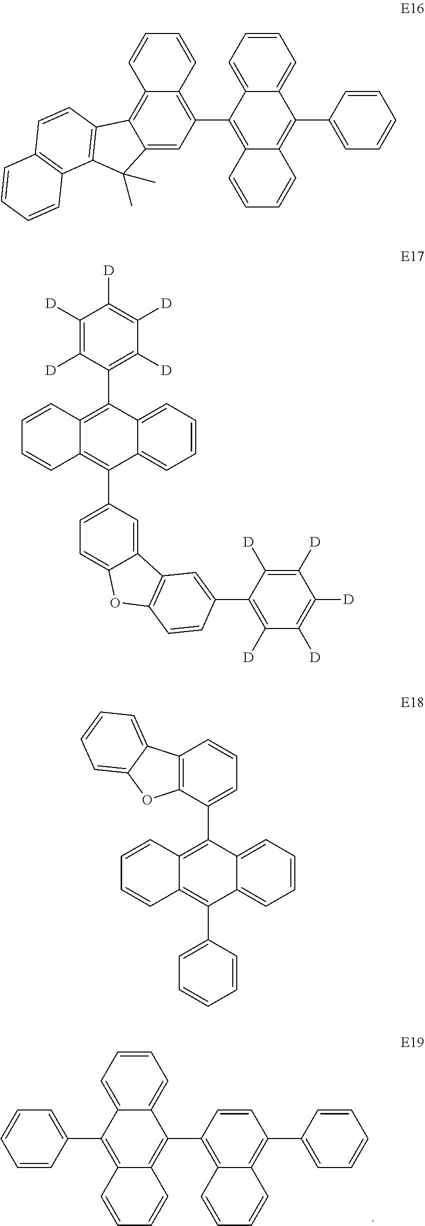

In one or more embodiments, the emission layer EML may include a compound represented by Formula E-2a or Formula E-2b. The compound represented by Formula E-2a or Formula E-2b may be utilized as a phosphorescent host material.

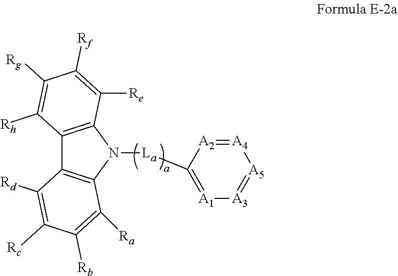

In Formula E-2a, a may be an integer of 0 to 10, and La may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a is an integer of 2 or greater, a plurality of La's may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. Rₐ to Rᵢ may be bonded to an adjacent group to form a hydrocarbon ring or a heterocycle containing N, O, S, and/or the like, as a ring-forming atom.

In some embodiments, in Formula E-2a, two or three selected from among A₁ to A₅ may be N, and the rest (i.e., each of the remaining A₁ to A₅) may be CRᵢ.

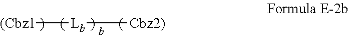

In Formula E-2b, Cbz1 and Cbz2 may each independently be an unsubstituted carbazole group, or a carbazole group substituted with an aryl group having 6 to 30 ring-forming carbon atoms. L_{b} is a direct linkage, a substituted or unsubstituted arylene group having 6 to 30 ring-forming carbon atoms, or a substituted or unsubstituted heteroarylene group having 2 to 30 ring-forming carbon atoms. In some embodiments, b is an integer of 0 to 10, and when b is an integer of 2 or more, a plurality of L_{b}'s may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one selected from among the compounds of Compound Group E-2. However, the compounds listed in Compound Group E-2 are example, and the compound represented by Formula E-2a or Formula E-2b is not limited to those represented in Compound Group E-2.

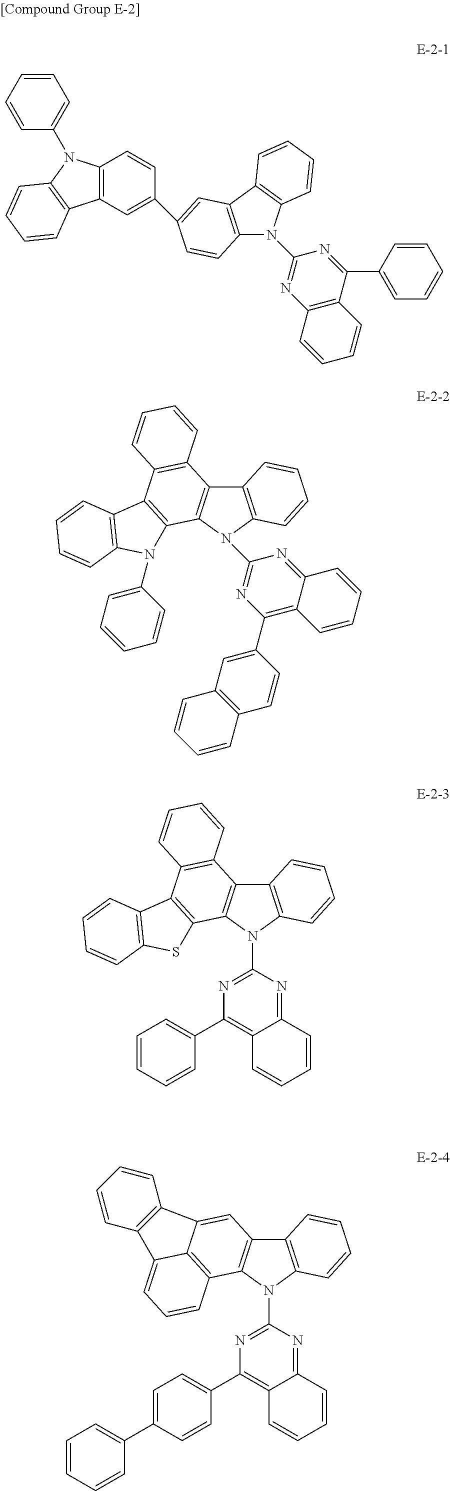 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1 ; c1ccc(-c2ccc(-c3nc(-n4c5ccccc5c5cc6c7c(cccc7c54)-c4ccccc4-6)nc4ccccc34)cc2)cc1]

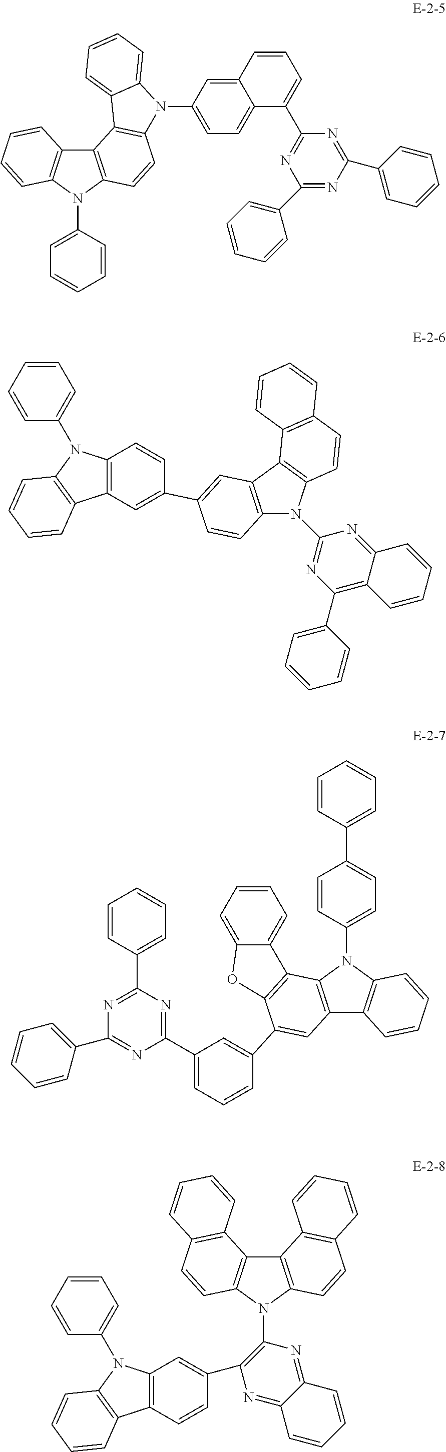 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

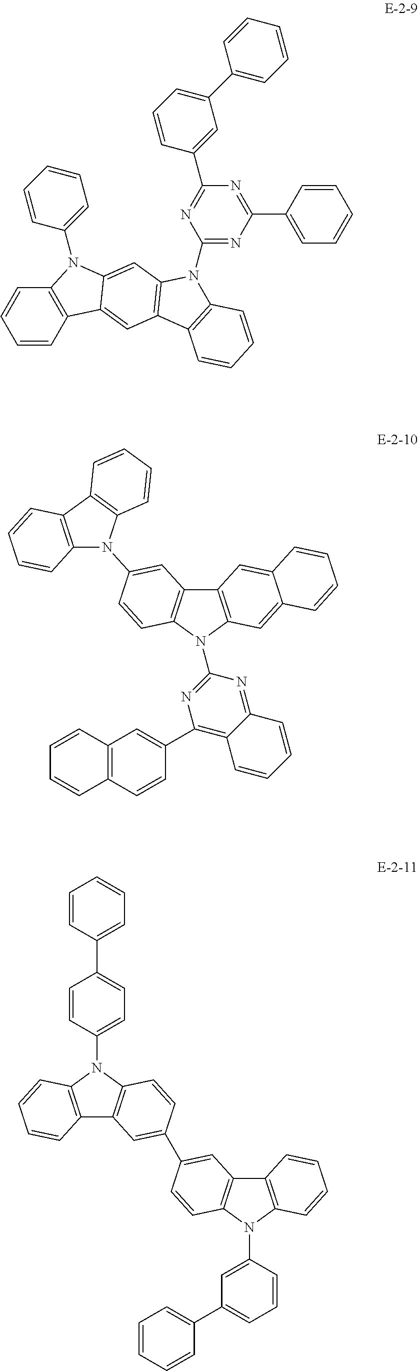 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

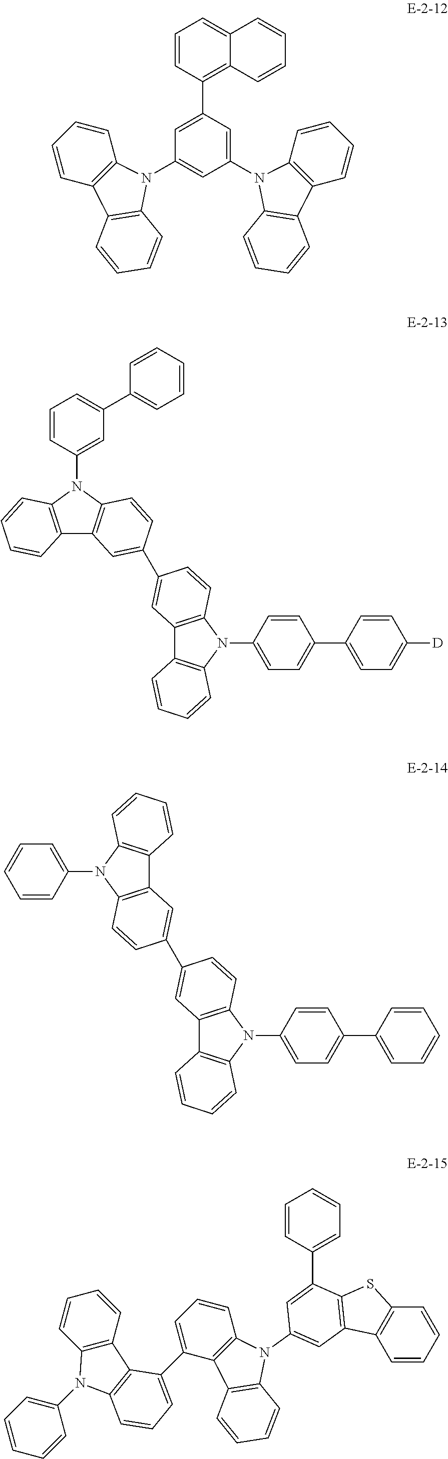 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

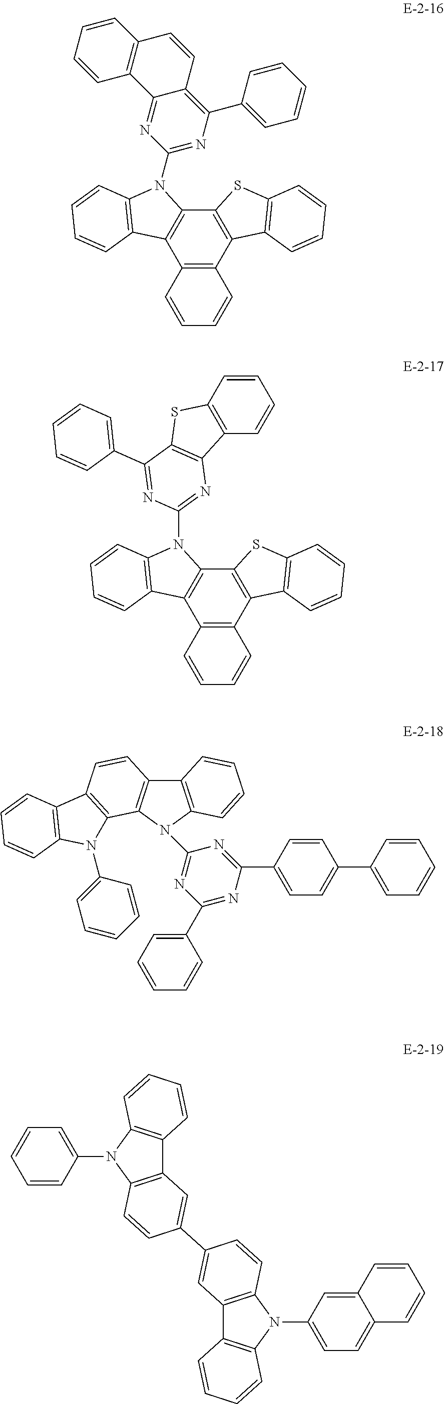 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1]

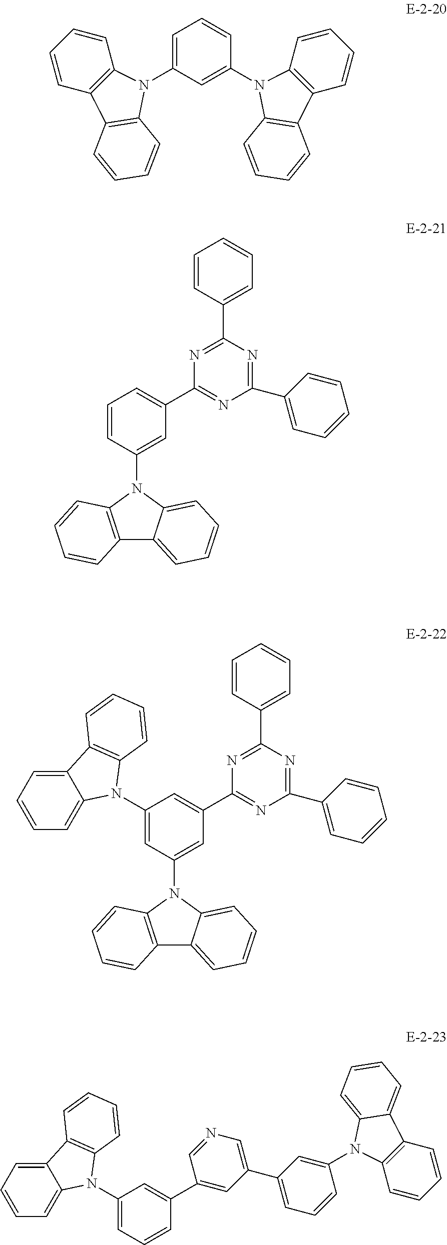 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

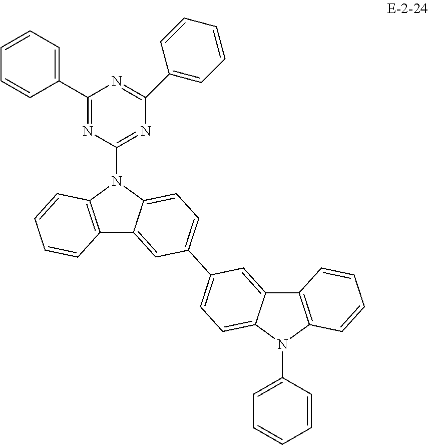 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a general material suitable in the art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(N-carbazolyl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, the embodiment of the present disclosure is not limited thereto, for example, tris(8-hydroxyquinolino)aluminum (Alq₃), 9,10-di(naphthalene-2-yl) anthracene (ADN), 2-tert-butyl-9,10-di(naphth-2-yl) anthracene (TBADN), distyrylarylene (DSA), 4,4′-bis(carbazol-9-yl)-2,2′-dimethyl-biphenyl (CDBP), 2-methyl-9,10-bis(naphthalen-2-yl) anthracene (MADN), hexaphenyl cyclotriphosphazene (CP1), 1,4-bis(triphenylsilyl)benzene (UGH₂), hexaphenylcyclotrisiloxane (DPSiO₃), octaphenylcyclotetrasiloxane (DPSiO₄), and/or the like may be utilized as a host material.

The emission layer EML may include the compound represented by Formula M-a. The compound represented by Formula M-a may be utilized as a phosphorescent dopant material.

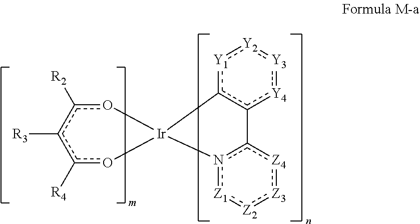

In Formula M-a, Y₁ to Y₄ and Z₁ to Z₄ may each independently be CR₁ or N, R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula M-a, m is 0 or 1, and n is 2 or 3. In Formula M-a, when m is 0, n is 3, and when m is 1, n is 2.

The compound represented by Formula M-a may be utilized as a phosphorescent dopant.

The compound represented by Formula M-a may be represented by any one selected from among Compound M-a1 to Compound M-a25. However, Compounds M-a1 to M-a25 are examples, and the compound represented by Formula M-a is not limited to those represented by Compounds M-a1 to M-a25.

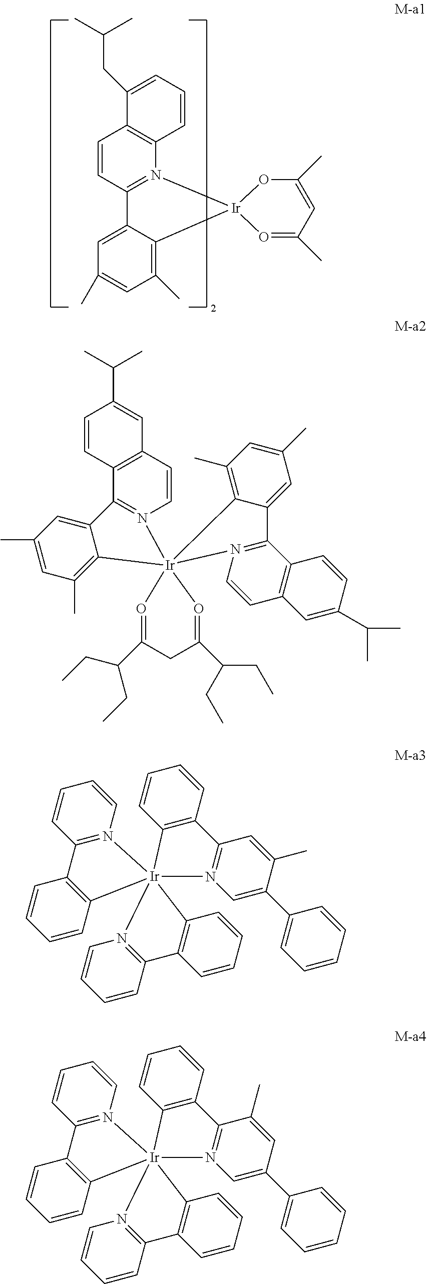

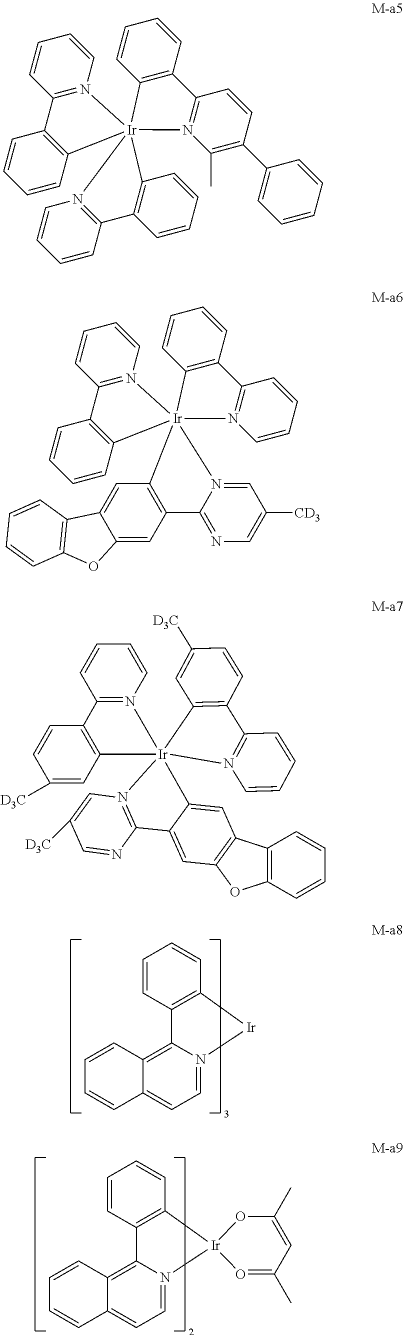

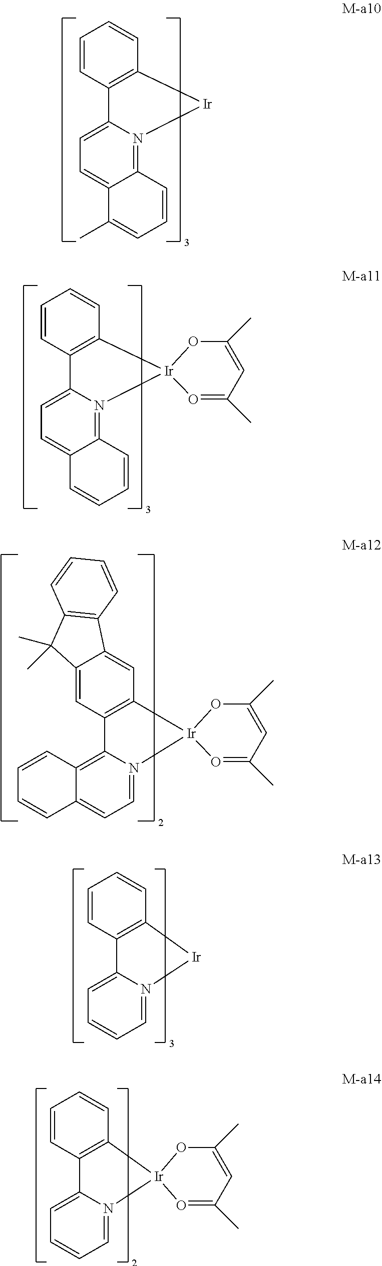

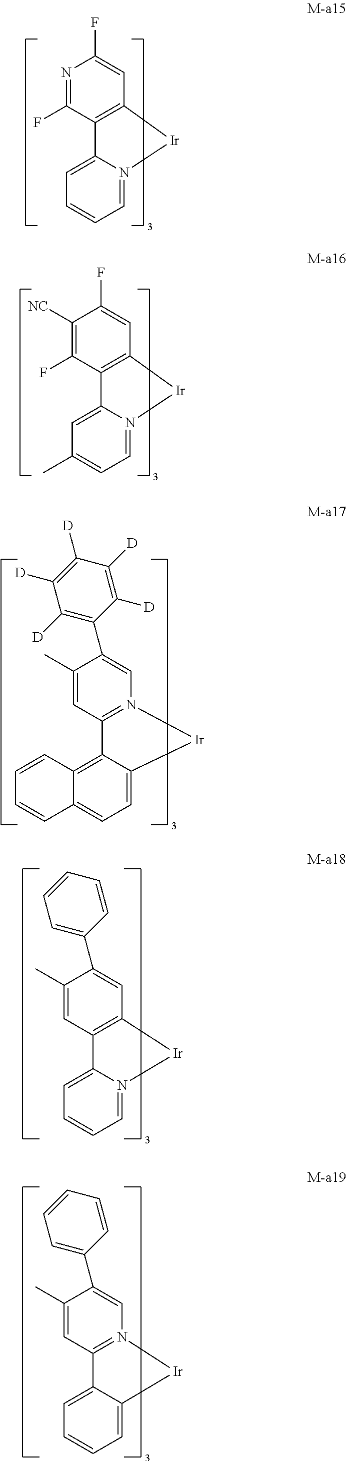

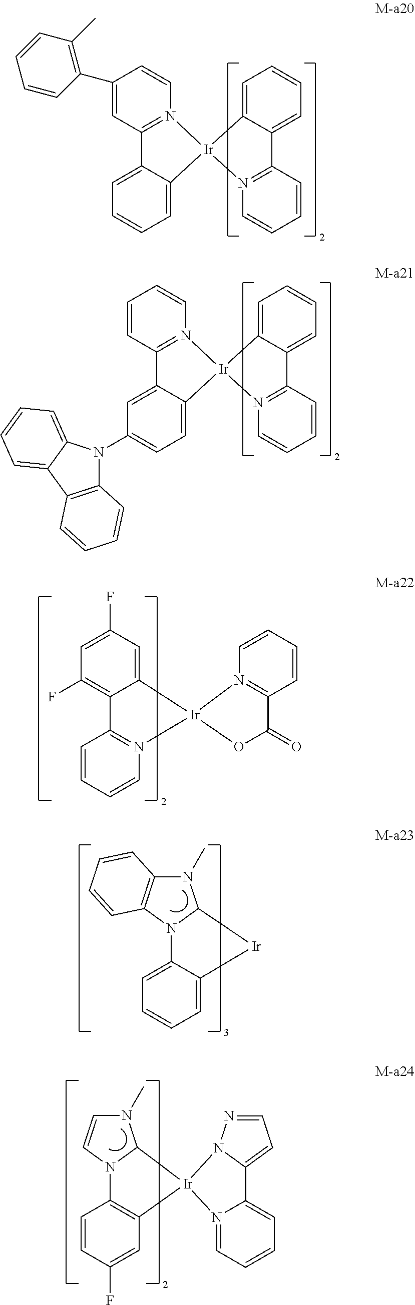

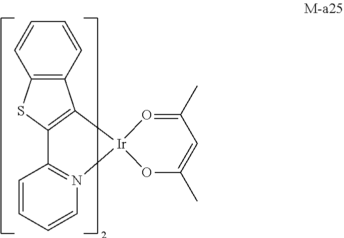

The emission layer EML may include a compound represented by any one selected from among Formula F-a to Formula F-c. The compound represented by Formula F-a to Formula F-c may be utilized as a fluorescence dopant material.

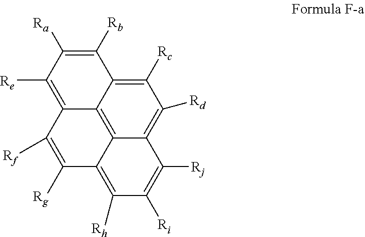

In Formula F-a, two selected from among Rₐ to Rⱼ may each independently be substituted with *—NAr₁Ar₂. The others, which are not substituted with *—NAr₁Ar₂, selected from among Rₐ to Rⱼ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In *—NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ and Ar₂ may be a heteroaryl group containing O or S as a ring-forming atom.

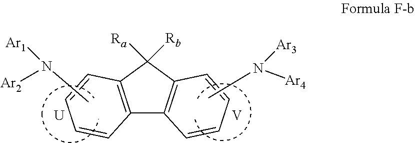

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms. At least one selected from among Ar₁ to Ar₄ may be a heteroaryl group containing O or S as a ring-forming atom.

In Formula F-b, the number of rings represented by U and V may each independently be 0 or 1. For example, in Formula F-b, it refers to that when the number of U or V is 1, one ring constitutes a fused ring at a portion indicated by U or V, and when the number of U or V is 0, a ring indicated by U or V does not exist. For example, when the number of U is 0 and the number of V is 1, or when the number of U is 1 and the number of V is 0, the fused ring having a fluorene core in Formula F-b may be a cyclic compound having four rings. In some embodiments, when each number of U and V is 0, the fused ring having a fluorene core in Formula F-b may be a cyclic compound having three rings. In some embodiments, when each number of U and V is 1, the fused ring having a fluorene core in Formula F-b may be a cyclic compound having five rings.

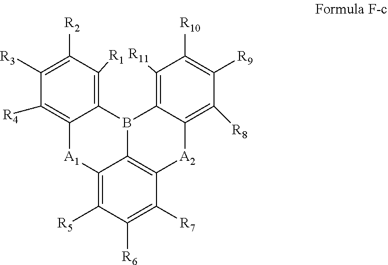

In Formula F-c, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring.

In Formula F-c, A₁ and A₂ may each independently be bonded to substituents of an adjacent ring to form a fused ring. For example, when A₁ and A₂ may each independently be NRₘ, A₁ may be bonded to R₄ or R₅ to form a ring. In some embodiments, A₂ may be bonded to R₇ or R₈ to form a ring.

In one or more embodiments, the emission layer EML may further include, as a suitable dopant material, at least one selected from among a styryl derivative (e.g., 1,4-bis[2-(3-N-ethylcarbazolyl)vinyl]benzene (BCzVB), 4-(di-p-tolylamino)-4′-[(di-p-tolylamino) styryl]stilbene (DPAVB), N-(4-((E)-2-(6-((E)-4-(diphenylamino) styryl) naphthalen-2-yl) vinyl)phenyl)-N-phenylbenzenamine (N-BDAVBi), and 4,4′-bis[2-(4-(N, N-diphenylamino)phenyl)vinyl]biphenyl (DPAVBi)), perylene and a derivative thereof (e.g., 2,5,8,11-tetra-t-butylperylene (TBP)), pyrene and a derivative thereof (e.g., 1,1′-dipyrene, 1,4-dipyrenylbenzene, 1,4-bis(N,N-diphenylamino) pyrene), and/or the like.

The emission layer EML may further include a suitable phosphorescence dopant material. For example, a metal complex containing iridium (Ir), platinum (Pt), osmium (Os), aurum (Au), titanium (Ti), zirconium (Zr), hafnium (Hf), europium (Eu), terbium (Tb), or thulium (Tm) may be utilized as a phosphorescent dopant. For example, iridium (III) bis(4,6-difluorophenylpyridinato-N,C2) picolinate (Flrpic), bis(2,4-difluorophenylpyridinato)-tetrakis(1-pyrazolyl) borate iridium (III) (Flr₆), or platinum octaethyl porphyrin (PtOEP) may be utilized as a phosphorescent dopant. However, the embodiment of the present disclosure is not limited thereto.

The emission layer EML may include a quantum dot material. The core of the quantum dot may be selected from a Group II-VI compound, a Group III-VI compound, a Group I-III-IV compound, a Group III-V compound, a Group III-II-V compound, a Group IV-VI compound, a Group IV element, a Group IV compound, or a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof.

The Group III-VI compound may include a binary compound such as In₂S₃ or In₂Se₃, a ternary compound such as InGaS₃ or InGaSe₃, or any combination thereof.

The Group I-III-VI compound may be selected from a ternary compound selected from the group consisting of AgInS, AgInS₂, CuInS, CuInS₂, AgGaS₂, CuGaS₂, CuGaO₂, AgGaO₂, AgAlO₂, and a mixture thereof, or a quaternary compound such as AgInGaS₂ or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In some embodiments, the Group III-V compound may further include a Group II metal. For example, InZnP, and/or the like, may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

Each element included in a polynary (i.e., multi-element) compound such as the binary compound, the ternary compound, or the quaternary compound may be present in a particle with a substantially uniform or non-substantially uniform concentration distribution. For example, the formulae refer to the types (kinds) of elements included in the compounds, and the elemental ratio in the compound may be different. For example, AgInGaS₂ may refer to AgInₓGa₁₋ₓS₂ (where x is a real number of 0 to 1).

In some embodiments, the quantum dot may have a single structure or a double structure of core-shell in which the concentration of each element included in the quantum dot is substantially uniform. For example, the material included in the core may be different from the material included in the shell.

The shell of the quantum dot may serve as a protection layer to prevent or reduce the chemical deformation of the core to maintain semiconductor properties, and/or a charging layer to impart electrophoresis properties to the quantum dot. The shell may be a single layer or multiple layers. An interface between the core and the shell may have a concentration gradient in which the concentration of an element present in the shell becomes lower towards the center.

In some embodiments, the quantum dot may have the herein-described core/shell structure including a core containing nanocrystals and a shell around (e.g., surrounding) the core. An example of the shell of the quantum dots may include a metal or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄, but the embodiment of the present disclosure is not limited thereto.

Also, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but the embodiment of the present disclosure is not limited thereto.

Each element included in a polynary (i.e., multi-element) compound such as the binary compound, or the ternary compound may be present in a particle with a substantially uniform or non-substantially uniform concentration distribution. For example, the formulae refer to the types (kinds) of elements included in the compounds, and the elemental ratio in the compound may be different.

The quantum dot may have a full width of half maximum (FWHM) of a light emitting wavelength spectrum of about 45 nm or less, about 40 nm or less, or about 30 nm or less, and color purity or color reproducibility may be improved in the described range. In some embodiments, light emitted through such quantum dot is emitted in all directions so that a wide viewing angle may be improved.

In some embodiments, the form of the quantum dot is not particularly limited as long as it is a form commonly utilized in the art, more specifically, the quantum dot in the form of spherical, pyramidal, multi-arm, or cubic nanoparticles, nanotubes, nanowires, nanofibers, nanoplates, and/or the like may be utilized.

As the size of the quantum dot is adjusted or the elemental ratio in the quantum dot compound is adjusted, it is possible to control the energy band gap, and thus light in one or more suitable wavelength ranges may be obtained in the quantum dot emission layer. Therefore, the quantum dot as described (utilizing different sizes of quantum dots or different elemental ratios in the quantum dot compound) is utilized, and thus the light-emitting element ED which emits light in one or more suitable wavelengths, may be implemented. For example, the adjustment of the size of the quantum dot or the elemental ratio in the quantum dot compound may be selected to emit red, green, and/or blue light. In some embodiments, the quantum dots may be configured to emit white light by combining one or more suitable colors of light.

In each of the light-emitting elements ED of embodiments illustrated in FIGS. 3 to 6, the electron transport region ETR is provided on the emission layer EML. The electron transport region ETR may include at least one of the hole blocking layer HBL, the electron transport layer ETL, and the electron injection layer EIL, but the embodiment of the present disclosure is not limited thereto.

The electron transport region ETR may have a single layer formed of a single material, a single layer formed of a plurality of different materials, or a multilayer structure including a plurality of layers formed of a plurality of different materials.

For example, the electron transport region ETR may have a single layer structure of the electron injection layer EIL or the electron transport layer ETL, and may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL are stacked in order from the emission layer EML, but the embodiment of the present disclosure is not limited thereto. The electron transport region ETR may have a thickness, for example, from about 1,000 Å to about 1,500 Å.

The electron transport region ETR may be formed utilizing one or more suitable methods such as a vacuum deposition method, a spin coating method, a cast method, a Langmuir-Blodgett (LB) method, an inkjet printing method, a laser printing method, and a laser induced thermal imaging (LITI) method.

The electron transport region ETR may include a compound represented by Formula ET-2:

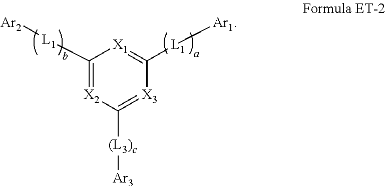

In Formula ET-2, at least one selected from among X₁ to X₃ is N, and the rest (e.g., each of the remaining X₁ to X₃) may be CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer of 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a to c may each independently be an integer of 2 or more, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, the embodiment of the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl) biphenyl-3-yl)-1,3,5-triazine, 2-(4-(N-phenylbenzoimidazol-1-yl)phenyl)-9,10-dinaphthylanthracene, 1,3,5-tri (1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (^{t}Bu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl) anthracene (ADN), 1,3-bis[3,5-di(pyridin-3-yl)phenyl]benzene (BmPyPhB), or a mixture thereof.

The electron transport region ETR may include at least one selected from among Compound ET1 to Compound ET36:

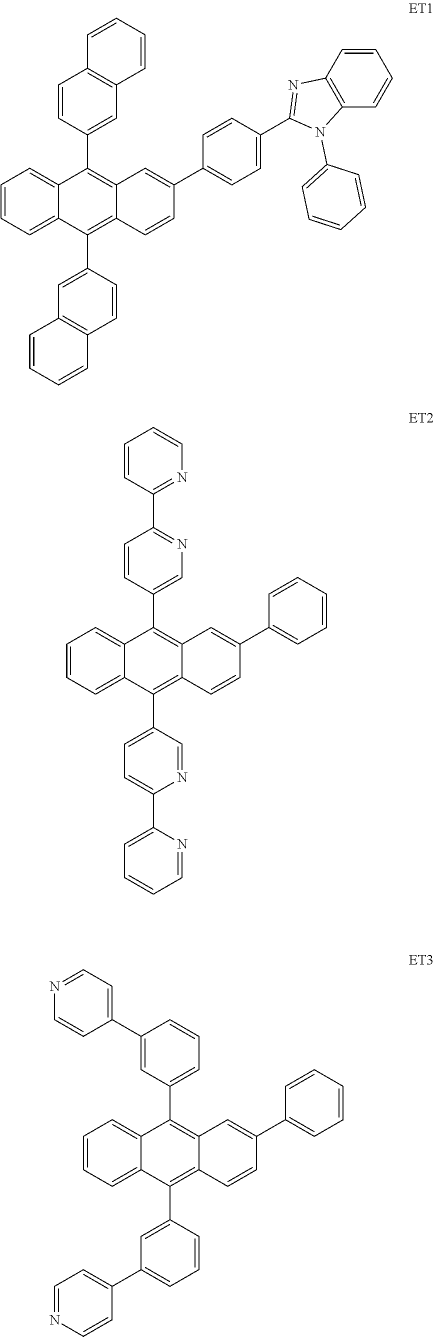

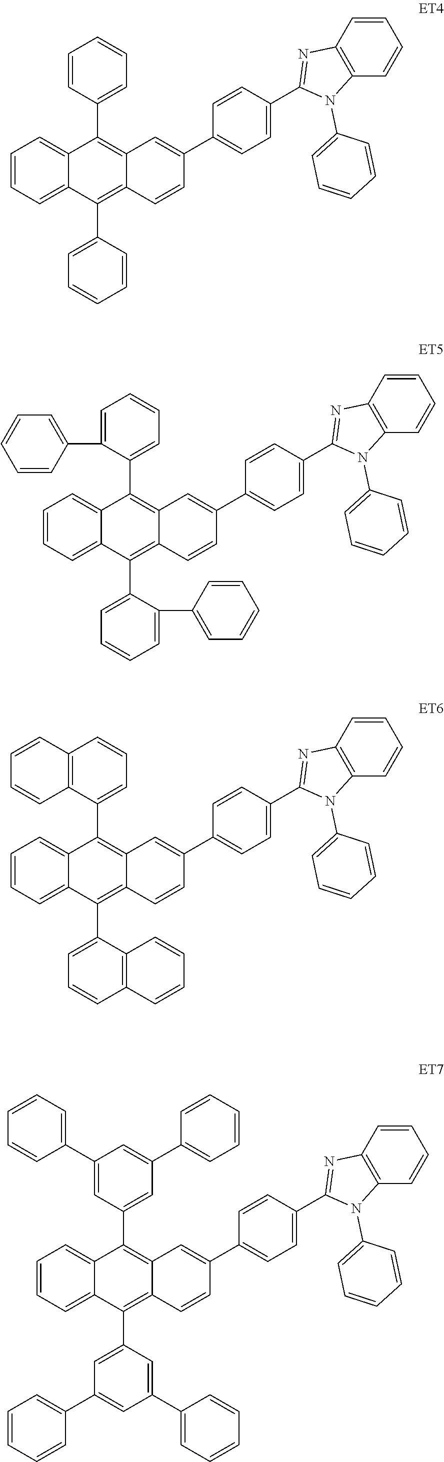 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

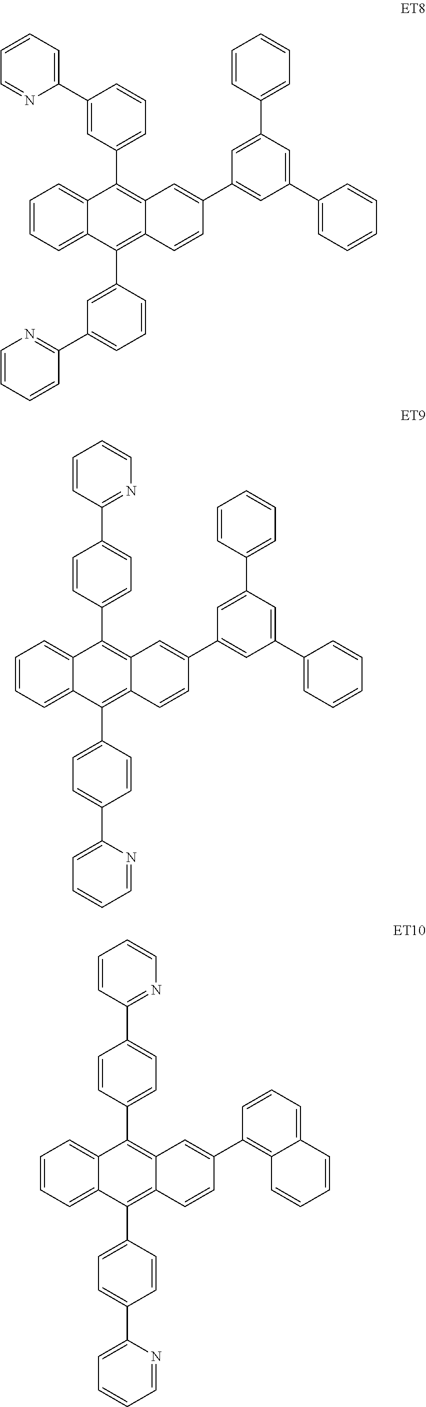

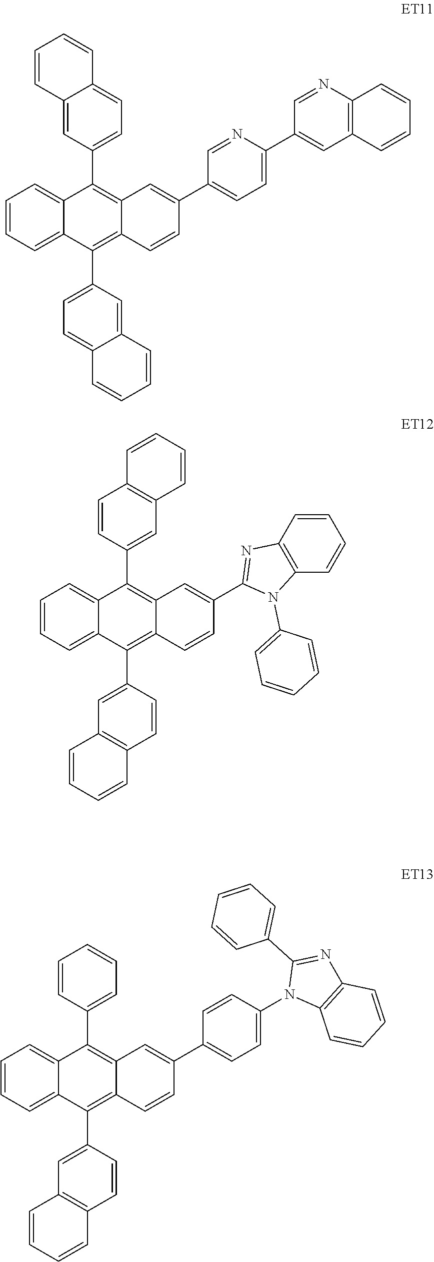 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

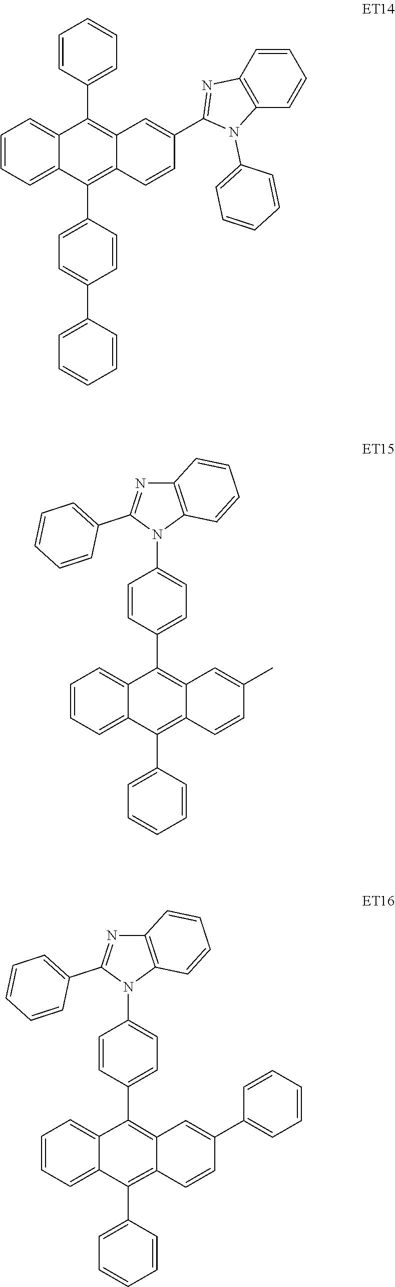 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

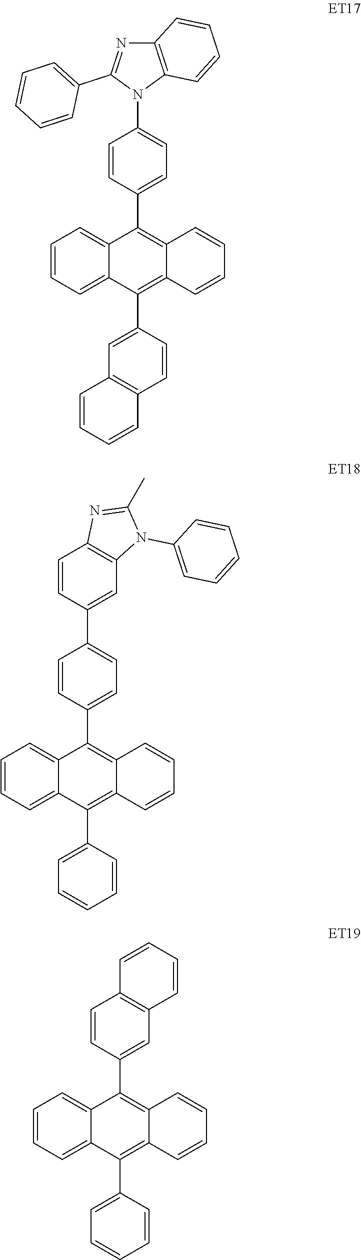

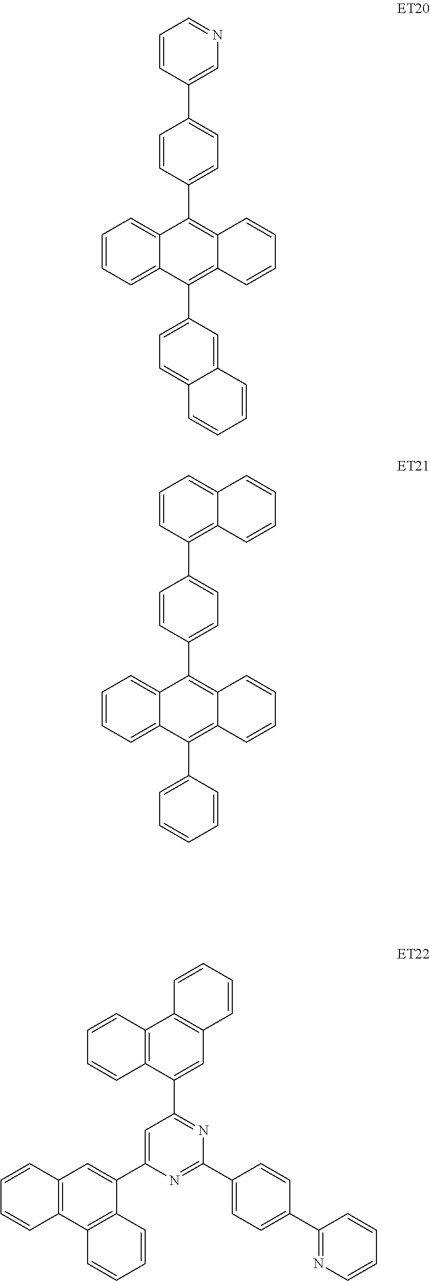

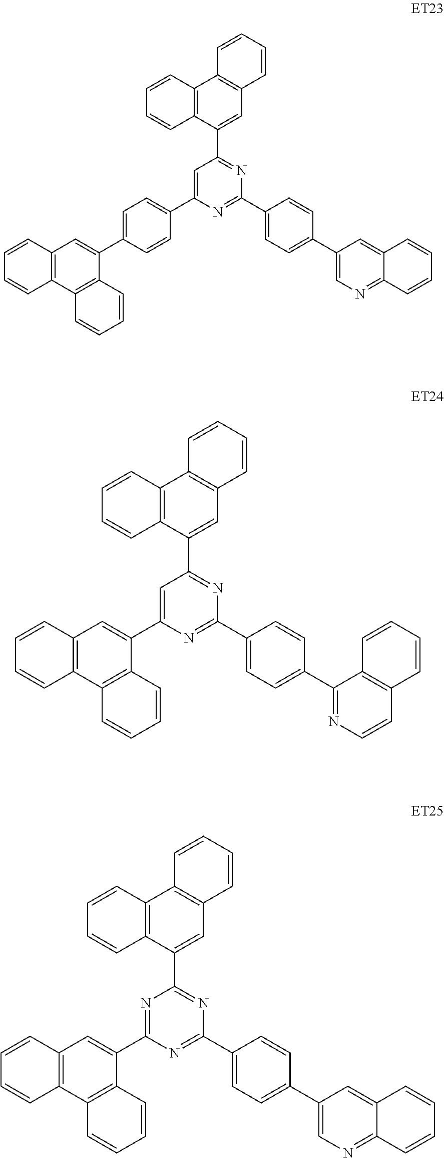 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

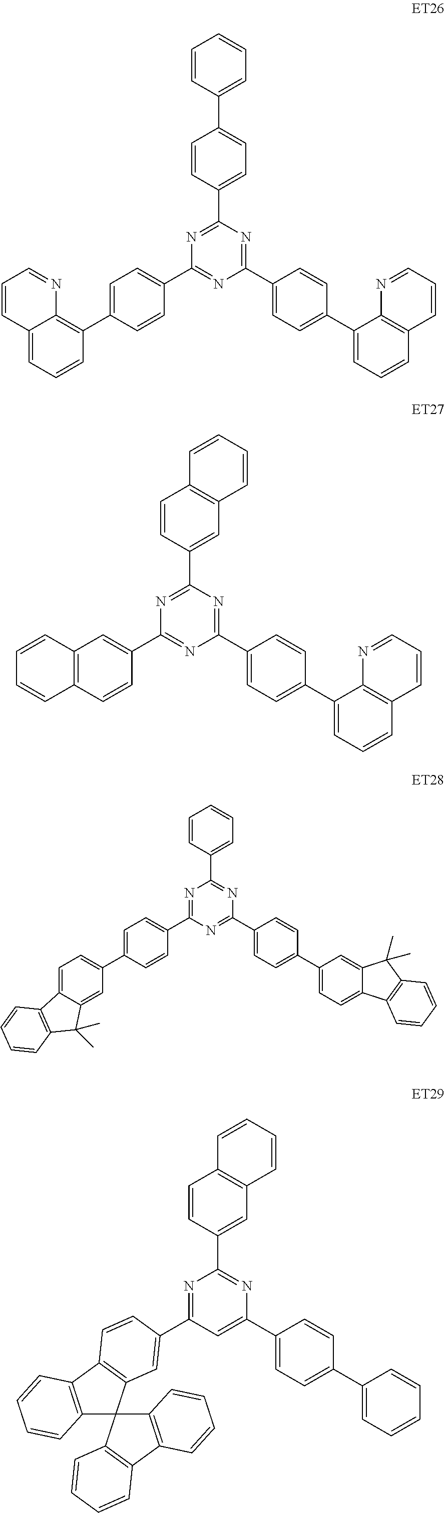 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1]

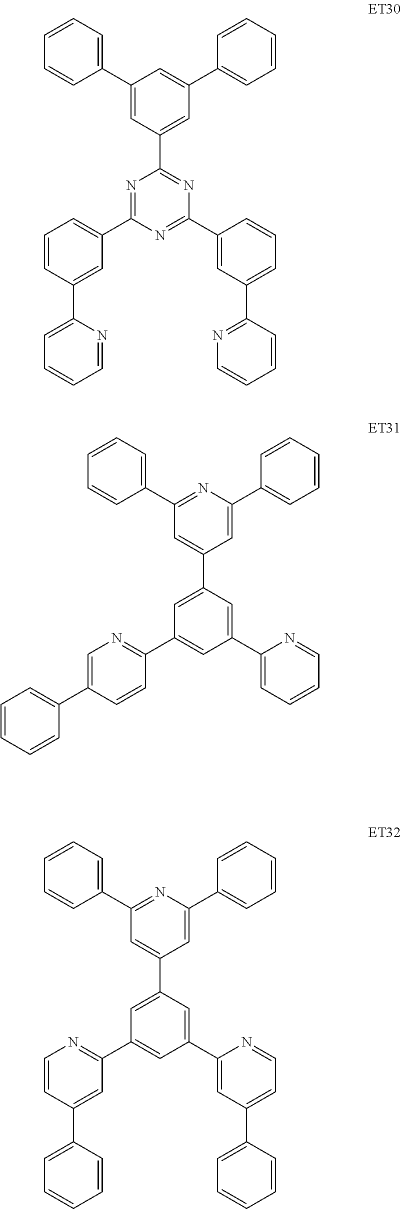 [SMILES: c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

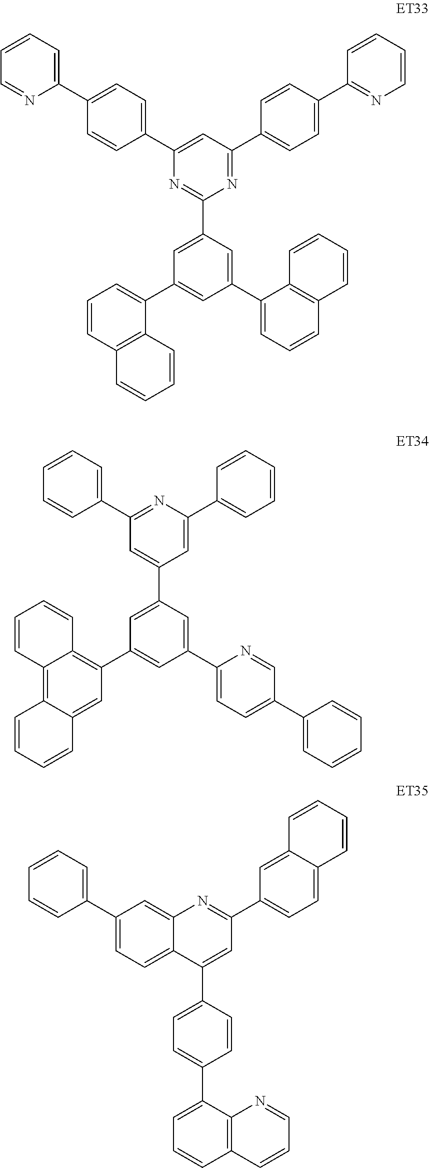

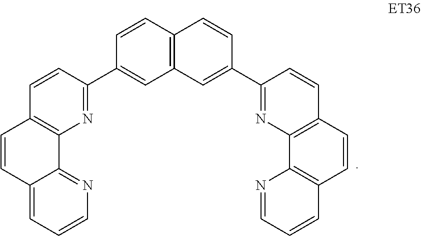 [SMILES: c1cnc2c(c1)ccc1ccc(-c3ccc4ccc(-c5ccc6ccc7cccnc7c6n5)cc4c3)nc12]

In some embodiments, the electron transport region ETR may include a metal halide such as LiF, NaCl, CsF, RbCl, Rbl, Cul, and KI, a lanthanide metal such as Yb, and a co-deposited material of the metal halide and the lanthanide metal. For example, the electron transport region ETR may include KI:Yb, Rbl:Yb, LiF:Yb, and/or the like, as a co-deposited material. In some embodiments, the electron transport region ETR may be formed utilizing a metal oxide such as Li₂O or BaO, or 8-hydroxyl-lithium quinolate (Liq), and/or the like, but the embodiment of the present disclosure is not limited thereto. The electron transport region ETR may also be formed of a mixture material of an electron transport material and an insulating organometallic salt. The organometallic salt may be a material having an energy band gap of about 4 eV or more. For example, the organometallic salt may include, for example, a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen) in addition to the herein-described materials, but the embodiment of the present disclosure is not limited thereto.

The electron transport region ETR may include the herein-described compounds of the electron transport region ETR in at least one of the electron injection layer EIL, the electron transport layer ETL, and the hole blocking layer HBL.

When the electron transport region ETR includes the electron transport layer ETL, the electron transport layer ETL may have a thickness of about 100 Å to about 1,000 Å, for example, about 150 Å to about 500 Å. When the thickness of the electron transport layer ETL satisfies the aforementioned range, satisfactory electron transport characteristics may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. When the thickness of the electron injection layer EIL satisfies the herein-described range, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but the embodiment of the present disclosure is not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), and/or the like.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF, Mo, Ti, Yb, W, a compound or mixture thereof (e.g., AgMg, AgYb, or MgYb), or materials with multilayer structures such as LiF/Ca or LiF/Al. In some embodiments, the second electrode EL2 may have a multilayer structure including a reflective film or a transflective film formed of the herein-described materials, and a transparent conductive film formed of ITO, IZO, ZnO, ITZO, and/or the like. For example, the second electrode EL2 may include the herein-described metal materials, combinations of at least two metal materials of the herein-described metal materials, oxides of the herein-described metal materials, and/or the like.

In some embodiments, the second electrode EL2 may be connected with an auxiliary electrode. When the second electrode EL2 is connected with the auxiliary electrode, the resistance of the second electrode EL2 may be decreased.

In some embodiments, a capping layer CPL may further be provided on the second electrode EL2 of the light-emitting element ED of one or more embodiments. The capping layer CPL may include a multilayer or a single layer.

In one or more embodiments, the capping layer CPL may be an organic layer or an inorganic layer. For example, when the capping layer CPL contains an inorganic material, the inorganic material may include an alkaline metal compound (e.g., LiF), an alkaline earth metal compound (e.g., MgF₂), SiON, SiNₓ, SiO_{y}, and/or the like.

For example, when the capping layer CPL includes an organic material, the organic material may include α-NPD, NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol-9-yl)triphenylamine (TCTA), and/or the like, or an epoxy resin, or acrylate such as methacrylate. However, the embodiment of the present disclosure is not limited thereto, and the capping layer CPL may include at least one selected from among Compounds P1 to P5:

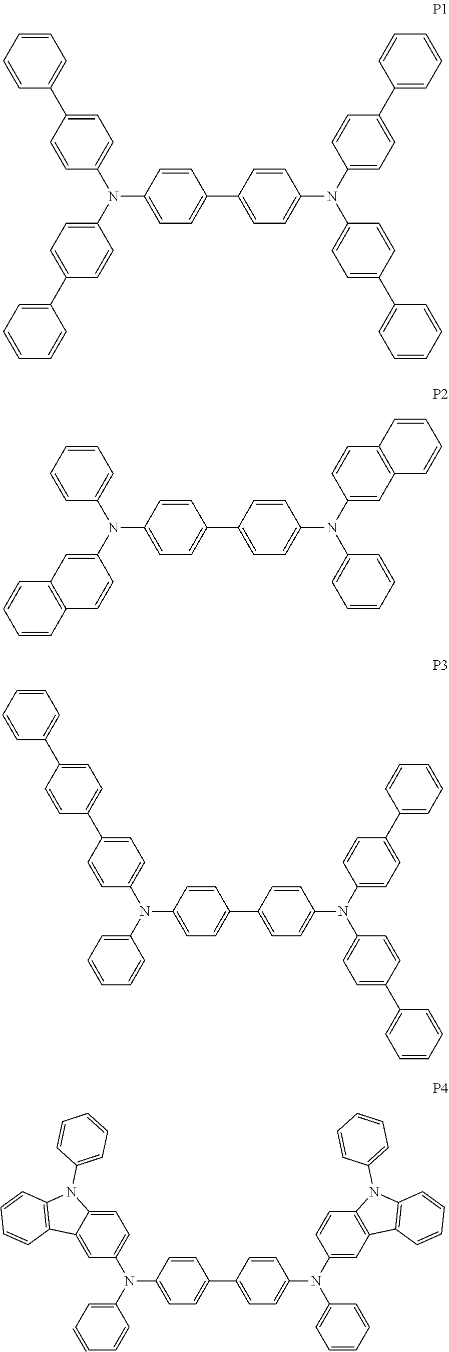 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

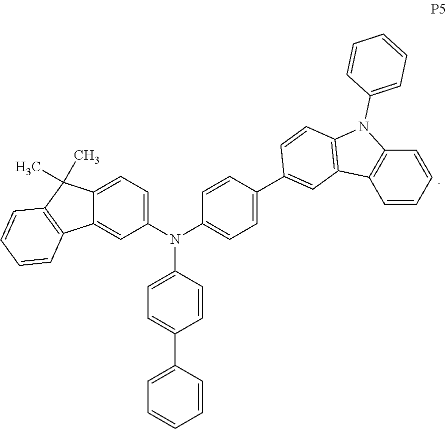 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, the refractive index of the capping layer CPL may be about 1.6 or more with respect to light in a wavelength range of about 550 nm to about 660 nm.

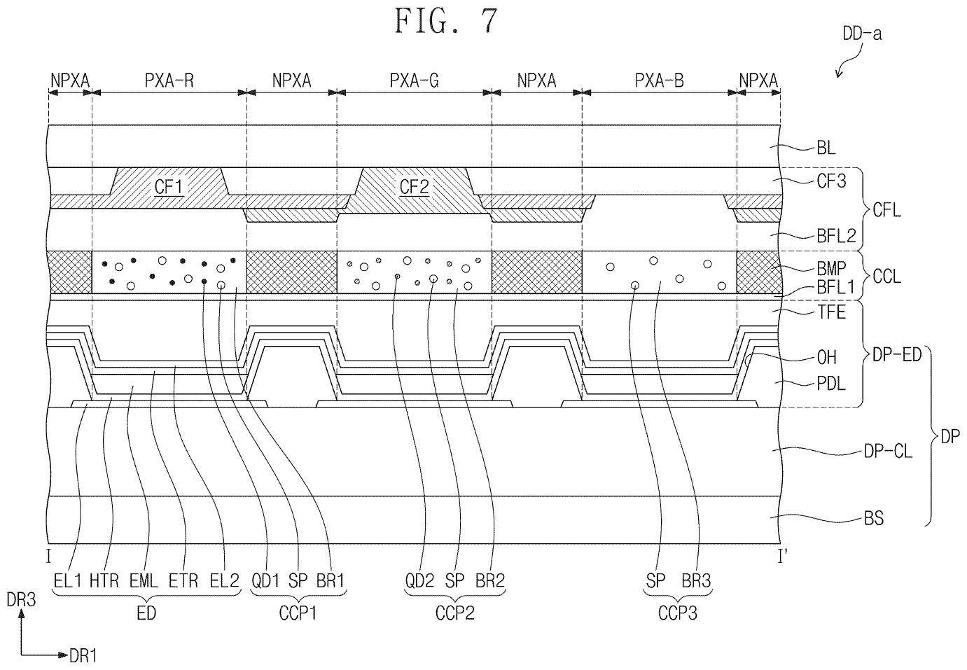

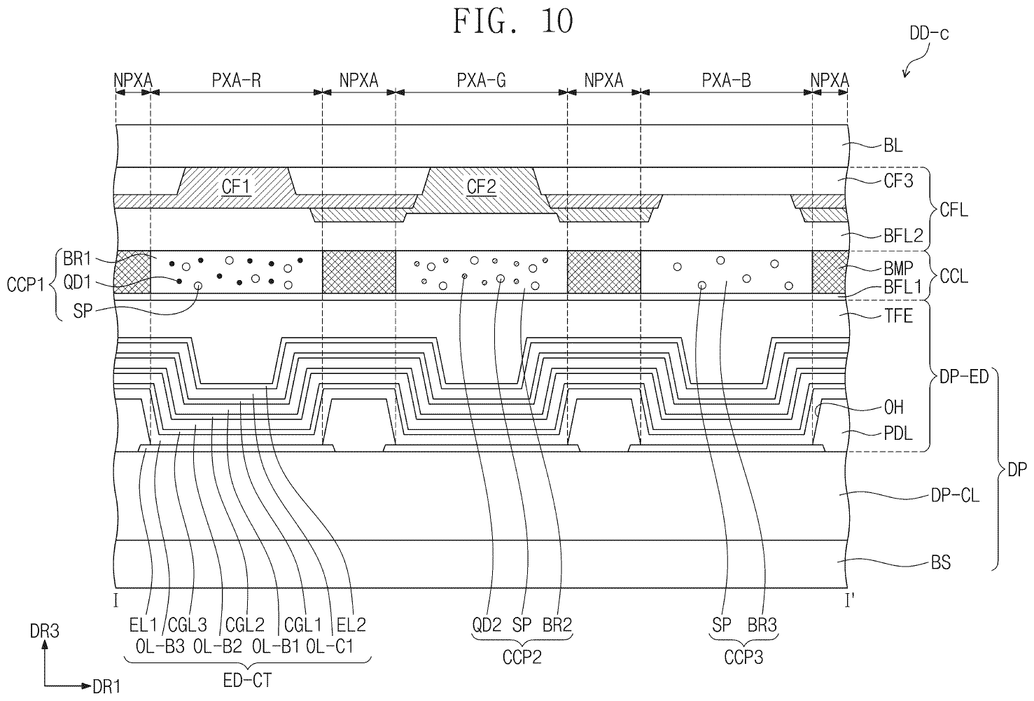

Each of FIGS. 7 to 10 is a cross-sectional view of display devices DD-a, DD-TD, DD-b and DD-c according to one or more embodiments of the present disclosure. Hereinafter, in describing the display devices of embodiments with reference to FIGS. 7 to 10, the duplicated features which have been described in FIGS. 1 to 6 are not described again, but their differences will be mainly described (e.g., in more detail).

Referring to FIG. 7, the display device DD-a according to one or more embodiments may include a display panel DP including a display device layer DP-ED, and a light control layer CCL and a color filter layer CFL provided on the display panel DP. In one or more embodiments illustrated in FIG. 7, the display panel DP may include a base layer BS, and a circuit layer DP-CL and the display device layer DP-ED provided on the base layer BS, and the display device layer DP-ED may include a light-emitting element ED.

The light-emitting element ED may include a first electrode EL1, a hole transport region HTR provided on the first electrode EL1, an emission layer EML provided on the hole transport region HTR, an electron transport region ETR provided on the emission layer EML, and a second electrode EL2 provided on the electron transport region ETR. In some embodiments, the structures of the light-emitting elements ED of FIGS. 3 to 6 as described herein may be equally applied to the structure of the light-emitting element ED illustrated in FIG. 7.

Referring to FIG. 7, the emission layer EML may be provided in an opening OH defined in a pixel defining film PDL. For example, the emission layer EML which is divided by the pixel defining film PDL and provided corresponding to each light emitting regions PXA-R, PXA-G, and PXA-B may be to emit light in substantially the same wavelength range. In the display device DD-a of one or more embodiments, the emission layer EML may be to emit blue light. In some embodiments, unlike the configuration illustrated, in one or more embodiments, the emission layer EML may be provided as a common layer in the entire light emitting regions PXA-R, PXA-G, and PXA-B.

The light control layer CCL may be provided on the display panel DP. The light control layer CCL may include a light conversion body. The light conversion body may be a quantum dot, a phosphor, and/or the like. The light conversion body may be to emit provided light by converting the wavelength thereof. For example, the light control layer CCL may be a layer containing the quantum dot or a layer containing the phosphor.

The light control layer CCL may include a plurality of light control parts CCP1, CCP2 and CCP3. The light control parts CCP1, CCP2, and CCP3 may be spaced and/or apart from each other.

Referring to FIG. 7, divided patterns BMP may be provided between the light control parts CCP1, CCP2 and CCP3 which are spaced and/or apart from each other, but the embodiment of the present disclosure is not limited thereto. FIG. 7 illustrates that the divided patterns BMP do not overlap the light control parts CCP1, CCP2 and CCP3, but at least a portion of the edges of the light control parts CCP1, CCP2 and CCP3 may overlap the divided patterns BMP.

The light control layer CCL may include a first light control part CCP1 containing a first quantum dot QD1 which converts first color light provided from the light-emitting element ED into second color light, a second light control part CCP2 containing a second quantum dot QD2 which converts the first color light into third color light, and a third light control part CCP3 which transmits the first color light.

In one or more embodiments, the first light control part CCP1 may provide red light that is the second color light, and the second light control part CCP2 may provide green light that is the third color light. The third light control part CCP3 may provide blue light by transmitting the blue light that is the first color light provided from the light-emitting element ED. For example, the first quantum dot QD1 may be a red quantum dot, and the second quantum dot QD2 may be a green quantum dot. The same as described herein may be applied with respect to the quantum dots QD1 and QD2.

In some embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but include the scatterer SP.

The scatterer SP may be inorganic particles. For example, the scatterer SP may include at least one of TiO₂, ZnO, Al₂O₃, SiO₂, and hollow sphere silica. The scatterer SP may include any one selected from among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 each may include base resins BR1, BR2, and BR3 in which the quantum dots QD1 and QD2 and the scatterer SP are dispersed. In one or more embodiments, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of one or more suitable resin compositions, which may be generally referred to as a binder. For example, the base resins BR1, BR2, and BR3 may be acrylic-based resins, urethane-based resins, silicone-based resins, epoxy-based resins, and/or the like. The base resins BR1, BR2, and BR3 may be transparent resins. In one or more embodiments, the first base resin BR1, the second base resin BR2, and the third base resin BR3 may be the same as or different from each other.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may block or reduce the light control parts CCP1, CCP2 and CCP3 from being exposed to moisture/oxygen. In some embodiments, the barrier layer BFL1 may cover the light control parts CCP1, CCP2, and CCP3. In some embodiments, the barrier layer BFL2 may be provided between the light control parts CCP1, CCP2, and CCP3 and the filters CF1, CF2, and CF3.

The barrier layers BFL1 and BFL2 may include at least one inorganic layer. For example, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, and/or the like. In some embodiments, the barrier layers BFL1 and BFL2 may further include an organic film. The barrier layers BFL1 and BFL2 may be formed of a single layer or a plurality of layers.

In the display device DD-a of one or more embodiments, the color filter layer CFL may be provided on the light control layer CCL. For example, the color filter layer CFL may be directly provided on the light control layer CCL. In this case, the barrier layer BFL2 may not be provided.

The color filter layer CFL may include filters CF1, CF2, and CF3. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment or dye. The first filter CF1 may include a red pigment or dye, the second filter CF2 may include a green pigment or dye, and the third filter CF3 may include a blue pigment or dye.

In some embodiments, the embodiment of the present disclosure is not limited thereto, and the third filter CF3 may not include (e.g., may exclude) a pigment or dye. The third filter CF3 may include a polymeric photosensitive resin and may not include (e.g., may exclude) a pigment or dye. The third filter CF3 may be transparent. The third filter CF3 may be formed of a transparent photosensitive resin.

Furthermore, in one or more embodiments, the first filter CF1 and the second filter CF2 may be a yellow filter. The first filter CF1 and the second filter CF2 may not be separated but be provided as one filter.

In one or more embodiments, the color filter layer CFL may further include a light shielding part. The light shielding part may be a black matrix. The light shielding part may include an organic light shielding material or an inorganic light shielding material containing a black pigment or dye. The light shielding part may prevent or reduce light leakage, and may separate boundaries between the adjacent filters CF1, CF2, and CF3.

The first to third filters CF1, CF2, and CF3 may be provided corresponding to the red light emitting region PXA-R, the green light emitting region PXA-G, and the blue light emitting region PXA-B, respectively.

A base substrate BL may be provided on the color filter layer CFL. The base substrate BL may be a member which provides a base surface on which the color filter layer CFL, the light control layer CCL, and/or the like are provided. The base substrate BL may be a glass substrate, a metal substrate, a plastic substrate, and/or the like. However, the embodiment of the present disclosure is not limited thereto, and the base substrate BL may be an inorganic layer, an organic layer, or a composite material layer. In some embodiments, unlike the configuration illustrated, in one or more embodiments, the base substrate BL may not be provided.

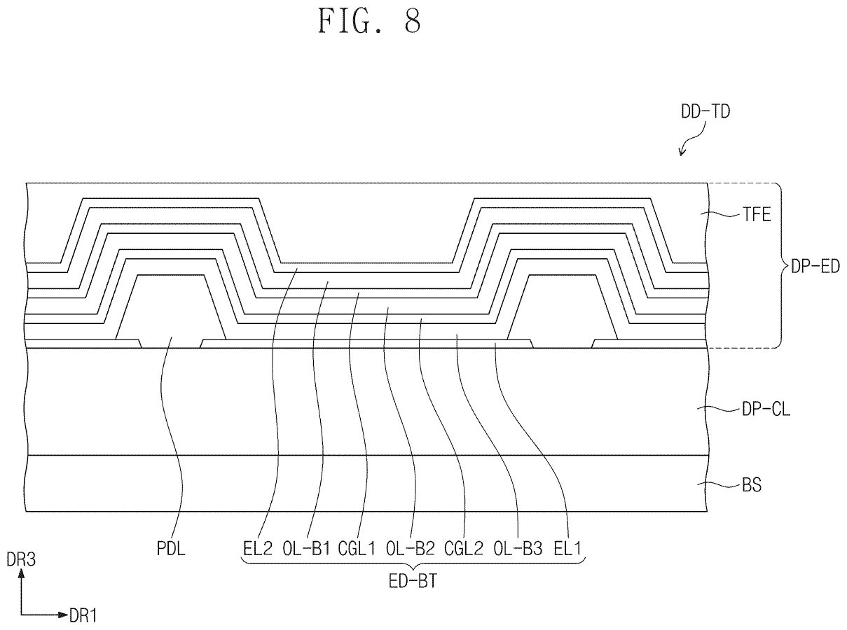

FIG. 8 is a cross-sectional view illustrating a portion of a display device DD-TD according to one or more embodiments. In the display device DD-TD of one or more embodiments, the light-emitting element ED-BT may include a plurality of light emitting structures OL-B1, OL-B2, and OL-B3. The light-emitting element ED-BT may include a first electrode EL1 and a second electrode EL2 which face each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 7) and a hole transport region HTR (FIG. 7) and an electron transport region ETR (FIG. 7) provided with the emission layer EML (FIG. 7) located therebetween.

For example, the light-emitting element ED-BT included in the display device DD-TD of one or more embodiments may be a light-emitting element having a tandem structure and including a plurality of emission layers.

In one or more embodiments illustrated in FIG. 8, all light beams respectively emitted from the light emitting structures OL-B1, OL-B2, and OL-B3 may be blue light. However, the embodiment of the present disclosure is not limited thereto, and the light beams respectively emitted from the light emitting structures OL-B1, OL-B2, and OL-B3 may have wavelength ranges different from each other. For example, the light-emitting element ED-BT including the plurality of light emitting structures OL-B1, OL-B2, and OL-B3 which emit light beams having wavelength ranges different from each other may be to emit white light.

Charge generation layers CGL1 and CGL2 may be respectively provided between two of the neighboring light emitting structures OL-B1, OL-B2, and OL-B3. The charge generation layers CGL1 and CGL2 may include a p-type or kind charge generation layer and/or an n-type or kind charge generation layer.

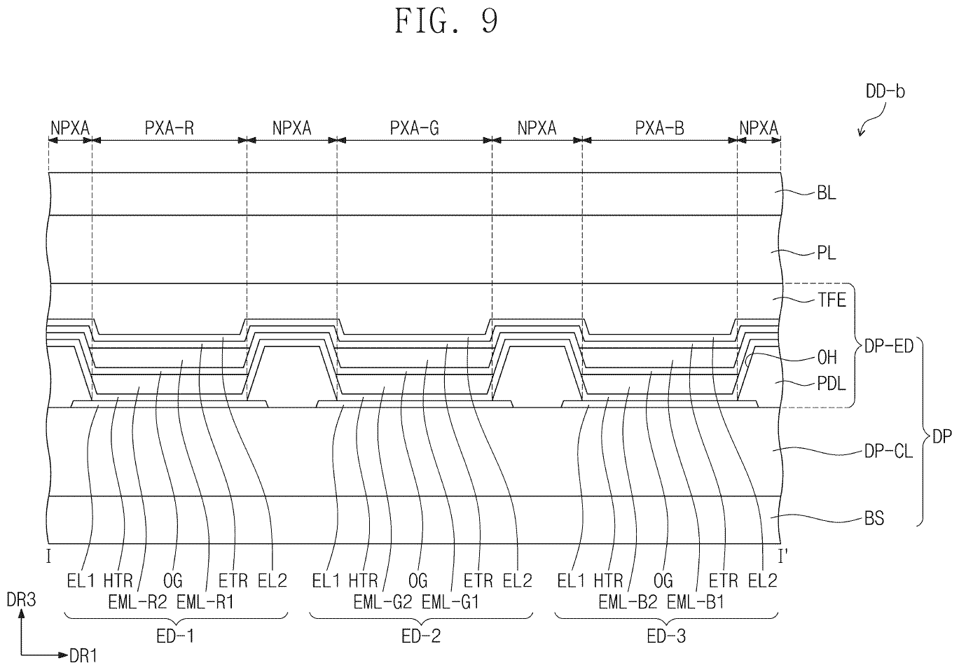

Referring to FIG. 9, the display device DD-b according to one or more embodiments may include light-emitting elements ED-1, ED-2, and ED-3 in which two emission layers are stacked. Compared with the display device DD of one or more embodiments illustrated in FIG. 2, one or more embodiments illustrated in FIG. 9 has a difference in that the first to third light-emitting elements ED-1, ED-2, and ED-3 each include two emission layers stacked in the thickness direction. In each of the first to third light-emitting elements ED-1, ED-2, and ED-3, the two emission layers may be to emit light in substantially the same wavelength region.

The first light-emitting element ED-1 may include a first red emission layer EML-R1 and a second red emission layer EML-R2. The second light-emitting element ED-2 may include a first green emission layer EML-G1 and a second green emission layer EML-G2. In some embodiments, the third light-emitting element ED-3 may include a first blue emission layer EML-B1 and a second blue emission layer EML-B2. An emission auxiliary part OG may be provided between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. More specifically, the emission auxiliary part OG may include an electron transport region, a charge generation layer, and a hole transport region that are sequentially stacked. The emission auxiliary part OG may be provided as a common layer in the whole of the first to third light-emitting elements ED-1, ED-2, and ED-3. However, the embodiment of the present disclosure is not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may be provided between the emission auxiliary part OG and the electron transport region ETR. The second red emission layer EML-R2, the second green emission layer EML-G2, and the second blue emission layer EML-B2 may be provided between the hole transport region HTR and the emission auxiliary part OG.

For example, the first light-emitting element ED-1 may include the first electrode EL1, the hole transport region HTR, the second red emission layer EML-R2, the emission auxiliary part OG, the first red emission layer EML-R1, the electron transport region ETR, and the second electrode EL2 that are sequentially stacked. The second light-emitting element ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light-emitting element ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

In some embodiments, an optical auxiliary layer PL may be provided on the display device layer DP-ED. The optical auxiliary layer PL may include a polarizing layer. The optical auxiliary layer PL may be provided on the display panel DP and control reflected light in the display panel DP due to external light. Unlike the configuration illustrated, the optical auxiliary layer PL in the display device according to one or more embodiments may not be provided.

Unlike FIGS. 8 and 9, FIG. 10 illustrates that a display device DD-c includes four light emitting structures OL-B1, OL-B2, OL-B3, and OL-C1. A light-emitting element ED-CT may include a first electrode EL1 and a second electrode EL2 which face each other, and first to fourth light emitting structures OL-B1, OL-B2, OL-B3, and OL-C1 that are sequentially stacked in the thickness direction between the first electrode EL1 and the second electrode EL2. The third light-emitting structure OL-B3, the second light-emitting structure OL-B2, the first light-emitting structure OL-B1 and the fourth light-emitting structure OL-C1 are stacked in the thickness direction in the stated order. Charge generation layers CGL1, CGL2, and CGL3 may be provided between the first to fourth light emitting structures OL-B1, OL-B2, OL-B3, and OL-C1. Among the four light emitting structures, the first to third light emitting structures OL-B, OL-B2, and OL-B3 may be to emit blue light, and the fourth light emitting structure OL-C1 may be to emit green light. However, the embodiment of the present disclosure is not limited thereto, and the first to fourth light emitting structures OL-B1, OL-B2, OL-B3, and OL-C1 may be to emit light beams in different wavelength regions.

The charge generation layers CGL1, CGL2, and CGL3 provided between adjacent light emitting structures OL-B1, OL-B2, OL-B3, and OL-C1 may include a p-type or kind charge generation layer (p-charge generation layer) and/or an n-type or kind charge generation layer (n-charge generation layer).

In one or more embodiments, the electronic apparatus may include a display device including a plurality of light-emitting elements and a control part which controls the display device The electronic apparatus of one or more embodiments may be a device that is activated according to an electrical signal. The electronic apparatus may include display apparatuses of one or more suitable embodiments. For example, the electronic apparatus may include not only large-sized electronic apparatuses such as a television set, a monitor, or an outdoor billboard but also include small- and medium-sized electronic apparatuses such as a personal computer, a laptop computer, a personal digital terminal, a display device for a vehicle, a game console, a portable electronic device, or a camera.

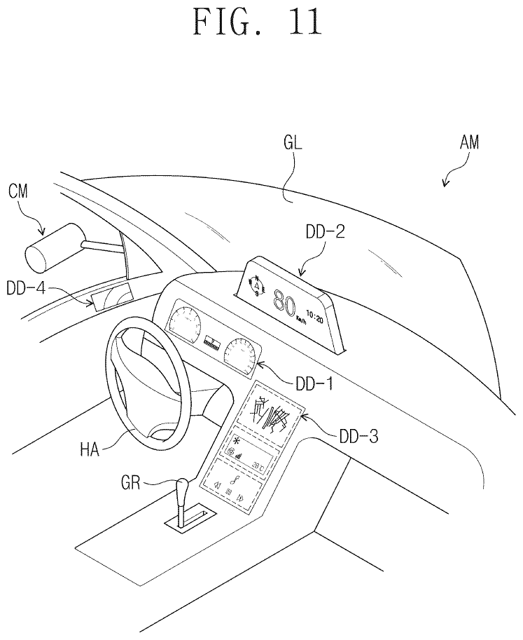

FIG. 11 is a view illustrating a vehicle AM in which first to fourth display apparatuses DD-1, DD-2, DD-3, and DD-4 are provided. At least one selected from among the first to fourth display apparatuses DD-1, DD-2, DD-3, and DD-4 may include the same configuration as the display apparatuses DD, DD-a, DD-TD, DD-b, and DD-c as described with reference to FIGS. 1, and 2, and 7 to 10.

FIG. 11 illustrates a vehicle AM, but this is an example, and the first to fourth display apparatuses DD-1, DD-2, DD-3, and DD-4 may be provided in another transportation such as bicycles, motorcycles, trains, ships, and airplanes. In some embodiments, at least one selected from among the first to fourth display apparatuses DD-1, DD-2, DD-3, and DD-4 including the same configuration as the display apparatuses DD, DD-TD, DD-a, DD-b, and DD-c of one or more embodiments may be employed in a personal computer, a laptop computer, a personal digital terminal, a game console, a portable electronic device, a television, a monitor, an outdoor billboard, and/or the like. In some embodiments, these are merely provided as embodiments, and thus may be employed in other electronic apparatuses unless departing from the present disclosure.

At least one selected from among the first to fourth display apparatuses DD-1, DD-2, DD-3, and DD-4 may include the light-emitting element ED of one or more embodiments as described with reference to FIGS. 3 to 6.

Referring to FIG. 11, the vehicle AM may include a steering wheel HA and a gear GR for driving the vehicle AM. In some embodiments, the vehicle AM may include a front window GL provided so as to face the driver.

The first display device DD-1 may be provided in a first region overlapping the steering wheel HA. For example, the first display device DD-1 may be a digital cluster which displays first information of the vehicle AM. The first information may include a first scale which indicates a driving speed of the vehicle AM, a second scale which indicates an engine speed (that is, revolutions per minute (RPM)), an image which indicates a fuel state, and/or the like. A first scale and a second scale may be indicated as a digital image.

The second display device DD-2 may be provided in a second region facing the driver's seat and overlapping the front window GL. The driver's seat may be a seat in which the steering wheel HA is provided. For example, the second display device DD-2 may be a head up display (HUD) which displays second information of the vehicle AM. The second display device DD-2 may be optically transparent. The second information may include digital numbers which indicate a driving speed, and may further include information such as the current time. Unlike the configuration illustrated, the second information of the second display device DD-2 may be projected to the front window GL to be displayed.

The third display device DD-3 may be provided in a third region adjacent to the gear GR. For example, the third display device DD-3 may be provided between the driver's seat and the passenger seat and may be a center information display (CID) for a vehicle for displaying third information. The passenger seat may be a seat spaced and/or apart from the driver's seat with the gear GR provided therebetween. The third information may include information about traffic (e.g., navigation information), playing music or radio or a video (or an image), temperatures inside the vehicle AM, and/or the like.

The fourth display device DD-4 may be spaced and/or apart from the steering wheel HA and the gear GR, and may be provided in a fourth region adjacent to the side of the vehicle AM. For example, the fourth display device DD-4 may be a digital side-view mirror which displays fourth information. The fourth display device DD-4 may display an image outside the vehicle AM taken by a camera module CM provided outside the vehicle AM. The fourth information may include an image outside the vehicle AM.

The herein-described first to fourth information may be examples, and the first to fourth display apparatuses DD-1, DD-2, DD-3, and DD-4 may further display information about the inside and outside of the vehicle AM. The first to fourth information may include different information. However, the embodiment of the present disclosure is not limited thereto, and a part of the first to fourth information may include the same information as one another.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or +30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The light emitting device, light emitting element, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the light emitting device and/or light emitting element may be formed on one integrated circuit (IC) chip or on separate IC chips. Further, the various components of the light emitting device and/or light emitting element may be implemented on a flexible printed circuit film, a tape carrier package (TCP), a printed circuit board (PCB), or formed on one substrate. Further, the various components of the light emitting device and/or light emitting element may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, when particles are spherical, “diameter” indicates an average particle diameter, and when the particles are non-spherical, the “diameter” indicates a major axis length. The diameter (or size) of the particles may be measured by particle size analysis, dynamic light scattering, scanning electron microscopy, and/or transmission electron microscope photography. When the size of the particles is measured utilizing a particle size analyzer, the average particle diameter (or size) may be referred to as D50. The term “D50” as utilized herein refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size. Particle size analysis may be performed with a HORIBA LA-950 laser particle size analyzer.

Hereinafter, with reference to Examples and Comparative Examples, a fused polycyclic compound according to one or more embodiments of the present disclosure and a light-emitting element according to one or more embodiments will be described in more detail. In some embodiments, Examples described are shown only for understanding the present disclosure, and the scope of the present disclosure is not limited thereto.

### Examples

### 1. Synthesis of Fused Polycyclic Compound

First, synthetic methods of fused polycyclic compounds according to this embodiment of the present disclosure will be described in more detail by exemplifying synthetic methods of Compounds 1, 7, 11, 31, 45, 46, 49, and 73. In some embodiments, the synthetic methods of the fused polycyclic compounds, which will be described hereinafter, are provided as examples, and thus the synthetic methods of the fused polycyclic compounds according to embodiments of the present disclosure are not limited to Examples.

### (1) Synthesis of Compound 1

### Synthesis of Intermediate Compound 1-a

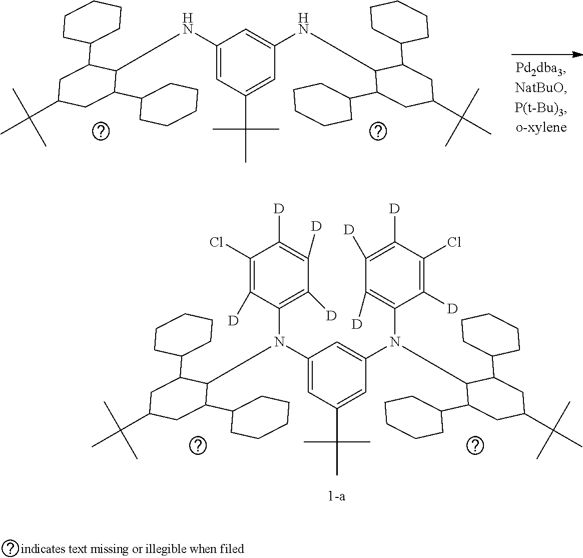

In an argon atmosphere, 5-(tert-butyl)-N1, N3-bis(5′-(tert-butyl)-[1,1′:3′,1″-terphenyl]-2′-yl)benzene-1,3-diamine (10 g, 13.5 mmol), 1-chloro-3-iodobenzene-2,4,5,6-d4 (6.6 g, 27 mmol), Pd₂dba₃ (1.6 g, 1.9 mmol), tris-tert-butyl phosphine (P (t-Bu) 3, 1.6 mL, 3.8 mmol), and sodium tert-butoxide (NatBuO, 11.5 g, 120 mmol) were put into a 2 L flask and dissolved in 300 mL of o-xylene, and then the reaction solution was stirred at about 140° C. for about 2 hours. After cooling, an organic layer was collected by adding water (1 L) and ethyl acetate (300 mL) and extracting. Then, the obtained organic layer was dried over anhydrous MgSO₄ and then filtered. A solvent was removed from the filtered solution under reduced pressure, and the obtained solid was purified and separated by column chromatography utilizing silica gel with CH₂Cl₂ and hexane as a developing solvent to obtain Intermediate Compound 1-a (white solid, 10 g, 77%).

ESI-LCMS for Intermediate Compound 1-a: [M]⁺: C₆₆H₅₆D₈Cl₂N₂. 958.4711

### Synthesis of Intermediate Compound 1-b

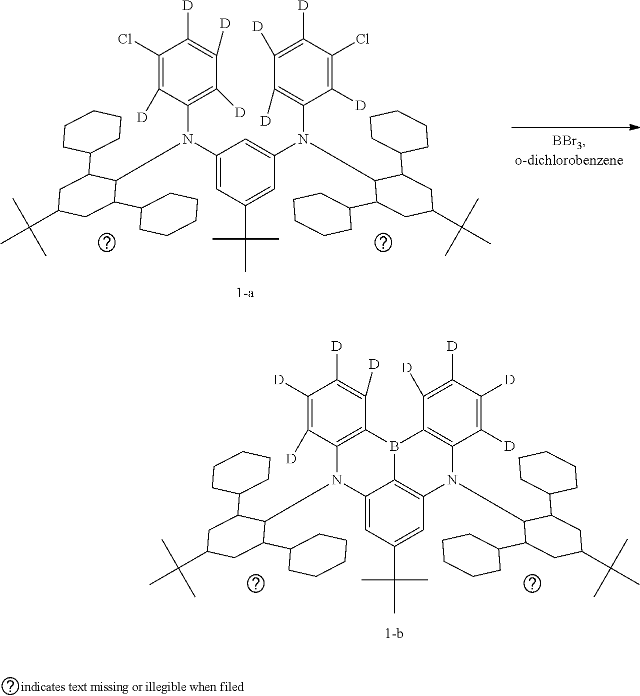

In an argon atmosphere, Intermediate Compound 1-a (10 g, 10 mmol) was put into a 1 L flask and dissolved in 100 mL of o-dichlorobenzene, and then BBr₃ (1.5 equiv.) was added. The reaction solution was stirred at about 140° C. for about 12 hours. After cooling, triethylamine was put to quench the reaction, and a solvent was removed under reducing pressure. The obtained solid was purified and separated by column chromatography utilizing silica gel with CH₂Cl₂ and hexane as a developing solvent to obtain Intermediate Compound 1-b (yellow solid, 2.4 g, 24%).

ESI-LCMS for Intermediate Compound 1-b: [M]⁺: C₆₆H₅₃D₆BCl₂N₂. 966.4532

### Synthesis of Compound 1

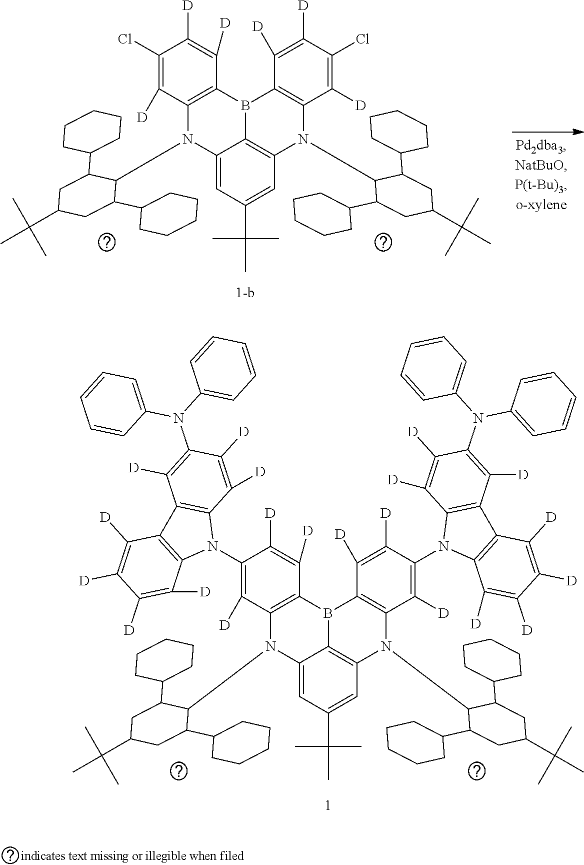

In an argon atmosphere, Intermediate Compound 1-b (2.4 g, 2.5 mmol), N,N-diphenyl-9H-carbazol-3-amine-1,2,4,5,6,7,8-d7 (1.7 g, 5 mmol), Pdzdba₃ (0.06 g, 0.12 mmol), tris-tert-butyl phosphine (0.06 mL, 0.24 mmol), and sodium tert-butoxide (0.5 g, 5.1 mmol) were put into a 1 L flask and dissolved in 100 mL of o-xylene, and then the reaction solution was stirred at about 100° C. for about 12 hours. After cooling, an organic layer was collected by adding water (1 L) and ethyl acetate (300 mL) and extracting. Then, the obtained organic layer was dried over anhydrous MgSO₄ and then filtered. A solvent was removed from the filtered solution under reduced pressure, and the obtained solid was purified and separated by column chromatography utilizing silica gel with CH₂Cl₂ and hexane as a developing solvent to obtain Compound 1 (yellow solid, 3 g, 77%).

ESI-LCMS for Compound 1: [M]⁺: C₁₁₄H₇₃D₂₀BN₆. 1576.8812

¹H-NMR for Compound 1 (CDCl₃): d=7.43 (s, 4H), 7.18 (m, 12H), 7.01 (m, 8H), 6.92 (m, 8H), 6.81 (m, 12H), 6.79 (s, 2H), 1.32 (s, 18H), 1.12 (s, 9H)

### (2) Synthesis of Compound 7

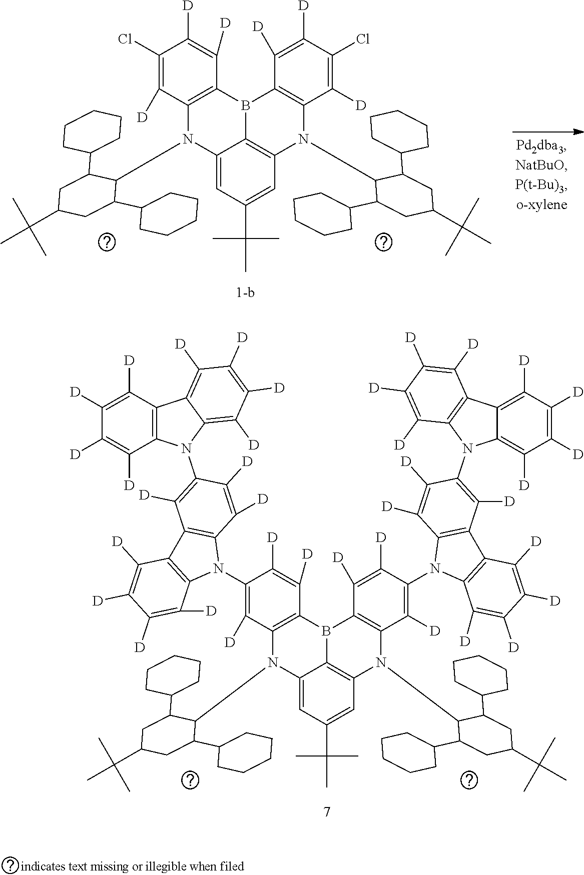

In an argon atmosphere, Intermediate Compound 1-b (2.4 g, 2.5 mmol), 9H-3,9′-bicarbazole-1,1′,2,2′,3′,4,4′,5,5′,6,6′,7,7′,8,8′-d15 (1.73 g, 5 mmol), Pd₂dba₃ (0.06 g, 0.12 mmol), tris-tert-butyl phosphine (0.06 mL, 0.24 mmol), and sodium tert-butoxide (0.5 g, 5.1 mmol) were put into a 1 L flask and dissolved in 100 mL of o-xylene, and then the reaction solution was stirred at about 100° C. for about 12 hours. After cooling, an organic layer was collected by adding water (1 L) and ethyl acetate (300 mL) and extracting. Then, the obtained organic layer was dried over anhydrous MgSO₄ and then filtered. A solvent was removed from the filtered solution under reduced pressure, and the obtained solid was purified and separated by column chromatography utilizing silica gel with CH₂Cl₂ and hexane as a developing solvent to obtain Compound 7 (yellow solid, 2.93 g, 74%).

ESI-LCMS for Compound 7: [M]⁺: C₁₁₄H₅₃D₃₆BN₆. 1588.9520

¹H-NMR for Compound 7 (CDCl₃): d=7.42 (s, 4H), 7.13 (m, 12H), 7.05 (m, 8H), 6.92 (s, 2H), 1.35 (s, 18H), 1.13 (s, 9H)

### (3) Synthesis of Compound 11

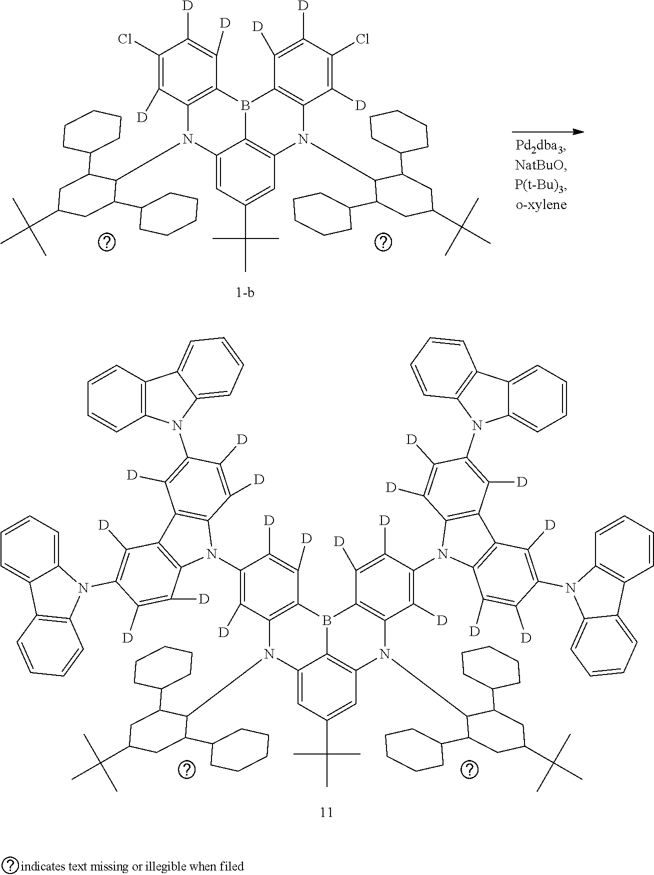

In an argon atmosphere, Intermediate Compound 1-b (2.4 g, 2.5 mmol), 9′H-9,3′: 6′,9″-tercarbazole-1′,2′,4′,5′,7′,8′-d6 (2.5 g, 5 mmol), Pdzdba₃ (0.06 g, 0.12 mmol), tris-tert-butyl phosphine (0.06 mL, 0.24 mmol), and sodium tert-butoxide (0.5 g, 5.1 mmol) were put into a 1 L flask and dissolved in 100 mL of o-xylene, and then the reaction solution was stirred at about 100° C. for about 12 hours. After cooling, an organic layer was collected by adding water (1 L) and ethyl acetate (300 mL) and extracting. Then, the obtained organic layer was dried over anhydrous MgSO₄ and then filtered. A solvent was removed from the filtered solution under reduced pressure, and the obtained solid was purified and separated by column chromatography utilizing silica gel with CH₂Cl₂ and hexane as a developing solvent to obtain Compound 11 (yellow solid, 2.93 g, 74%).

ESI-LCMS for Compound 11: [M]⁺: C₁₃₈H₈₅D₁₈BN₈. 1900.9500

¹H-NMR for Compound 11 (CDCl₃): d=8.55 (d, 8H), 7.94 (d, 8H), 7.68 (d, 8H), 7.55 (d, 8H), 7.45 (s, 4H), 7.21 (m, 12H), 7.11 (m, 8H), 6.88 (s, 2H), 1.38 (s, 18H), 1.11 (s, 9H)

### (4) Synthesis of Compound 31

### Synthesis of Intermediate Compound 31-a

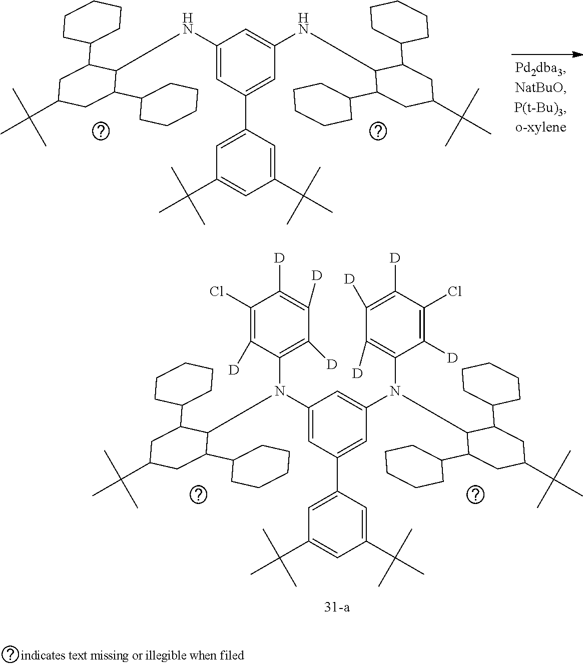

In an argon atmosphere, 3′,5′-d₁-tert-butyl-N³, N⁵-bis(5′-(tert-butyl)-[1,1′: 3′,1″-terphenyl]-2′-yl)-[1,1′-biphenyl]-3,5-diamine (10 g, 11.5 mmol), 1-chloro-3-iodobenzene-2,4,5,6-d4 (6.6 g, 27 mmol), Pdzdba₃ (1.6 g, 1.9 mmol), tris-tert-butyl phosphine (1.6 mL, 3.8 mmol), and sodium tert-butoxide (11.5 g, 120 mmol) were put into a 2 L flask and dissolved in 300 mL of o-xylene, and then the reaction solution was stirred at about 140° C. for about 2 hours. After cooling, an organic layer was collected by adding water (1 L) and ethyl acetate (300 mL) and extracting. Then, the obtained organic layer was dried over anhydrous MgSO₄ and then filtered. A solvent was removed from the filtered solution under reduced pressure, and the obtained solid was purified and separated by column chromatography utilizing silica gel with CH₂Cl₂ and hexane as a developing solvent to obtain Intermediate Compound 31-a (white solid, 8.2 g, 65%).

ESI-LCMS for Intermediate Compound 31-a: [M]⁺: C₇₆H₆₈D₈Cl₂N₂. 1090.1256

### Synthesis of Intermediate Compound 31-b

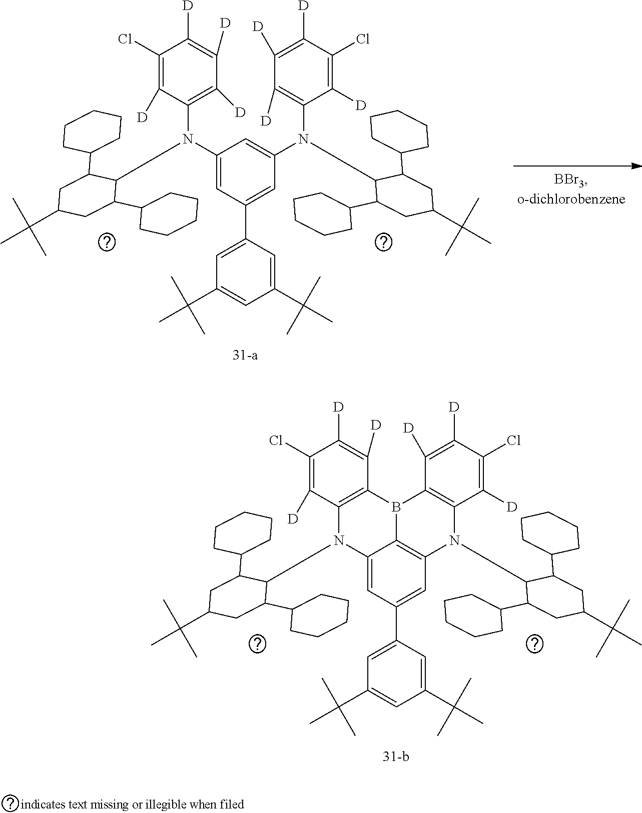

In an argon atmosphere, Intermediate Compound 31-a (8 g, 7.3 mmol) was put into a 1 L flask and dissolved in 100 mL of o-dichlorobenzene, and then BBr₃ (1.5 equiv.) was added. The reaction solution was stirred at about 140° C. for about 12 hours. After cooling, triethylamine was put to quench the reaction, a solvent was removed under reduced pressure, and the obtained solid was purified and separated by column chromatography utilizing silica gel with CH₂Cl₂ and hexane as a developing solvent to obtain Intermediate Compound 31-b (yellow solid, 3.5 g, 43%).

ESI-LCMS for Intermediate Compound 31-b: [M]⁺: C₇₆H₆₅D₆BCl₂N₂. 1098.5545

### Synthesis of Compound 31

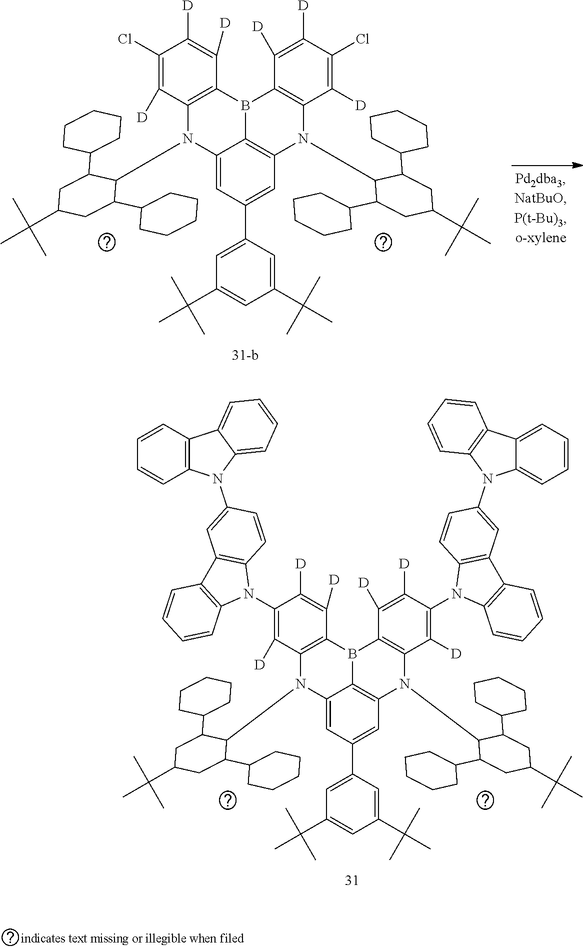

In an argon atmosphere, Intermediate Compound 31-b (3.5 g, 3.1 mmol), 9H-3,9′-bicarbazole (2.1 g, 6.2 mmol), Pd₂dba₃ (0.06 g, 0.12 mmol), tris-tert-butyl phosphine (0.06 mL, 0.24 mmol), and sodium tert-butoxide (0.5 g, 5.1 mmol) were put into a 1 L flask and dissolved in 100 mL of o-xylene, and then the reaction solution was stirred at about 100° C. for about 12 hours. After cooling, an organic layer was collected by adding water (1 L) and ethyl acetate (300 mL) and extracting. Then, the obtained organic layer was dried over anhydrous MgSO₄ and then filtered. A solvent was removed from the filtered solution under reduced pressure, and the obtained solid was purified and separated by column chromatography utilizing silica gel with CH₂Cl₂ and hexane as a developing solvent to obtain Compound 31 (yellow solid, 4 g, 75%).

ESI-LCMS for Compound 31: [M]⁺: C₁₂₄H₉₅D₆BN₆. 1690.0096

1H-NMR for Compound 31 (CDCl₃): d=8.55 (d, 4H), 8.19 (d, 4H), 7.94 (d, 4H), 7.72 (d, 4H), 7.61 (s, 2H), 7.58 (d, 4H), 7.51 (t, 4H), 7.43 (s, 4H), 7.33 (m, 4H), 7.22 (t, 4H), 7.18 (m, 12H), 6.93 (s, 2H), 1.35 (s, 18H), 1.25 (s, 18H)

### (5) Synthesis of Compound 45

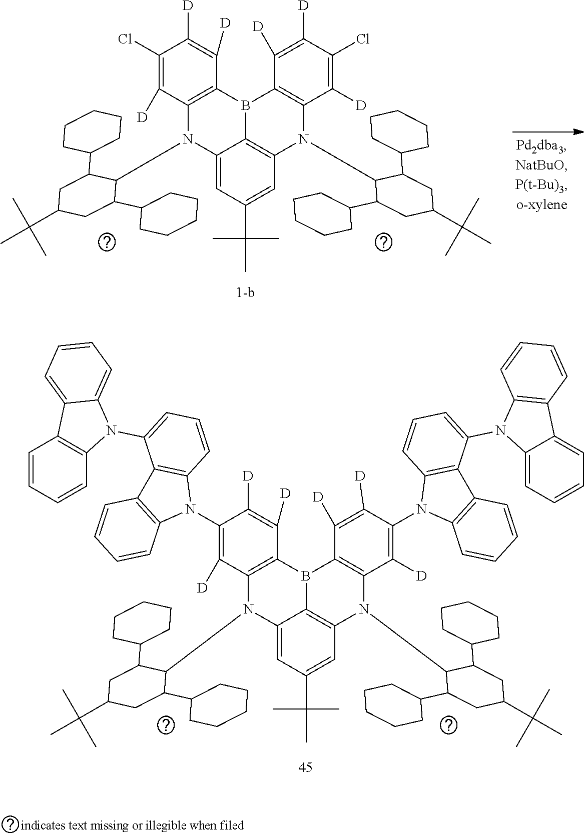 [SMILES: [2H]c1c([2H])c2c(c([2H])c1Cl)N(C1C(C3CCCCC3)CC(C(C)(C)C)CC1C1CCCCC1)c1cc(C(C)(C)C)cc3c1B2c1c([2H])c([2H])c(Cl)c([2H])c1N3C1C(C2CCCCC2)CC(C(C)(C)C)CC1C1CCCCC1 ; [2H]c1c([2H])c(-n2c3ccccc3c3c(-n4c5ccccc5c5ccccc54)cccc32)c([2H])c2c1B1c3c(cc(C(C)(C)C)cc3N(C3C(C4CCCCC4)CC(C(C)(C)C)CC3C3CCCCC3)c3c([2H])c(-n4c5ccccc5c5c(-n6c7ccccc7c7ccccc76)cccc54)c([2H])c([2H])c31)N2C1C(C2CCCCC2)CC(C(C)(C)C)CC1C1CCCCC1]

In an argon atmosphere, Intermediate Compound 1-b (2.4 g, 2.5 mmol), 9H-4,9′-bicarbazole (1.66 g, 5 mmol), Pd₂dba₃ (0.06 g, 0.12 mmol), tris-tert-butyl phosphine (0.06 mL, 0.24 mmol), and sodium tert-butoxide (0.5 g, 5.1 mmol) were put into a 1 L flask and dissolved in 100 mL of o-xylene, and then the reaction solution was stirred at about 100° C. for about 12 hours. After cooling, an organic layer was collected by adding water (1 L) and ethyl acetate (300 mL) and extracting. Then, the obtained organic layer was dried over anhydrous MgSO₄ and then filtered. A solvent was removed from the filtered solution under reduced pressure, and the obtained solid was purified and separated by column chromatography utilizing silica gel with CH₂Cl₂ and hexane as a developing solvent to obtain Compound 45 (yellow solid, 2.7 g, 71%).

ESI-LCMS for Compound 45: [M]⁺: C₁₁₄H₈₃D₆BN₆. 1558.1276

1H-NMR for Compound 45 (CDCl₃): d=8.53 (d, 8H), 8.19 (d, 4H), 7.90 (d, 8H), 7.64 (d, 8H), 7.55 (d, 4H), 7.51 (d, 2H), 7.45 (s, 2H), 7.30 (s, 2H), 7.21 (m, 12H), 7.11 (m, 8H), 6.92 (s, 2H), 1.42 (s, 18H), 1.13 (s, 9H)

### (6) Synthesis of Compound 46

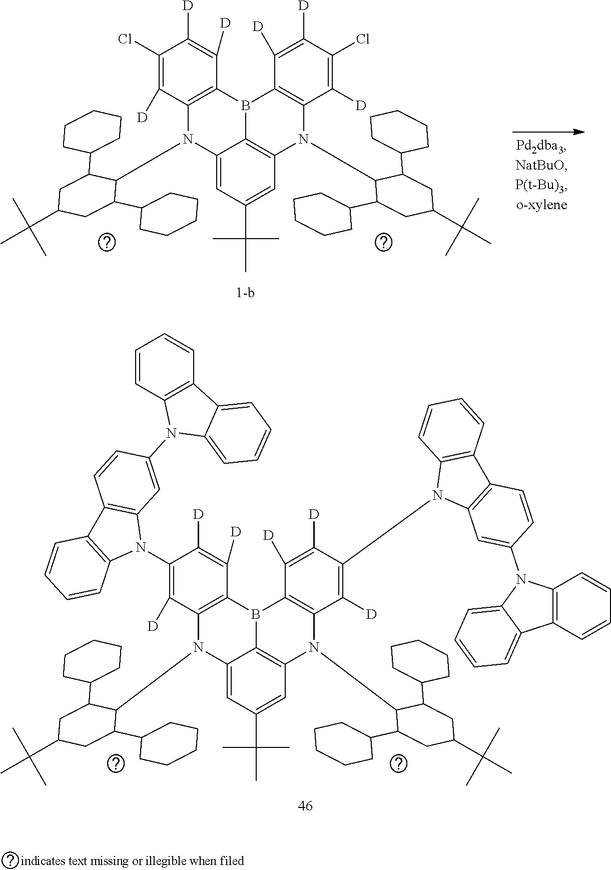

In an argon atmosphere, Intermediate Compound 1-b (2.4 g, 2.5 mmol), 9H-2,9′-bicarbazole (1.66 g, 5 mmol), Pd₂dba₃ (0.06 g, 0.12 mmol), tris-tert-butyl phosphine (0.06 mL, 0.24 mmol), and sodium tert-butoxide (0.5 g, 5.1 mmol) were put into a 1 L flask and dissolved in 100 mL of o-xylene, and then the reaction solution was stirred at about 100° C. for about 12 hours. After cooling, an organic layer was collected by adding water (1 L) and ethyl acetate (300 mL) and extracting. Then, the obtained organic layer was dried over anhydrous MgSO₄ and then filtered. A solvent was removed from the filtered solution under reduced pressure, and the obtained solid was purified and separated by column chromatography utilizing silica gel with CH₂Cl₂ and hexane as a developing solvent to obtain Compound 46 (yellow solid, 2.6 g, 68%).

ESI-LCMS for Compound 46: [M]⁺: C₁₁₄H₈₃D₆BN₆. 1558.1216

1H-NMR for Compound 46 (CDCl₃): d=8.51 (d, 2H), 8.26 (d, 2H), 8.19 (d, 2H), 7.94 (d, 4H), 7.58 (d, 2H), 7.51 (d, 4H), 7.48 (d, 2H), 7.41 (s, 4H), 7.35 (d, 4H), 7.21 (m, 12H), 7.14 (m, 8H), 6.90 (s, 2H), 1.36 (s, 18H), 1.21 (s, 9H)

### (7) Synthesis of Compound 49

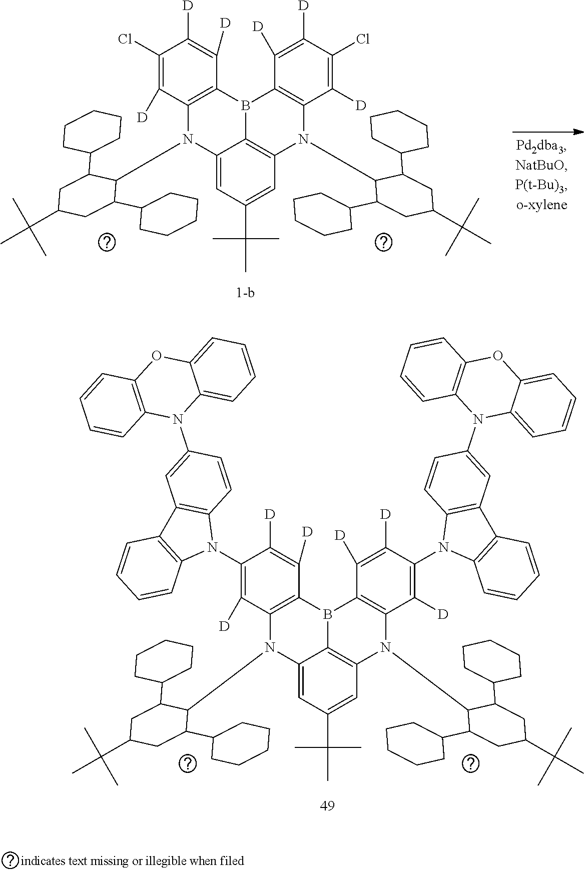

In an argon atmosphere, Intermediate Compound 1-b (2.4 g, 2.5 mmol), 10-(9H-carbazol-3-yl)-10H-phenoxazine (1.74 g, 5 mmol), Pd₂dba₃ (0.06 g, 0.12 mmol), tris-tert-butyl phosphine (0.06 mL, 0.24 mmol), and sodium tert-butoxide (0.5 g, 5.1 mmol) were put into a 1 L flask and dissolved in 100 mL of o-xylene, and then the reaction solution was stirred at about 100° C. for about 12 hours. After cooling, an organic layer was collected by adding water (1 L) and ethyl acetate (300 mL) and extracting. Then, the obtained organic layer was dried over anhydrous MgSO₄ and then filtered. A solvent was removed from the filtered solution under reduced pressure, and the obtained solid was purified and separated by column chromatography utilizing silica gel with CH₂Cl₂ and hexane as a developing solvent to obtain Compound 49 (yellow solid, 3.1 g, 78%).

ESI-LCMS for Compound 49: [M]⁺: C₁₁₄H₈₃D₆BN₆O₂. 1590.5175

1H-NMR for Compound 49 (CDCl₃): d=8.55 (d, 2H), 7.94 (d, 2H), 7.54 (d, 2H), 7.45 (s, 4H), 7.35 (m, 6H), 7.20 (t, 2H), 7.11 (m, 4H), 7.05 (m, 8H), 6.96 (d, 4H), 7.14 (m, 8H), 6.90 (s, 2H), 1.36 (s, 18H), 1.21 (s, 9H)

### (8) Synthesis of Compound 73

### Synthesis of Intermediate Compound 73-a

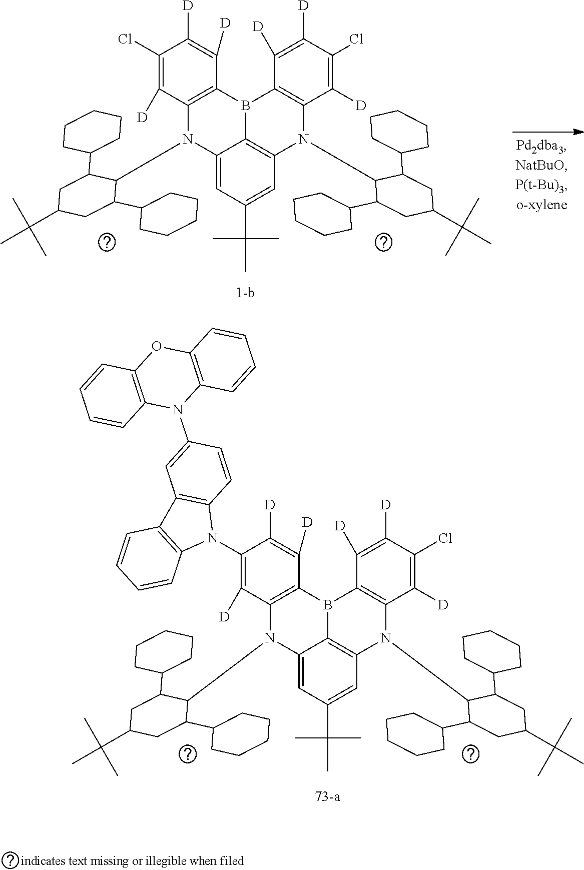

In an argon atmosphere, Intermediate Compound 1-b (2.4 g, 2.5 mmol), 10-(9H-carbazol-3-yl)-10H-phenoxazine (0.87 g, 2.5 mmol), Pd₂dba₃ (0.06 g, 0.12 mmol), tris-tert-butyl phosphine (0.06 mL, 0.24 mmol), and sodium tert-butoxide (0.5 g, 5.1 mmol) were put into a 1 L flask and dissolved in 100 mL of o-xylene, and then the reaction solution was stirred at about 100° C. for about 12 hours. After cooling, an organic layer was collected by adding water (1 L) and ethyl acetate (300 mL) and extracting. Then, the obtained organic layer was dried over anhydrous MgSO₄ and then filtered. A solvent was removed from the filtered solution under reduced pressure, and the obtained solid was purified and separated by column chromatography utilizing silica gel with CH₂Cl₂ and hexane as a developing solvent to obtain Intermediate Compound 73-a (yellow solid, 1.8 g, 56%).

ESI-LCMS for Intermediate Compound 73-a: [M]⁺: C₉₀H₆₈D₆BClN₄O. 1278.6011

### Synthesis of Compound 73

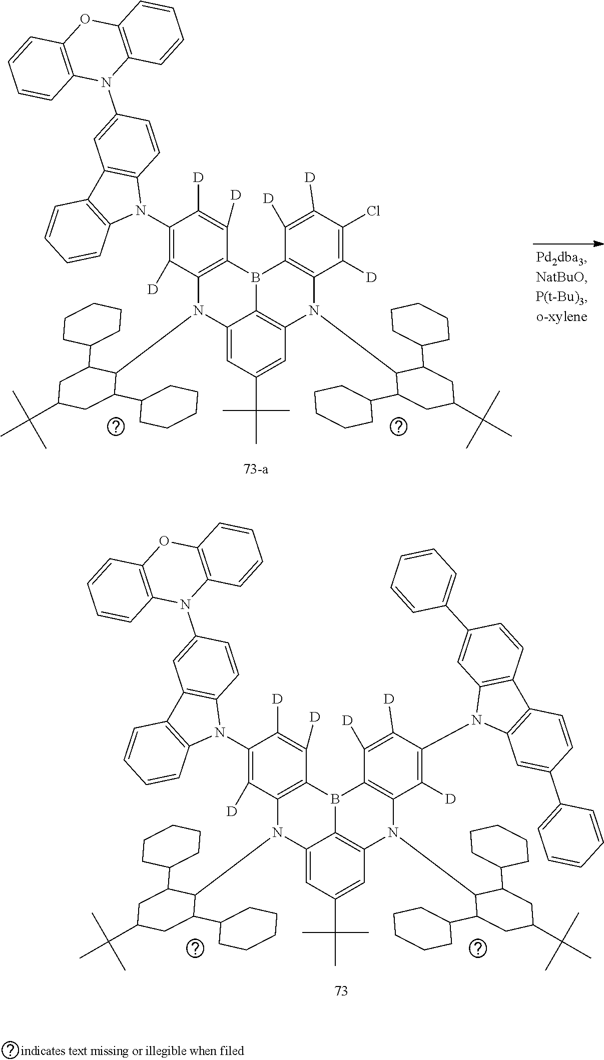

In an argon atmosphere, Intermediate Compound 73-a (1.8 g, 1.4 mmol), 2,7-diphenyl-9H-carbazole (0.45 g, 1.4 mmol), Pd₂dba₃ (0.06 g, 0.12 mmol), tris-tert-butyl phosphine (0.06 mL, 0.24 mmol), and sodium tert-butoxide (0.5 g, 5.1 mmol) were put into a 1 L flask and dissolved in 100 mL of o-xylene, and then the reaction solution was stirred at about 100° C. for about 12 hours. After cooling, an organic layer was collected by adding water (1 L) and ethyl acetate (300 mL) and extracting. Then, the obtained organic layer was dried over anhydrous MgSO₄ and then filtered. A solvent was removed from the filtered solution under reduced pressure, and the obtained solid was purified and separated by column chromatography utilizing silica gel with CH₂Cl₂ and hexane as a developing solvent to obtain Compound 73 (yellow solid, 1.6 g, 76%).

ESI-LCMS for Compound 73: [M]⁺: C₁₁₄H₈₄D₆BN₅O. 1278.6011

1H-NMR for Compound 73 (CDCl₃): d=8.62 (d, 2H), 8.55 (d, 1H), 8.31 (d, 2H), 8.22 (d, 2H), 7.94 (d, 2H), 7.74 (d, 2H), 7.60 (m, 4H), 7.49 (m, 6H), 7.45 (s, 4H), 7.35 (m, 12H), 7.31 (s, 1H), 7.21 (m, 3H), 7.11 (t, 1H), 7.05 (m, 8H), 6.96 (s, 2H), 6.78 (m, 8H), 1.44 (s, 18H), 1.29 (s, 9H)

### 1. Manufacture and Evaluation of Light-Emitting Element

Light emitting elements according to one or more embodiments including a fused polycyclic compound according to one or more embodiments in an emission layer were manufactured utilizing a method as described herein. Light emitting elements according to Examples 1 to 8 were manufactured utilizing fused polycyclic compounds of Compounds 1, 7, 11, 31, 45, 46, 49, and 73, which are Example Compounds described herein, each as a dopant material of an emission layer. Comparative Examples 1 and 2 each correspond to light-emitting elements manufactured utilizing Comparative Example Compound A and B each as a dopant material of an emission layer.

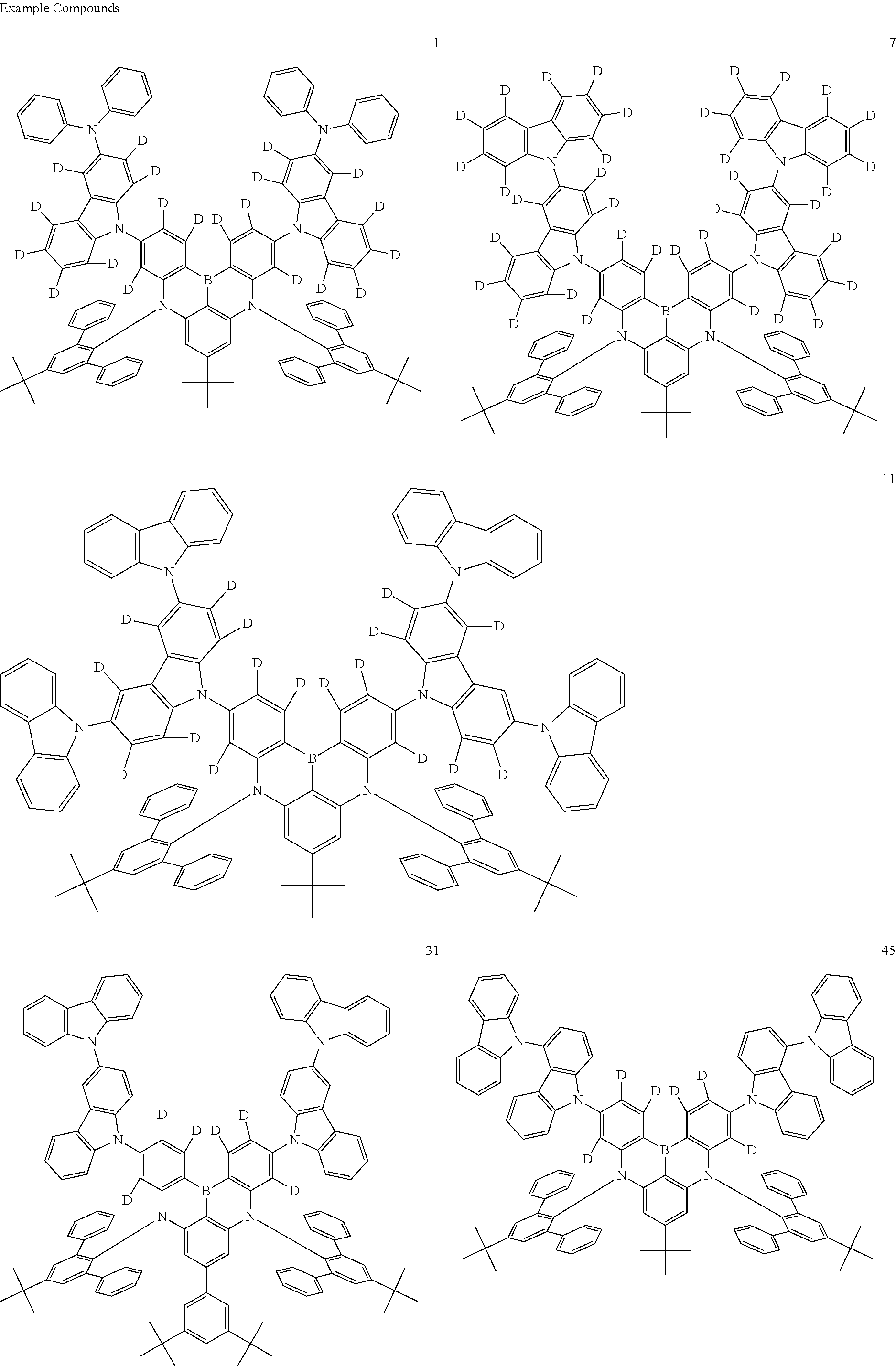

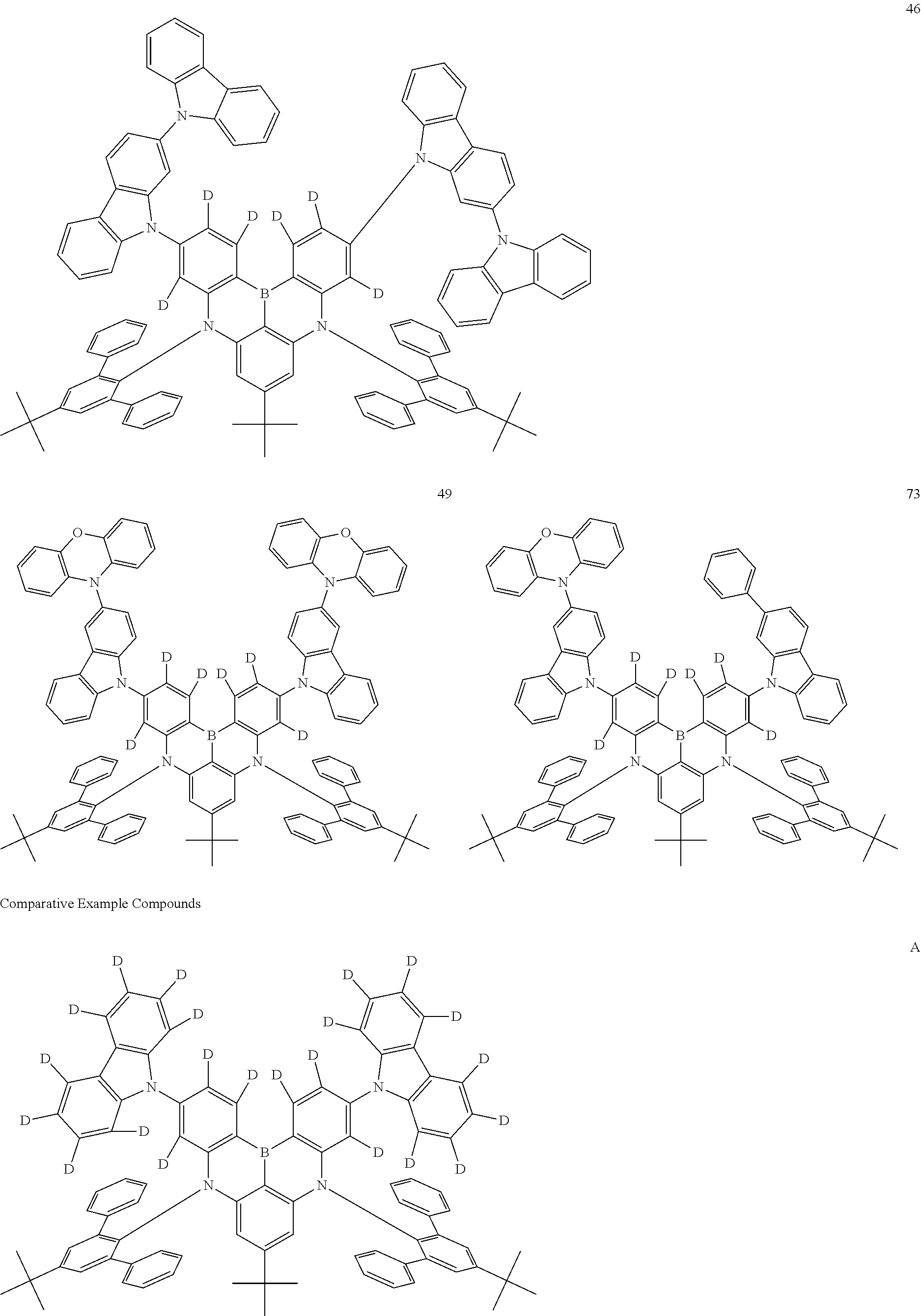

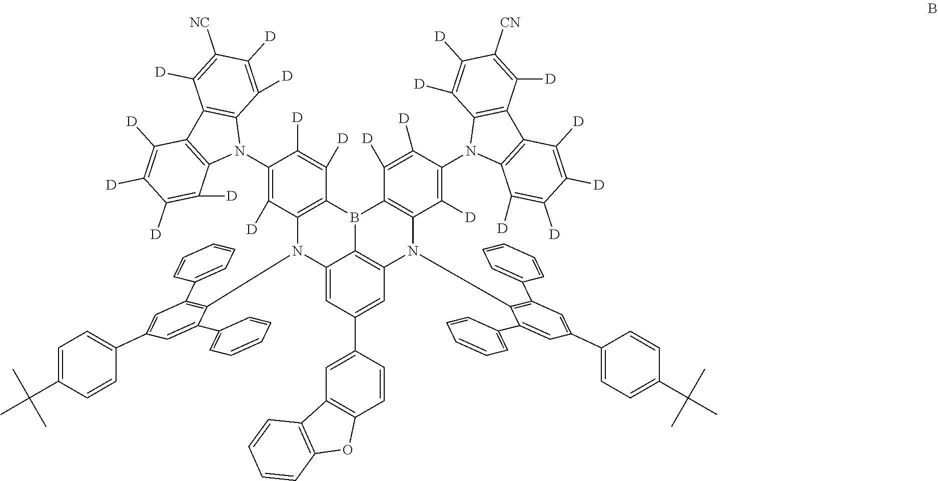 [SMILES: [2H]c1c([2H])c(-n2c3c([2H])c([2H])c([2H])c([2H])c3c3c([2H])c(C#N)c([2H])c([2H])c32)c([2H])c2c1B1c3c(cc(-c4ccc5oc6ccccc6c5c4)cc3N(c3c(-c4ccccc4)cc(-c4ccc(C(C)(C)C)cc4)cc3-c3ccccc3)c3c([2H])c(-n4c5c([2H])c([2H])c([2H])c([2H])c5c5c([2H])c(C#N)c([2H])c([2H])c54)c([2H])c([2H])c31)N2c1c(-c2ccccc2)cc(-c2ccc(C(C)(C)C)cc2)cc1-c1ccccc1]

### Manufacture of Light-Emitting Element

A glass substrate (product of Corning), on which an ITO electrode of about 15 ohm per square centimeter (Ω/cm²) (1,200 angstrom (Å)) was formed as a first electrode, was cut to a size of about 50 millimeter (mm)×50 mm×0.7 mm, subjected to ultrasonic cleaning utilizing isopropyl alcohol and pure water for 5 minutes each, and ultraviolet irradiation for 30 minutes and then exposed to ozone for cleaning. Then, the glass substrate was mounted on a vacuum deposition apparatus. N,N′-Di[(1-naphthalenyl)-N,N′-diphenyl]-1,1′-biphenyl-4,4′-diamine (NPD) was deposited on the first electrode to form a hole injection layer having a thickness of 300 Å, and Compound H-1-19 was deposited on the hole injection layer to form a hole transport layer having a thickness of 200 Å. Then, CzSi was deposited on the hole transport layer to form an electron-blocking layer having a thickness of about 100 Å. Then, a host mixture, in which a first host HT and a second host ET were mixed at a weight ratio of 1:1, a sensitizer AD-39, and Example Compounds or Comparative Example Compounds were co-deposited at a weight ratio of 85:14:1 to form an emission layer having a thickness of 200 Å, respectively. Thereafter, TSPO1 was deposited to form a hole-blocking layer having a thickness of 200 Å on the emission layer, and then TPBi was deposited Å on the hole-blocking layer to form an electron transport layer having a thickness of 300. Then, LiF was deposited on the electron transport layer to form an electron injection layer having a thickness of 10 Å, Al was deposited on the electron injection layer to form a second electrode having a thickness of 3,000 Å, and compound P4 was deposited on the second electrode to form a capping layer having a thickness of 700 Å to manufacture a light-emitting element. The compounds utilized in the manufacturing of the light-emitting elements are disclosed. The light-emitting elements according to Examples 1 to 8, and Comparative Examples 1 and 2 were evaluated and the results were listed in Table 2. In some embodiments, in the evaluation results of Examples and Comparative Examples, a driving voltage, luminous efficiency, and a luminous color at a current density of 1,000 candela per square meter (cd/m²) were measured utilizing Keithley MU 236 and a luminance meter PR650. The time taken for the luminance to decrease to 95% of an initial luminance was measured as a lifespan (T95). The relative lifespans were calculated with respect to the lifespan of the light-emitting element according to Comparative Example 1, and the results are listed respectively.

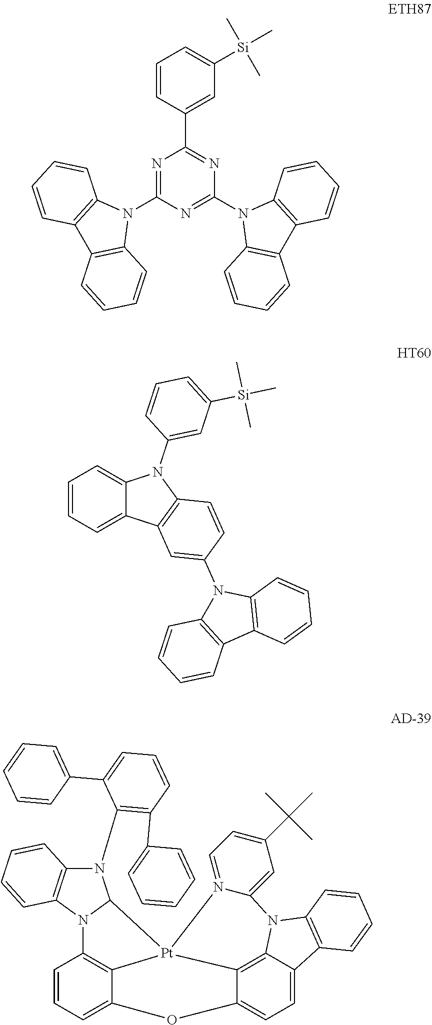

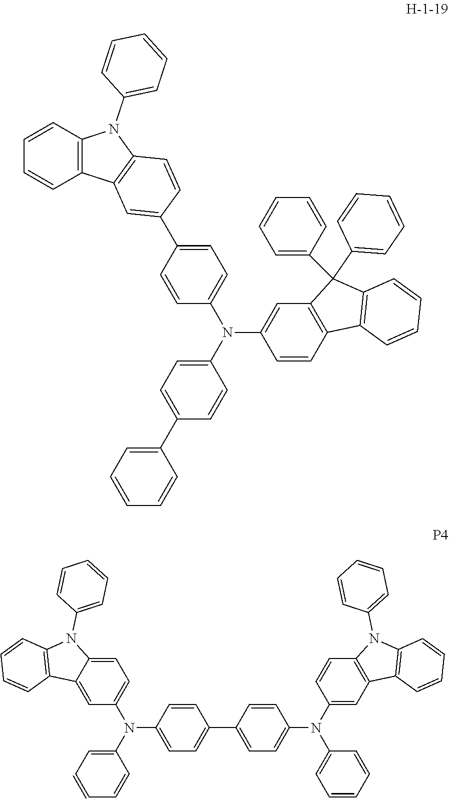 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

### Evaluation of Light-Emitting Element Characteristics

Element efficiency and element lifespan of each of the light-emitting elements manufactured utilizing the herein-mentioned Example Compounds 1, 7, 11, 31, 45, 46, 49, and 73 and Comparative Example Compounds A and B were evaluated. The physical properties of materials included in the light-emitting elements were listed in Table 1. An energy of a singlet exciton (S1, eV), an energy of a triplet exciton (T1, eV), an energy difference (ΔE_{ST}, eV) of the singlet-triplet excitons, an absorption wavelength (λ_{Abs}, nm), an emission wavelength (λₑₘᵢ, nm), Stokes-Shift (nm) were shown. As the energy difference (ΔE_{ST}, eV) of the singlet-triplet excitons is smaller, a rate of reverse inter-system crossing increases, and thus characteristics of the light-emitting element may be improved. In some embodiments, as the Stokes-Shift (nm) values, which are each a difference of the absorption wavelength (λ_{Abs}, nm) and the emission wavelength (λₑₘᵢ, nm), are smaller, the actual values are less deviated from the user's intended color coordinates, and thus the light-emitting element may have improved characteristics.

TABLE 1

| | | | | | | | Stokes- |
|---|---|---|---|---|---|---|---|
| | | S1 | T1 | | λ_{Abs} | λₑₘᵢ | shift |
| | Dopant | (eV) | (eV) | ΔE_{ST}(eV) | (nm) | (nm) | (nm) |
| Example 1 | Compound 1 | 2.70 | 2.64 | 0.06 | 448 | 458 | 10 |
| Example 2 | Compound 7 | 2.69 | 2.61 | 0.08 | 449 | 459 | 10 |
| Example 3 | Compound 11 | 2.68 | 2.64 | 0.04 | 451 | 460 | 9 |
| Example 4 | Compound 31 | 2.70 | 2.61 | 0.09 | 452 | 463 | 11 |
| Example 5 | Compound 45 | 2.70 | 2.60 | 0.10 | 448 | 458 | 10 |
| Example 6 | Compound 46 | 2.70 | 2.63 | 0.07 | 447 | 458 | 11 |
| Example 7 | Compound 49 | 2.70 | 2.65 | 0.05 | 449 | 457 | 9 |
| Example 8 | Compound 73 | 2.70 | 2.63 | 0.07 | 448 | 458 | 10 |
| Comparative | Compound A | 2.70 | 2.56 | 0.14 | 446 | 459 | 13 |
| Example 1 | | | | | | | |
| Comparative | Compound B | 2.71 | 2.55 | 0.16 | 454 | 468 | 14 |
| Example 2 | | | | | | | |

Referring to Table 1, each of the light-emitting elements according to Examples 1 to 8 has the energy difference of the singlet-triplet excitons of about 0.04 eV to about 0.10 eV. In comparison, the light-emitting elements according to Comparative Examples 1 and 2 have the energy difference of the singlet-triplet excitons of about 0.14 eV and about 0.16 eV, respectively. For example, the light-emitting elements according to Comparative Examples 1 and 2 have the energy difference values of the singlet-triplet excitons (ΔE_{ST}, eV) of about 1.4 times to about 4 times as large as those of the light-emitting elements according to Examples 1 to 8.

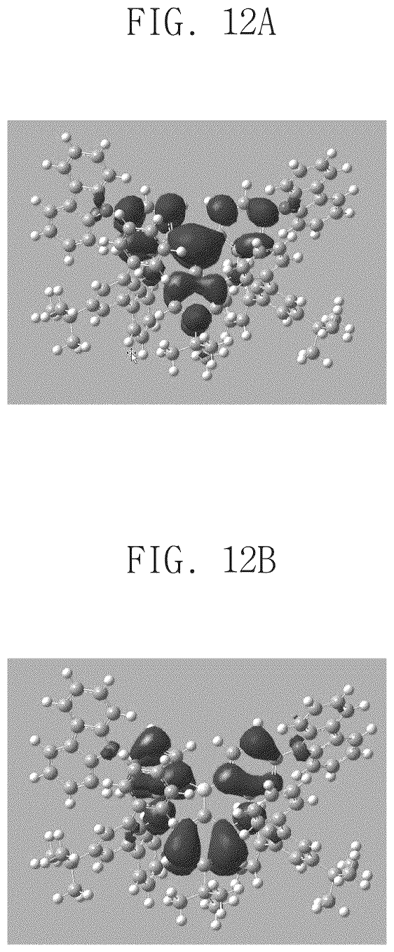

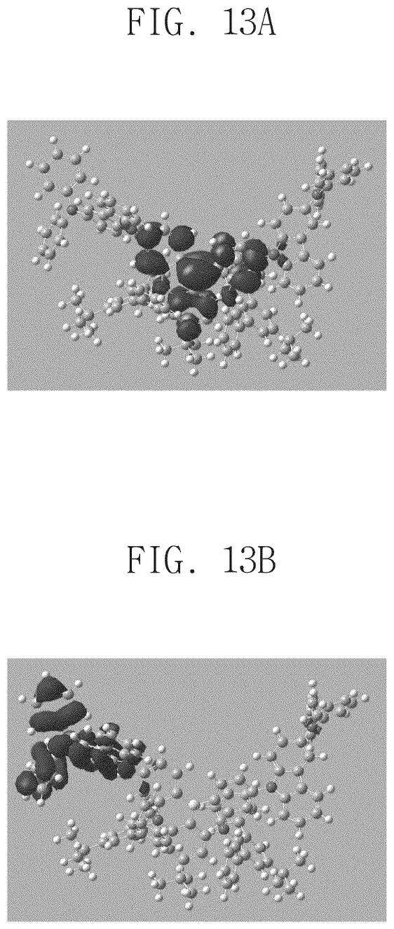

FIG. 12A is an orbital distribution of a highest occupied molecular orbital (HOMO) of Comparative Example Compound A. FIG. 12B is an orbital distribution of a lowest unoccupied molecular orbital (LUMO) of Comparative Example Compound A. FIG. 13A is an orbital distribution of the HOMO of the fused polycyclic compound according to one or more embodiments of the present disclosure. FIG. 13B is an orbital distribution of the LUMO of the fused polycyclic compound according to one or more embodiments of the present disclosure. FIGS. 13A and 13B show the orbital distributions of the HOMO and the LUMO of Compound 1. Referring to FIGS. 12A to 13B, the orbital overlap between the HOMO and the LUMO of Example Compound 1 substituted with a nitrogen-containing substituent, which is an electron donating group, is smaller than the orbital overlap between the HOMO and the LUMO of Comparative Example Compounds A. Therefore, Example Compound 1 is stabilized compared to Comparative Example Compound A. In the same way, because each of Example Compounds 7, 11, 31, 45, 46, 49, and 73 is substituted for the NBN core with a nitrogen-containing substituent, which is an electron donating group, a degree of the overlap between the HOMO and the LUMO is lower compared to those of Comparative Example Compounds A and B. Accordingly, Example Compounds 7, 11, 31, 45, 46, 49, and 73 are thereby each relatively more stable, and thus the singlet-triplet excitons associated with the Example Compounds each have the smaller energy difference (ΔE_{ST}, eV) value. Therefore, the rates of reverse intersystem crossing of the light-emitting elements according to Examples 1 to 8 are each faster than those according to Comparative Examples 1 and 2, and thus a thermally activated delayed fluorescent light-emitting element according to Examples 1 to 8 is expected to have improved efficiency and lifespan.

In some embodiments, the light-emitting elements according to Examples 1 to 8 each have a Stokes-Shift value (nm) of about 9 nm to about 11 nm, and the light-emitting elements according to Comparative Examples 1 and 2 have Stokes-Shift values (nm) of 13 nm and 14 nm, respectively. For example, the light-emitting elements according to Comparative Examples 1 and 2 each have at least about 1.18 times to at most about 1.44 times larger Stokes-Shift values (nm) than those according to Examples 1 to 8. Therefore, because the light-emitting elements according to Examples 1 to 8 have smaller Stokes-Shift values (nm) than those of Comparative Examples 1 and 2, the actual values are less deviated from the user's intended color coordinates, and thus the light-emitting elements may have improved performance characteristics.

The light-emitting elements according to Examples 1 to 8 and Comparative Examples 1 and 2 were evaluated, and the results were listed in Table 2. For evaluation of characteristics of the light-emitting elements manufactured according to Examples 1 to 8, and Comparative Examples 1 and 2, a driving voltage, a front efficiency (cd/A/y), emission wavelength (nm), lifespan (T95), and color coordinates (CIE y) at a current density of 10 milliampere per square centimeter (mA/cm²) were measured. The driving voltage and the current density of the light-emitting elements were measured utilizing a source meter (made by Keithley Instrument Co., Ltd, 2400 series) and the time taken for the luminance to decrease to 95% of an initial luminance was measured as a lifespan. The lifespans were compared with that of the light-emitting element according to Comparative Example 1, and the results are listed respectively as relative element lifespans. As the front efficiency increases, the efficiency of the light-emitting element improves, and the emission wavelength refers to an actual wavelength measured in an experiment, with a target value of 460 nm. The smaller the difference from the value of 460 nm, the better the color rendering characteristics. The larger the lifespan (T95) value, the longer the lifespan of the light-emitting element. The closer the value of the color coordinates is to 0.055, the better the color implementation characteristics.

TABLE 2

| | | | Dopant | Driving | Front | Emission | | |
|---|---|---|---|---|---|---|---|---|
| | Host | | (Compound | voltage | efficiency | wavelength | Lifespan | |
| | (HT/ET) | Sensitizer | ID) | (V) | (cd/A/y) | (nm) | (T95) | CIE y |
| Example 1 | HT60/ | AD-39 | 1 | 4.1 | 500.4 | 461 | 3.3 | 0.057 |
| | ETH87 | | | | | | | |
| Example 2 | HT60/ | AD-39 | 7 | 4.0 | 489.9 | 461 | 5.2 | 0.055 |
| | ETH87 | | | | | | | |
| Example 3 | HT60/ | AD-39 | 11 | 4.1 | 561.8 | 462 | 2.3 | 0.056 |
| | ETH87 | | | | | | | |
| Example 4 | HT60/ | AD-39 | 31 | 4.1 | 555.4 | 463 | 4.8 | 0.057 |
| | ETH87 | | | | | | | |
| Example 5 | HT60/ | AD-39 | 45 | 4.0 | 471.5 | 461 | 1.9 | 0.057 |
| | ETH87 | | | | | | | |
| Example 6 | HT60/ | AD-39 | 46 | 4.0 | 474.4 | 461 | 2.1 | 0.054 |
| | ETH87 | | | | | | | |
| Example 7 | HT60/ | AD-39 | 49 | 3.9 | 548.1 | 461 | 4.1 | 0.053 |
| | ETH87 | | | | | | | |
| Example 8 | HT60/ | AD-39 | 73 | 4.0 | 489.3 | 461 | 3.7 | 0.055 |
| | ETH87 | | | | | | | |
| Comparative | HT60/ | AD-39 | A | 4.1 | 455.1 | 462 | 1 | 0.053 |
| Example 1 | ETH87 | | | | | | | |
| Comparative | HT60/ | AD-39 | B | 4.2 | 465.5 | 470 | 1.3 | 0.065 |
| Example 2 | ETH87 | | | | | | | |

Referring to Table 2 herein, the light-emitting elements according to Examples 1 to 8, and Comparative Examples 1 and 2 have no significant difference in the driving voltages (V). In the case of the front efficiency (cd/A/y), the light-emitting elements according to Examples 1 to 8 each have a value of about 471.5 cd/A/y to about 561.8 cd/A/y, while the light-emitting elements according to Comparative Examples 1 and 2 have values 455.1 cd/A/y and 465.5 cd/A/y, respectively. Compared to the light-emitting elements according to Comparative Examples 1 and 2, the light-emitting elements according to Examples 1 to 8 each have a difference of at least about 6 cd/A/y and at most about 106.7 cd/A/y. Therefore, because each of the light-emitting elements according to Examples 1 to 8 has a larger front efficiency value than those according to Comparative Examples 1 and 2, the light-emitting elements according to Examples 1 to 8 have more excellent or suitable efficiency characteristics than those according to Comparative Examples 1 and 2. In the cases of the emission wavelength (nm) and the color coordinate (CIE y), the light-emitting elements according to Examples 1 to 8 have the emission wavelength of about 461 nm to about 463 nm, and the color coordinate value of about 0.053 to about 0.057, while the light-emitting element according to Comparative Example 1 has the emission wavelength of 462 nm and the color coordinate value of 0.053 and the light-emitting element according to Comparative Example 2 has the emission wavelength of 470 nm and the color coordinate value of 0.065. Therefore, the light-emitting elements according to Examples 1 to 8 have similar levels of luminous characteristics compared with the light-emitting element according to Comparative Example 1, but compared with the light-emitting element according to Comparative Example 2, the light-emitting elements according to Examples 1 to 8 have a difference of at least about 7 nm and at most about 9 nm in emission wavelength, and, in the case of color coordinates, have a difference of at least about 0.008 and at most about 0.012. Therefore, the light-emitting elements according to Examples 1 to 8 have excellent or suitable color rendering characteristics compared to the light-emitting elements according to Comparative Example 2. In the case of the lifespan (T95), the light-emitting elements according to Examples 1 to 8 have about 1.9 times to about 5.2 times as large as that of Comparative Example 1 and have about 1.46 times to about 4 times as large as that of Comparative Example 2. Therefore, the light-emitting elements according to Examples 1 to 8 have excellent or suitable lifespan characteristics compared to those according to Comparative Examples 1 and 2.

The fused polycyclic compound according to one or more embodiments includes, as a central structure (hereinafter, referred to as an NBN core), a pentacyclic fused ring containing two nitrogen (N) atoms and one boron (B) atom as ring-forming atoms. The NBN core according to one or more embodiments includes three substituted or unsubstituted benzene rings. In the NBN core of the fused polycyclic compound according to one or more embodiments, a fused ring substituent of three rings is bonded to the carbon atom at a para-position with respect to the boron atom that forms a ring. For example, in one or more embodiments, when a nitrogen-containing substituent, which includes a diphenyl amine group, a carbazole group, a phenoxazine group, a phenothiazine group, a phenoselenazine group, a phenotelorazine group, a dimethylacridine group, a dimethyldibenzoazacyline group, a dimethyldibenzoazamine group, a phenazine group, a benzoxazine group, a dihydroquinoline group, and/or a difuropyridine group, is applied to the fused ring substituent of three rings, the orbital overlap between the HOMO and the LUMO of the molecule decreases, and thus stability thereof is improved. As a result, the energy difference of the singlet-triplet excitons formed by molecules is reduced. Accordingly, because the rate of the reverse inter-system crossing (RISC) increases, the material stability increases, and thus the light-emitting element including the fused polycyclic compound in the emission layer has improved lifespan characteristics and efficiency characteristics. The light-emitting element according to one or more embodiments includes a first compound according to one or more embodiments as a dopant material for phosphorescent light-emitting elements, and for example, in blue light wavelength region, high element efficiency may be achieved.

Comparative Example Compounds A and B included in the light-emitting elements according to Comparative Examples 1 and 2, respectively, include the NBN core structure according to one or more embodiments, and a compound in which two carbazole groups are connected to the NBN core. In some embodiments, in Comparative Example Compound A according to Comparative Example 1, the nitrogen-containing substituent is unsubstituted for the carbazole group, which is substituted with the NBN core, and in Comparative Example Compound B according to Comparative Example 2, the carbazole group substituted with the NBN core contains a cyano (CN) group, which is an electron-withdrawing substituent rather than an electron donating substituent. It may be confirmed that, compared to the light-emitting elements according to Example Compounds, the color implementation characteristics, luminous efficiency, and element lifespan characteristics are low when applied to a light-emitting element.

A light-emitting element according to one or more embodiments may exhibit improved element characteristics of high efficiency and/or long-lifespan.

A display device according to one or more embodiments may exhibit improved emission characteristics of high efficiency and/or long-lifespan.

A fused polycyclic compound according to one or more embodiments may be included in an emission layer of the light-emitting element or the display device, and thus contribute to improvements in high efficiency and/or long-lifespan of the light-emitting element and the display device.

Although the embodiments of the present disclosure have been described, it is understood that the present disclosure should not be limited to these embodiments but one or more suitable changes and modifications can be made by one ordinary skilled in the art within the spirit and scope of the present disclosure as claimed.

Therefore, the technical scope of the present disclosure should not be limited to the contents described in the detailed description of the specification but should be defined by the claims, and equivalents thereof.

1. A light-emitting element comprising:
a first electrode;
a second electrode facing the first electrode; and
an emission layer between the first electrode and the second electrode,
wherein the emission layer comprises a first compound represented by Formula 1: 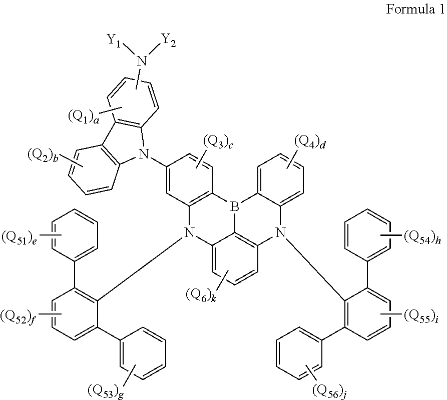
wherein in Formula 1,
b and d are each independently an integer of 0 to 4,
a, c, f, i, and k are each independently an integer of 0 to 3,
e, g, h, and j are each independently an integer of 0 to 5,
Q₁ to Q₃, and Q₅₁ to Q₅₆ are each independently a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
Q₄ is a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted silyl group, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
Q₆ is a hydrogen atom, a deuterium atom, a substituted or unsubstituted alkyl group having 1 to 20 carbon atoms, a substituted or unsubstituted cycloalkyl group having 5 to 30 ring-forming carbon atoms, a substituted or unsubstituted aryl group having 6 to 30 ring-forming carbon atoms, a substituted or unsubstituted heteroaryl group having 2 to 30 ring-forming carbon atoms, a substituted or unsubstituted germyl group, or a substituted or unsubstituted silyl group, and
Y₁ and Y₂ are each independently a hydrogen atom, a deuterium atom, a substituted or unsubstituted alkyl group having 1 to 20 carbon atoms, a substituted or unsubstituted cycloalkyl group having 5 to 30 ring-forming carbon atoms, a substituted or unsubstituted alkoxy group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring.

2. The light-emitting element of claim 1, wherein the first compound represented by Formula 1 is represented by Formula 1-1: 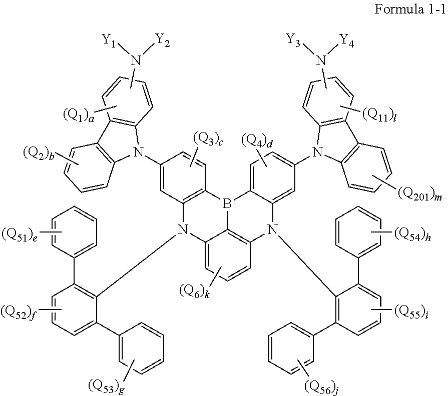
wherein, in Formula 1-1,
I and d₁ are each independently an integer of 0 to 3,
m is an integer of 0 to 4,
Q₁₁ and Q₂₀₁ are each independently a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or a substituted or unsubstituted amine group, and/or are bonded to an adjacent group to form a ring,
Y₃ and Y₄ are each independently a hydrogen atom, a deuterium atom, a substituted or unsubstituted alkyl group having 1 to 20 carbon atom, a substituted or unsubstituted cycloalkyl group having 5 to 30 ring-forming carbon atoms, a substituted or unsubstituted alkoxy group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring, and
Y₁, Y₂, Q₁, to Q₄, Q₅₁ to Q₅₆, Q₆, a to c and e to k are as defined for Formula 1.

3. The light-emitting element of claim 1, wherein the first compound represented by Formula 1 is represented by at least one selected from among Formula 2-1 to Formula 2-10: 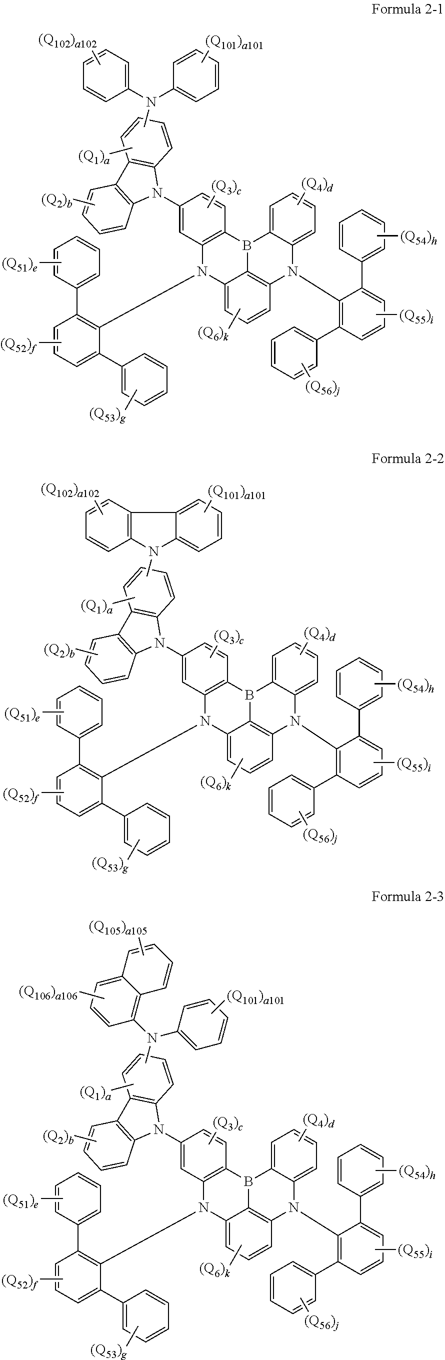 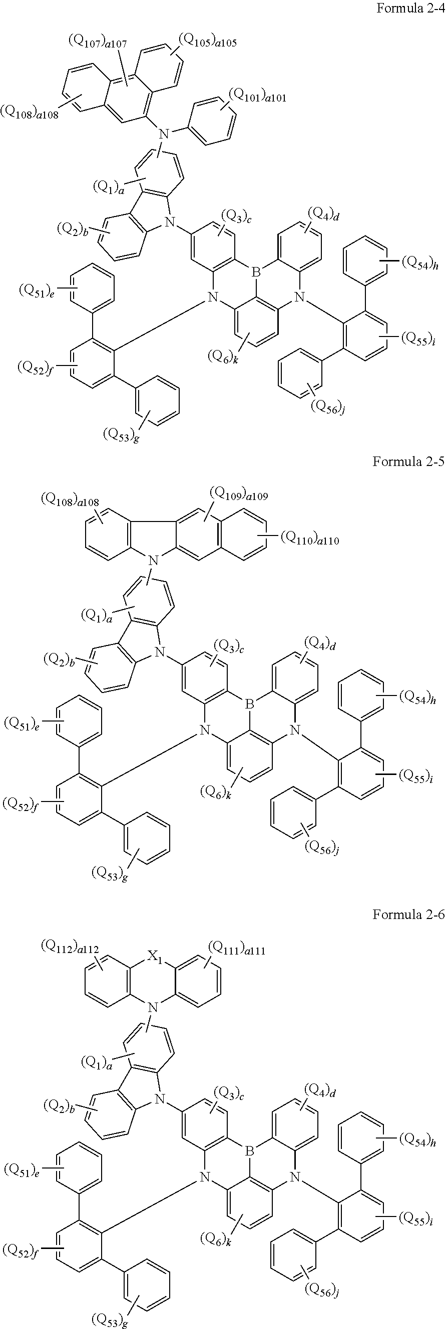 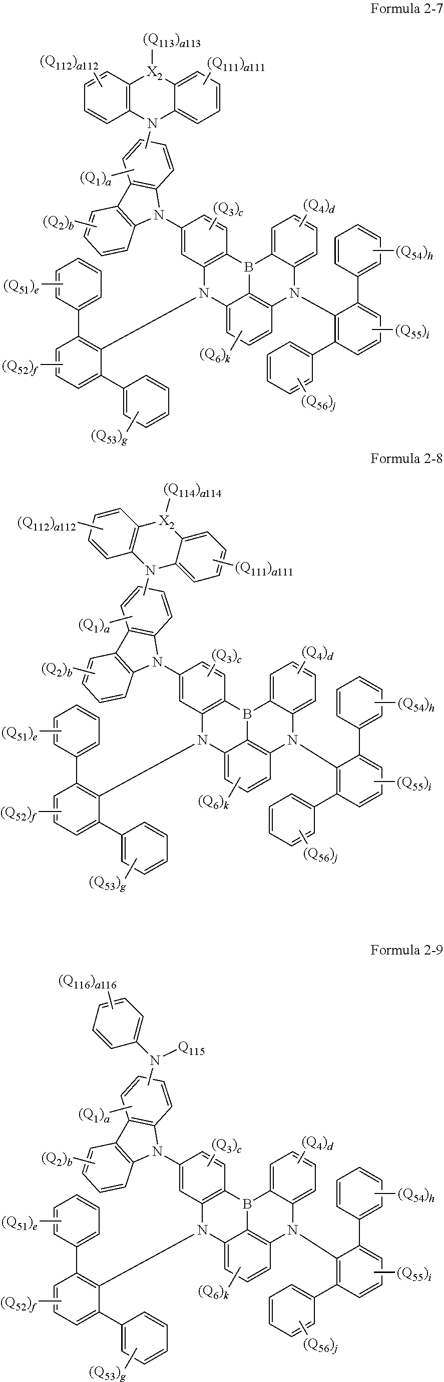 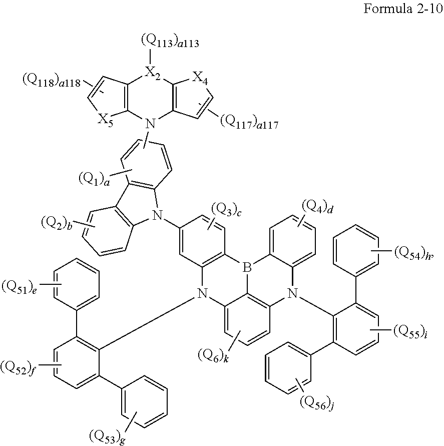
wherein, in Formula 2-1 to Formula 2-10,
a₁₀₁, a₁₀₂, and a₁₁₆ are each independently an integer of 0 to 5,
a₁₀₃, a₁₀₄, a₁₀₅, a₁₀₈, a₁₁₀, a₁₁₁, and a₁₁₂ are each independently an integer of 0 to 4,
a₁₀₆ is an integer of 0 to 3,
a₁₀₉, a₁₁₄, a₁₁₇, a₁₁₈, and a₁₁₉ are each independently an integer of 0 to 2,
a₁₀₇ and a₁₁₃ are each independently 0 or 1,
Q₁₀₁ to Q₁₁₂, and Q₁₁₆ to Q₁₁₉ are each independently a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or a substituted or unsubstituted amine group, and/or are bonded to an adjacent group to form a ring,
Q₁₁₃ to Q₁₁₅ are each independently a hydrogen atom, a deuterium atom, a substituted or unsubstituted alkyl group having 1 to 20 carbon atom, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
X₁, X₄, and X₅ are each independently an oxygen atom, a sulfur atom, a selenium atom, or a tellurium atom,
X₂ is a nitrogen atom,
X₃ is a carbon atom, a silicon atom, or germanium atom, and
Q₁ to Q₄, Q₅₁ to Q₅₆, Q₆, and a to k are as defined for Formula 1.

4. The light-emitting element of claim 1, wherein the first compound represented by Formula 1 is represented by Formula 3: 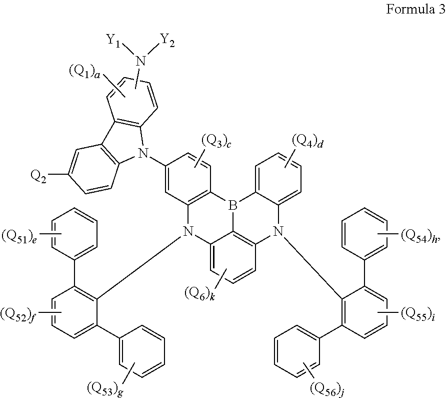
wherein, in Formula 3,
Y₁, Y₂, Q₁ to Q₄, Q₅₁ to Q₅₆, Q₆, a, and c to k are as defined for Formula 1.

5. The light-emitting element of claim 4, wherein Q₂ are represented by at least one selected from among Formula 3-1 to Formula 3-5: 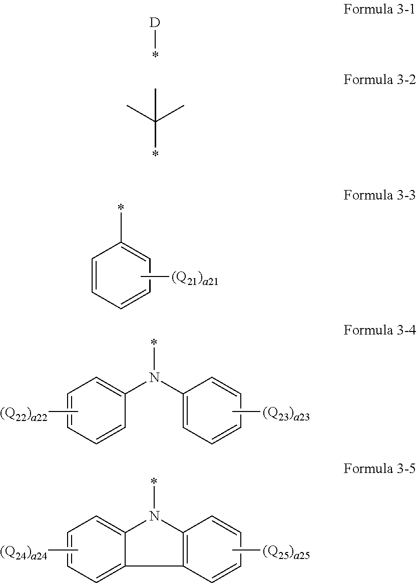
wherein in Formula 3-1, D is a deuterium atom,
in Formula 3-3 to Formula 3-5,
Q₂₁ to Q₂₅ are each independently a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or a substituted or unsubstituted amine group, and/or are bonded to an adjacent group to form a ring,
a₂₁ to a₂₃ are each independently an integer of 0 to 5, and
a₂₄ and a₂₅ are each independently an integer of 0 to 4, and
in Formula 3-1 to Formula 3-5,
-* is a position connected to Formula 3.

6. The light-emitting element of claim 1, wherein the first compound represented by Formula 1 is represented by Formula 4 or Formula 5: 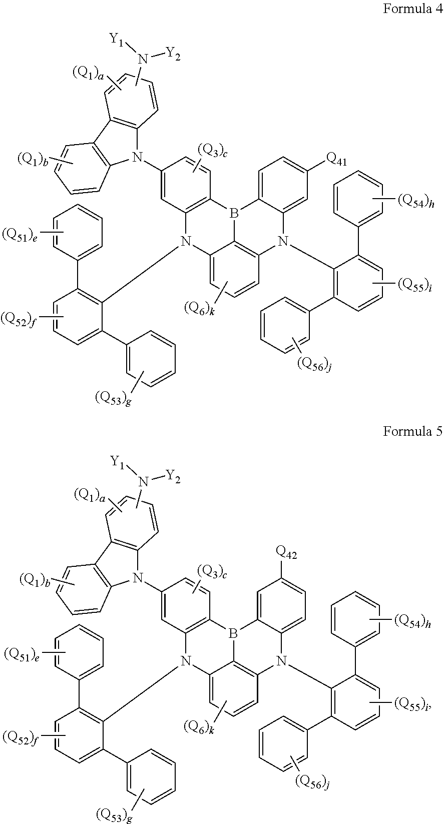
wherein in Formula 4 and Formula 5,
Q₄₁ and Q₄₂ are each independently a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or a substituted or unsubstituted amine group, and
Y₁, Y₂, Q₁ to Q₃, Q₅₁ to Q₅₆, and Q₆, a to c, and e to k are as defined for Formula 1.

7. The light-emitting element of claim 6, wherein, in Formula 4,
Q₄₁ is represented by Formula 4-1 or Formula 4-2: 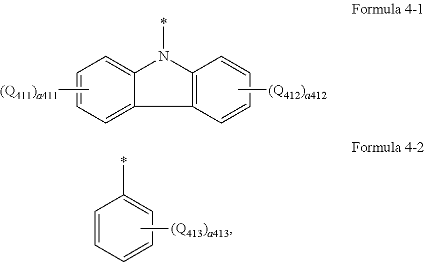
wherein in Formula 4-1 and Formula 4-2,
a₄₁₁, and a₄₁₂ are each independently an integer of 0 to 4,
a₄₁₃ is an integer of 0 to 5,
Q₄₁₁, Q₄₁₂, and Q₄₁₃ are each independently a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or a substituted or unsubstituted amine group, and/or are bonded to an adjacent group to form a ring, and
-* is a position connected to Formula 4.

8. The light-emitting element of claim 6, wherein, in Formula 5,
Q₄₂ is represented by Formula 4-3 or Formula 4-4: 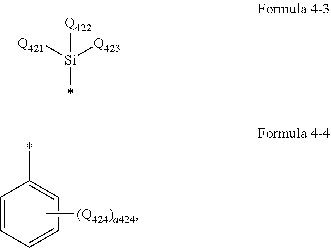
wherein, in Formula 4-3 and Formula 4-4,
a₄₂₄ is an integer of 0 to 5,
Q₄₂₁ to Q₄₂₃ are each independently a hydrogen atom, a deuterium atom, a substituted or unsubstituted alkyl group having 1 to 20 carbon atom, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring,
Q₄₂₄ is a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or a substituted or unsubstituted amine group, and/or are bonded to an adjacent group to form a ring, and
-* is a position connected to Formula 5.

9. The light-emitting element of claim 1, wherein the first compound represented by Formula 1 is represented by Formula 6: 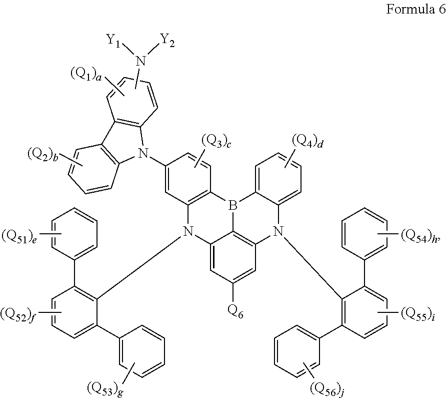
wherein, in Formula 6,
Y₁, Y₂, Q₁ to Q₄, Q₅₁ to Q₅₆, Q₆, and a to j are as defined for Formula 1.

10. The light-emitting element of claim 9, wherein Q₆ is represented by any one selected from among Formula 6-1 to Formula 6-6: 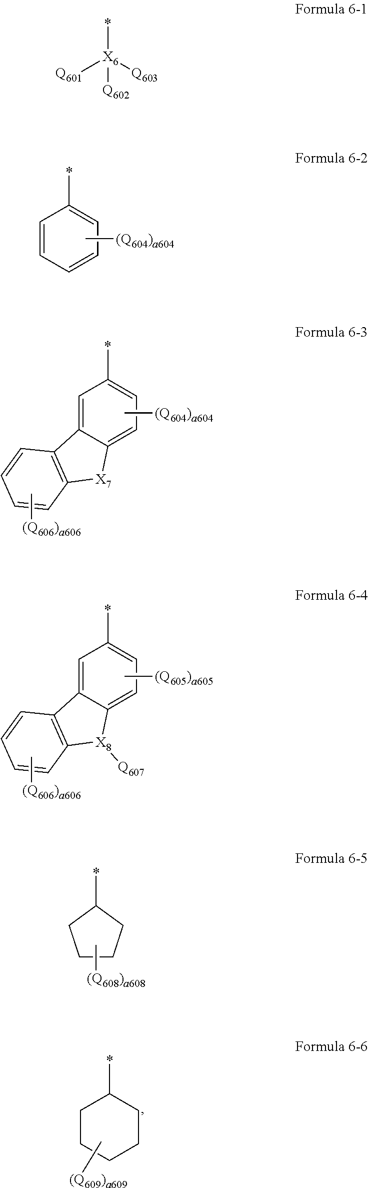
wherein, in Formula 6-1 to Formula 6-6,
X₆ is a carbon atom, a silicon atom, or a germanium atom,
X₇ is an oxygen atom, a sulfur atom, a selenium atom or a tellurium atom,
X₈ is a nitrogen atom,
a₆₀₄ is an integer of 0 to 5,
a₆₀₅ is an integer of 0 to 3,
a₆₀₆ is an integer of 0 to 4,
a₆₀₈ is an integer of 0 to 9,
a₆₀₉ is an integer of 0 to 11,
Q₆₀₁ to Q₆₀₆, Q₆₀₈, and Q₆₀₉ are each independently a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or a substituted or unsubstituted amine group, and/or are bonded to an adjacent group to form a ring,
Q₆₀₇ is a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted alkoxy group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or are bonded to an adjacent group to form a ring, and
-* is a position connected to Formula 6.

11. The light-emitting element of claim 1, wherein the first compound represented by Formula 1 is represented by at least one selected from among compounds in Compound Group 1:

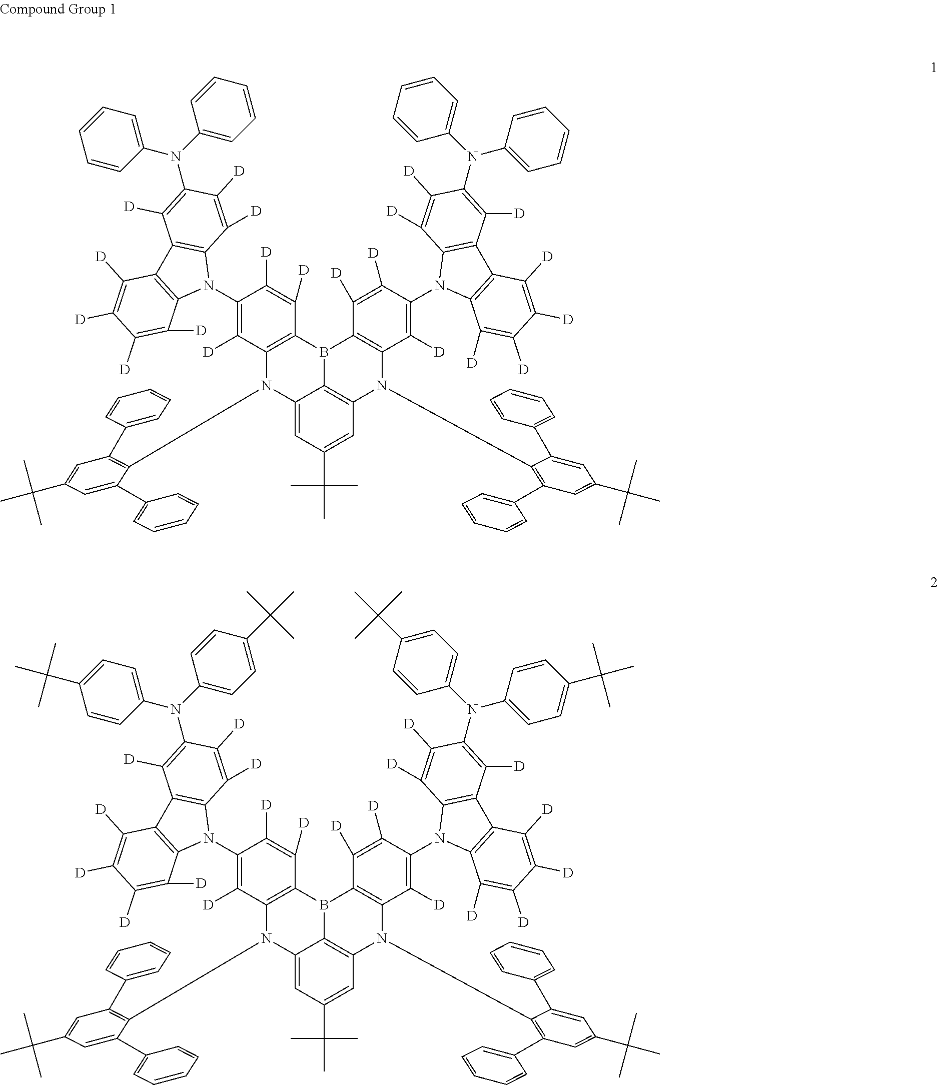

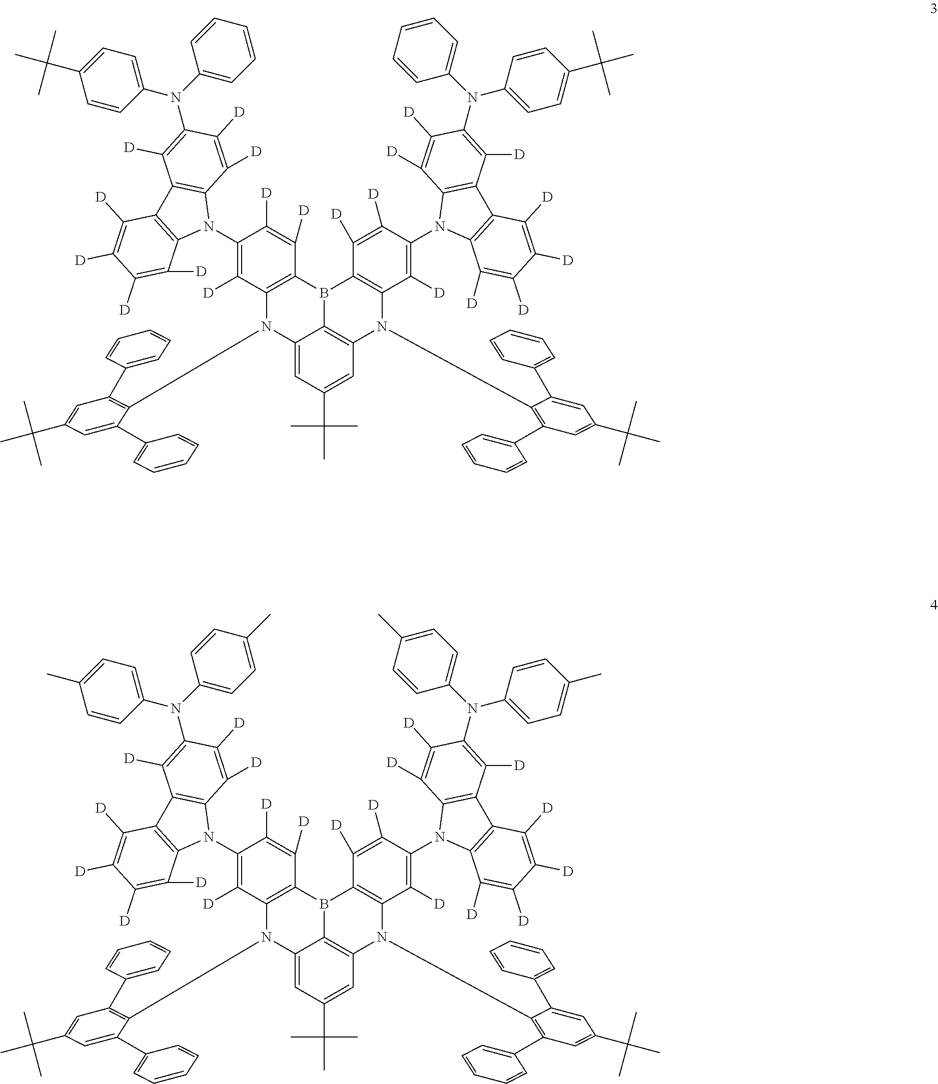

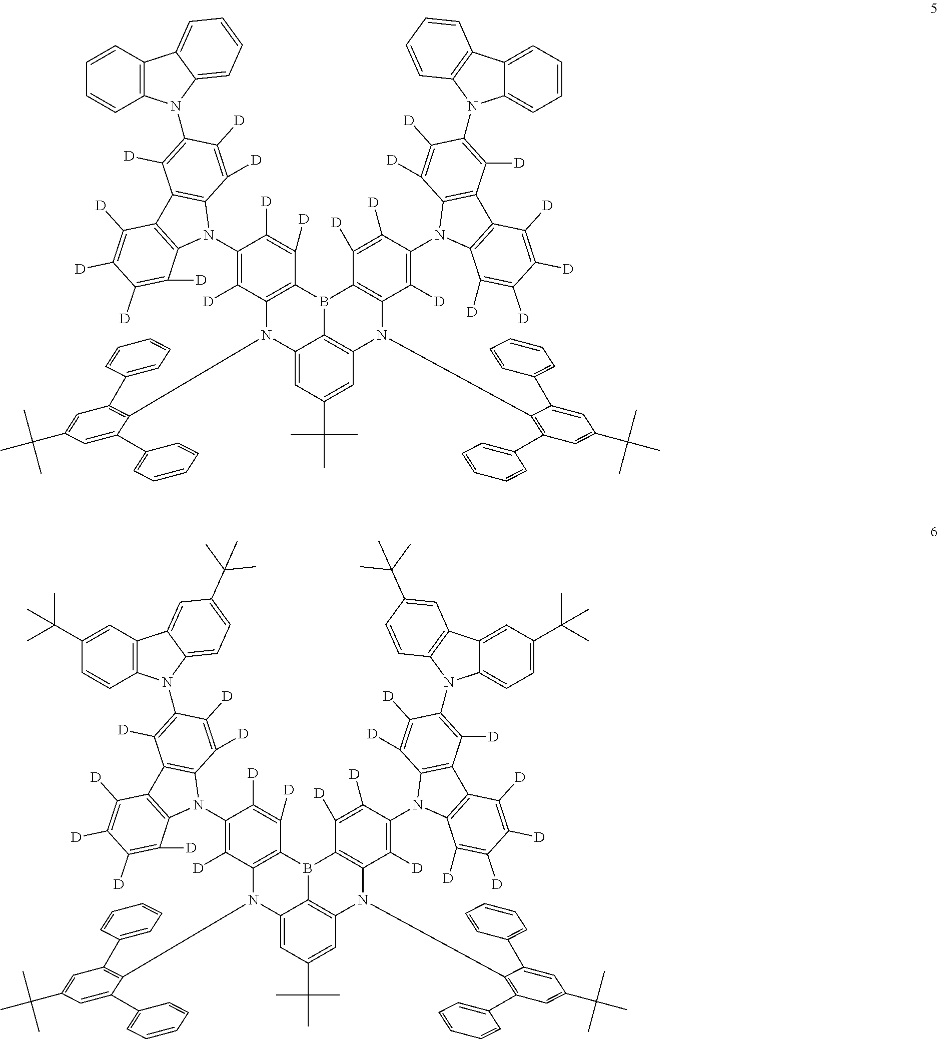

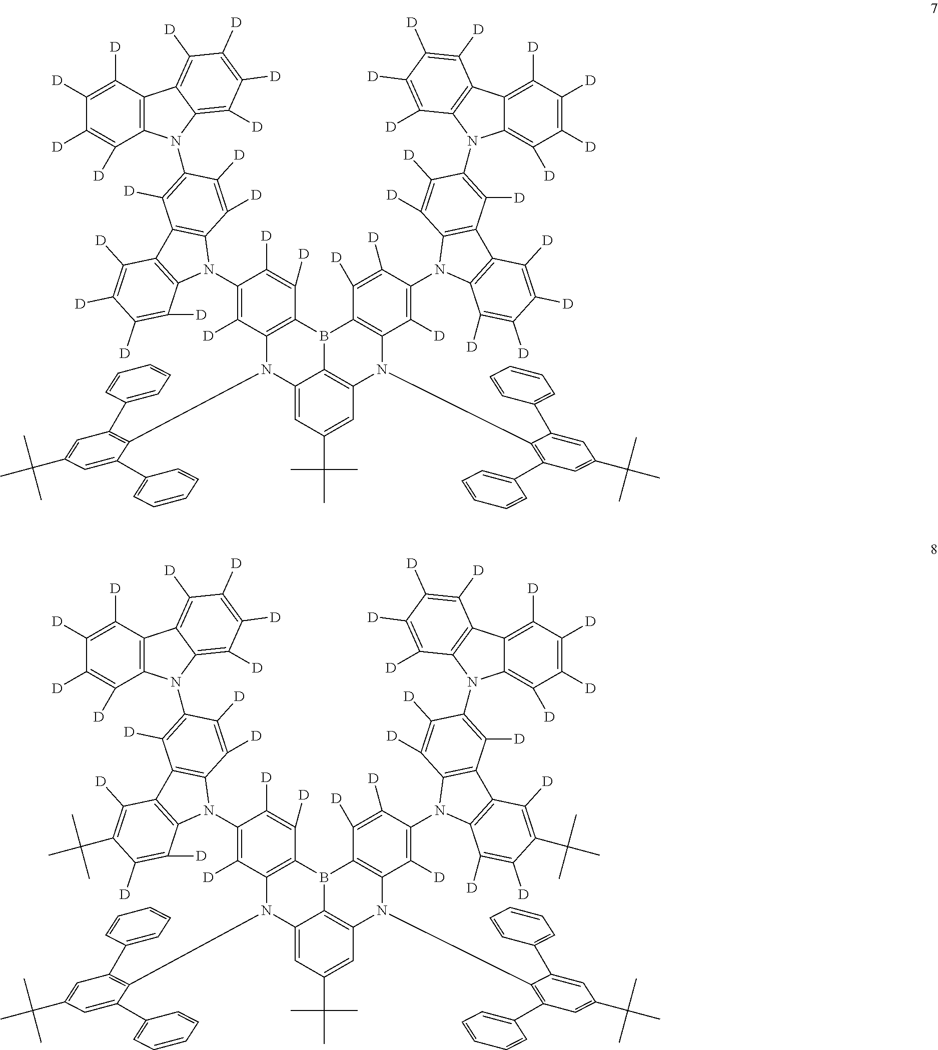

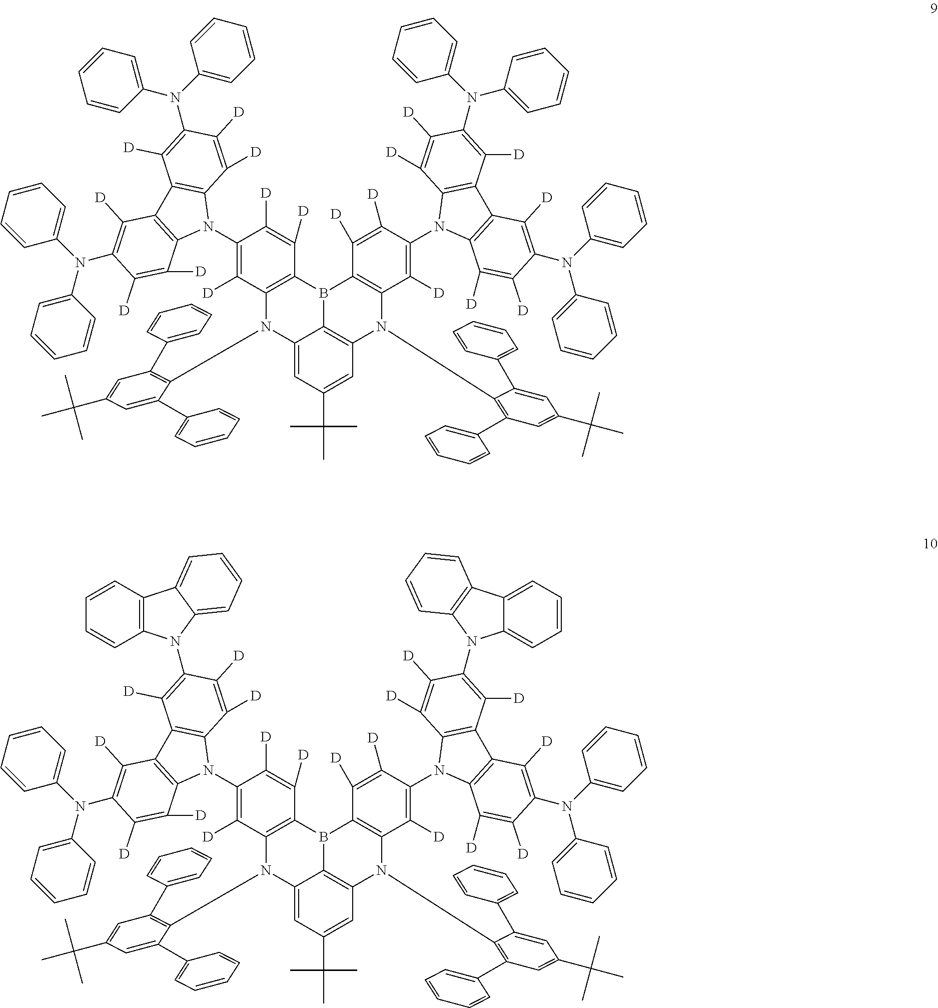

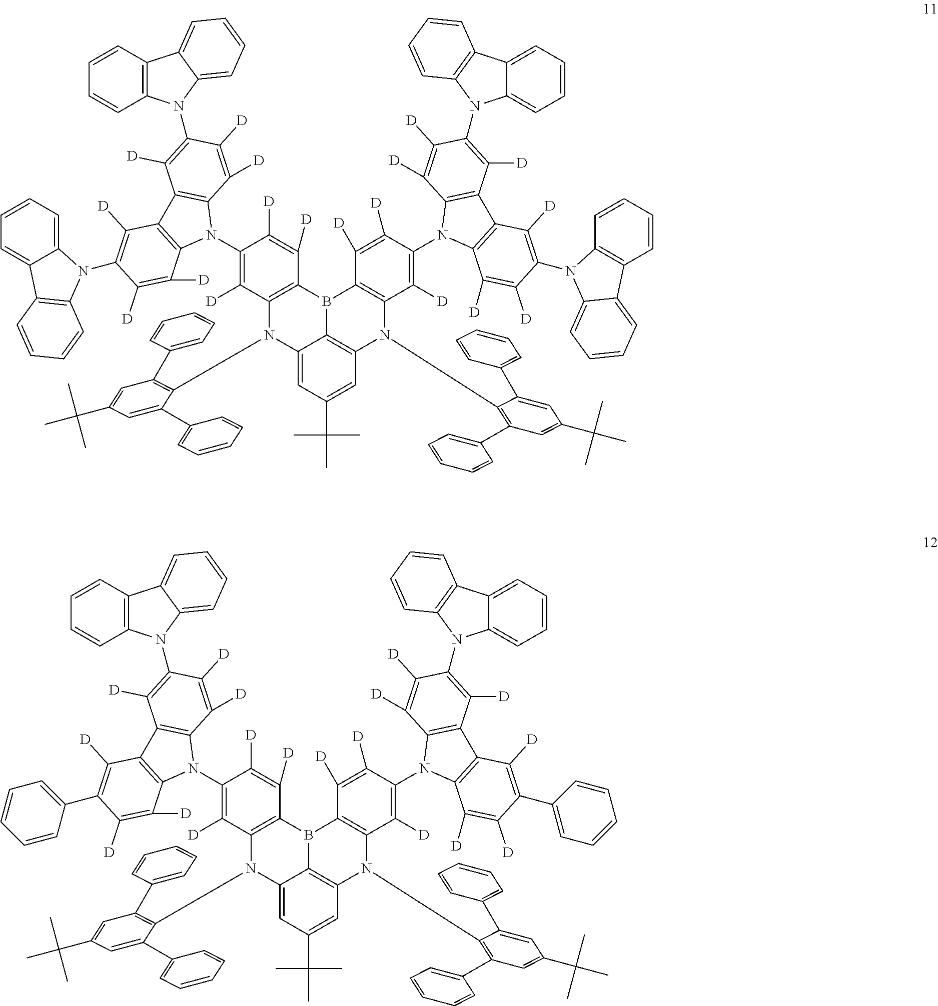

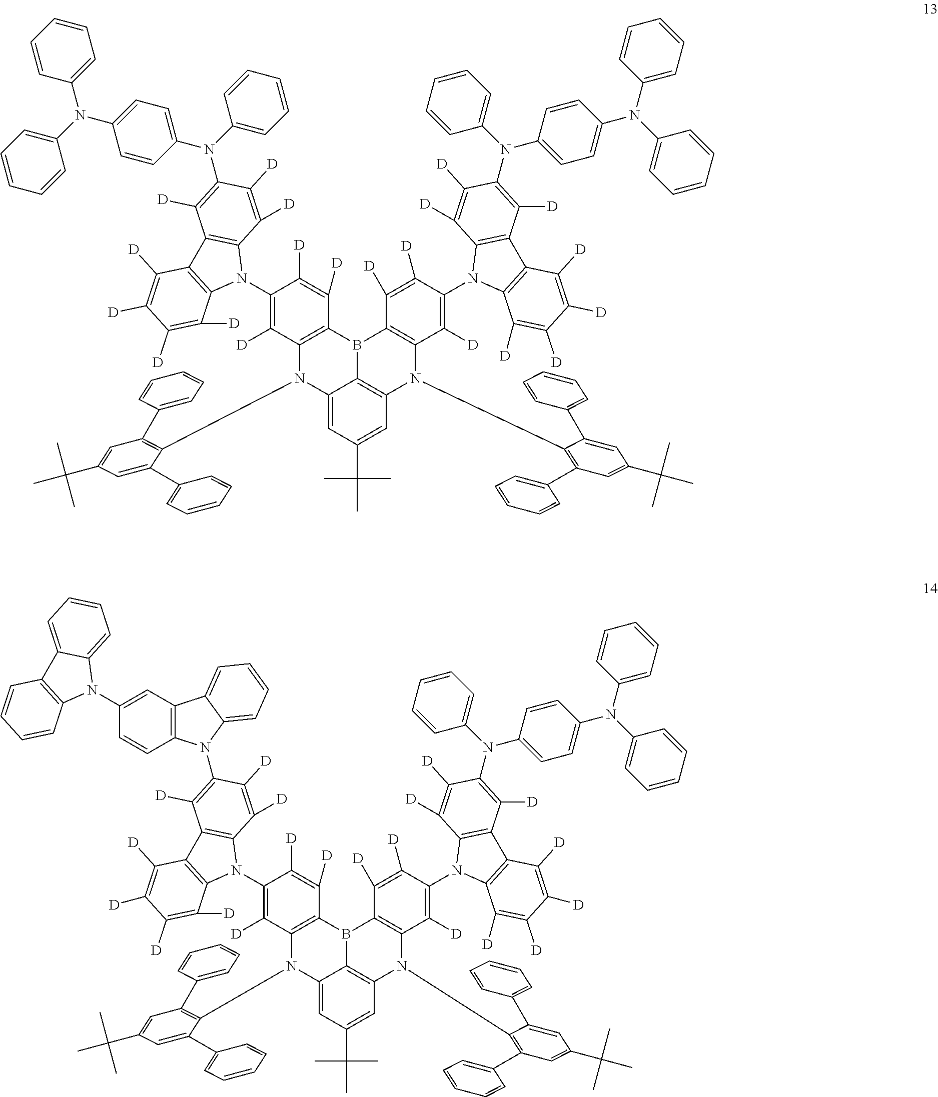

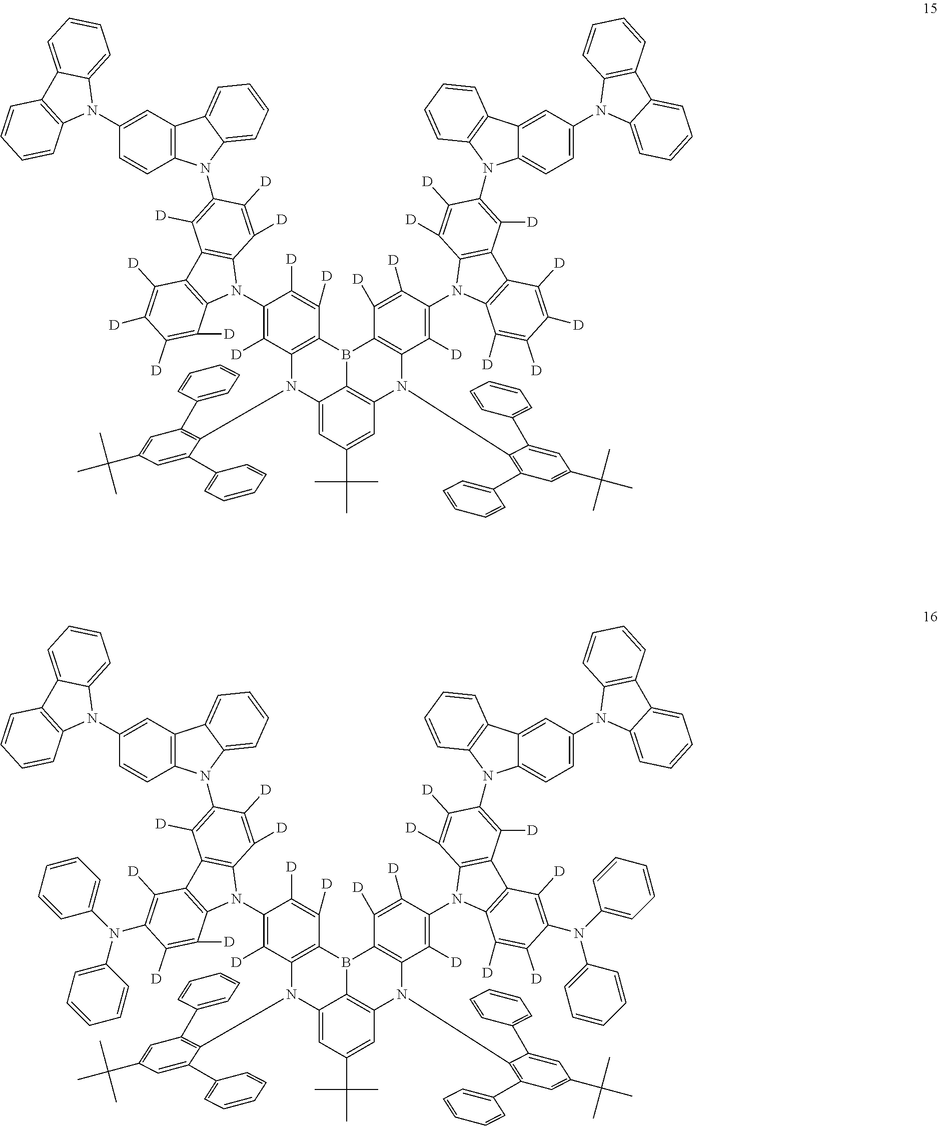

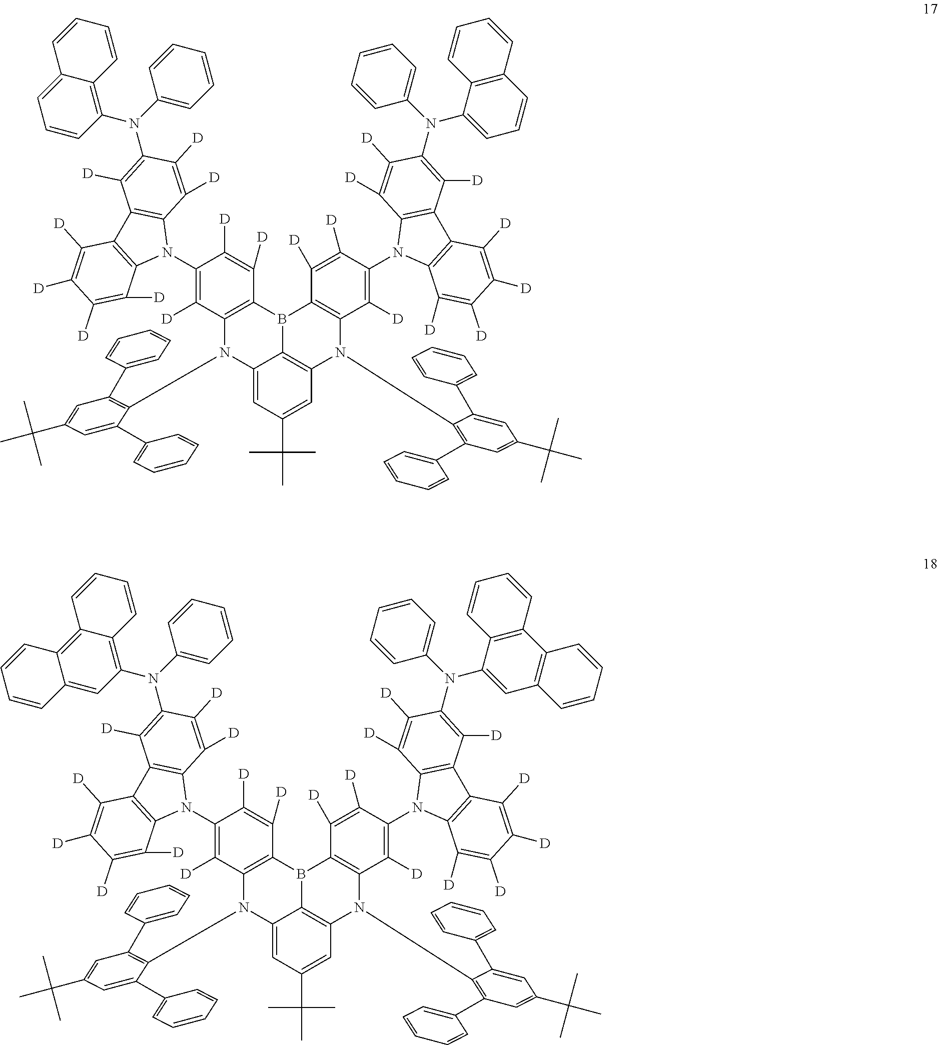

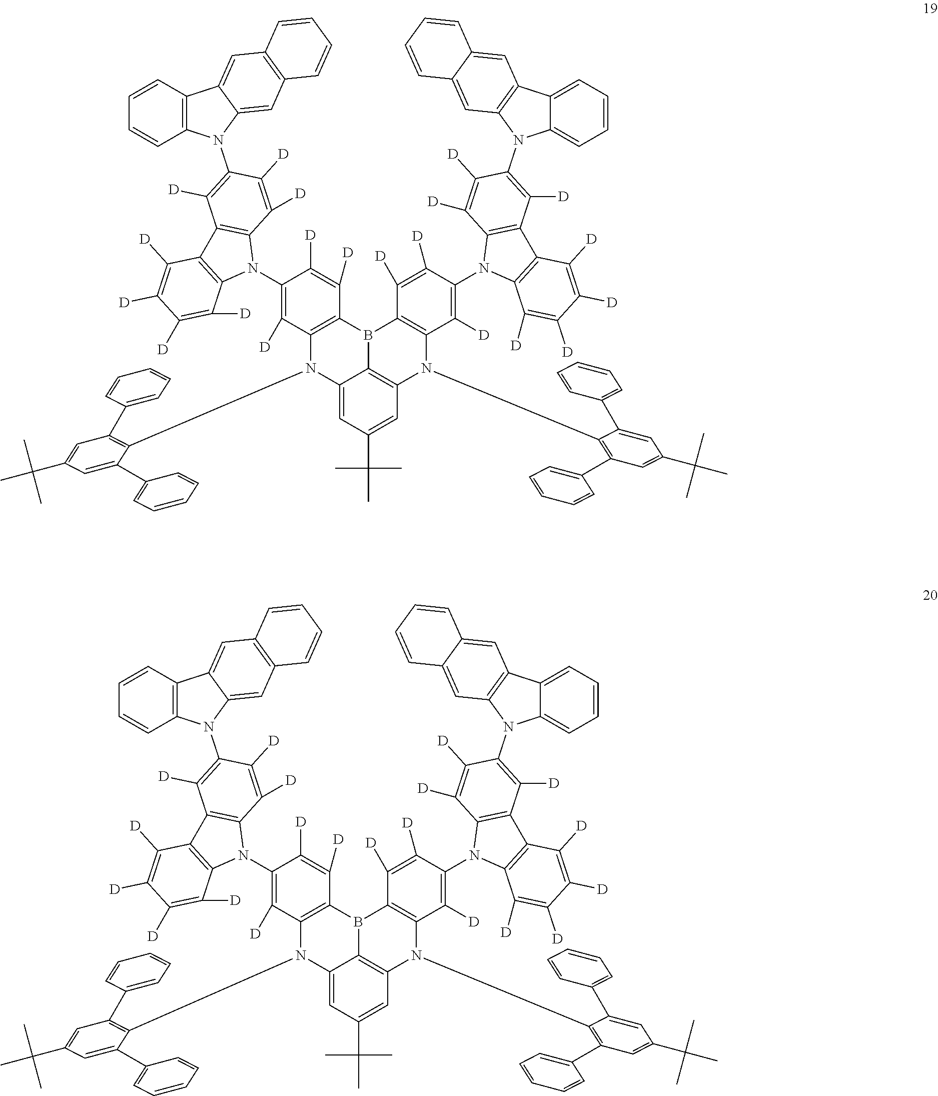

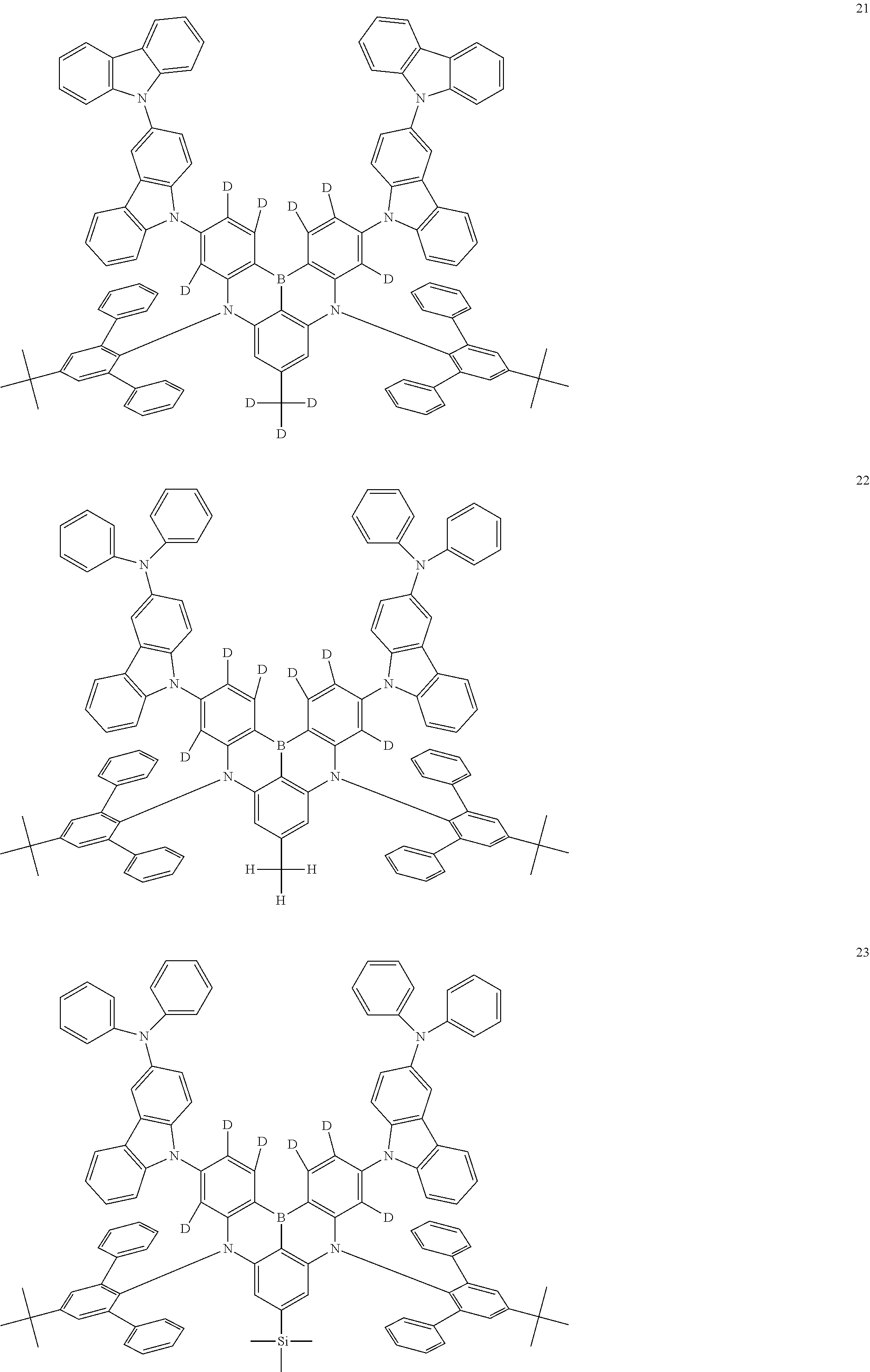

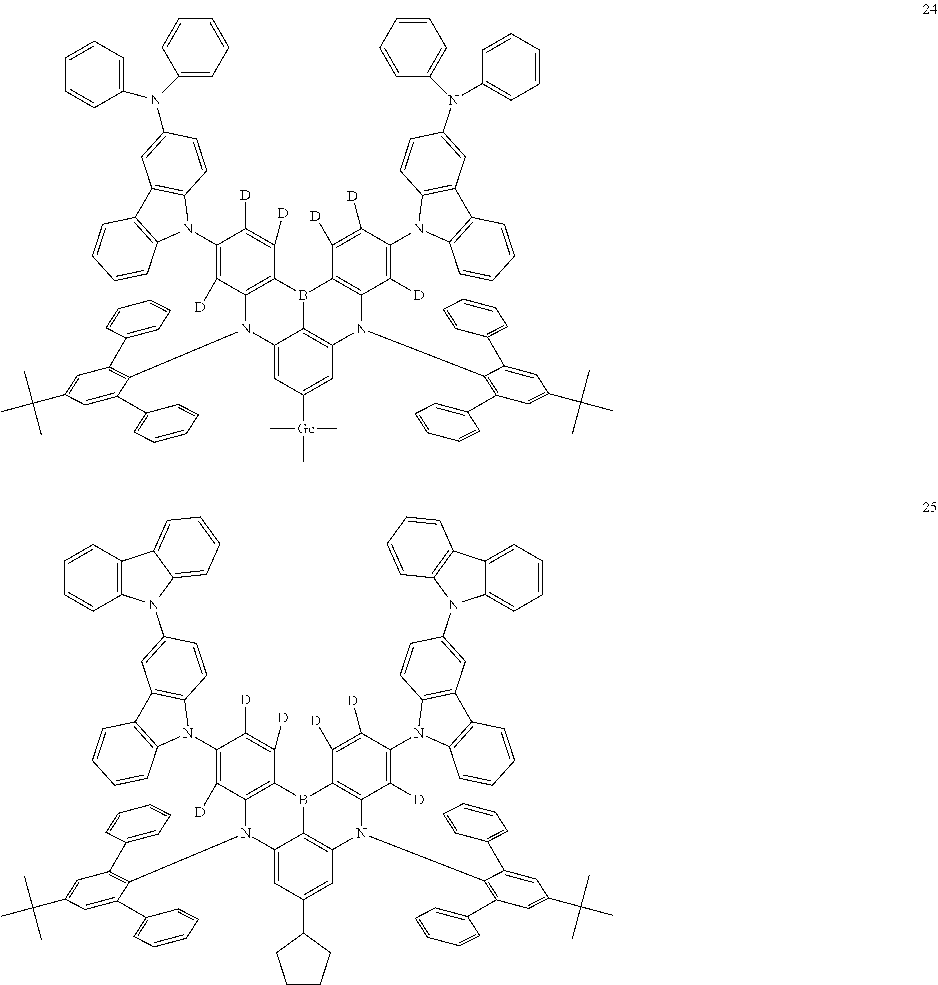

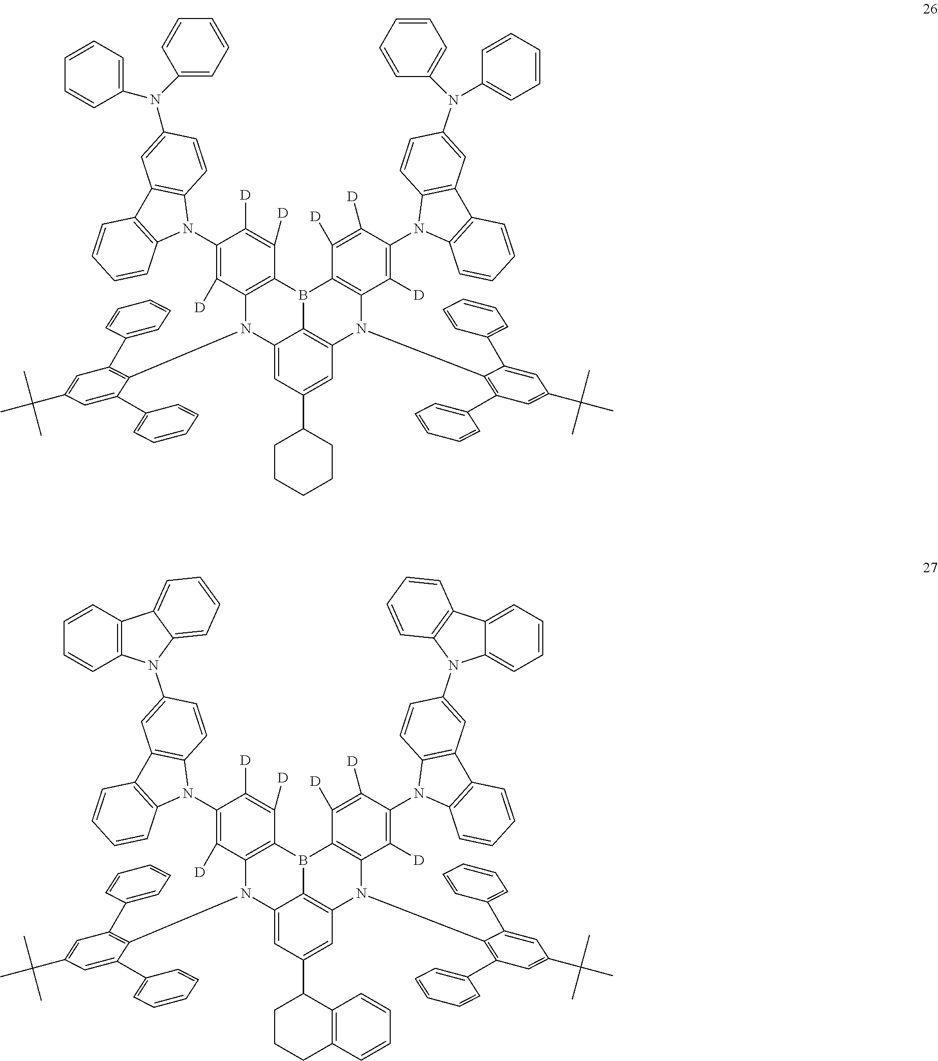

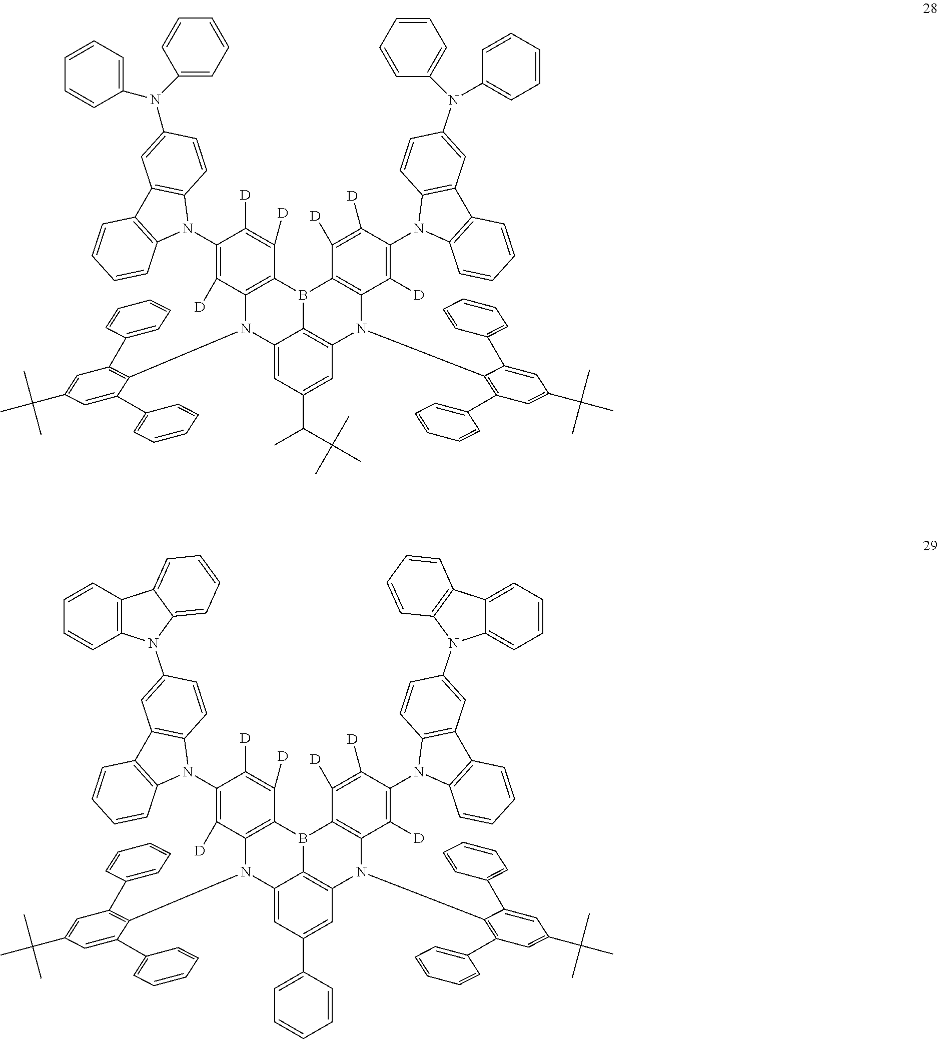

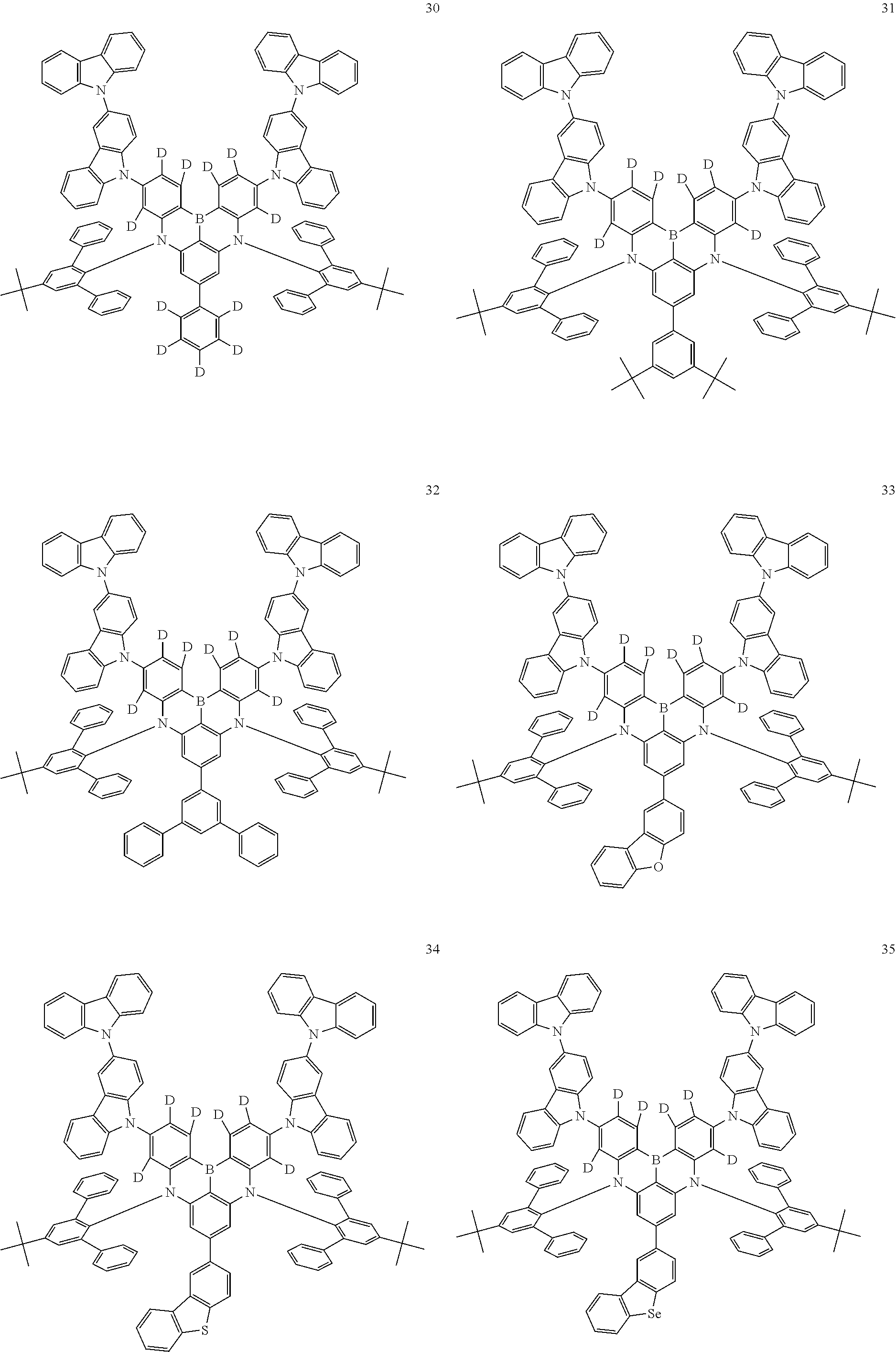

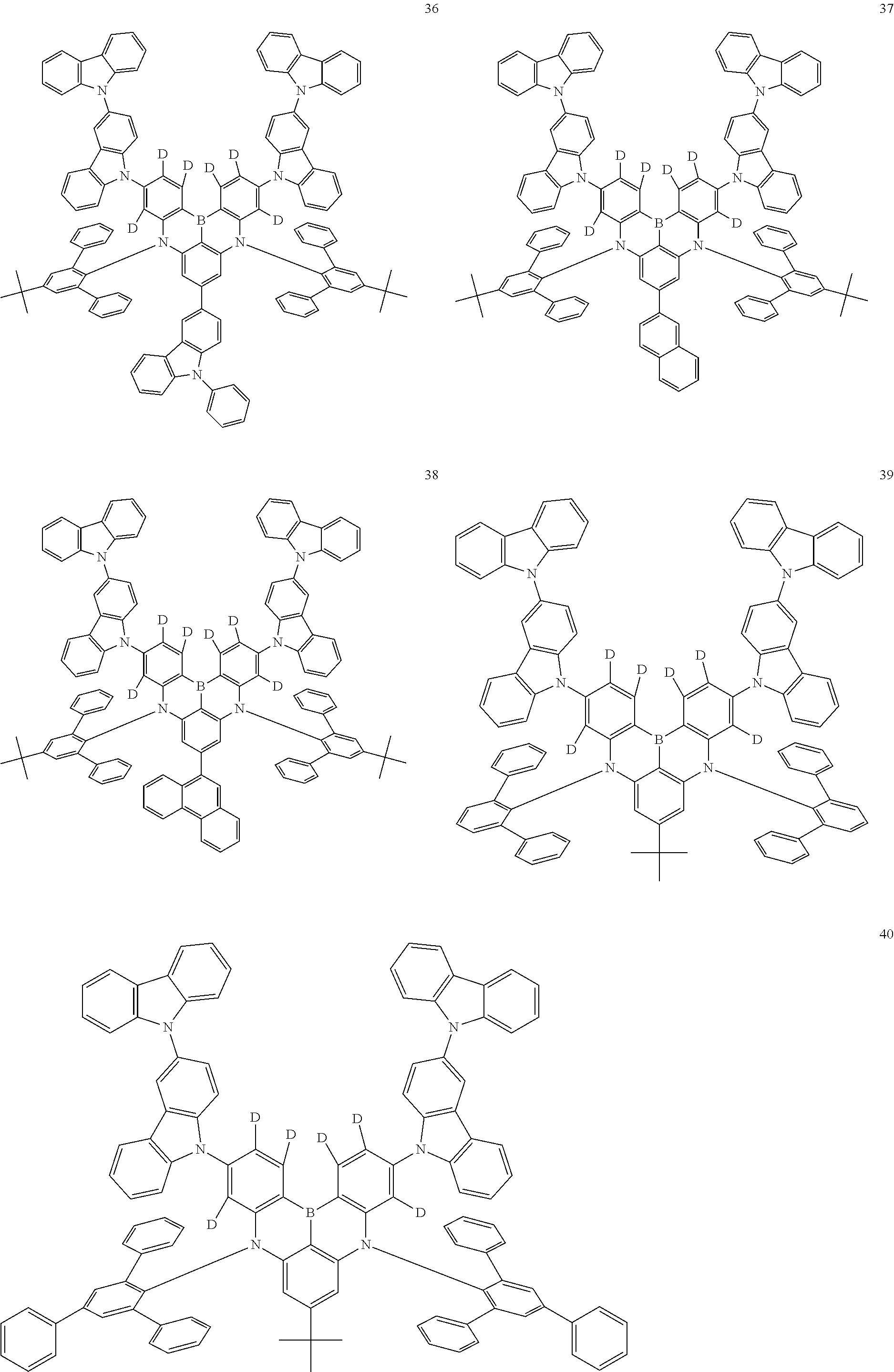

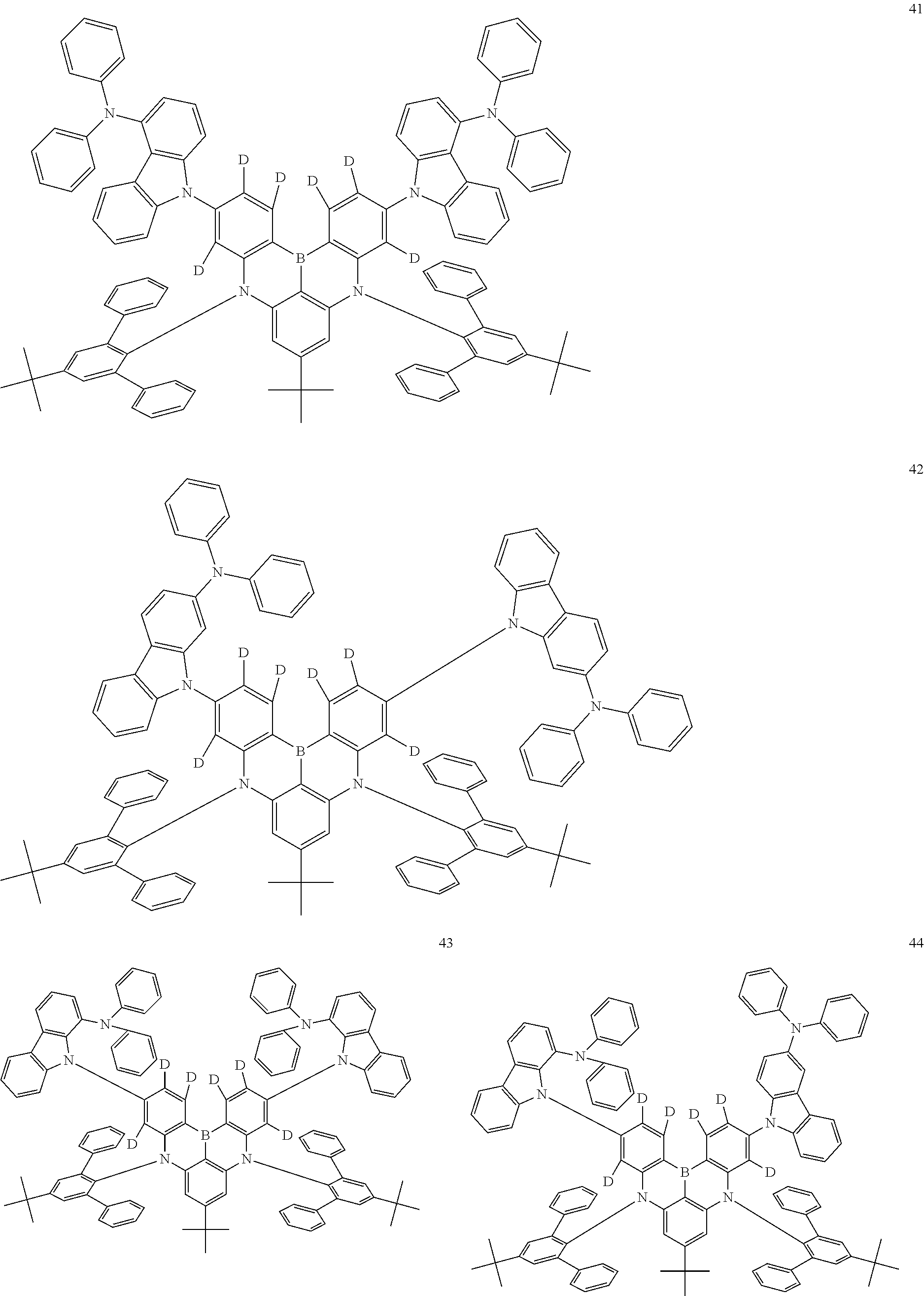

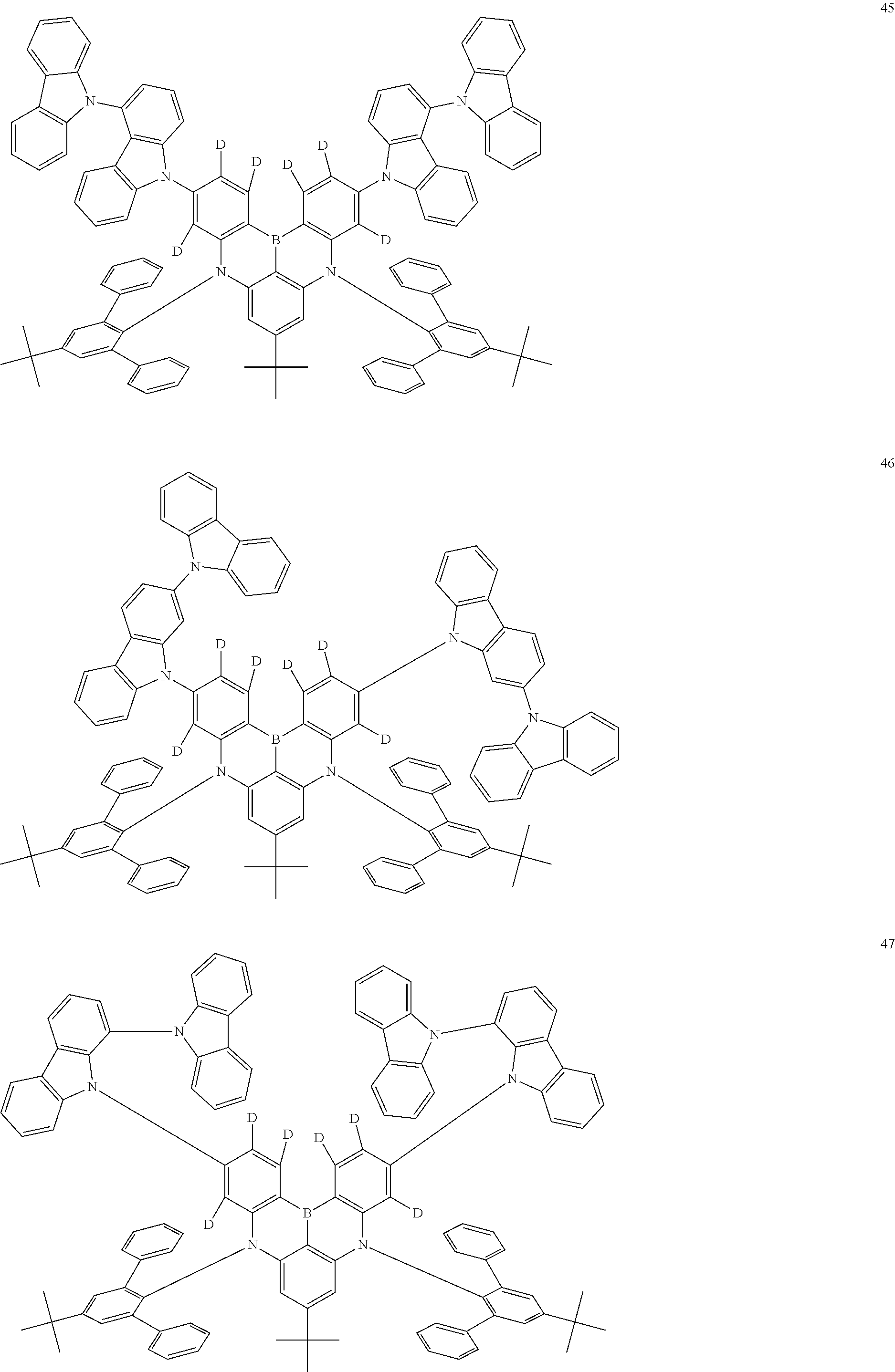

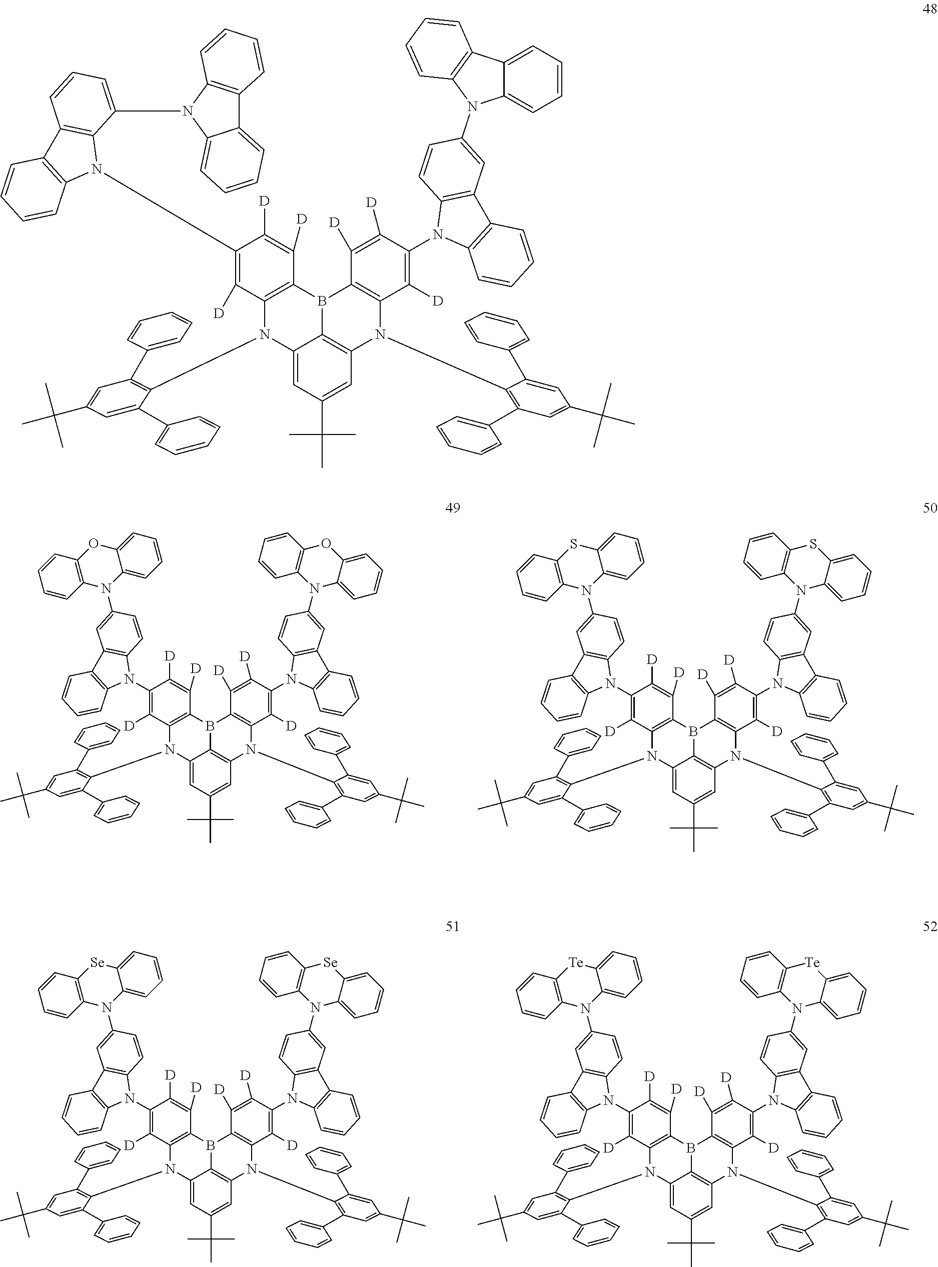

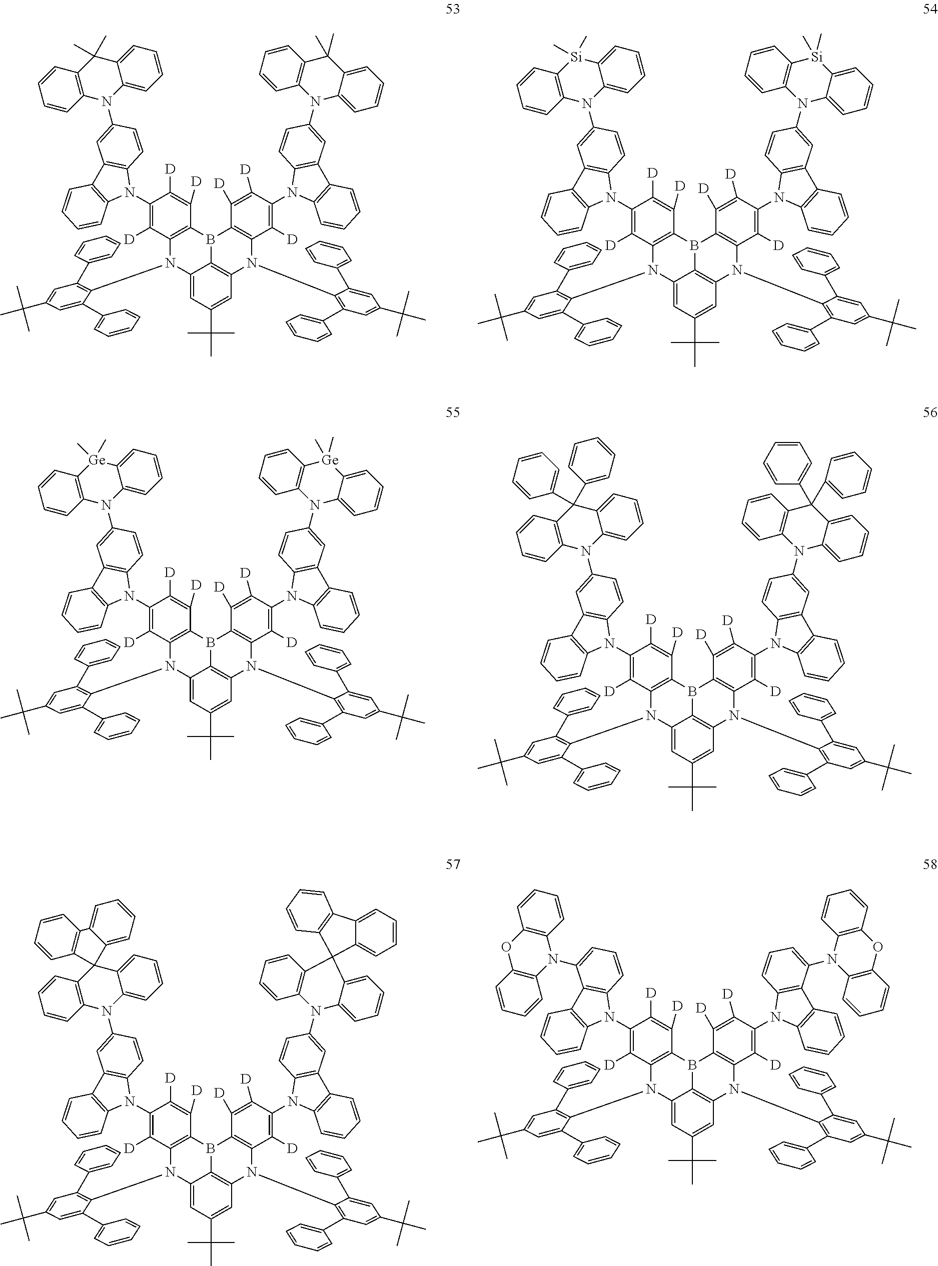

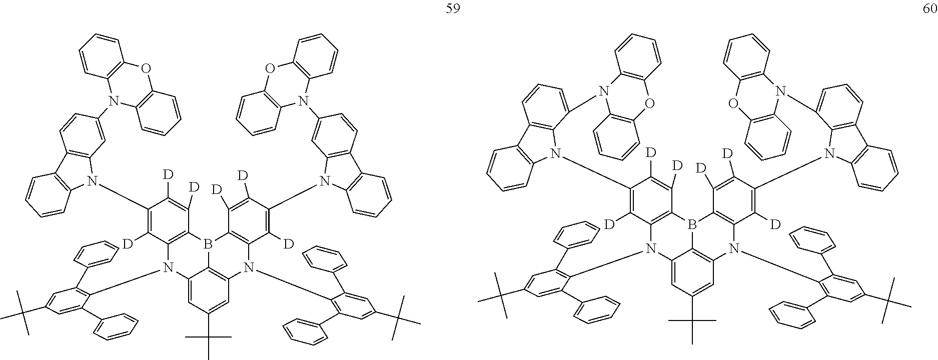 [SMILES: [2H]c1c([2H])c(-n2c3ccccc3c3ccc(N4c5ccccc5Oc5ccccc54)cc32)c([2H])c2c1B1c3c(cc(C(C)(C)C)cc3N(c3c(-c4ccccc4)cc(C(C)(C)C)cc3-c3ccccc3)c3c([2H])c(-n4c5ccccc5c5ccc(N6c7ccccc7Oc7ccccc76)cc54)c([2H])c([2H])c31)N2c1c(-c2ccccc2)cc(C(C)(C)C)cc1-c1ccccc1 ; [2H]c1c([2H])c(-n2c3ccccc3c3cccc(N4c5ccccc5Oc5ccccc54)c32)c([2H])c2c1B1c3c(cc(C(C)(C)C)cc3N(c3c(-c4ccccc4)cc(C(C)(C)C)cc3-c3ccccc3)c3c([2H])c(-n4c5ccccc5c5cccc(N6c7ccccc7Oc7ccccc76)c54)c([2H])c([2H])c31)N2c1c(-c2ccccc2)cc(C(C)(C)C)cc1-c1ccccc1]

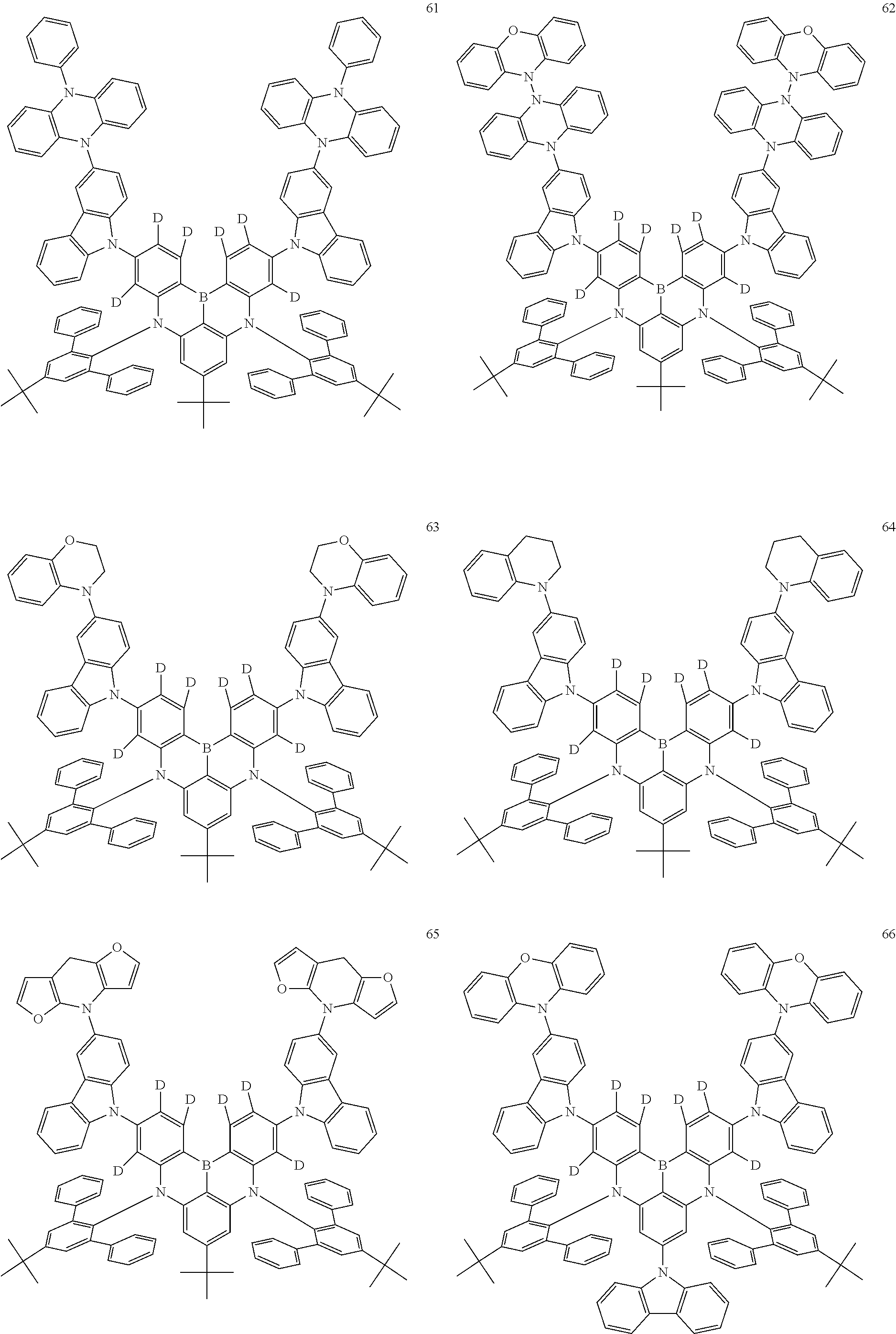

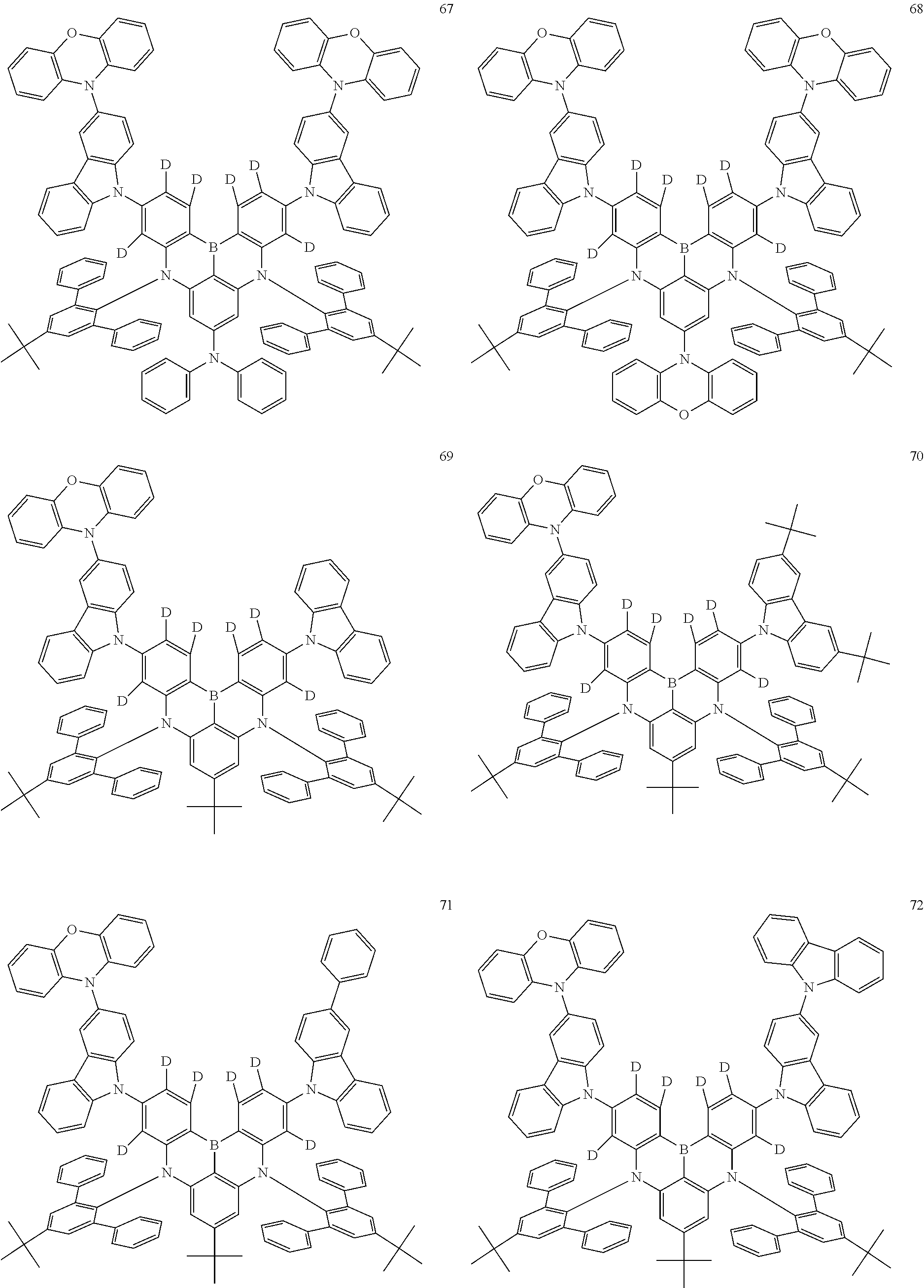

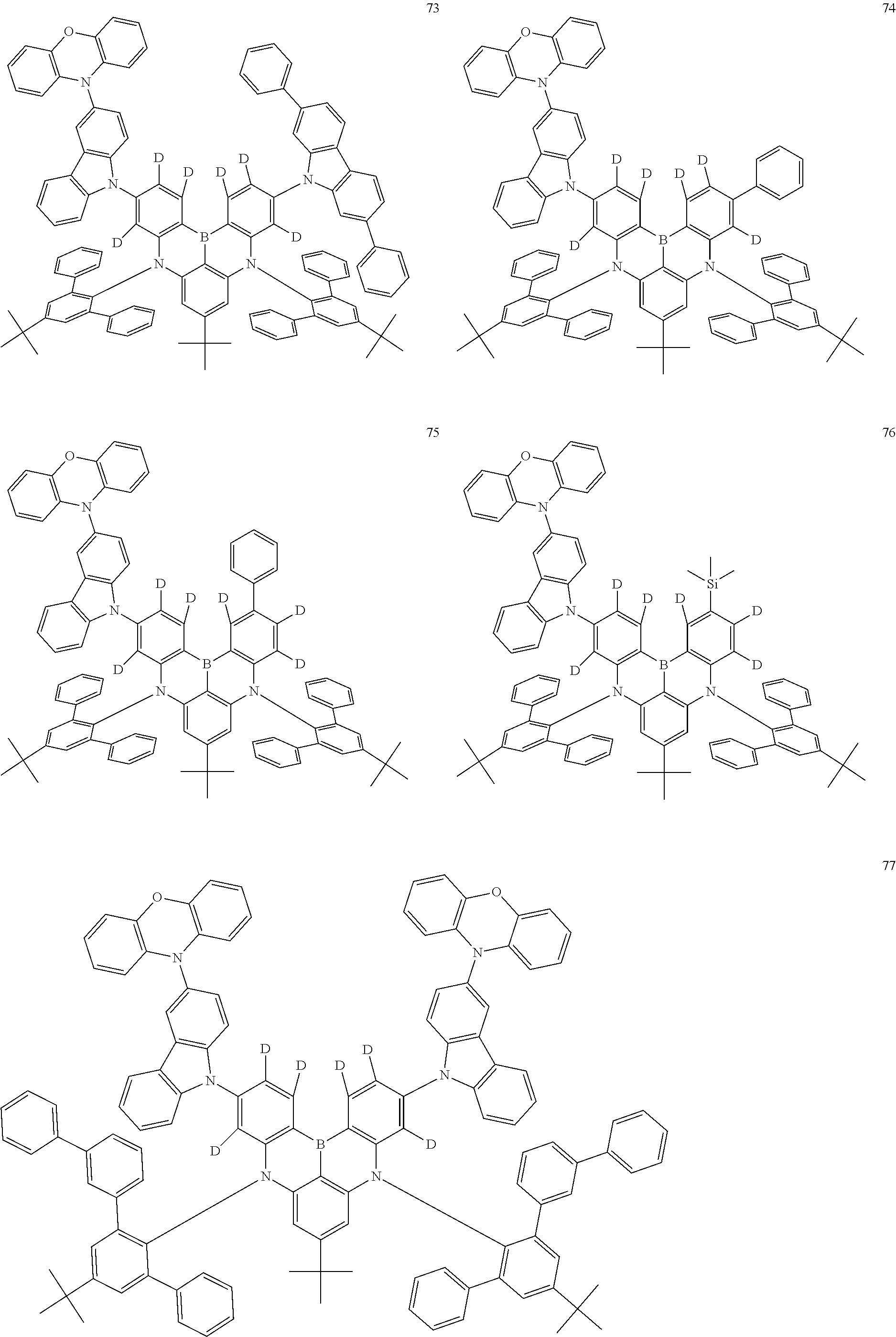

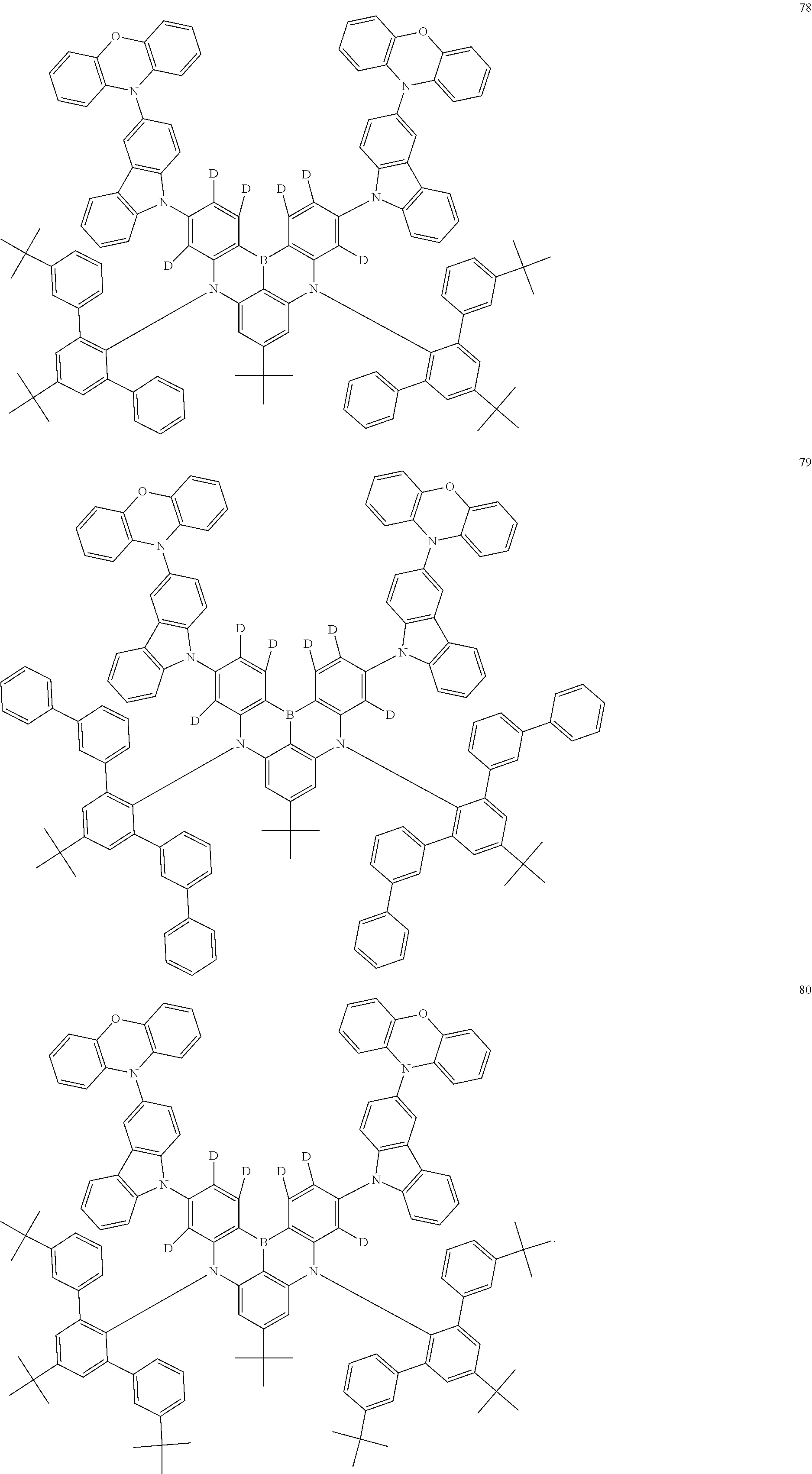

12. The light-emitting element of claim 1, wherein the light-emitting element further comprises:
a hole transport region between the first electrode and the emission layer; and
an electron transport region between the emission layer and the second electrode.

13. The light-emitting element of claim 1, wherein the emission layer is configured to emit delayed fluorescence.

14. The light-emitting element of claim 1, wherein the emission layer is configured to emit light having an emission center wavelength of 430 nm to 490 nm.

15. The light-emitting element of claim 1, wherein the emission layer further comprises at least one selected from among a second compound represented by Formula HT-1, and a third compound represented by Formula ET-1: 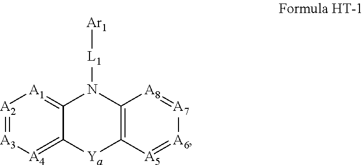
wherein, in Formula HT-1,
λ₁ to λ₈ are each independently N or CR₅₁,
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, CR₅₂R₅₃, or SiR₅₄R₅₅,
Ar₁ is a substituted or unsubstituted aryl group having 6 to 30 ring-forming carbon atoms, or a substituted or unsubstituted heteroaryl group having 2 to 30 ring-forming carbon atoms,
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and/or are bonded to an adjacent group to form a ring; 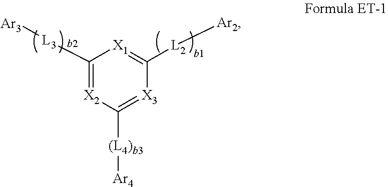
wherein, in Formula ET-1,
at least one selected from among X₁ to X₃ is N, and any remaining X₁ to X₃ are CR₅₆,
R₅₆ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
b₁ to b₃ are each independently an integer of 0 to 10,
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms,
if b₁ to b₃ are each an integer of 2 or more, L₂ to L₄ are each independently a substituted or unsubstituted arylene group having 6 to 30 ring-forming carbon atoms, or a substituted or unsubstituted heteroarylene group having 2 to 30 ring-forming carbon atoms, and
Ar₂ to Ar₄ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

16. The light-emitting element of claim 1, wherein the light-emitting element further comprises a fourth compound represented by Formula D-1: 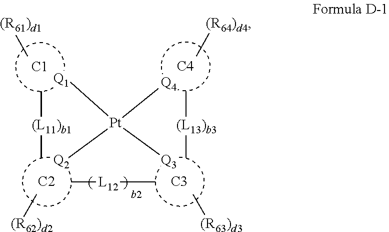
wherein, in Formula D-1,
Q₁ to Q₄ are each independently C or N,
C₁ to C₄ are each independently a substituted or unsubstituted hydrocarbon ring having 5 to 30 carbon atoms, or a substituted or unsubstituted heterocycle having 2 to 30 ring-forming carbon atoms,
L₁₁ to L₁₃ are each independently a direct linkage, 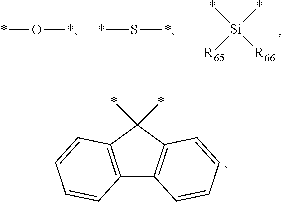
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b₁ to b₃ are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 ring-forming carbon atoms, a substituted or unsubstituted aryl group having 6 to 60 ring-forming carbon atoms, or a substituted or unsubstituted heteroaryl group having 2 to 60 ring-forming carbon atoms, and/or are bonded to an adjacent group to form a ring, and
d1 to d4 are each independently an integer of 0 to 4.

17. A display device comprising:
a base layer;
a circuit layer on the base layer; and
a display element layer on the circuit layer and comprising a light-emitting element,
wherein, the light-emitting element comprises
a first electrode,
a second electrode on the first electrode, and
an emission layer between the first electrode and the second electrode,
wherein the emission layer comprises a first compound represented by Formula 1,
wherein, the emission layer further comprises at least one selected from among a second compound represented by Formula HT-1, a third compound represented by Formula ET-1, and a fourth compound represented by Formula D-1:
